(19) United States
(12) Patent Application Publication
(10) Pub. No.: US 2025/0324848 A1
(43) Pub. Date: Oct. 16, 2025

(54) LIGHT-EMITTING DEVICE, AND ELECTRONIC APPARATUS AND ELECTRONIC EQUIPMENT INCLUDING THE SAME

(71) Applicant: Samsung Display Co., Ltd., Yongin-si (KR)

(72) Inventors: Hyunbin Park, Yongin-si (KR); Dongjun Kim, Yongin-si (KR); Hankyu Pak, Yongin-si (KR); Jinyoung Yun, Yongin-si (KR); Sanghyun Han, Yongin-si (KR)

(21) Appl. No.: 19/020,892

(22) Filed: Jan. 14, 2025

(30) Foreign Application Priority Data
Apr. 12, 2024 (KR) 10-2024-0049405

(51) Int. Cl. H10K 50/165; H10K 50/155; H10K 85/30; H10K 85/40; H10K 85/60

(52) U.S. Cl. CPC H10K 50/165; H10K 50/155; H10K 85/324; H10K 85/342; H10K 85/346; H10K 85/348; H10K 85/40; H10K 85/622; H10K 85/623; H10K 85/633; H10K 85/636; H10K 85/654; H10K 85/656; H10K 85/6572; H10K 85/6574; H10K 85/6576; H10K 85/658

(57) ABSTRACT

A light-emitting device is disclosed. The light-emitting device may include a first electrode, a second electrode that may face the first electrode, and an interlayer that may be arranged between the first electrode and the second electrode and that may include an emission layer. The interlayer may include a first compound represented by Formula 1 and a second compound represented by Formula 2:

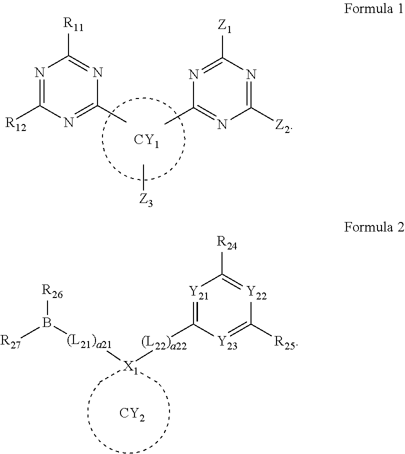

### CROSS-REFERENCE TO RELATED APPLICATION

The present application claims priority to and the benefit of Korean Patent Application No. 10-2024-0049405, filed on Apr. 12, 2024, in the Korean Intellectual Property Office, the entire disclosure of which is incorporated herein by reference.

### BACKGROUND

### 1. Field

One or more embodiments of the present disclosure relate to a light-emitting device, an electronic apparatus, and electronic equipment, wherein each of the electronic apparatus and the electronic equipment may include the light-emitting device.

### 2. Description of the Related Art

Self-emissive devices (for example, organic light-emitting devices) in light-emitting devices have relatively wide viewing angles, high contrast ratios, short response times, and/or excellent or suitable characteristics in terms of luminance, driving voltage, and/or response speed.

A light-emitting device may include a first electrode, a hole transport region, an emission layer, an electron transport region, and a second electrode, that may be arranged sequentially. Holes injected from the first electrode may move toward the emission layer through the hole transport region. Electrons injected from the second electrode may move toward the emission layer through the electron transport region. Carriers, such as holes and electrons, may recombine in the emission layer to produce excitons. If (e.g., when) the excitons drop from an excited state to a ground state, light may be generated.

### SUMMARY

One or more aspects of embodiments of the present disclosure are directed toward a light-emitting device having excellent or suitable driving voltage, luminescence efficiency, and lifespan and electronic apparatus and electronic equipment, each of the electronic apparatus and electronic equipment has improved or suitable display quality by including the light-emitting device.

Additional aspects of embodiments will be set forth in part in the description which follows and, in part, will be apparent from the description, or may be learned by practice of the presented embodiments of the present disclosure.

According to one or more embodiments, a light-emitting device may include a first electrode, a second electrode that may face the first electrode, and an interlayer that may be arranged between the first electrode and the second electrode and that may include an emission layer, wherein the interlayer may include a first compound represented by Formula 1 and a second compound represented by Formula 2:

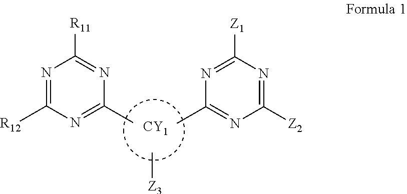

wherein, in Formula 1,
at least one selected from among Z₁ to Z₃ may be a group represented by Formula TZ:

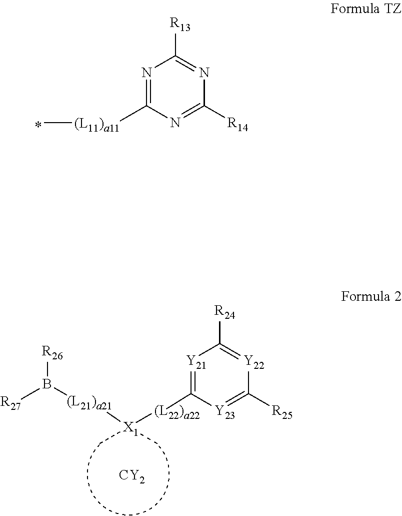

wherein, in Formula 1, Formula TZ, and Formula 2,
ring CY₁ may be a C₃-C₃₀ carbocyclic group unsubstituted or substituted with at least one R₁₀ₐ or a C₁-C₃₀ heterocyclic group unsubstituted or substituted with at least one R₁₀ₐ,
ring CY₂ may be a C₃-C₂₀ cycloalkyl group unsubstituted or substituted with at least one R₁₀ₐ,
X₁ may be a carbon atom (C) that forms a ring of CY₂, and X₁ may be bonded to four different atoms,
L₁₁, L₂₁, and L₂₂ may each independently be a single bond (e.g., a single covalent bond), a C₃-C₃₀ carbocyclic group unsubstituted or substituted with at least one R₁₀ₐ, or a C₁-C₃₀ heterocyclic group unsubstituted or substituted with at least one R₁₀ₐ,
a11, a21, and a22 may each independently be an integer of 1 to 5,
Y₂₁ may be N or C(R₂₁), Y₂₂ may be N or C(R₂₂), Y₂₃ may be N or C(R₂₃), and at least one selected from among Y₂₁ to Y₂₃ may be N,
Z₁ to Z₄, R₁ to R₁₄, and R₂₁ to R₂₇ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₂₆ and L₂₁ may optionally be bonded to each other via a direct bond (e.g., a single covalent bond) or *—O—*′ to form a C₁-C₃₀ heterocyclic group unsubstituted or substituted with at least one R₁₀ₐ,
R₂₇ and L₂₁ may optionally be bonded to each other via a direct bond (e.g., a single covalent bond) or *—O—*′ to form a C₁-C₃₀ heterocyclic group unsubstituted or substituted with at least one R₁₀ₐ,
R₂₆ and R₂₇ may optionally be bonded to each other via a direct bond (e.g., a single covalent bond) or *—O—*′ to form a C₁-C₃₀ heterocyclic group unsubstituted or substituted with at least one R₁₀ₐ,
R₁₀ₐ may be:
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(032), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be hydrogen, deuterium, —F, —Cl, —Br, —I, a hydroxyl group, a cyano group, or a nitro group, or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ may each independently be a binding site to a neighboring atom.

According to one or more embodiments, an electronic apparatus may include the light-emitting device according to one or more embodiments and a thin-film transistor that is electrically connected to the light-emitting device.

According to one or more embodiments, electronic equipment may include the light-emitting device as described in one or more embodiments, wherein the electronic equipment may be one selected from among a flat panel display, a curved display, a computer monitor, a medical monitor, a television, a billboard, a light for indoor or outdoor lighting and/or signaling (e.g., a light for indoor or outdoor lighting (e.g., an indoor or outdoor light) or a light for indoor or outdoor signaling (e.g., an indoor or outdoor light for signal)), a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual or augmented reality display, a vehicle, a video wall including multiple displays tiled together, a theater or stadium screen, a phototherapy device, a signboard, and/or the like.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic view of a light-emitting device according to one or more embodiments;

FIG. 2 is a schematic view of an electronic apparatus according to one or more embodiments;

FIG. 3 is a schematic view of an electronic apparatus according to another embodiment;

FIG. 4 is a schematic perspective view of electronic equipment including a light-emitting device according to one or more embodiments;

FIG. 5 is a diagram schematically illustrating the exterior of a vehicle as electronic equipment including a light-emitting device according to one or more embodiments; and

FIGS. 6A-6C are each a diagram schematically illustrating the interior of the vehicle of FIG. 5.

### DETAILED DESCRIPTION

Reference will now be made in more detail to one or more embodiments, examples of which are illustrated in the accompanying drawings, wherein like reference numerals refer to like elements throughout the present disclosure. In this regard, one or more embodiments of the present disclosure may have different forms and should not be construed as being limited to the embodiments set forth herein. For example, certain embodiments are merely described in one or more embodiments, by referring to the figures, to illustrate aspects of embodiments of the present disclosure.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element, such as a layer, film, region, or substrate, is referred to as being “on” another element, it may be directly on the other elements or intervening elements may also be present. In contrast, when an element is referred to as being “directly on” another element, there are no intervening elements present.

As used herein, the terms, “and/or” and “or” may include any and all combinations of one or more of the associated listed items.

In the context of the present disclosure and unless otherwise defined, the terms, “use,” “using,” and “used,” may be considered synonymous with the terms “utilize,” “utilizing,” and “utilized,” respectively.

As utilized herein, the term, “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations, or within ±30%, 20%, 10%, or 5% of the stated value.

It will be further understood that the terms, “comprise,” “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms, “a,” “an,” and “the,” are intended to include the plural forms as well, unless the context clearly indicates otherwise. Further, the utilization of “may” when describing embodiments of the present disclosure refers to “one or more embodiments of the present disclosure”.

Throughout the disclosure, the expression, “at least one selected from a and b,” may refer to only a, only b, or both a and b. Throughout the disclosure, the expression, “at least one selected from among a, b, and c,” may refer to only a, only b, only c, both a and b, both a and c, both b and c, all of a, b, and c, or variations thereof. Throughout the disclosure, the expression, “at least one selected from among A₁ to A₃,” may refer to only A₁, only A₂, only A₃, both A₁ and A₂, both A₁ and A₃, both A₂ and A₃, all of A₁, A₂, and A₃, or variations thereof.

As used herein, the terms, “substantially,” “about,” and similar terms are used as terms of approximation and not as terms of degree, and are intended to account for the inherent deviations in measured or calculated values that would be recognized by those of ordinary skill in the art. Also, any numerical range recited herein may be intended to include all sub-ranges of the same numerical precision subsumed within the recited range. For example, a range of “1.0 to 5.0” may be intended to include all subranges between (and including) the recited minimum value of 1.0 and the recited maximum value of 5.0, for example, having a minimum value equal to or greater than 1.0 and a maximum value equal to or less than 5.0, such as, for example, 1.2 to 4.7. Any maximum numerical limitation recited herein may be intended to include all lower numerical limitations subsumed therein, and any minimum numerical limitation recited in this specification is intended to include all higher numerical limitations subsumed therein. In one or more embodiments, Applicant reserves the right to amend this specification, including the claims, to expressly recite any sub-range subsumed within the ranges expressly recited herein.

As used herein, the terms, “combination thereof” and “combinations thereof,” may refer to a chemical combination (e.g., an alloy or chemical compound), a mixture, or a laminated structure of components.

According to one or more embodiments, a light-emitting device may include: a first electrode; a second electrode that may face the first electrode; and an interlayer that may be arranged between the first electrode and the second electrode and that may include an emission layer, wherein the interlayer may include: a first compound represented by Formula 1; and a second compound represented by Formula 2:

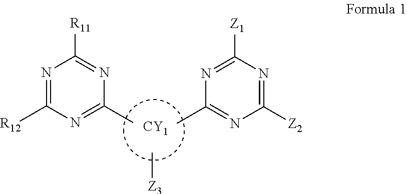

wherein, in Formula 1,
at least one selected from among Z₁ to Z₃ may be a group represented by Formula TZ:

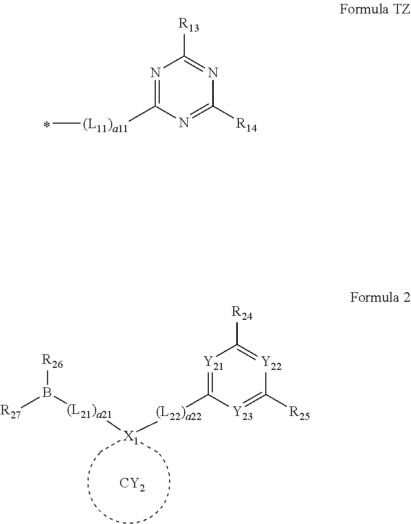

wherein, in Formula 1, Formula TZ, and Formula 2,
ring CY₁ may be a C₃-C₃₀ carbocyclic group unsubstituted or substituted with at least one R₁₀ₐ or a C₁-C₃₀ heterocyclic group unsubstituted or substituted with at least one R₁₀ₐ,
ring CY₂ may be a C₃-C₂₀ cycloalkyl group unsubstituted or substituted with at at least one R₁₀ₐ,
X₁ may be a carbon atom (C) that forms a ring of CY₂, and X₁ may be bonded to four different atoms,
L₁₁, L₂₁, and L₂₂ may each independently be a single bond (e.g., a single covalent bond), a C₃-C₃₀ carboxylic group unsubstituted or substituted with at least one R₁₀ₐ, or a C₁-C₃₀ heterocyclic group unsubstituted or substituted with at least one R₁₀ₐ,
a11, a21, and a22 may each independently be an integer of 1 to 5,
Y₂₁ may be N or C(R₂₁), Y₂₂ may be N or C(R₂₂), Y₂₃ may be N or C(R₂₃), and at least one selected from among Y₂₁ to Y₂₃ may be N,
Z₁ to Z₃, R₁₁ to R₁₄, and R₂₁ to R₂₇ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-Coo carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₂₆ and L₂₁ may optionally be bonded to each other via a direct bond (e.g., a single covalent bond) or *—O—*′ to form a C₁-C₆₀ heterocyclic group unsubstituted or substituted with at least one R₁₀ₐ,
R₂₇ and L₂₁ may optionally be bonded to each other via a direct bond (e.g., a single covalent bond) or *—O—*′ to form a C₁-C₆₀ heterocyclic group unsubstituted or substituted with at least one R₁₀ₐ,
R₂₆ and R₂₇ may optionally be bonded to each other via a direct bond (e.g., a single covalent bond) or *—O—*′ to form a C₁-C₆₀ heterocyclic group unsubstituted or substituted with at least one R₁₀ₐ,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂)(Q₂₃), —N(Q₂₁)(Q₂), —B(Q₂₁)(Q₂), —C(═O)(Q₂₁), —S(═O)₂(Q₂₁), —P(═O)(Q₂₁)(Q₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ may each independently be a binding site to a neighboring atom.

The light-emitting device may include both (e.g., simultaneously) the first compound and the second compound. In one or more embodiments, the light-emitting device according to one or more embodiments of the present disclosure may be clearly different from a light-emitting device which includes the first compound and does not include the second compound or a light-emitting device which does not include the first compound and includes the second compound. In one or more embodiments, the light-emitting device according to one or more embodiments may be clearly different from a light-emitting device that does not include either the first compound or the second compound.

The term, “interlayer,” as used herein refers to a single layer and/or all of multiple layers arranged between the first electrode and the second electrode of the light-emitting device.

The interlayer may further include: a hole transport region arranged between the first electrode and the emission layer; and an electron transport region arranged between the emission layer and the second electrode.

The hole transport region may include a hole injection layer, a hole transport layer, an emission auxiliary layer, an electron-blocking layer, or any combination thereof.

The electron transport region may include a hole-blocking layer, an electron transport layer, an electron injection layer, or any combination thereof. For example, the electron transport region may include a hole-blocking layer arranged on the emission layer, an electron transport layer arranged on the hole-blocking layer, and an electron injection layer arranged between the electron transport layer and the second electrode.

In one or more embodiments, the first compound and the second compound may be in the same (e.g., substantially the same) layer of the interlayer. For example, the first compound and the second compound may be mixed to be in the same (e.g., substantially the same) layer of the interlayer.

In one or more embodiments, the electron transport region may include the first compound and the second compound. For example, the electron transport layer may include the first compound and the second compound. For example, the first compound and the second compound may be mixed to be in the electron transport layer.

Throughout one or more embodiments of the present disclosure, the expression, “an interlayer and/or an electron transport layer may include a first compound represented by Formula 1 and a second compound represented by Formula 2,” may be construed as meaning that “an interlayer and/or an electron transport layer may include i) one kind of first compound represented by Formula 1 and one kind of second compound represented by Formula 2, ii) two different kinds of first compounds represented by Formula 1 and one kind of second compound represented by Formula 2, and iii) one kind of first compound represented by Formula 1 and two kinds of second compound represented by Formula 2.”

In one or more embodiments, the emission layer may emit blue light. The blue light may be deep blue light. For example, a maximum emission wavelength of the blue light may be in a range of about 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm. The CIEx coordinate of the blue light may be in a range of about 0.125 to about 0.140 or about 0.130 to about 0.140. The CIEy coordinate of the blue light may be in a range of about 0.120 to about 0.210.

In one or more embodiments, the interlayer (for example, the emission layer) may include a hole-transporting host that may include a group represented by Formula 3, an electron-transporting host that may include at least one π electron-deficient nitrogen-containing C₁-C₆₀ heterocyclic group, a sensitizer that may include a transition metal, a dopant that may include at least one cyclic group including boron and nitrogen each acting or serving as a ring-forming atom, or any combination thereof, wherein the first compound, the second compound, the hole-transporting host, the electron-transporting host, the sensitizer, and the dopant may be different from each other:

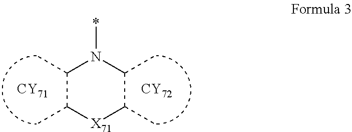

wherein, in Formula 3,
ring CY₇₁ and ring CY₇₂ may each independently be a π electron-rich C₃-C₆₀ cyclic group or a pyridine group,
X₇₁ may be a single bond (e.g., a single covalent bond) or a linking group including oxygen (O), sulfur (S), nitrogen (N), boron (B), carbon (C), silicon (Si), or any combination thereof, and
* may be a binding site to any atom in the remaining part other than Formula 3 in the hole-transporting host.

The hole-transporting host may be represented by any one selected from among Formulae 3-1 to 3-5:

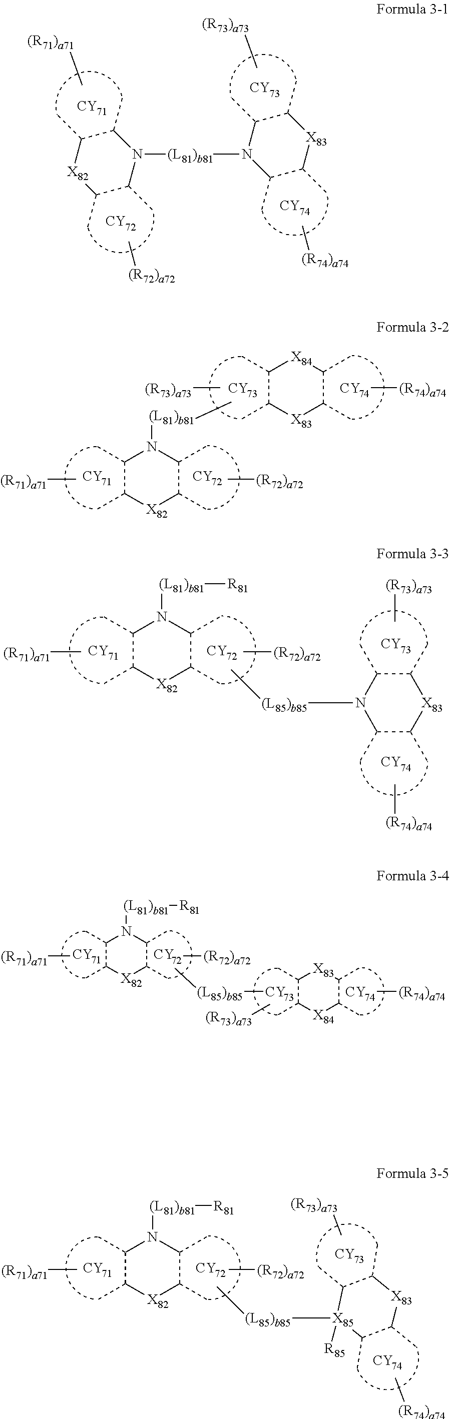

wherein, in Formulae 3-1 to 3-5,
ring CY₇₁ to ring CY₇₄ may each independently be a π electron-rich C₃-C₆₀ cyclic group or a pyridine group,
X₈₂ may be a single bond (e.g., a single covalent bond), O, S, N-[(L₈₂)_{b82}-R₈₂], C(R₈₂ₐ)(R_{82b}), or Si(R₈₂ₐ)(R_{82b}),
X₈₃ may be a single bond (e.g., a single covalent bond), O, S, N-[(L₈₃)_{b83}-R₈₃], C(R₈₃ₐ)(R_{83b}), or Si(R₈₃ₐ)(R_{83b}),
X₈₄ may be O, S, N-[(L₈₄)_{b84}-R₈₄], C(R₈₄ₐ)(R_{84b}), or Si(R₈₄ₐ)(R_{84b}),
X₈₅ may be C or Si,
L₈₁ to L₈₅ may each independently be a single bond (e.g., a single covalent bond), *—C(Q₄)(Q₅)-*′, *—Si(Q₄)(Q₅)-*′, a π electron-rich C₃-C₆₀ cyclic group unsubstituted or substituted with at least one R₁₀ₐ, or a pyridine group unsubstituted or substituted with at least one R₁₀ₐ, wherein Q₄ and Q₅ may each independently be the same (e.g., substantially the same) as described in connection with Q₁,
b81 to b85 may each independently be an integer of 1 to 5,
R₇₁ to R₇₄, R₈₁ to R₈₅, R₈₂ₐ, R_{82b}, R₈₃ₐ, R_{83b}, R₈₄ₐ, and R_{84b} may each independently be the same (e.g., substantially the same) as described in connection with R₁₁,
a71 to a74 may each independently be an integer of 0 to 20, and
R₁₀ₐ may be the same (e.g., substantially the same) as described in one or more embodiments.

The hole-transporting host may be any one selected from among Compounds HTH1 to HTH50:

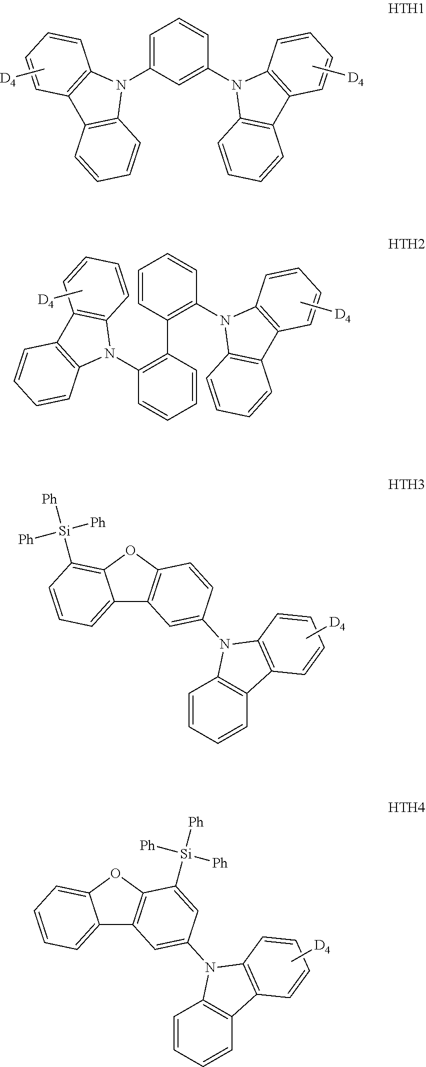

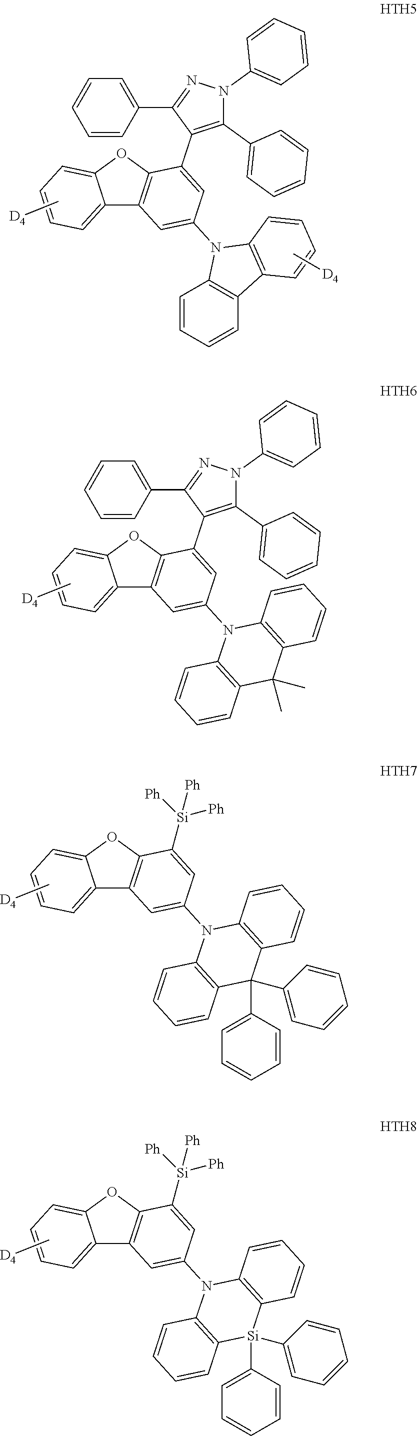

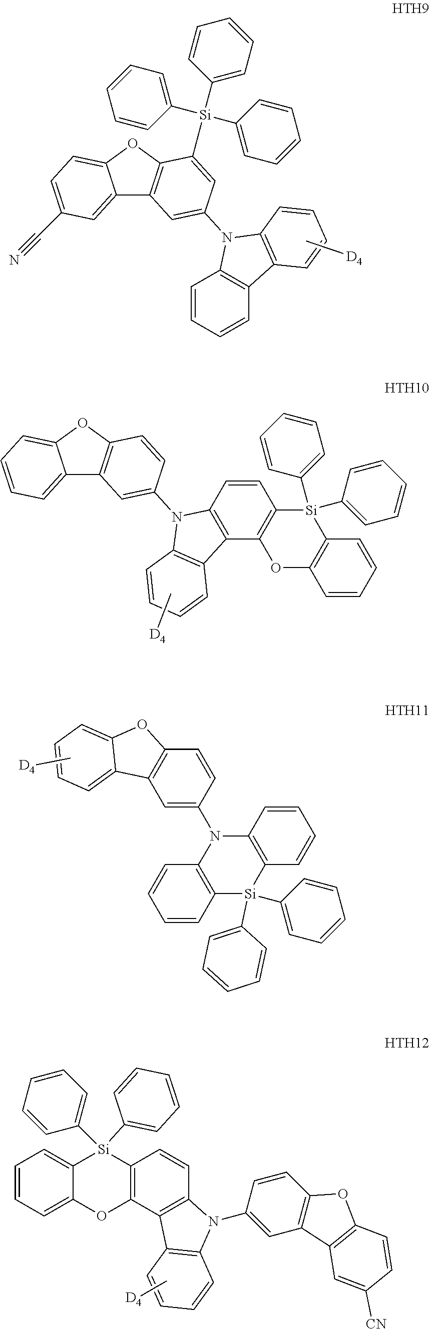

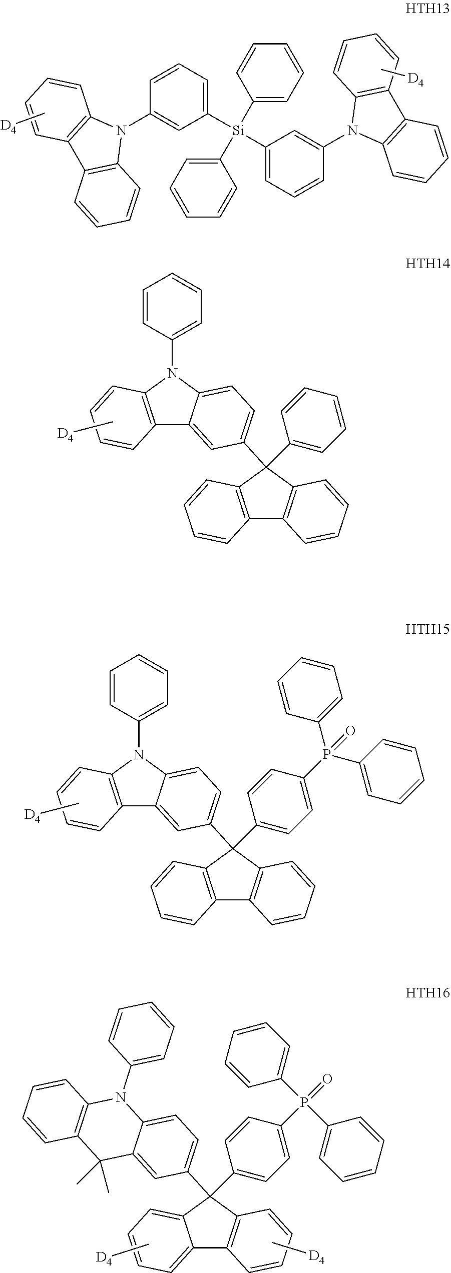

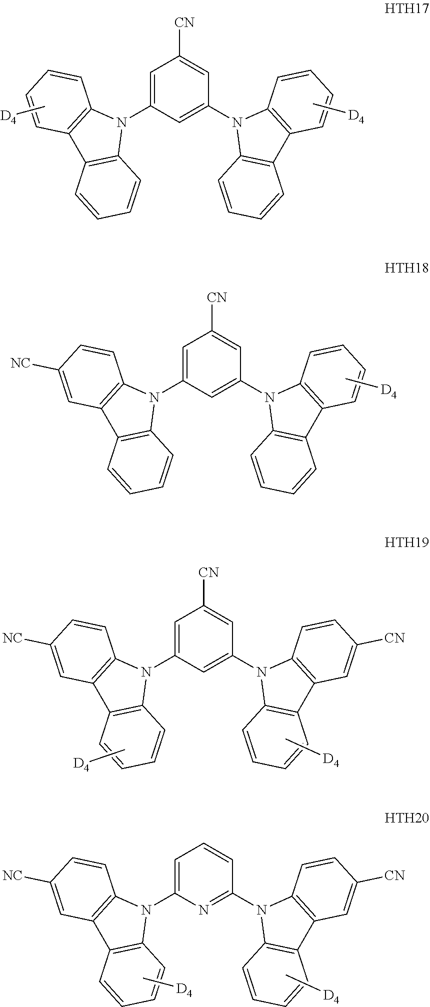

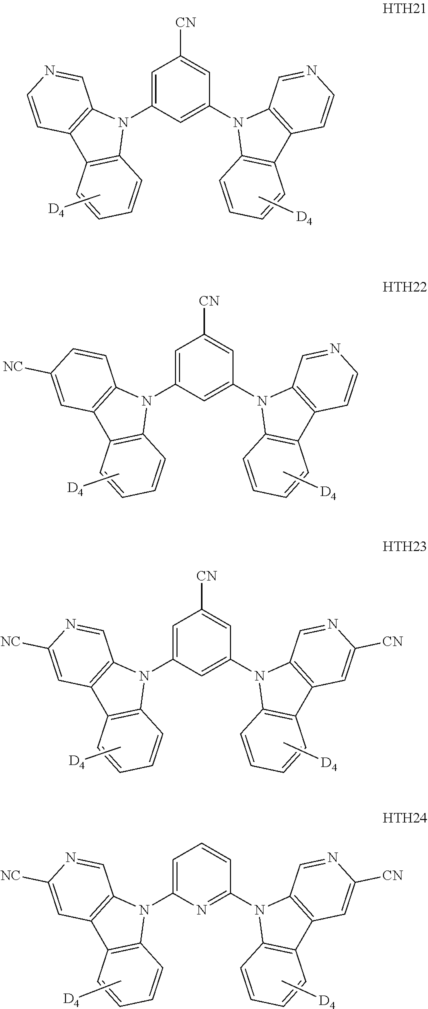

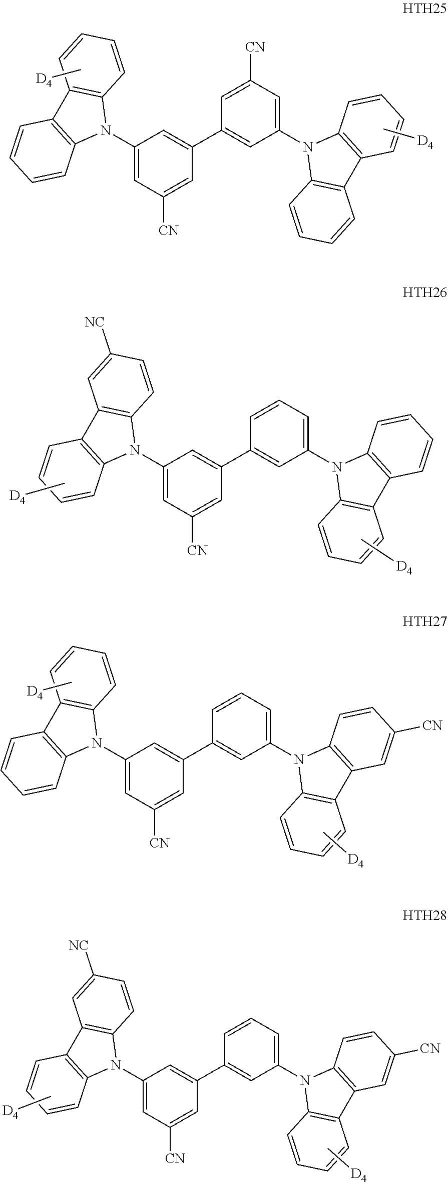

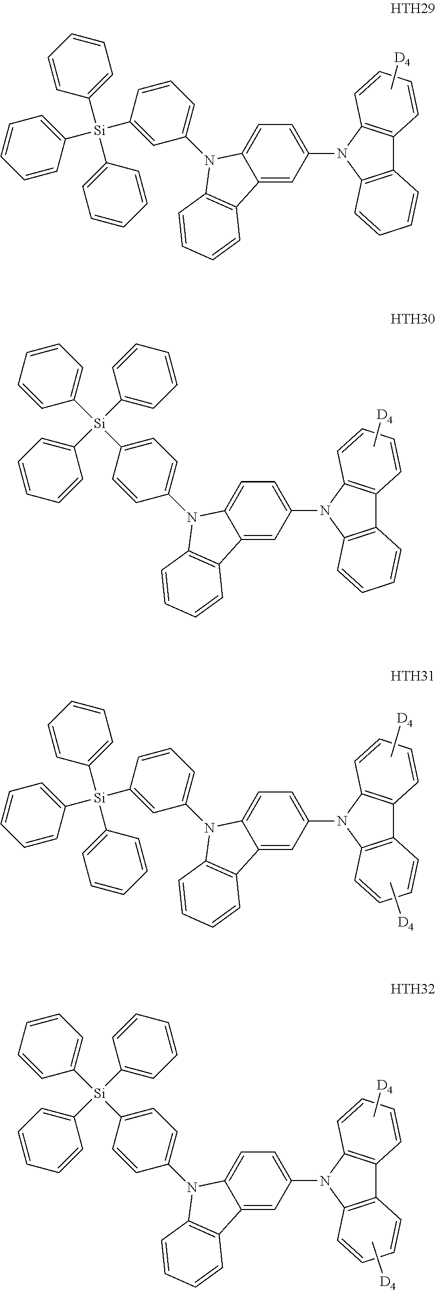

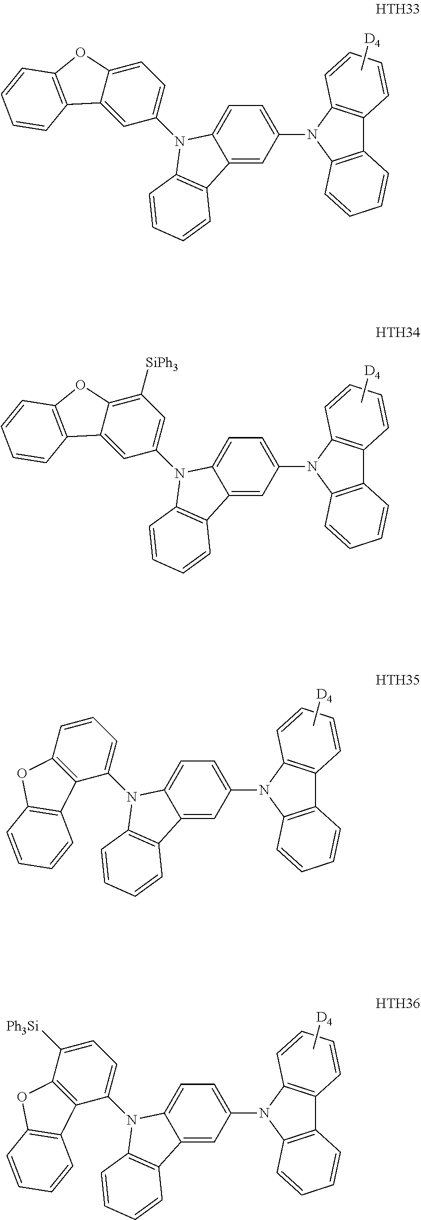

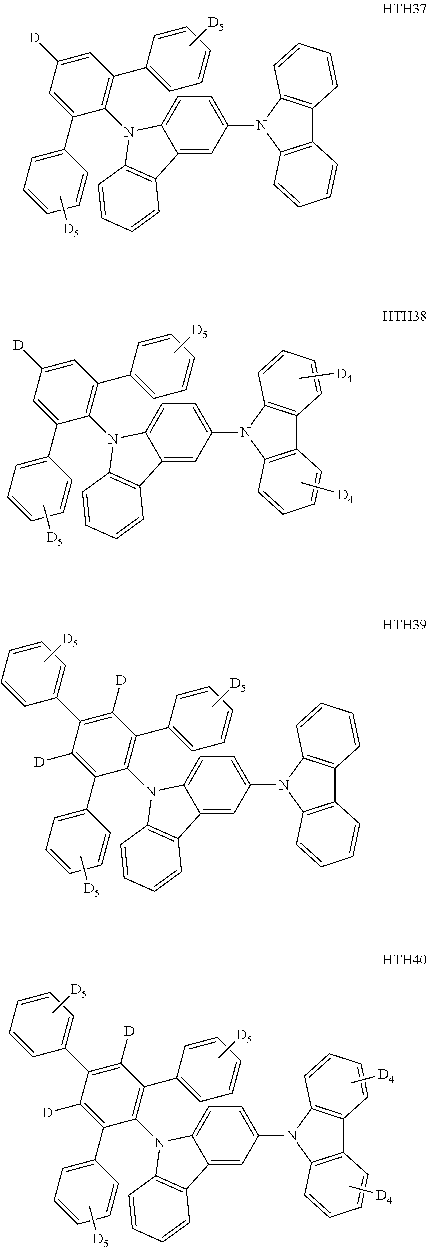

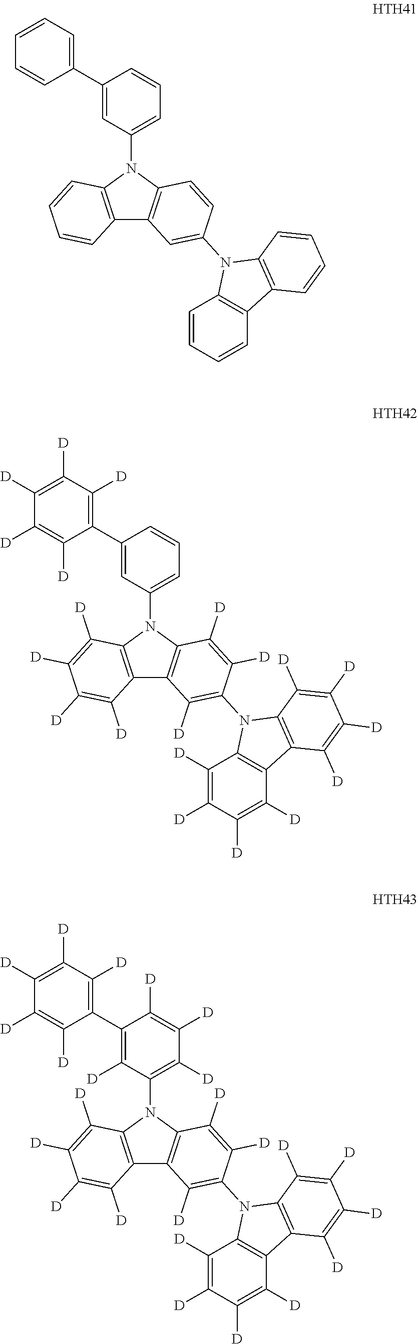 [SMILES: c1ccc(-c2cccc(-n3c4ccccc4c4cc(-n5c6ccccc6c6ccccc65)ccc43)c2)cc1 ; [2H]c1c([2H])c([2H])c(-c2cccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H] ; [2H]c1c([2H])c([2H])c(-c2c([2H])c([2H])c([2H])c(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2[2H])c([2H])c1[2H]]

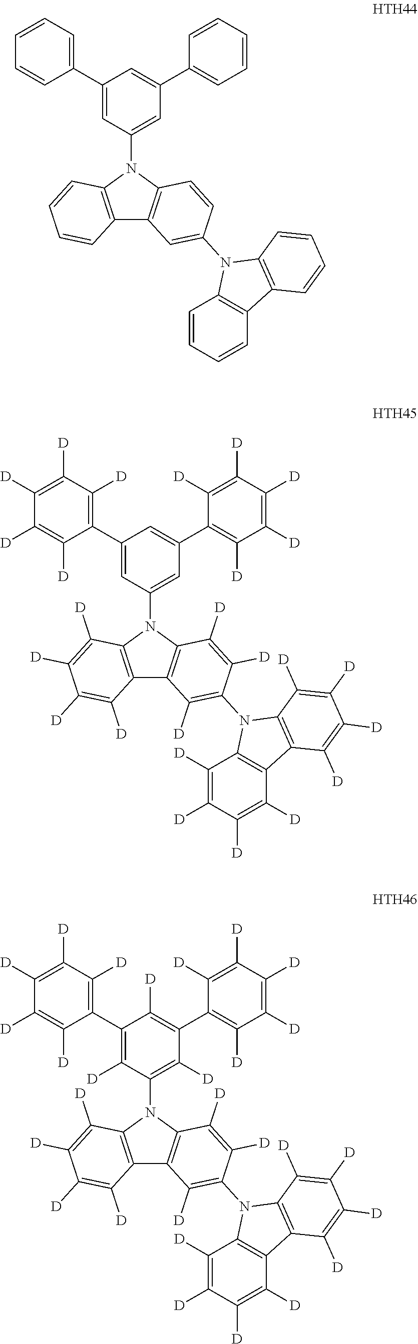

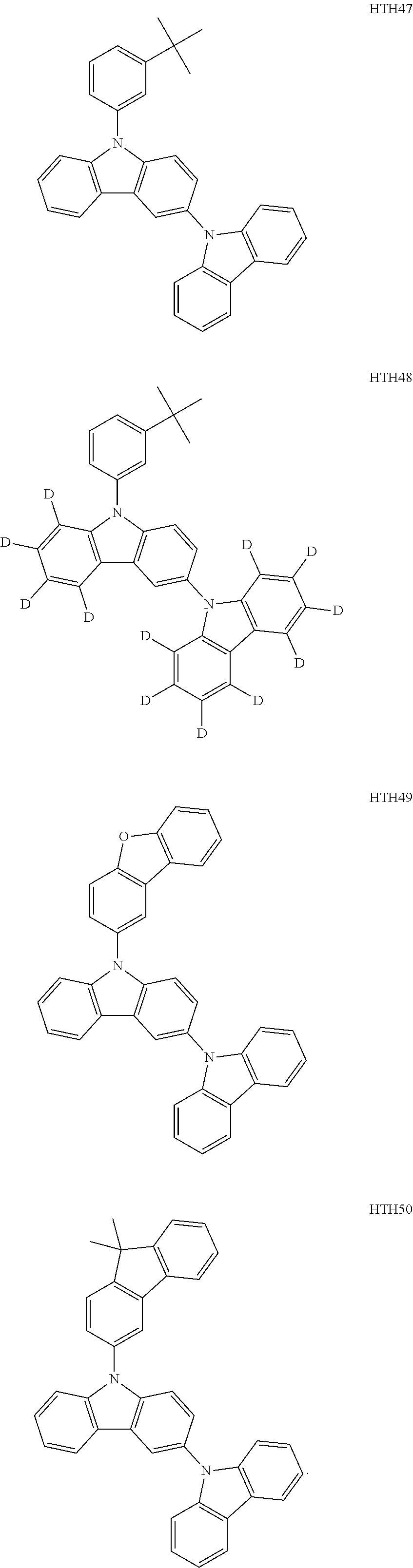 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21]

The electron-transporting hose may be represented by Formula 4:

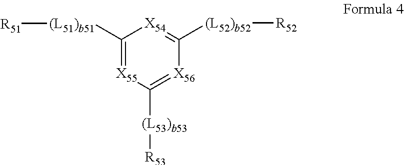

wherein, in Formula 4,
L₅₁ to L₅₃ may each independently be a single bond (e.g., a single covalent bond), a C₃-C₆₀ carbocyclic group unsubstituted or substituted with at least one R₁₀ₐ, or a C₁-C₆₀ heterocyclic group unsubstituted or substituted with at least one R₁₀ₐ,
b51 to b53 may each independently be an integer of 1 to 5,
X₅₄ may be N or C(R₅₄), X₅₅ may be N or C(R₅₅), X₅₆ may be N or C(R₅₆), and at least one selected from among X₅₄ to X₅₆ may be N,
R₅₁ to R₅₆ may each independently be the same (e.g., substantially the same) as described in connection with R₁₁, and
R₁₀ₐ may be the same (e.g., substantially the same) as described in one or more embodiments.

The electron-transporting host may be any one selected from among Compounds ETH1 to ETH102:

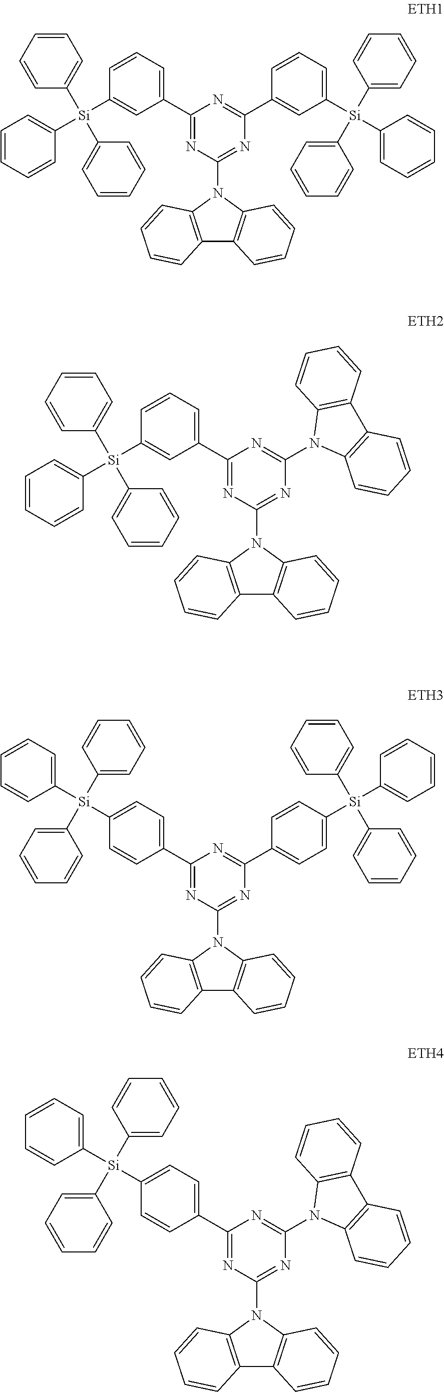 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

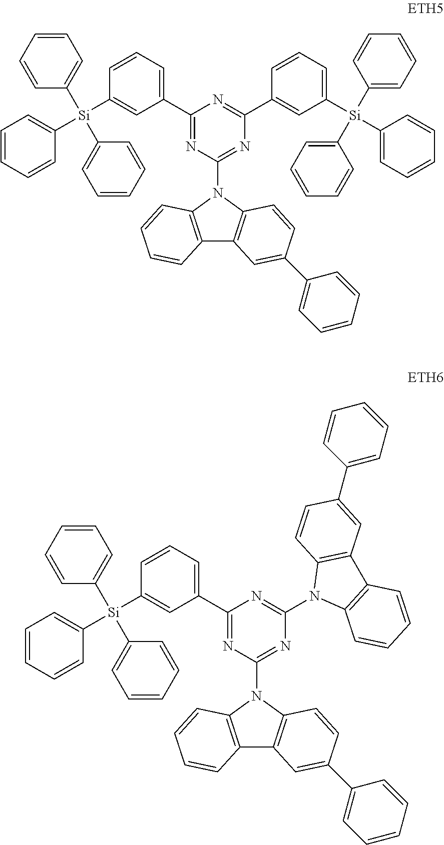 [SMILES: c1ccc(-c2ccc3c(c2)c2ccccc2n3-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1]

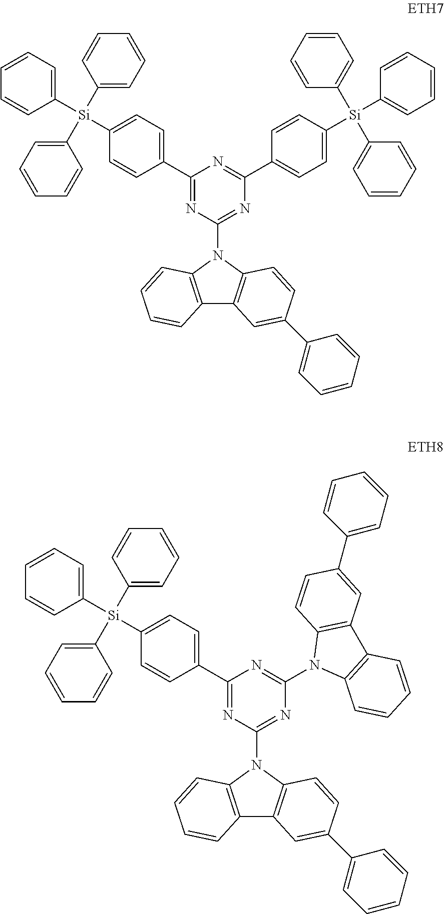 [SMILES: c1ccc(-c2ccc3c(c2)c2ccccc2n3-c2nc(-c3ccc([Si](c4ccccc4)(c4ccccc4)c4ccccc4)cc3)nc(-c3ccc([Si](c4ccccc4)(c4ccccc4)c4ccccc4)cc3)n2)cc1 ; c1ccc(-c2ccc3c(c2)c2ccccc2n3-c2nc(-c3ccc([Si](c4ccccc4)(c4ccccc4)c4ccccc4)cc3)nc(-n3c4ccccc4c4cc(-c5ccccc5)ccc43)n2)cc1]

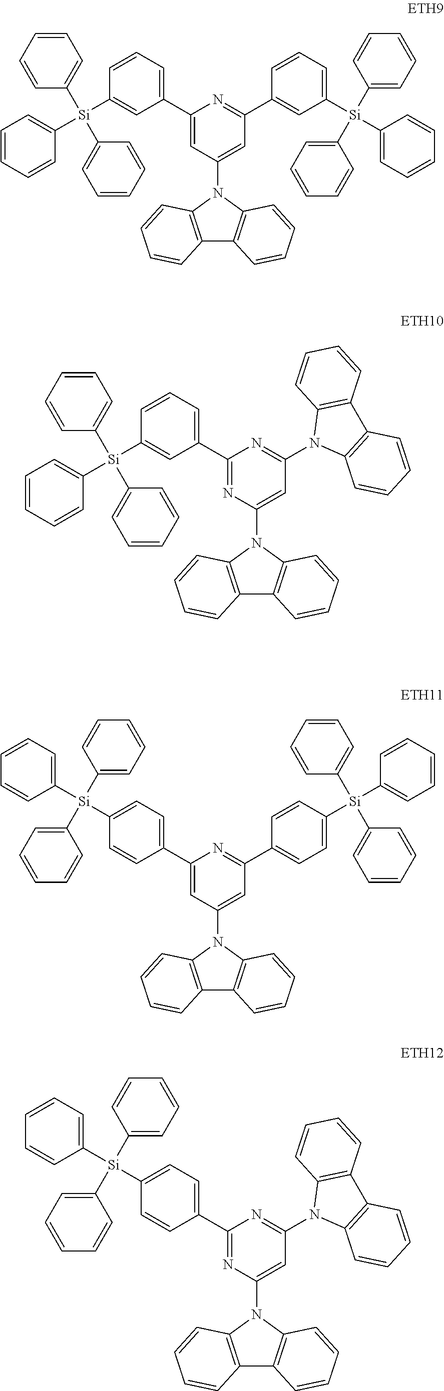 [SMILES: c1ccc([Si](c2ccccc2)(c2ccccc2)c2cccc(-c3cc(-n4c5ccccc5c5ccccc54)cc(-c4cccc([Si](c5ccccc5)(c5ccccc5)c5ccccc5)c4)n3)c2)cc1 ; c1ccc([Si](c2ccccc2)(c2ccccc2)c2cccc(-c3nc(-n4c5ccccc5c5ccccc54)cc(-n4c5ccccc5c5ccccc54)n3)c2)cc1 ; c1ccc([Si](c2ccccc2)(c2ccccc2)c2ccc(-c3cc(-n4c5ccccc5c5ccccc54)cc(-c4ccc([Si](c5ccccc5)(c5ccccc5)c5ccccc5)cc4)n3)cc2)cc1 ; c1ccc([Si](c2ccccc2)(c2ccccc2)c2ccc(-c3nc(-n4c5ccccc5c5ccccc54)cc(-n4c5ccccc5c5ccccc54)n3)cc2)cc1]

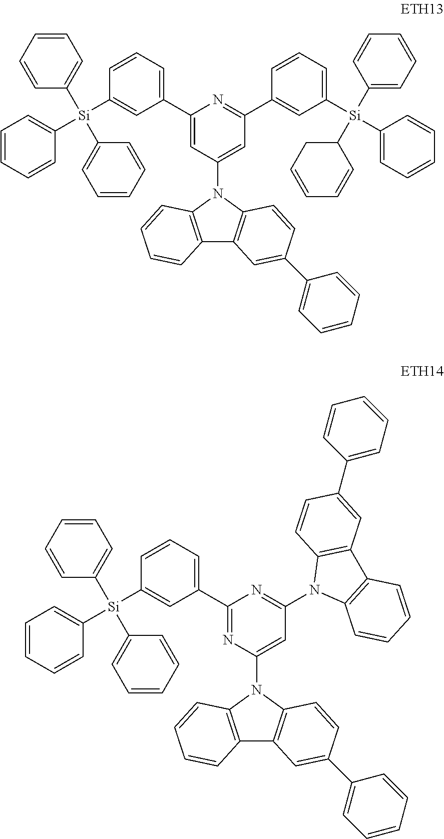 [SMILES: C1=CCC([Si](c2ccccc2)(c2ccccc2)c2cccc(-c3cc(-n4c5ccccc5c5cc(-c6ccccc6)ccc54)cc(-c4cccc([Si](c5ccccc5)(c5ccccc5)c5ccccc5)c4)n3)c2)C=C1 ; c1ccc(-c2ccc3c(c2)c2ccccc2n3-c2cc(-n3c4ccccc4c4cc(-c5ccccc5)ccc43)nc(-c3cccc([Si](c4ccccc4)(c4ccccc4)c4ccccc4)c3)n2)cc1]

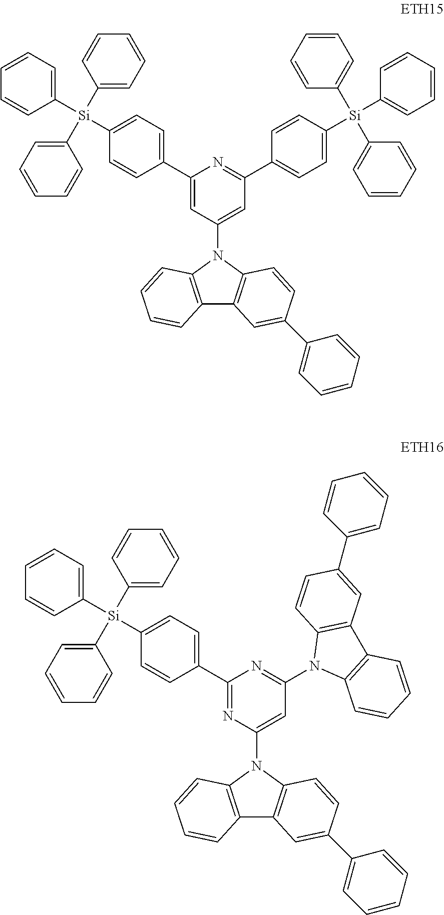 [SMILES: c1ccc(-c2ccc3c(c2)c2ccccc2n3-c2cc(-c3ccc([Si](c4ccccc4)(c4ccccc4)c4ccccc4)cc3)nc(-c3ccc([Si](c4ccccc4)(c4ccccc4)c4ccccc4)cc3)c2)cc1 ; c1ccc(-c2ccc3c(c2)c2ccccc2n3-c2cc(-n3c4ccccc4c4cc(-c5ccccc5)ccc43)nc(-c3ccc([Si](c4ccccc4)(c4ccccc4)c4ccccc4)cc3)n2)cc1]

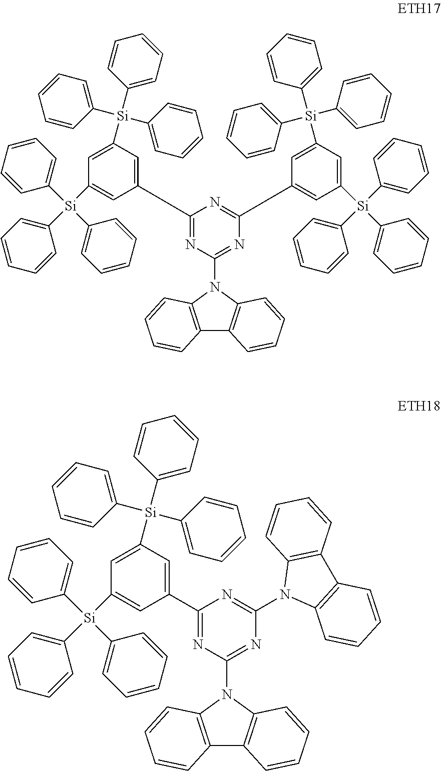 [SMILES: c1ccc([Si](c2ccccc2)(c2ccccc2)c2cc(-c3nc(-c4cc([Si](c5ccccc5)(c5ccccc5)c5ccccc5)cc([Si](c5ccccc5)(c5ccccc5)c5ccccc5)c4)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1]

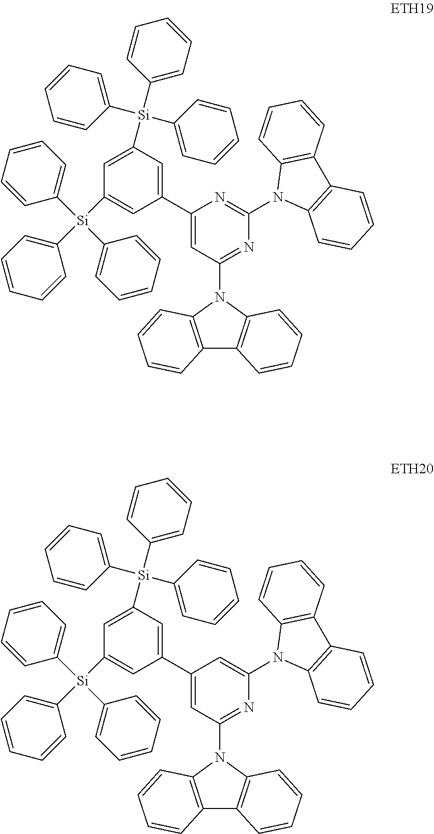 [SMILES: c1ccc([Si](c2ccccc2)(c2ccccc2)c2cc(-c3cc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3cc(-n4c5ccccc5c5ccccc54)nc(-n4c5ccccc5c5ccccc54)c3)cc([Si](c3ccccc3)(c3ccccc3)c3ccccc3)c2)cc1]

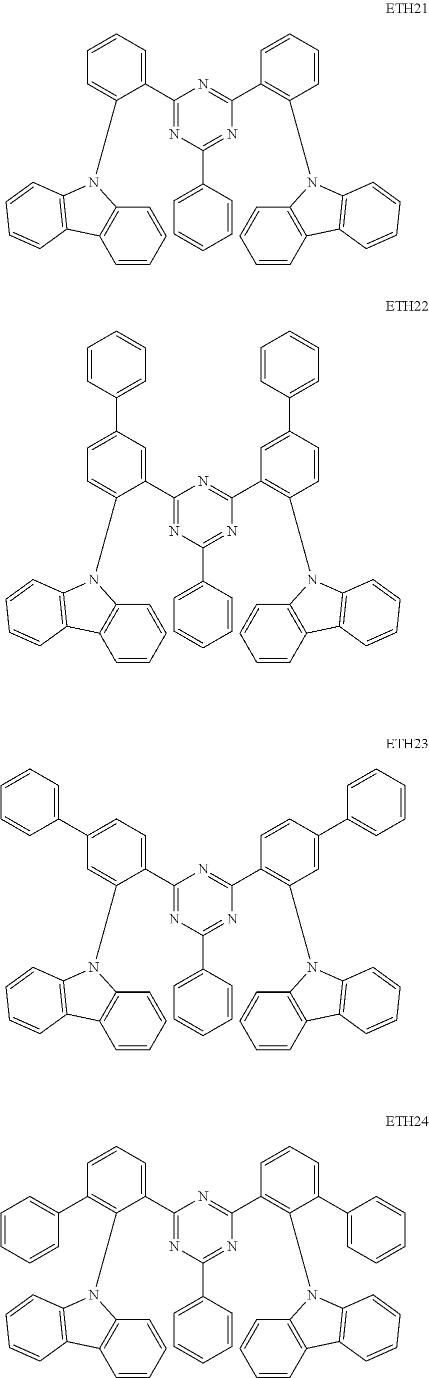 [SMILES: c1ccc(-c2nc(-c3ccccc3-n3c4ccccc4c4ccccc43)nc(-c3ccccc3-n3c4ccccc4c4ccccc43)n2)cc1 ; c1ccc(-c2ccc(-n3c4ccccc4c4ccccc43)c(-c3nc(-c4ccccc4)nc(-c4cc(-c5ccccc5)ccc4-n4c5ccccc5c5ccccc54)n3)c2)cc1 ; c1ccc(-c2ccc(-c3nc(-c4ccccc4)nc(-c4ccc(-c5ccccc5)cc4-n4c5ccccc5c5ccccc54)n3)c(-n3c4ccccc4c4ccccc43)c2)cc1 ; c1ccc(-c2nc(-c3cccc(-c4ccccc4)c3-n3c4ccccc4c4ccccc43)nc(-c3cccc(-c4ccccc4)c3-n3c4ccccc4c4ccccc43)n2)cc1]

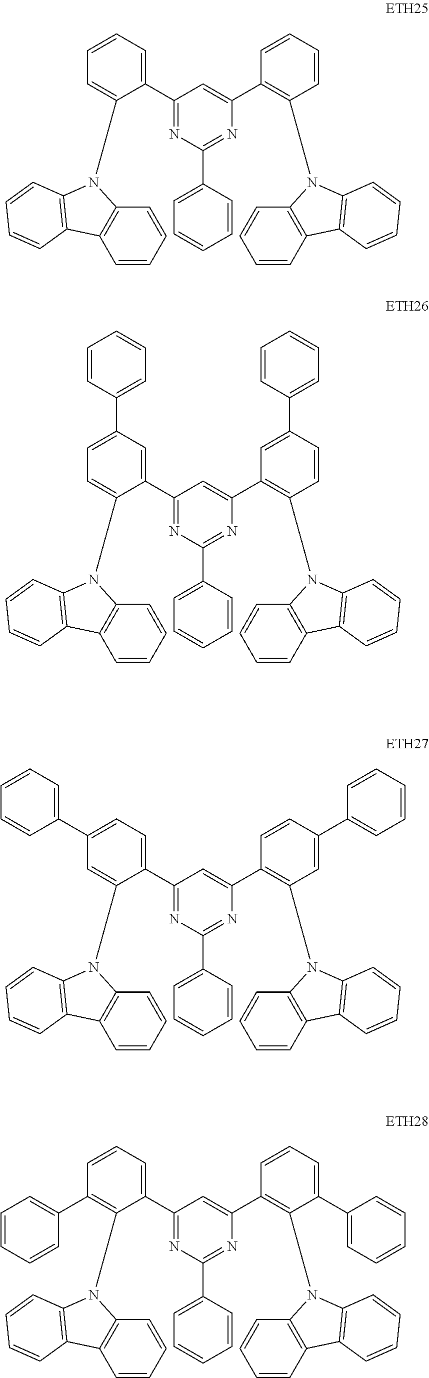 [SMILES: c1ccc(-c2nc(-c3ccccc3-n3c4ccccc4c4ccccc43)cc(-c3ccccc3-n3c4ccccc4c4ccccc43)n2)cc1 ; c1ccc(-c2ccc(-n3c4ccccc4c4ccccc43)c(-c3cc(-c4cc(-c5ccccc5)ccc4-n4c5ccccc5c5ccccc54)nc(-c4ccccc4)n3)c2)cc1 ; c1ccc(-c2ccc(-c3cc(-c4ccc(-c5ccccc5)cc4-n4c5ccccc5c5ccccc54)nc(-c4ccccc4)n3)c(-n3c4ccccc4c4ccccc43)c2)cc1 ; c1ccc(-c2nc(-c3cccc(-c4ccccc4)c3-n3c4ccccc4c4ccccc43)cc(-c3cccc(-c4ccccc4)c3-n3c4ccccc4c4ccccc43)n2)cc1]

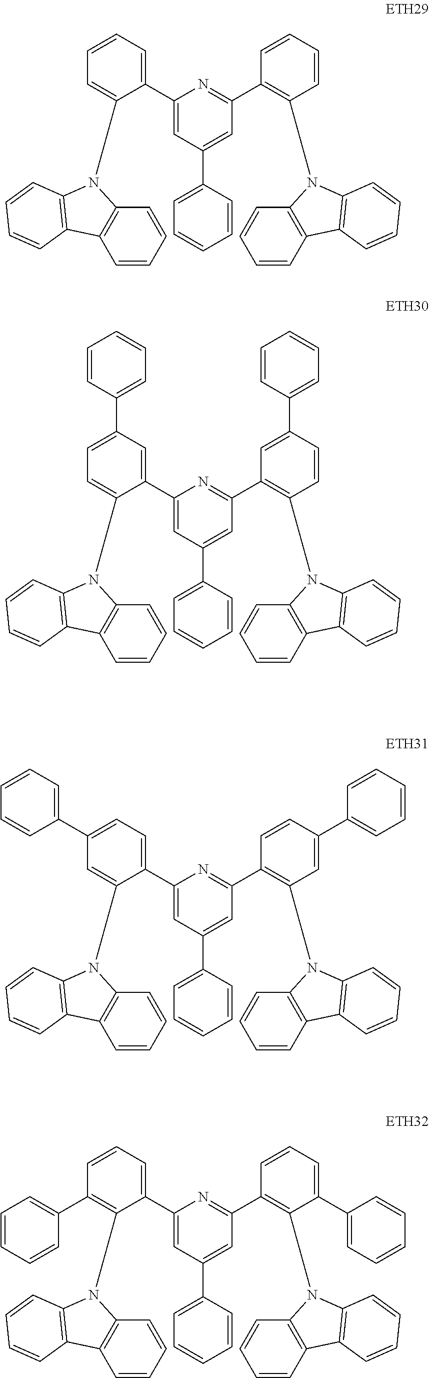 [SMILES: c1ccc(-c2cc(-c3ccccc3-n3c4ccccc4c4ccccc43)nc(-c3ccccc3-n3c4ccccc4c4ccccc43)c2)cc1 ; c1ccc(-c2cc(-c3cc(-c4ccccc4)ccc3-n3c4ccccc4c4ccccc43)nc(-c3cc(-c4ccccc4)ccc3-n3c4ccccc4c4ccccc43)c2)cc1 ; c1ccc(-c2cc(-c3ccc(-c4ccccc4)cc3-n3c4ccccc4c4ccccc43)nc(-c3ccc(-c4ccccc4)cc3-n3c4ccccc4c4ccccc43)c2)cc1 ; c1ccc(-c2cc(-c3cccc(-c4ccccc4)c3-n3c4ccccc4c4ccccc43)nc(-c3cccc(-c4ccccc4)c3-n3c4ccccc4c4ccccc43)c2)cc1]

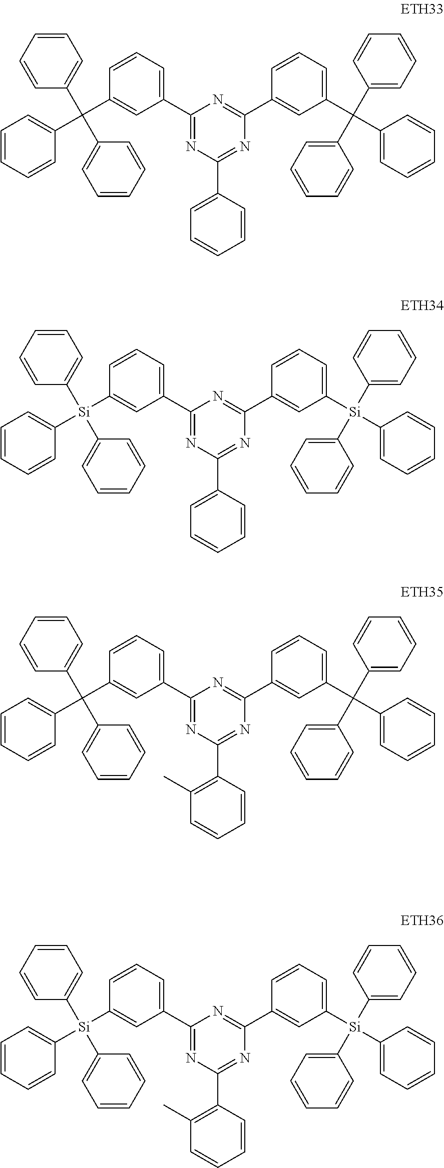 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

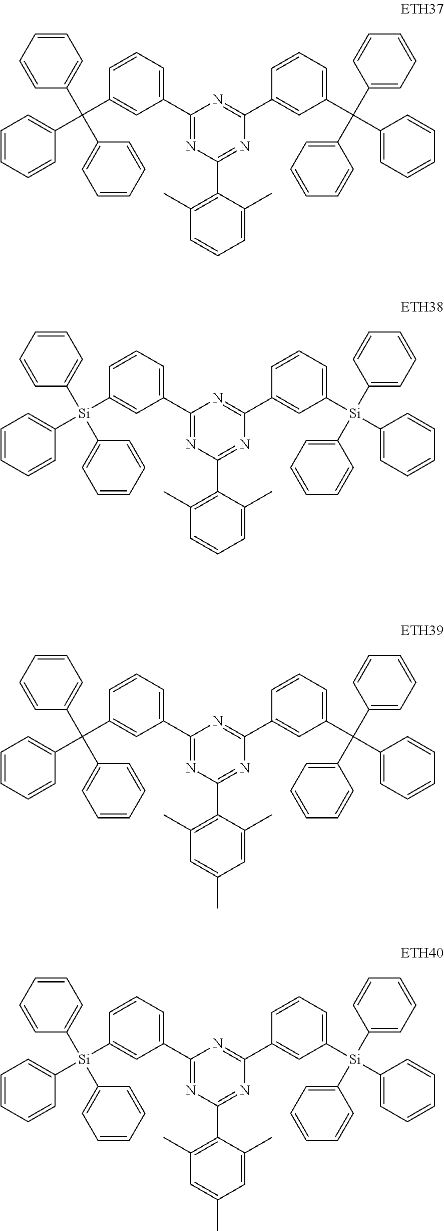 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

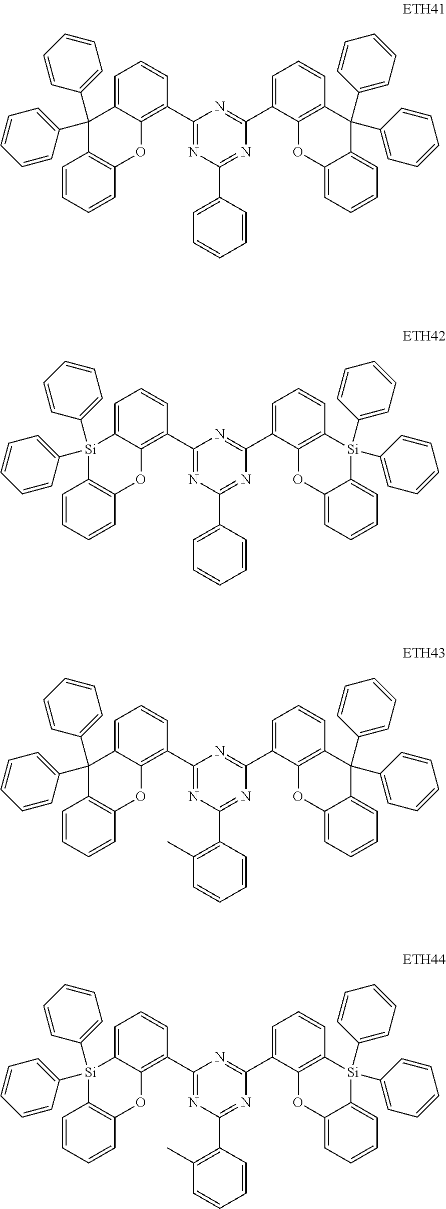 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

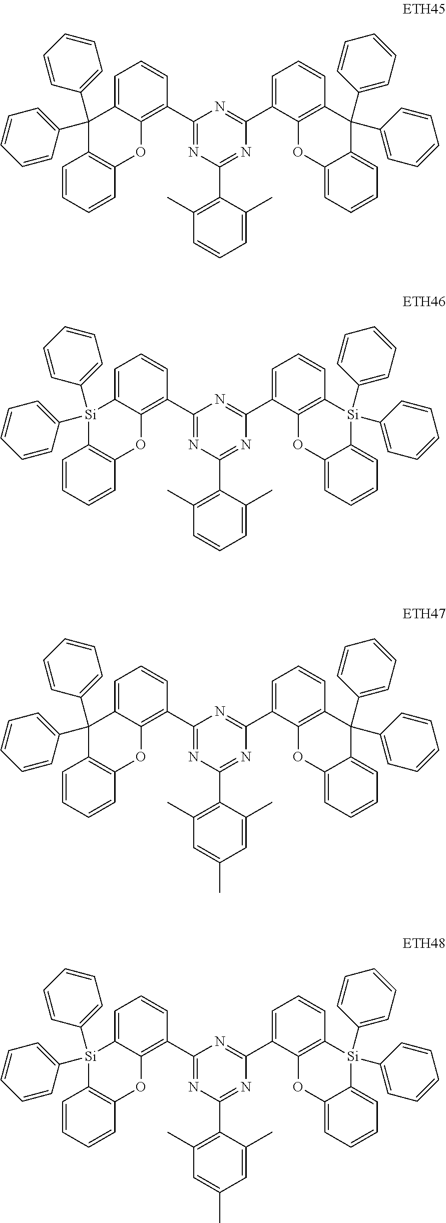 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

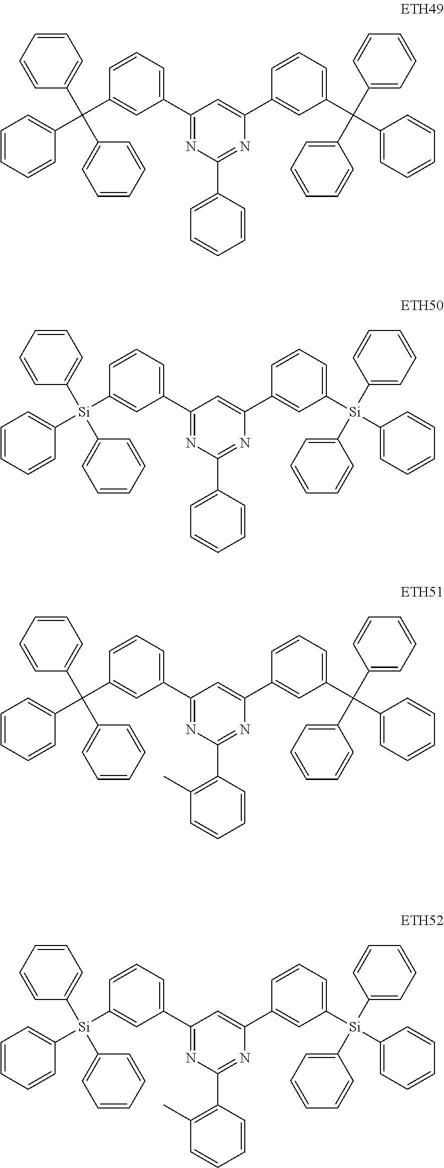 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

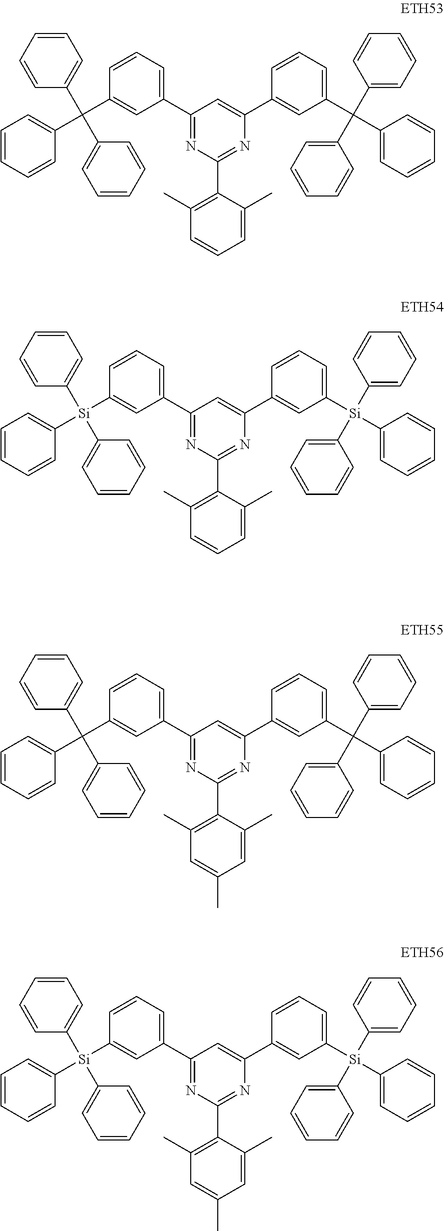 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

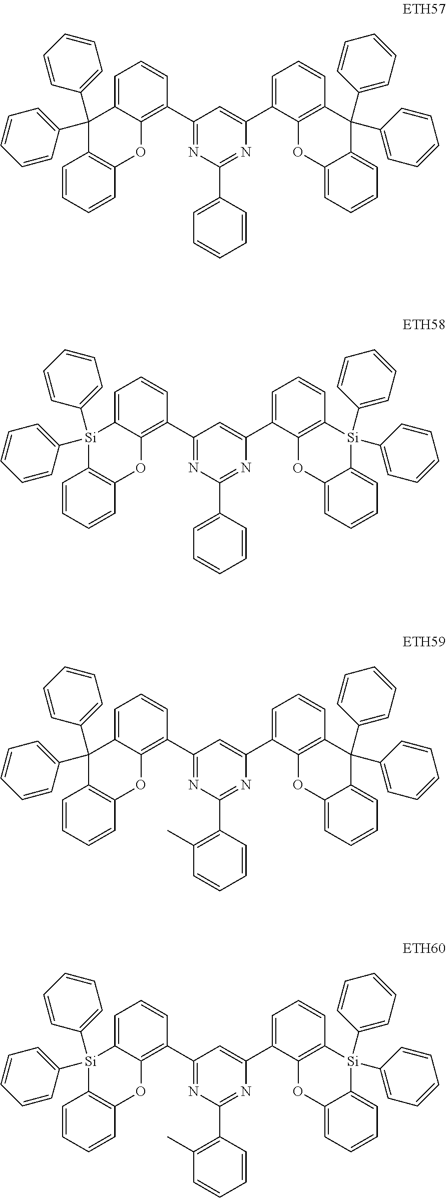 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

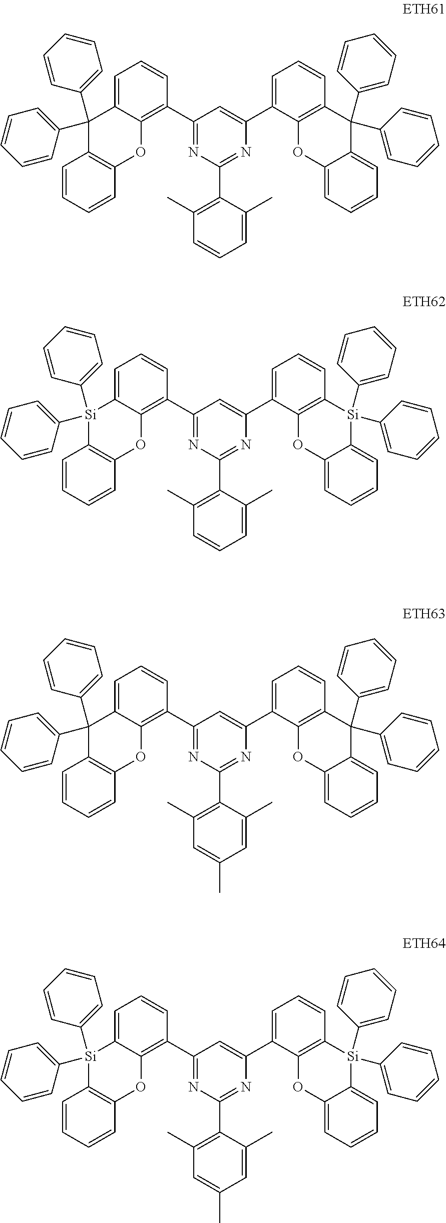 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

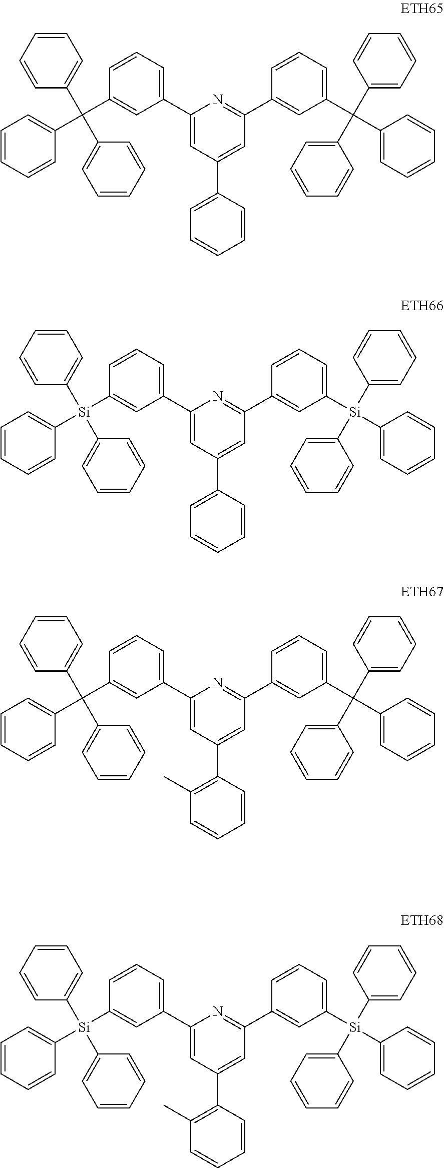 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

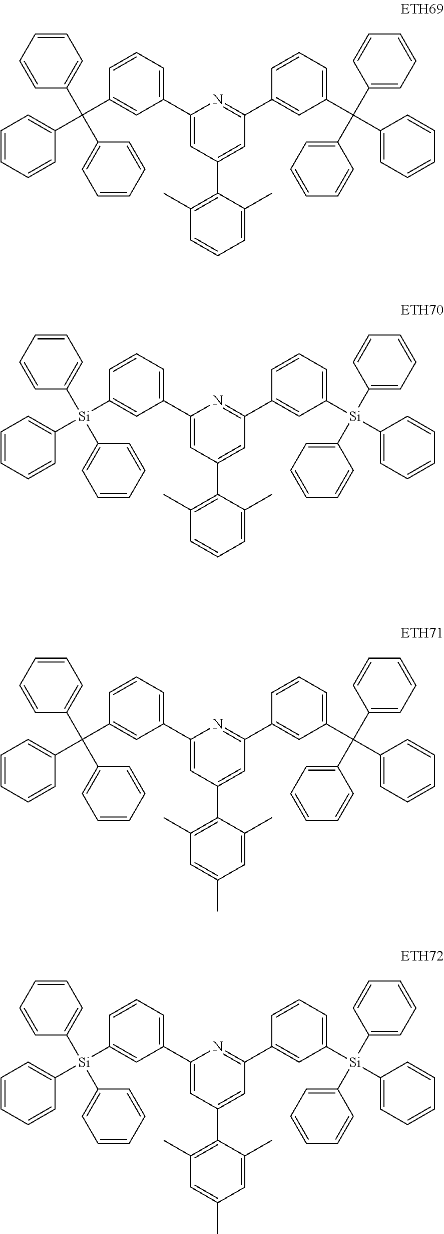 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

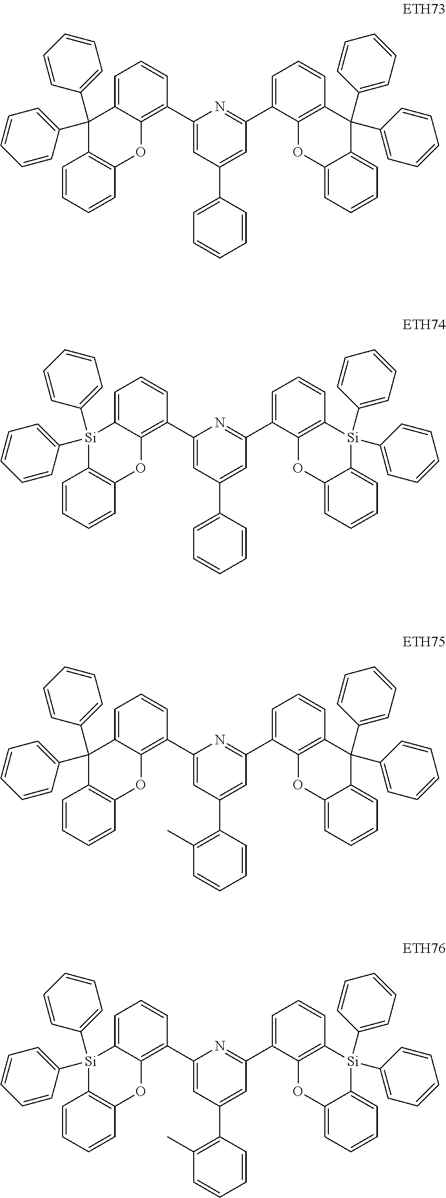 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

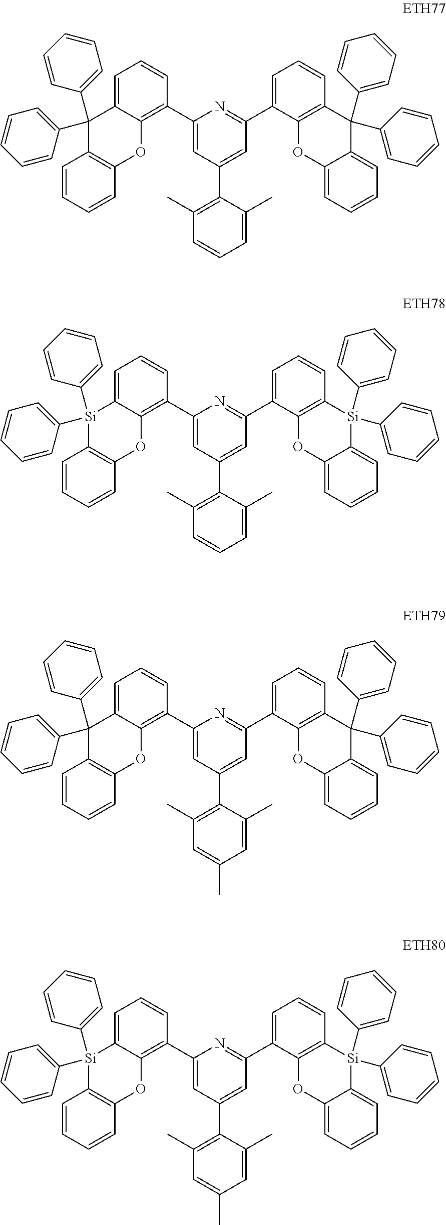 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

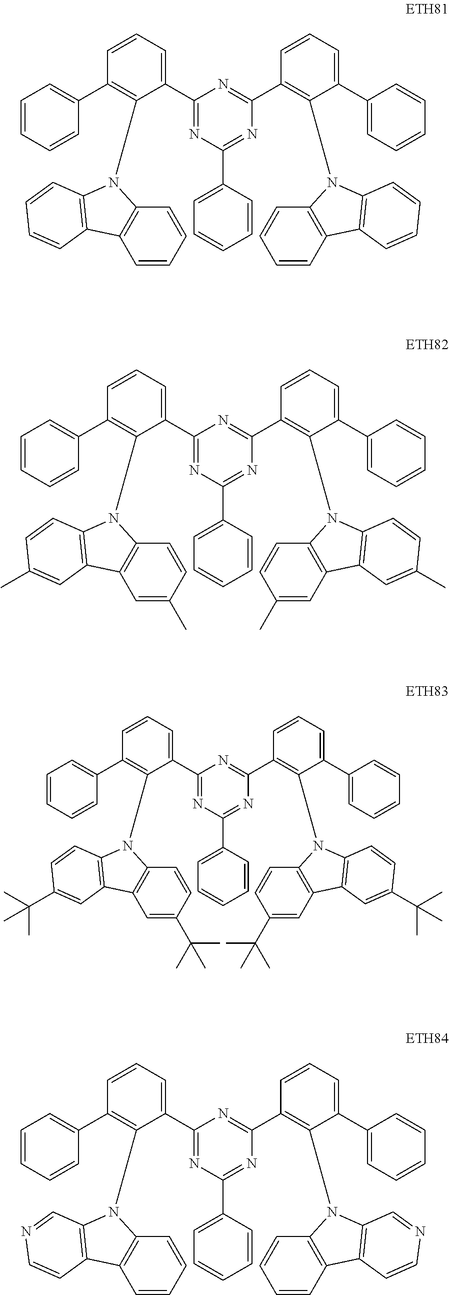

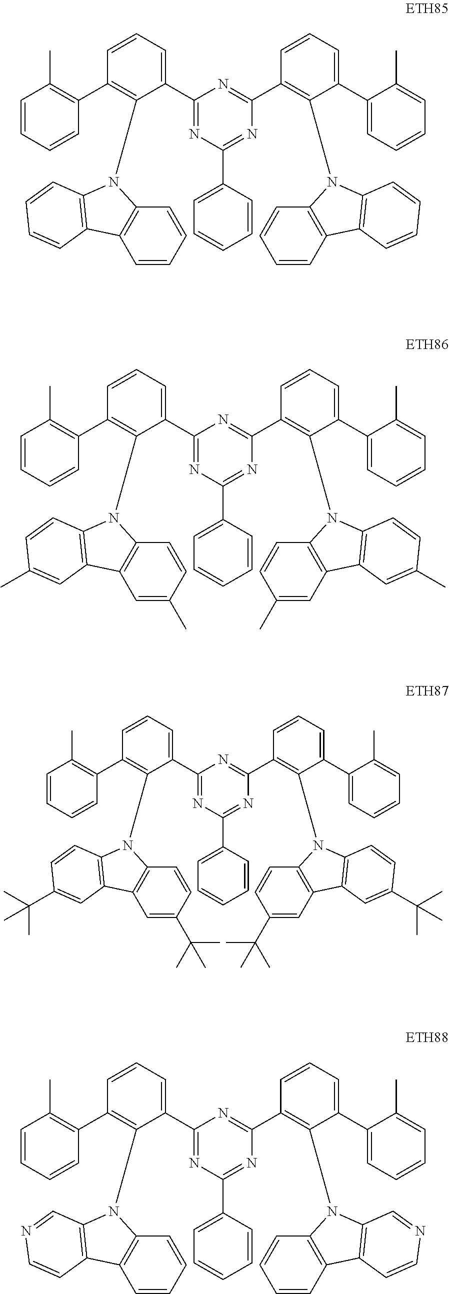

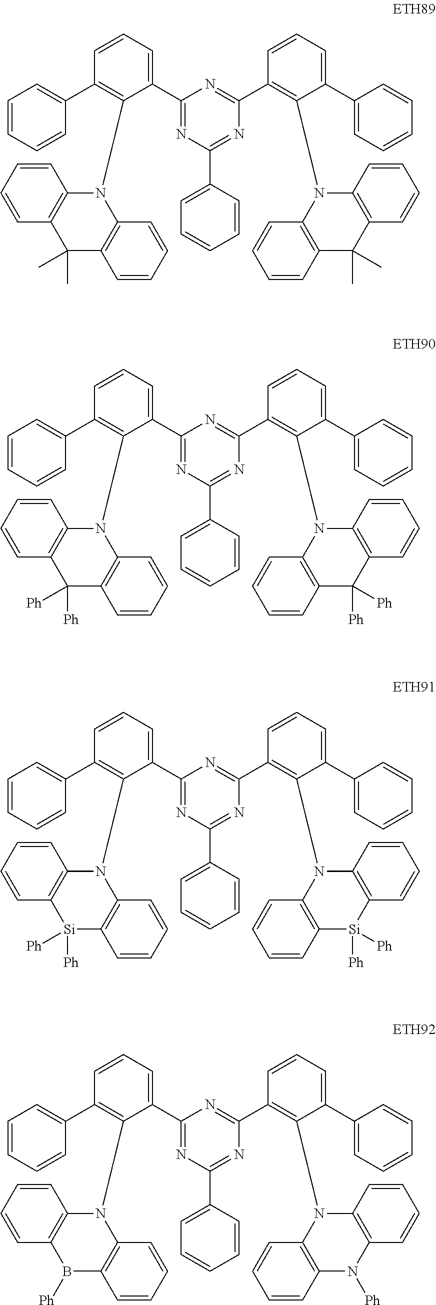

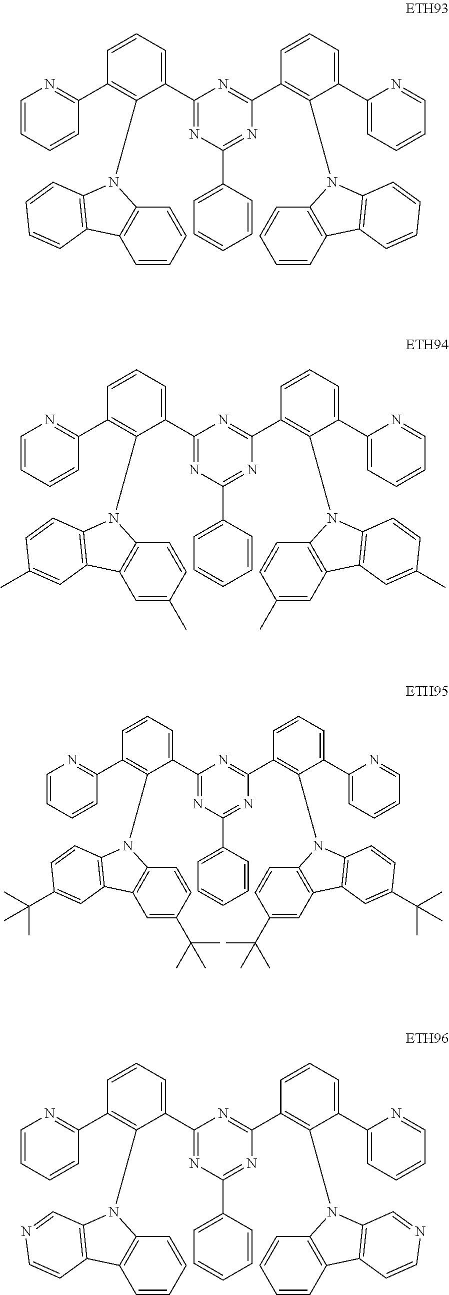

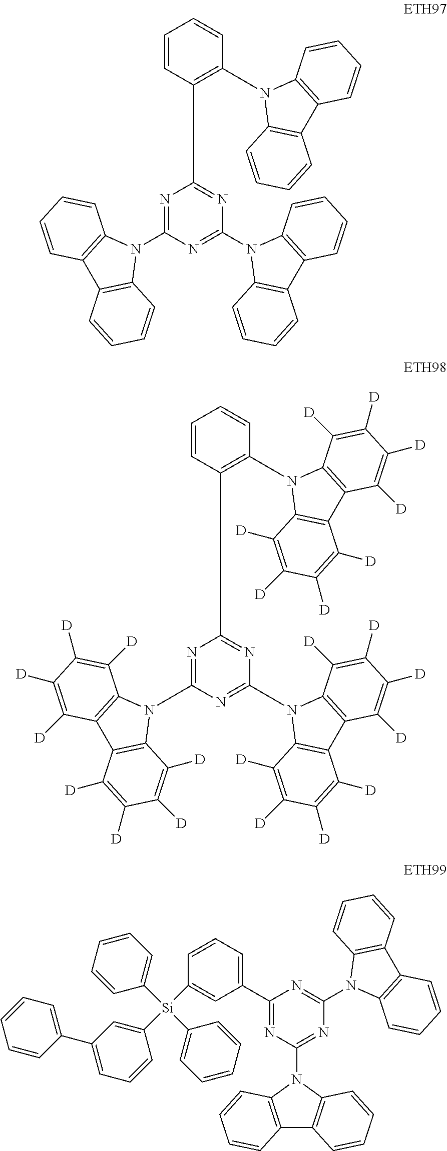 [SMILES: c1ccc(-n2c3ccccc3c3ccccc32)c(-c2nc(-n3c4ccccc4c4ccccc43)nc(-n3c4ccccc4c4ccccc43)n2)c1 ; [2H]c1c([2H])c([2H])c2c(c1[2H])c1c([2H])c([2H])c([2H])c([2H])c1n2-c1nc(-c2ccccc2-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1 ; c1ccc(-c2cccc([Si](c3ccccc3)(c3ccccc3)c3cccc(-c4nc(-n5c6ccccc6c6ccccc65)nc(-n5c6ccccc6c6ccccc65)n4)c3)c2)cc1]

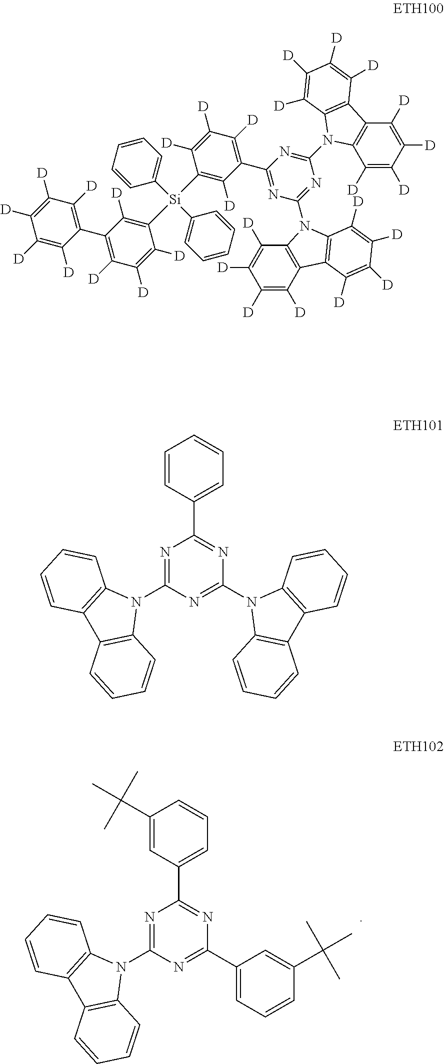 [SMILES: [2H]c1c([2H])c([2H])c(-c2c([2H])c([2H])c([2H])c([Si](c3ccccc3)(c3ccccc3)c3c([2H])c([2H])c([2H])c(-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)c3[2H])c2[2H])c([2H])c1[2H] ; c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

The sensitizer may be a compound that includes a transition metal and a ligand. The transition metal may be platinum (Pt), palladium (Pd), gold (Au), silver (Ag), nickel (Ni), copper (Cu), and/or the like, and the ligand may include a monodentate ligand, a bidentate ligand, a tridentate ligand, a tetradentate ligand, or any combination thereof. For example, the sensitizer may be represented by Formula 5:

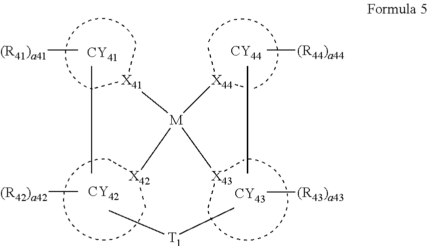

wherein, in Formula 5,
M may be platinum (Pt), palladium (Pd), gold (Au), silver (Ag), nickel (Ni), copper (Cu), and/or the like,
X₄₁ to X₄₄ may each independently be carbon (C) or nitrogen (N),
T₁ may be a single bond (e.g., a single covalent bond), O, N(Z₁₁), or C(Z₁₁)(Z₁₂),
ring CY₄₁ to CY₄₄ may each independently be a C₃-C₆₀ carbocyclic group or a C₁-C₆₀ heterocyclic group,
Z₁₁, Z₁₂ and R₄₁ to R₄₄ may each independently be the same (e.g., substantially the same) as described in connection with R₁₁, and
a41 to a44 may each independently be an integer of 0 to 20.

The sensitizer may be any one selected from among Compounds D1 to D10 and PS-1 to PS-3 or may be a compound in which at least one hydrogen that is in any one selected from among Compounds D1 to D10 and PS-1 to PS-3 may be substituted with deuterium:

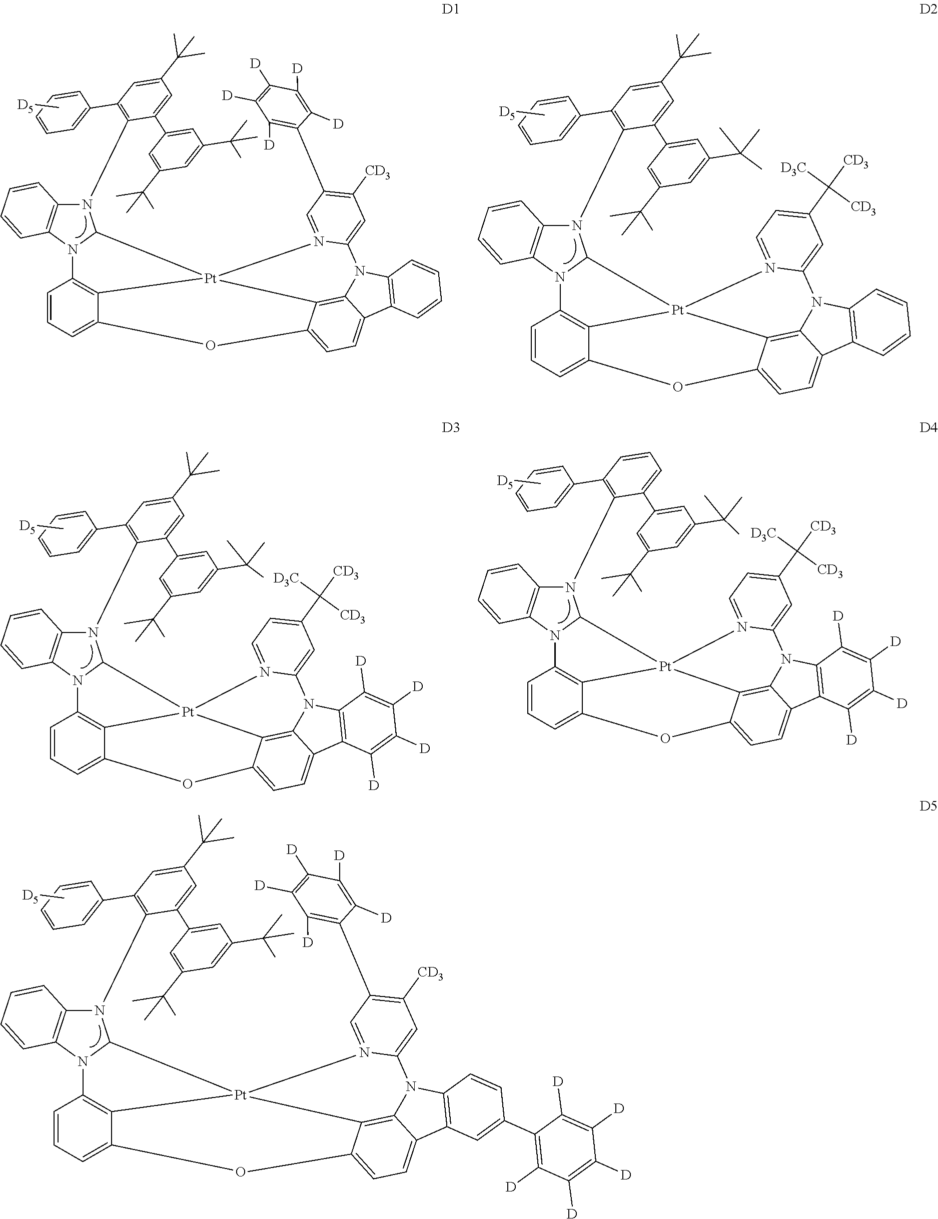

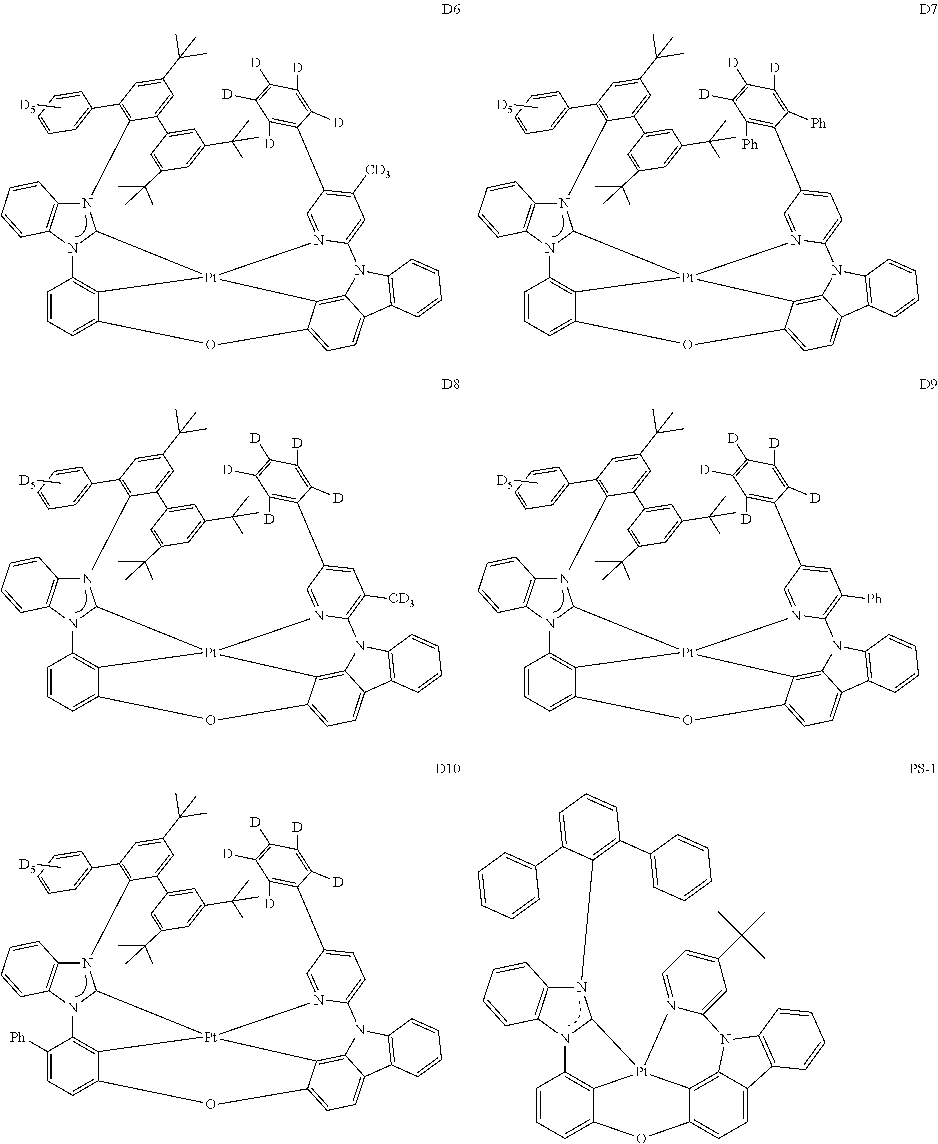

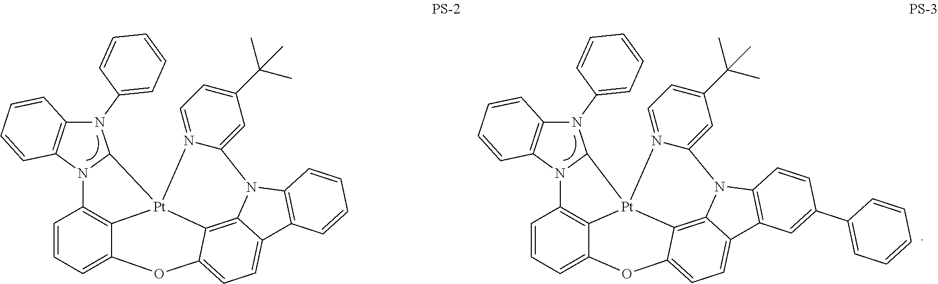

The dopant may be a C₈-C₆₀ polycyclic group-containing compound in which two or more cyclic groups are condensed while sharing a boron atom (B). The dopant may include a condensed ring in which at least one third ring and at least one fourth ring are condensed with each other,
wherein the third ring may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and
the fourth ring may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group.

The dopant may include a compound represented by Formula 6-1, a compound represented by Formula 6-2, or any combination thereof:

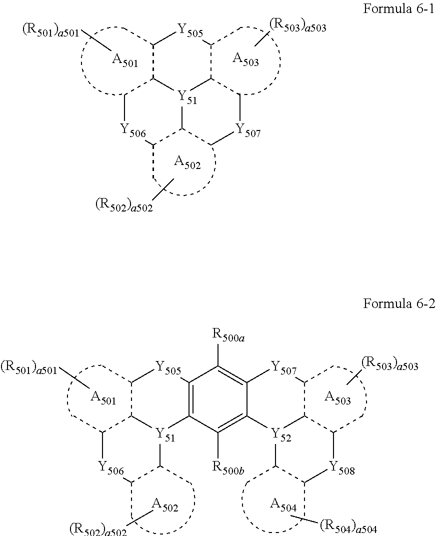

wherein, in Formulae 6-1 and 6-2,
ring A₅₀₁ to ring A₅₀₄ may each independently be a C₃-C₆₀ carbocyclic group or a C₁-C₆₀ heterocyclic group,
Y₅₀₅ may be O, S, N(R₅₀₅), B(R₅₀₅), C(R₅₀₅ₐ)(R_{505b}), or Si(R₅₀₅ₐ)(R_{505b}),
Y₅₀₆ may be O, S, N(R₅₀₆), B(R₅₀₆), C(R₅₀₆ₐ)(R_{506b}), or Si(R₅₀₆ₐ)(R_{506b}),
Y₅₀₇ may be O, S, N(R₅₀₇), B(R₅₀₇), C(R₅₀₇ₐ)(R_{507b}), or Si(R₅₀₇ₐ)(R_{507b}),
Y₅₀₈ may be O, S, N(R₅₀₈), B(R₅₀₈), C(R₅₀₈ₐ)(R_{508b}), or Si(R₅₀₈ₐ)(R_{508b}),
Y₅₁ and Y₅₂ may each independently be B, P(═O), or S(═O), R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may each independently be the same (e.g., substantially the same) as described in connection with R₁₁, and
a501 to a504 may each independently be an integer of 0 to 20.

The dopant may be any one selected from among Compounds DFD1 to DFD31:

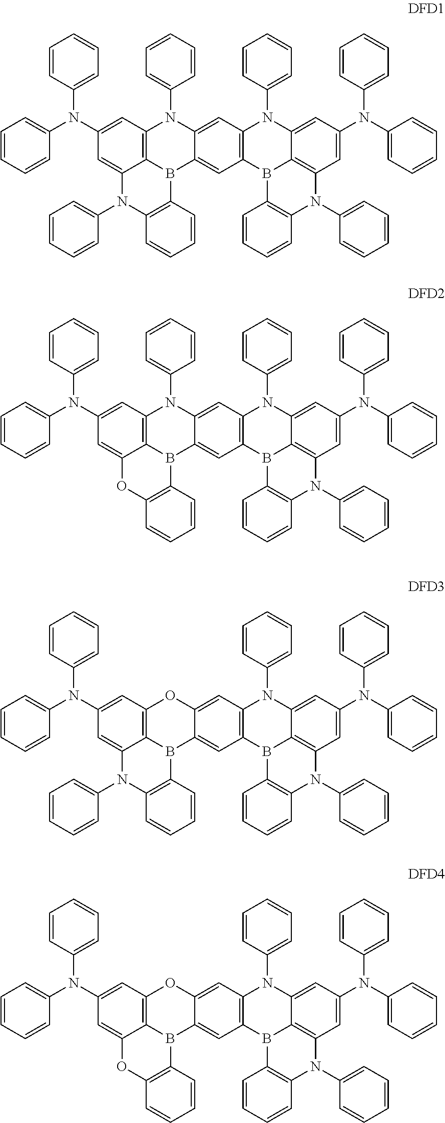

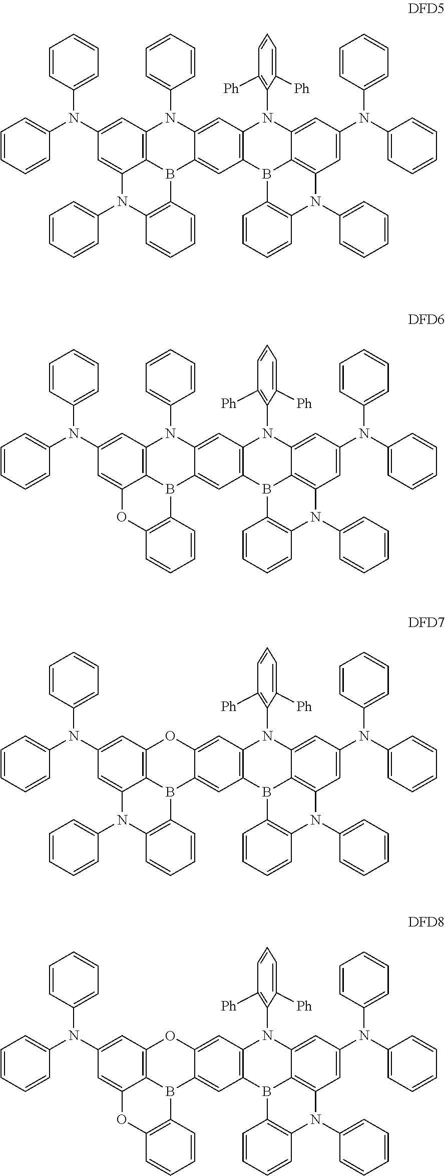

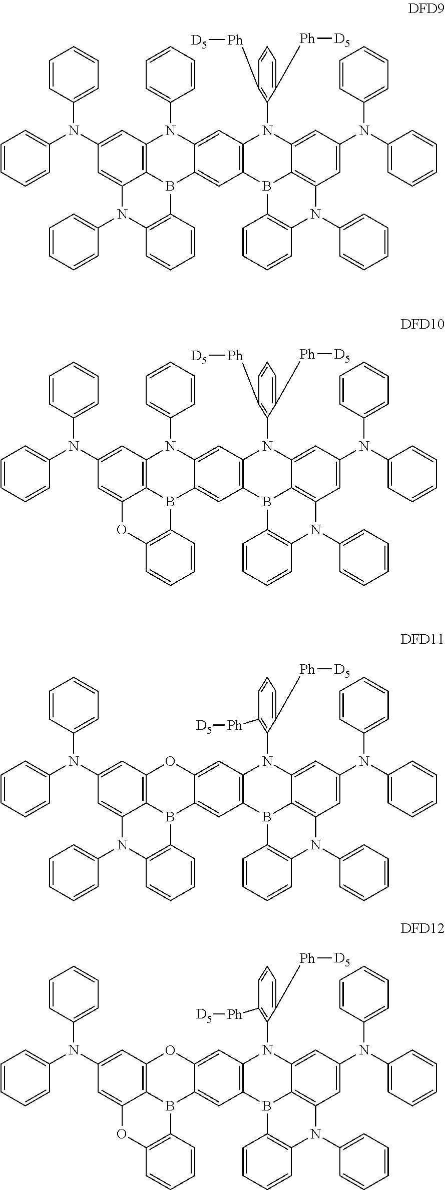

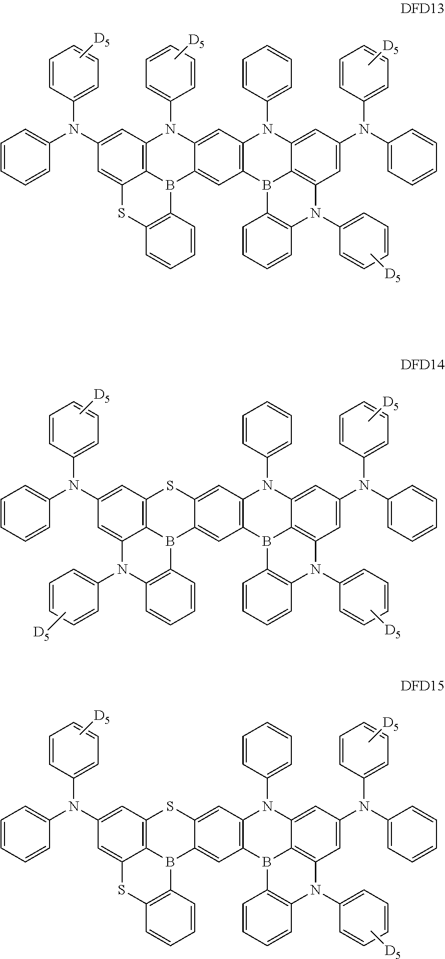

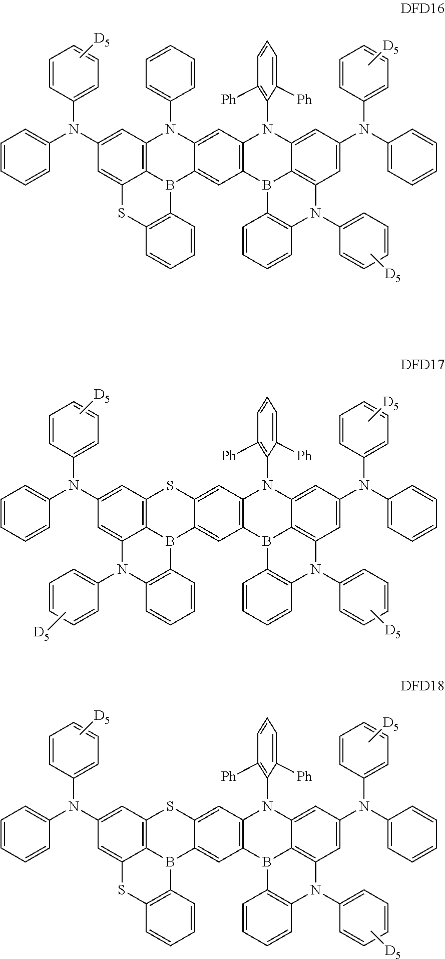

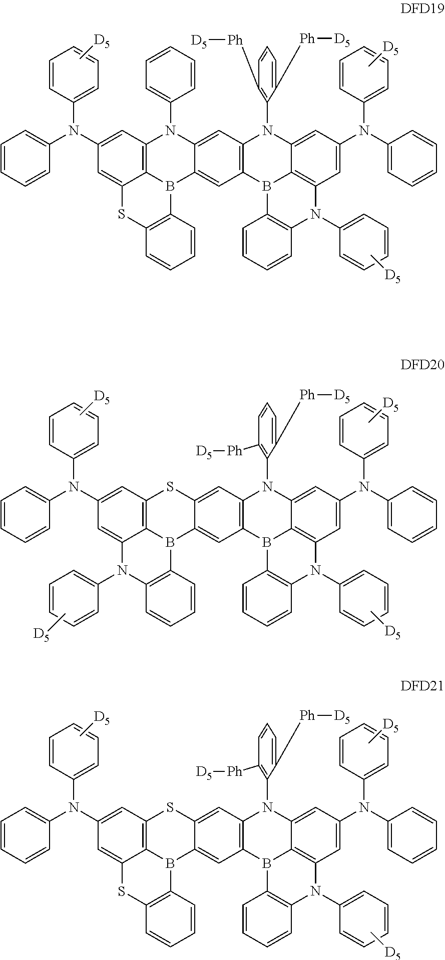

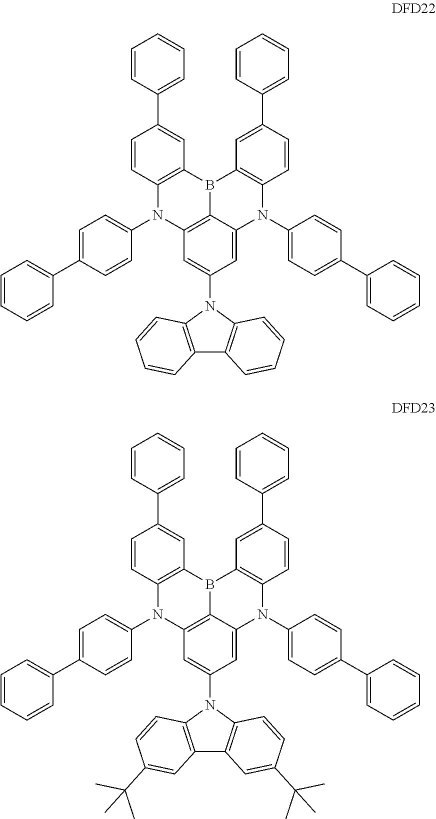 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

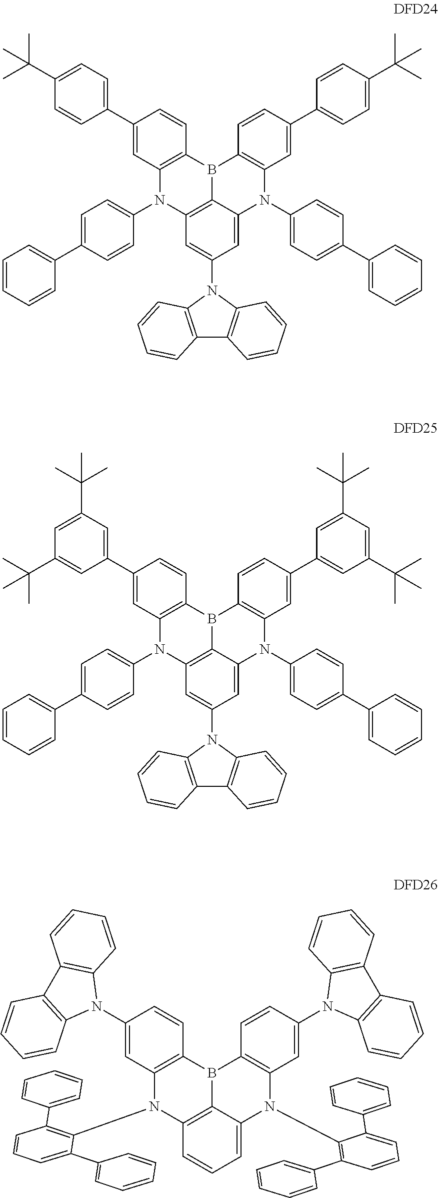 [SMILES: CC(C)(C)c1ccc(-c2ccc3c(c2)N(c2ccc(-c4ccccc4)cc2)c2cc(-n4c5ccccc5c5ccccc54)cc4c2B3c2ccc(-c3ccc(C(C)(C)C)cc3)cc2N4c2ccc(-c3ccccc3)cc2)cc1 ; CC(C)(C)c1cc(-c2ccc3c(c2)N(c2ccc(-c4ccccc4)cc2)c2cc(-n4c5ccccc5c5ccccc54)cc4c2B3c2ccc(-c3cc(C(C)(C)C)cc(C(C)(C)C)c3)cc2N4c2ccc(-c3ccccc3)cc2)cc(C(C)(C)C)c1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1]

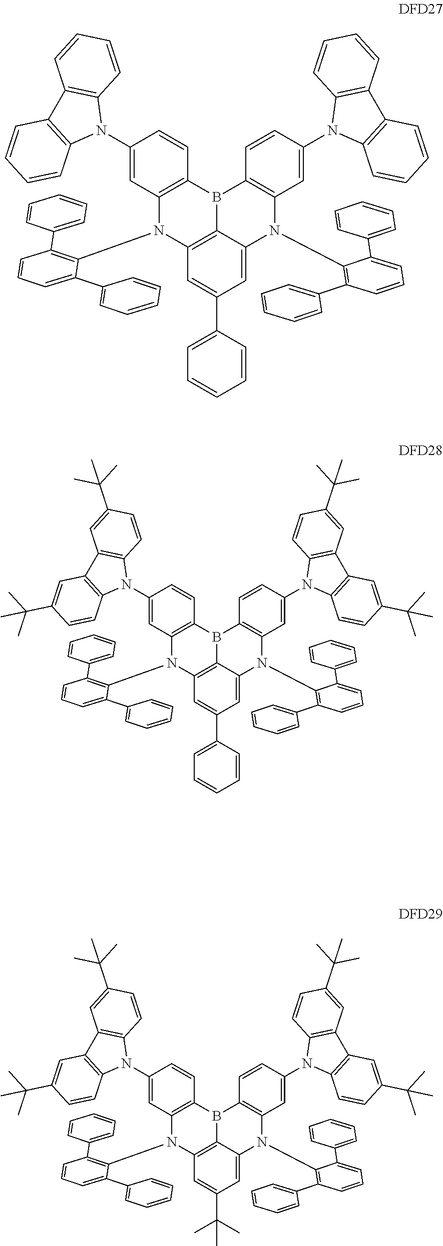

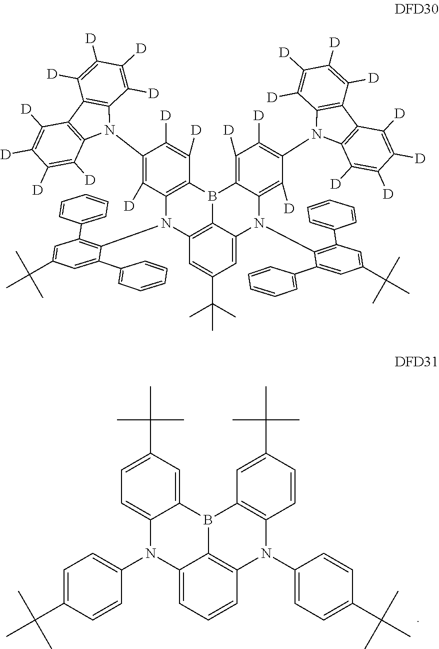 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5c([2H])c([2H])c([2H])c([2H])c5c5c([2H])c([2H])c([2H])c([2H])c54)c([2H])c([2H])c31)N2c1c(-c2ccccc2)cc(C(C)(C)C)cc1-c1ccccc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1]

According to one or more embodiments, an electronic apparatus may include: the light-emitting device according to one or more embodiments of the present disclosure; and a thin-film transistor electrically that is connected to the light-emitting device. For example, the thin-film transistor may include a source electrode and a drain electrode, and the first electrode of the light-emitting device may be electrically connected to the source electrode or the drain electrode. The electronic apparatus may further include a color filter, a color conversion layer, a touch screen layer, a polarizing layer, or any combination thereof. More details on the electronic apparatus may be referred to the descriptions provided in one or more embodiments of the present disclosure.

According to one or more embodiments, electronic equipment may include the light-emitting device, wherein the electronic equipment may be one selected from among a flat panel display, a curved display, a computer monitor, a medical monitor, a television, a billboard, a light for indoor or outdoor lighting and/or signaling (e.g., a light for indoor or outdoor lighting (e.g., an indoor or outdoor light) or a light for indoor or outdoor signaling (e.g., an indoor or outdoor light for signal)), a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual or augmented reality display, a vehicle, a video wall including multiple displays tiled together, a theater or stadium screen, a phototherapy device, a signboard, and/or the like.

### First Compound

The first compound may be represented by Formula 1:

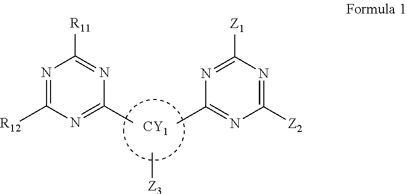

wherein, in Formula 1,
at least one selected from among Z1 to Z₃ may be a group represented by Formula TZ:

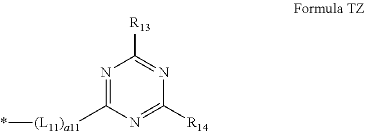

wherein, in Formula 1 and Formula TZ,
ring CY₁, L₁₁, a11, R₁₁ to R₁₄, and * may each independently be the same (e.g., substantially the same) as described in one or more embodiments.

In one or more embodiments, Z₁ to Z₃ may each independently be a group represented by Formula TZ. Two selected from among Z₁ to Z₃ may be a group represented by Formula TZ. For example, Z₁ and Z₂ may each independently be a group represented by Formula TZ, and Z₃ may not be a group represented by Formula TZ. In one or more embodiments, Z₁ and Z₃ may each independently be a group represented by Formula TZ, and Z₂ may not be a group represented by Formula TZ. In one or more embodiments, Z₂ and Z₃ may each independently be a group represented by Formula TZ, and Z₁ may not be a group represented by Formula TZ. A compound in which Z₁ and Z₃ may each independently be a group represented by Formula TZ and Z₂ is not the group represented by Formula TZ may be substantially identical (e.g., substantially same) to a compound in which Z₂ and Z₃ may each independently be the group represented by Formula TZ and Z₁ may not be the group represented by the Formula TZ due to a rotation of the molecular structure.

In one or more embodiments, one selected from among Z₁ to Z₃ may be a group represented by Formula TZ. In one or more embodiments, the first compound may include three triazine groups. For example, Z₁ may be a group represented by Formula TZ, and Z₂ and Z₃ may not each independently be a group represented by Formula TZ. In another example, Z₂ may be a group represented by Formula TZ, and Z₁ and Z₃ may not each independently be a group represented by Formula TZ. In another example, Z₃ may be a group represented by Formula TZ, and Z₁ and Z₂ may not each independently be a group represented by Formula TZ. A compound in which Z₁ is a group represented by Formula TZ and Z₂ and Z₃ are each independently not the group represented by Formula TZ may be substantially identical to a compound in which Z₂ is the group represented by Formula TZ and Z₁ and Z₃ are each independently not the group represented by Formula TZ due to a rotation of the molecular structure.

In one or more embodiments, ring CY₁ may be a C₆-C₆₀ aryl group unsubstituted or substituted with at least one R₁₀ₐ, a C₁-C₆₀ heteroaryl group unsubstituted or substituted with at least one R₁₀ₐ, a non-aromatic condensed polycyclic group unsubstituted or substituted with at least one R₁₀ₐ, or a non-aromatic condensed heteropolycyclic group unsubstituted or substituted with at least one R₁₀ₐ.

In one or more embodiments, ring CY₁ may be a 6-membered monocyclic group unsubstituted or substituted with at least one R₁₀ₐ. For example, ring CY₁ may be a benzene group unsubstituted or substituted with at least one R₁₀ₐ.

In one or more embodiments, in Formula 1, a group represented by

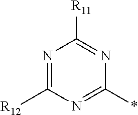

and a group represented by

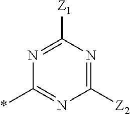

may be in a meta relationship (e.g., may be at a meta position) with respect to ring CY₁, wherein * in the groups may be a binding site to ring CY₁ in Formula 1. For example, ring-forming atom A₁ of CY₁ which is a binding site to a group represented by

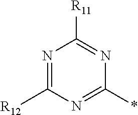

may be different from ring-forming atom A₂ of CY₁ which may be a binding site to a group represented by

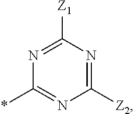

and the atom A₁ may be linked to the atom A₂ via ring-forming atom A₃ of CY₁.

In one or more embodiments, the first compound may be represented by Formula 1-1:

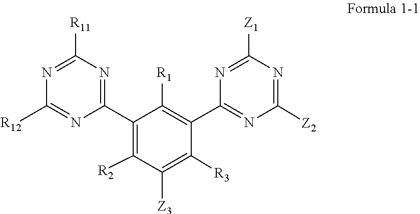

wherein, in Formula 1-1,
Z₁ to Z₃, R₁₁, and R₁₂ may each independently be the same (e.g., substantially the same) as described in Formula 1, and
R₁ to R₃ may each independently be the same (e.g., substantially the same) as described in connection with R₁₀ₐ.

In one or more embodiments, in Formula TZ, L₁₁ may be a single bond (e.g., a single covalent bond), a C₆-C₆₀ aryl group unsubstituted or substituted with at least one R₁₀ₐ, a C₁-C₆₀ heteroaryl group unsubstituted or substituted with at least one R₁₀ₐ, a non-aromatic condensed polycyclic group unsubstituted or substituted with at least one R₁₀ₐ, or a non-aromatic condensed heteropolycyclic group unsubstituted or substituted with at least one R₁₀ₐ. a11 may be an integer of 1 to 4. a11 may be an integer of 1 to 3. a11 may be 1 or 2. a11 may be 1.

In one or more embodiments, i) if (e.g., when) Z₁ or Z₂ in Formula 1 is a group represented by Formula TZ, L₁₁ may be a C₃-C₃₀ carbocyclic group unsubstituted or substituted with at least one R₁₀ₐ or a C₁-C₃₀ heterocyclic group unsubstituted or substituted with at least one R₁₀ₐ, and ii) if (e.g., when) Z₃ in Formula 1 is a group represented by Formula TZ, L₁₁ may be a single bond (e.g., a single covalent bond).

In one or more embodiments, L₁₁ may be a single bond (e.g., a single covalent bond) or a 6-membered monocyclic group unsubstituted or substituted with at least one R₁₀ₐ. For example, L₁₁ may be a single bond (e.g., a single covalent bond) or a benzene group unsubstituted or substituted with at least one R₁₀ₐ.

In one or more embodiments, L₁₁ may be a single bond (e.g., a single covalent bond) or a group represented by any one selected from among Formulae BZ1 to BZ3:

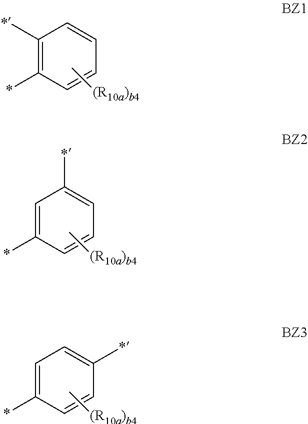

wherein, in Formulae BZ1 to BZ3,
R₁₀ₐ, *, and *′ may each independently be the same (e.g., substantially the same) as described in one or more embodiments, and
b4 may be an integer of 0 to 4.

In Formulae 1 and 1-1, at least one selected from among Z₁ to Z₃ may be a group represented by Formula TZ, and in Formula 1, Formula TZ, and Formula 1-1, R₁₁ to R₁₄ and Z₁ to Z₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a phenyl group unsubstituted or substituted with at least one R₁₀ₐ, a pyridinyl group unsubstituted or substituted with at least one R₁₀ₐ, or a pyrimidinyl group unsubstituted or substituted with at least one R₁₀ₐ.

In one or more embodiments, the first compound may be any one selected from among Compounds A1 to A60:

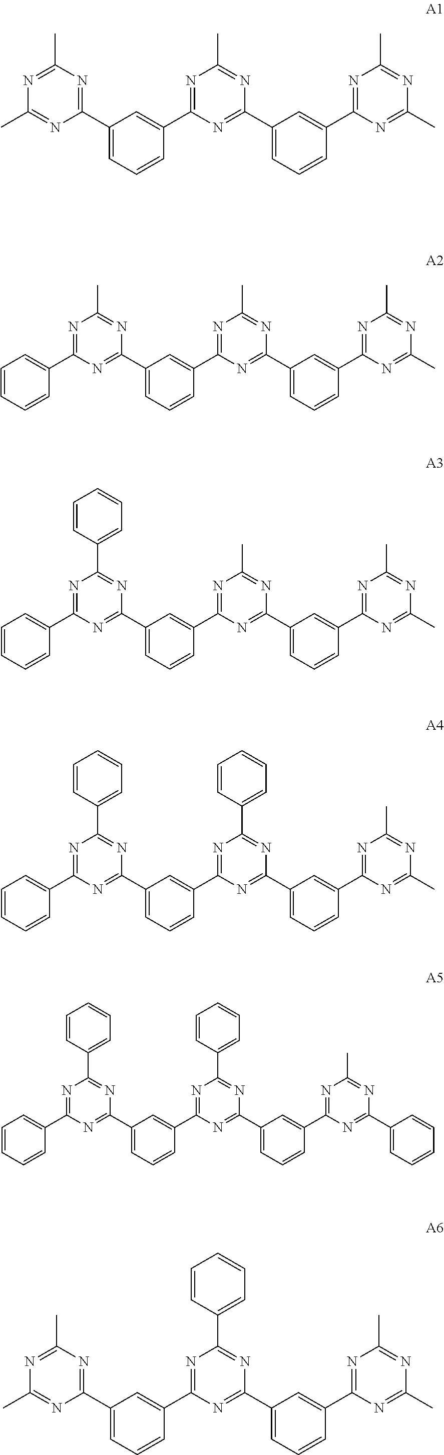

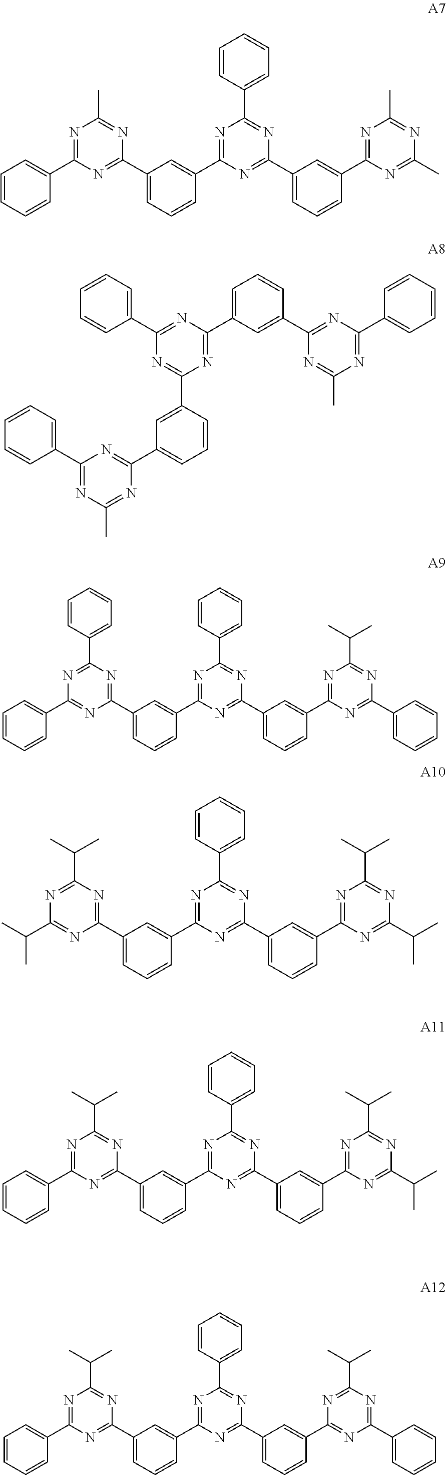

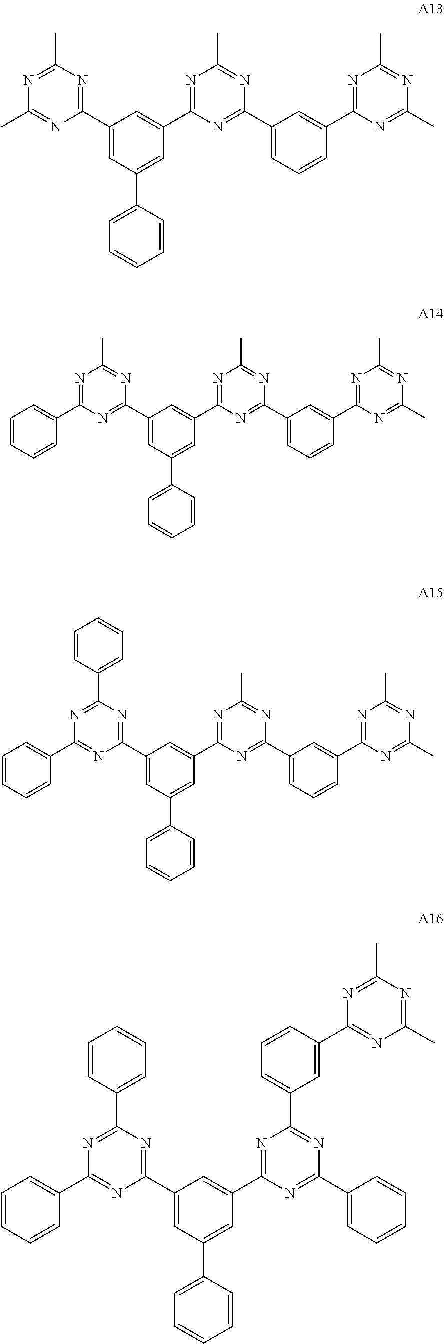

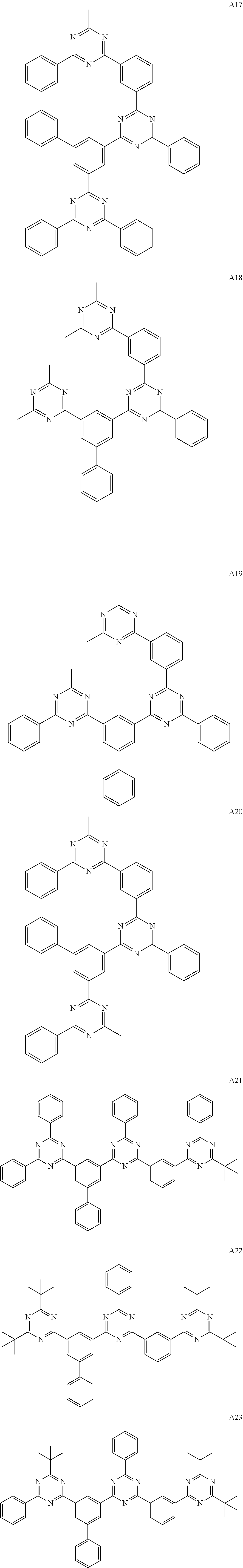

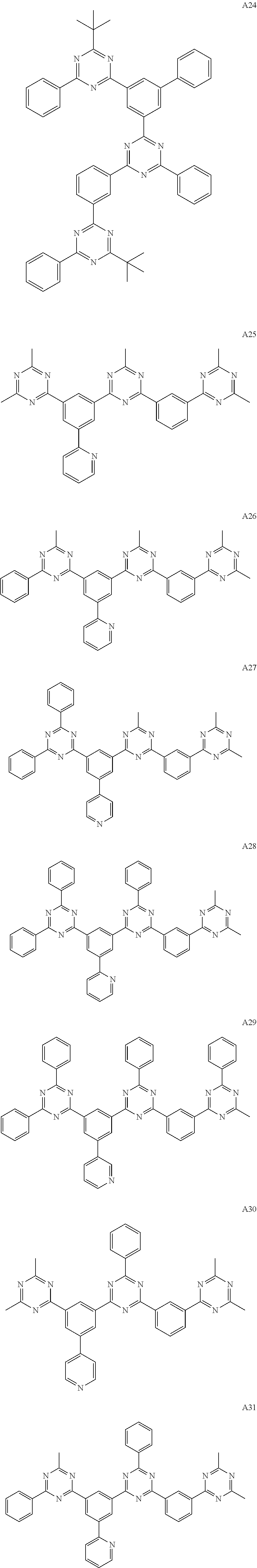

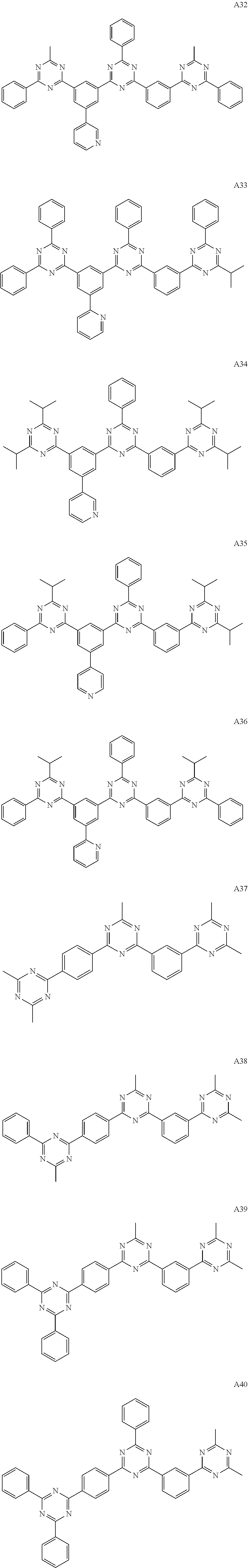

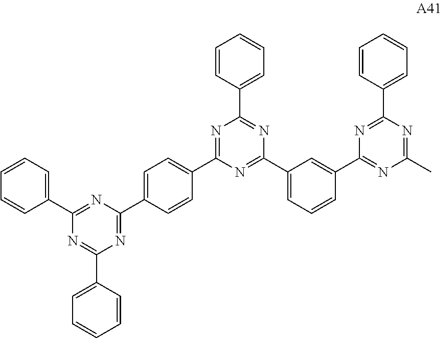 [SMILES: Cc1nc(-c2ccccc2)nc(-c2cccc(-c3nc(-c4ccccc4)nc(-c4ccc(-c5nc(-c6ccccc6)nc(-c6ccccc6)n5)cc4)n3)c2)n1]

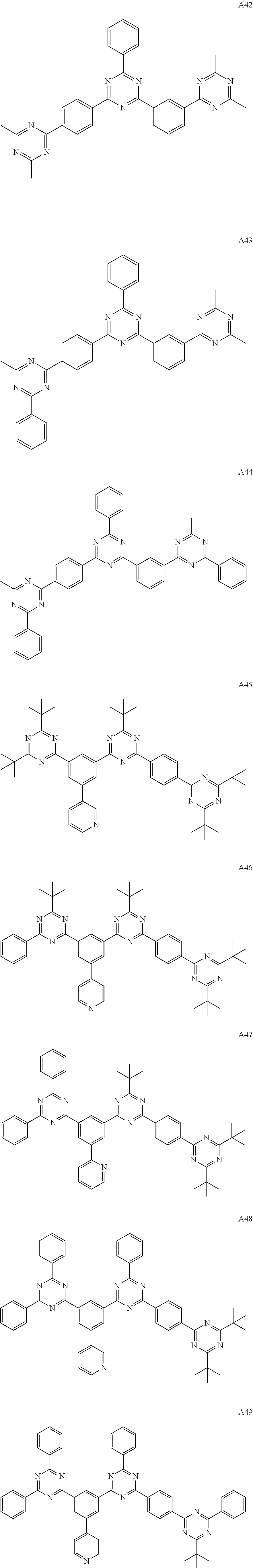

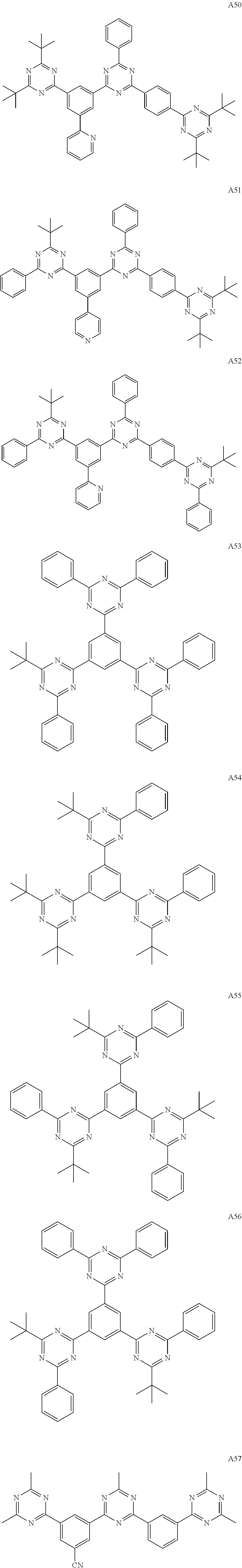

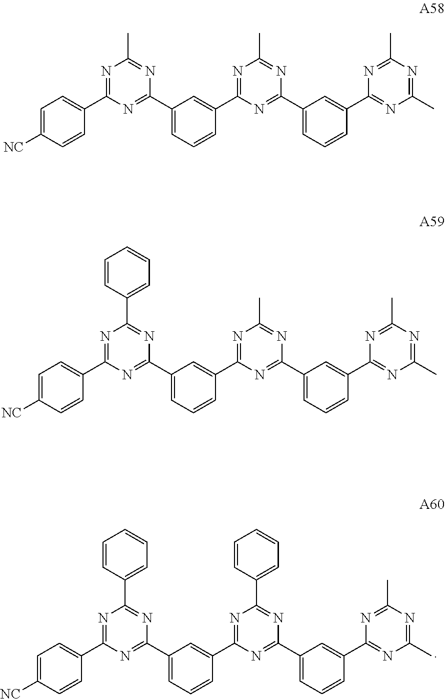 [SMILES: Cc1nc(C)nc(-c2cccc(-c3nc(C)nc(-c4cccc(-c5nc(C)nc(-c6ccc(C#N)cc6)n5)c4)n3)c2)n1 ; Cc1nc(C)nc(-c2cccc(-c3nc(C)nc(-c4cccc(-c5nc(-c6ccccc6)nc(-c6ccc(C#N)cc6)n5)c4)n3)c2)n1 ; Cc1nc(C)nc(-c2cccc(-c3nc(-c4ccccc4)nc(-c4cccc(-c5nc(-c6ccccc6)nc(-c6ccc(C#N)cc6)n5)c4)n3)c2)n1]

### Second Compound

The second compound may be represented by Formula 2:

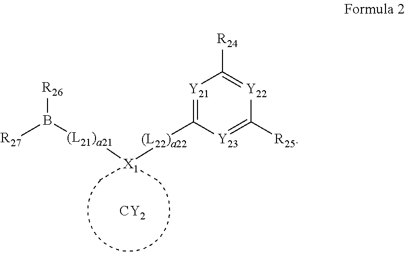

Formula 2 may be the same (e.g., substantially the same) as described in one or more embodiments.

For example, the second compound may be a compound in which a group represented by

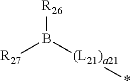

and a group represented by

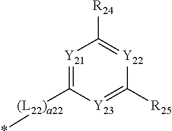

in Formula 2 may be bonded to the ring-forming atom X₁ of CY₂. In one or more embodiments, the second compound may be clearly (or structurally) different from compounds in which the groups are bonded to each of different atoms of one ring.

In one or more embodiments, in Formula 2, ring CY₂ may be a C₆-C₁₀ cycloalkyl group unsubstituted or substituted with at least one R₁₀ₐ. For example, ring CY₂ may be a cyclopentyl group unsubstituted or substituted with at least one R₁₀ₐ, a cyclohexyl group unsubstituted or substituted with at least one R₁₀ₐ, a cycloheptyl group unsubstituted or substituted with at least one R₁₀ₐ, a cyclooctyl group unsubstituted or substituted with at least one R₁₀ₐ, a norbornanyl group unsubstituted or substituted with at least one R₁₀ₐ, or an adamantanyl group unsubstituted or substituted with at least one R₁₀ₐ.

In one or more embodiments, in Formula 2, L₂₁ and L₂₂ may each independently be a C₆-C₆₀ aryl group unsubstituted or substituted with at least one R₁₀ₐ, a C₁-C₆₀ heteroaryl group unsubstituted or substituted with at least one R₁₀ₐ, a non-aromatic condensed polycyclic group unsubstituted or substituted with at least one R₁₀ₐ, or a non-aromatic condensed heteropolycyclic group unsubstituted or substituted with at least one R₁₀ₐ.

a21 may be an integer of 1 to 3. a21 may be 1 or 2. a21 may be 1. a22 may be an integer of 1 to 3. a22 may be 1 or 2. a22 may be 1.

In one or more embodiments, at least one selected from L₂₁ and L₂₂ may be a 6-membered monocyclic group unsubstituted or substituted with at least one R₁₀ₐ. For example, at least one selected from L₂₁ and L₂₂ may be a benzene group unsubstituted or substituted with at least one R₁₀ₐ.

In one or more embodiments, L₂₁ and L₂₂ may each independently be a group represented by any one selected from among Formulae BZ1 to BZ3:

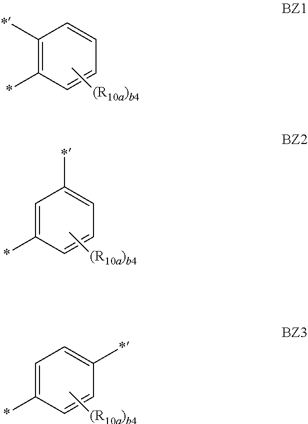

wherein, in Formulae BZ1 to BZ3,
R₁₀ₐ, *, and *′ may each independently be the same (e.g., substantially the same) as described in one or more embodiments, and
b4 may be an integer of 0 to 4.

In one or more embodiments, the second compound may be represented by Formula 2-1:

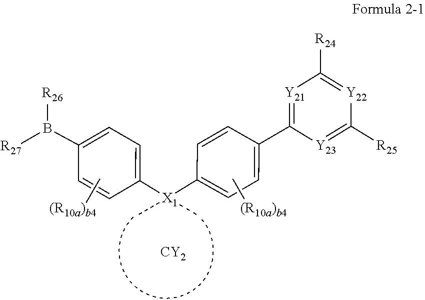

wherein, in Formula 2-1, ring CY₂, X₁, Y₂₁ to Y₂₃, R₂₄ to R₂₇, R₁₀ₐ, and b4 may each independently be the same (e.g., substantially the same) as described in one or more embodiments.

In one or more embodiments, in Formulae 2 and 2-1, at least one selected from among Y₂₁ to Y₂₃ may be N. In one or more embodiments, Y₂₁ may be N, Y₂₂ may be C(R₂₂), and Y₂₃ may be C(R₂₃). In one or more embodiments, Y₂₁ may be C(R₂₁), Y₂₂ may be N, and Y₂₃ may be C(R₂₃). In one or more embodiments, Y₂₁ may be C(R₂₁), Y₂₂ may be C(R₂₂), and Y₂₃ may be N.

In one or more embodiments, in Formulae 2 and 2-1, two selected from among Y₂₁ to Y₂₃ may be N. In one or more embodiments, Y₂₁ may be N, Y₂₂ may be N, and Y₂₃ may be C(R₂₃). In one or more embodiments, Y₂₁ may be N, Y₂₂ may be C(R₂₂), and Y₂₃ may be N. In one or more embodiments, Y₂₁ may be C(R₂₁), Y₂₂ may be N, and Y₂₃ may be N.

In one or more embodiments, in Formulae 2 and 2-1, all of Y₂₁ to Y₂₃ may be N.

In one or more embodiments, in Formulae 2 and 2-1, R₂₁ to R₂₇ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a phenyl group unsubstituted or substituted with at least one R₁₀ₐ, a naphthyl group unsubstituted or substituted with at least one R₁₀ₐ, a fluorenyl group unsubstituted or substituted with at least one R₁₀ₐ, a carbazolyl group unsubstituted or substituted with at least one R₁₀ₐ, a dibenzofuranyl group unsubstituted or substituted with at least one R₁₀ₐ, or a dibenzothiophenyl group unsubstituted or substituted with at least one R₁₀ₐ.

In one or more embodiments, in Formula 2, a group represented by

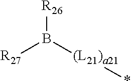

may be a group represented by any one selected from among Formulae 2A to 2H:

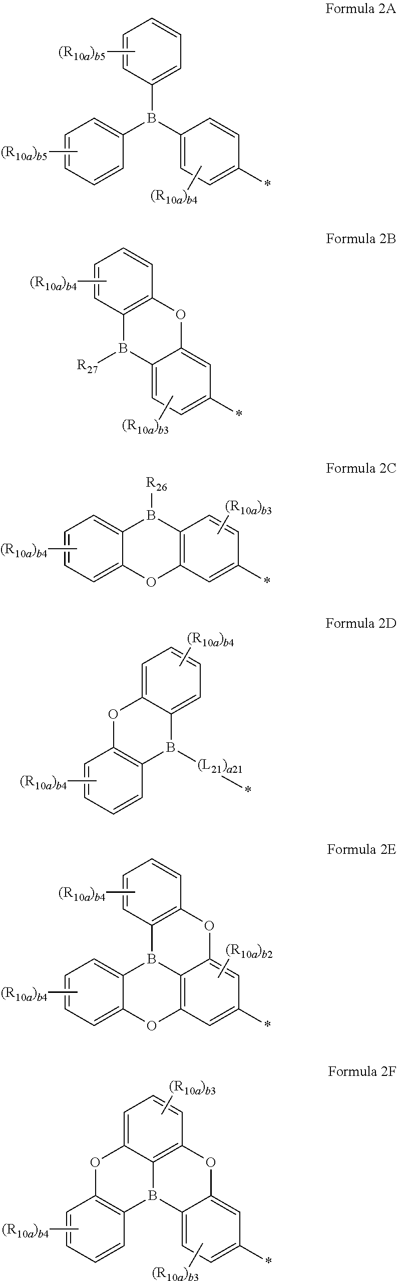

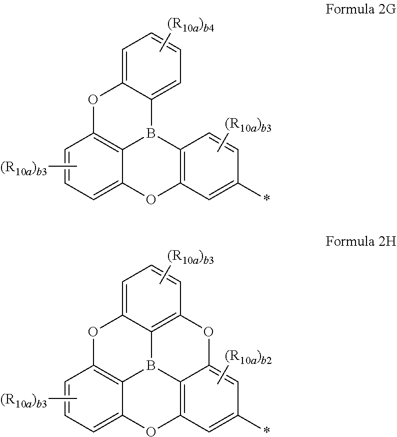

wherein, in Formulae 2A to 2H,
R₁₀ₐ is the same (e.g., substantially the same) as described in one or more embodiments,
adjacent R₂₆, R₂₇, and R₁₀ₐ may not be bonded to each other directly or via *—O—*′,
b2 may be an integer of 0 to 2,
b3 may be an integer of 0 to 3,
b4 may be an integer of 0 to 4, and
b5 may be an integer of 0 to 5.

The second compound may be any one selected from among Compounds B1 to B64:

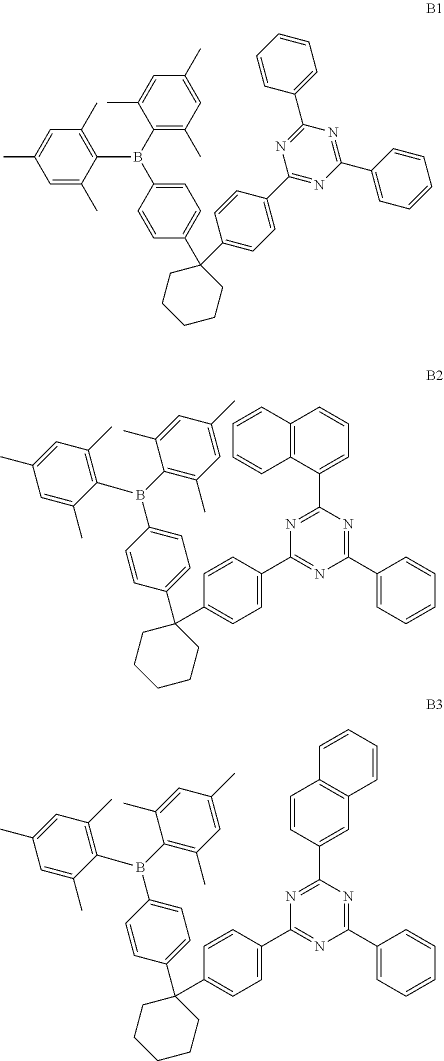 [SMILES: Cc1cc(C)c(B(c2ccc(C3(c4ccc(-c5nc(-c6ccccc6)nc(-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cccc7ccccc67)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6)n5)cc4)CCCCC3)cc2)c2c(C)cc(C)cc2C)c(C)c1]

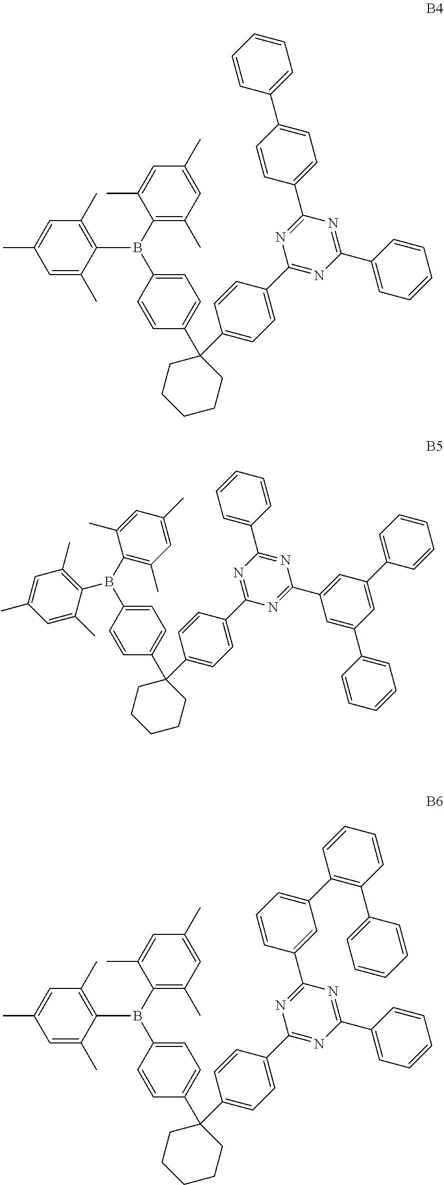 [SMILES: Cc1cc(C)c(B(c2ccc(C3(c4ccc(-c5nc(-c6ccccc6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cc(-c7ccccc7)cc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7-c7ccccc7)c6)n5)cc4)CCCCC3)cc2)c2c(C)cc(C)cc2C)c(C)c1]

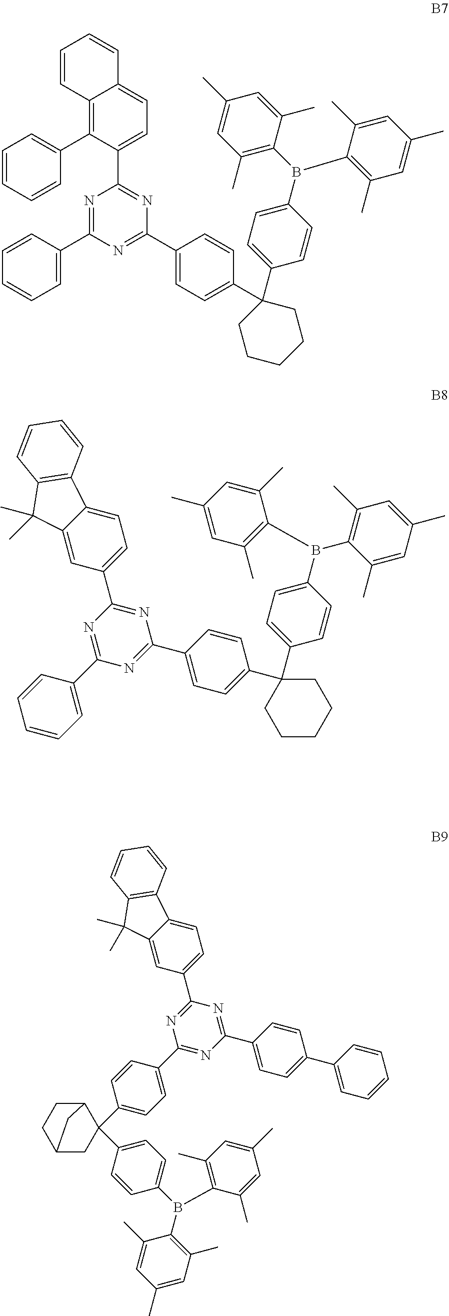

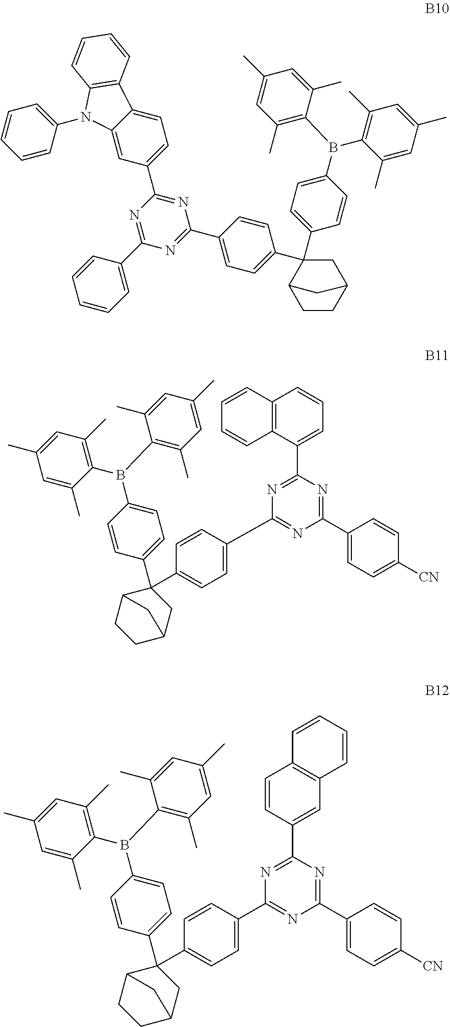

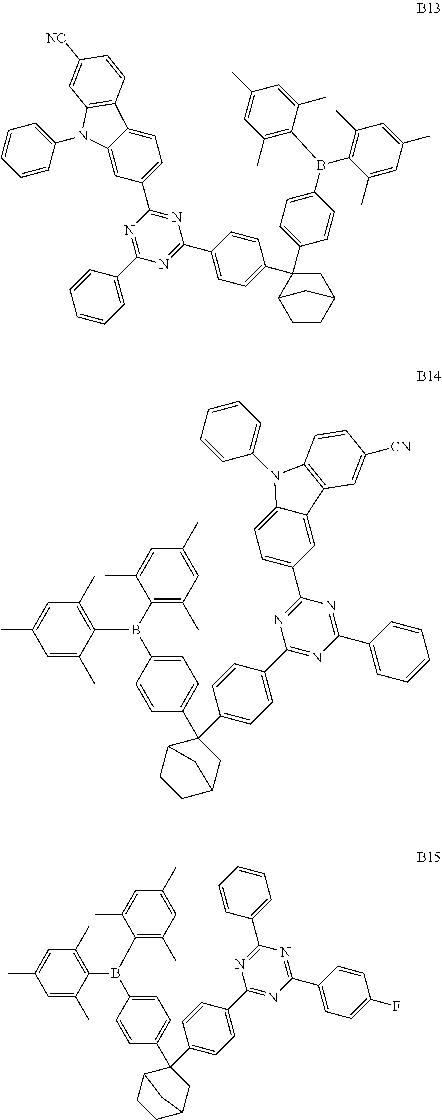

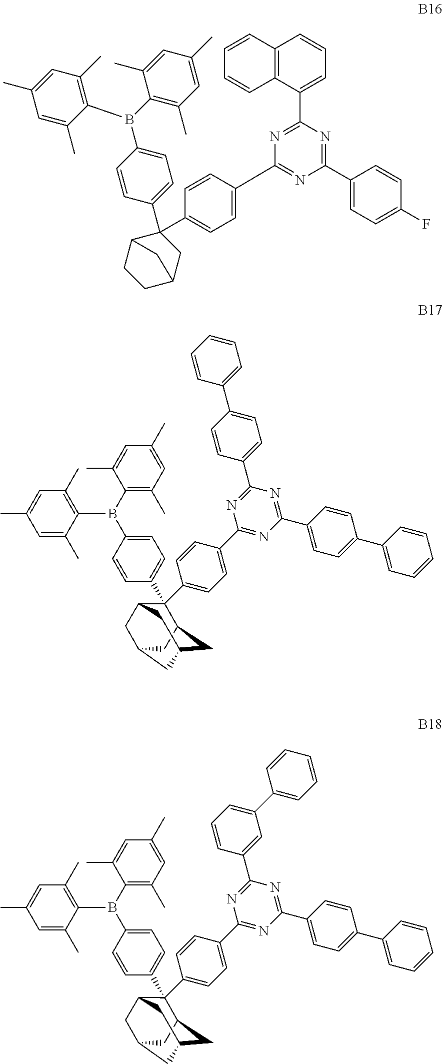

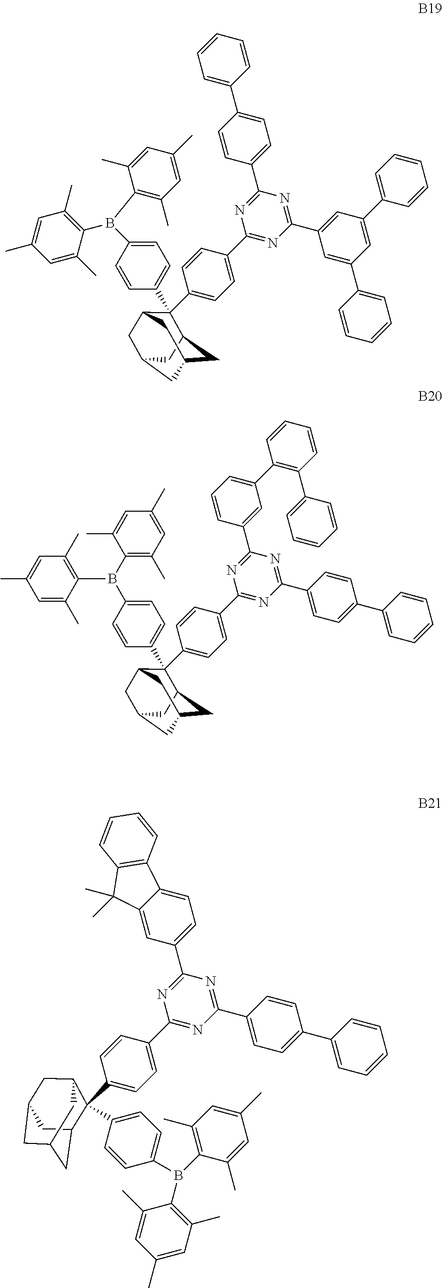

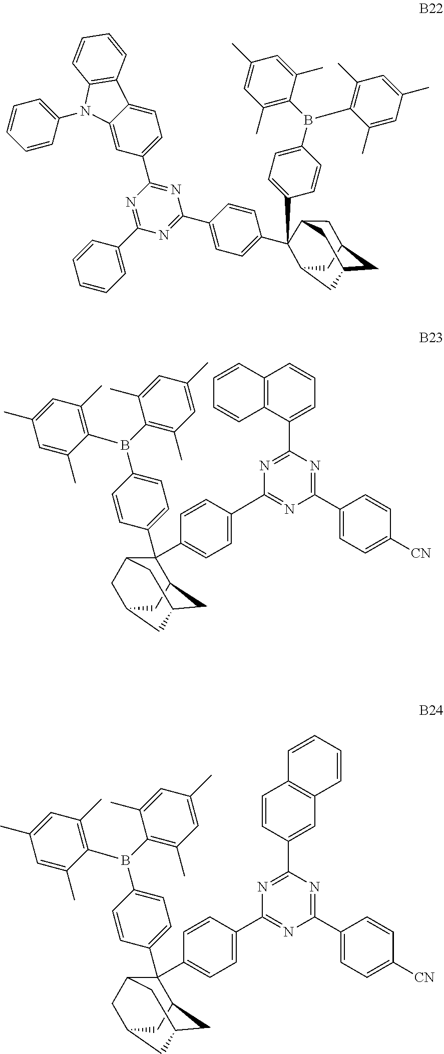

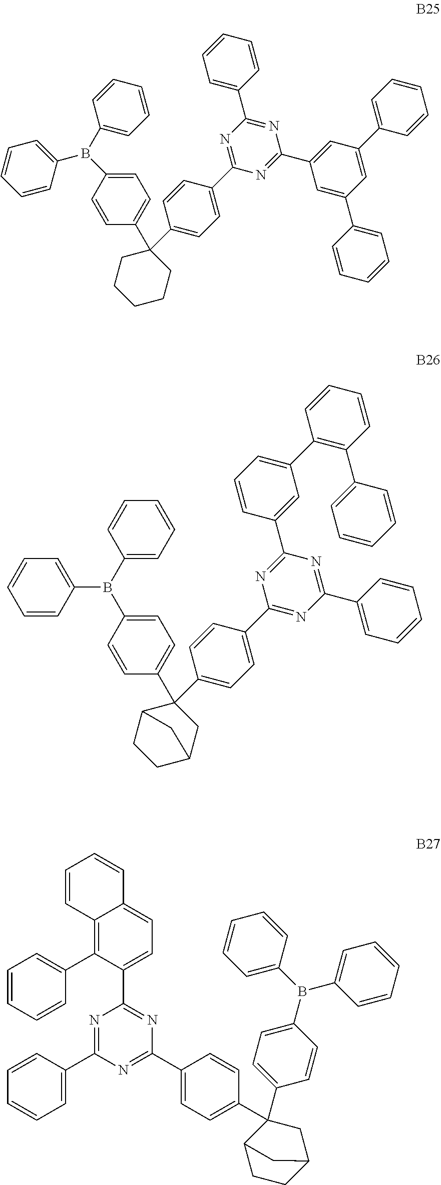 [SMILES: c1ccc(B(c2ccccc2)c2ccc(C3(c4ccc(-c5nc(-c6ccccc6)nc(-c6cc(-c7ccccc7)cc(-c7ccccc7)c6)n5)cc4)CCCCC3)cc2)cc1 ; c1ccc(B(c2ccccc2)c2ccc(C3(c4ccc(-c5nc(-c6ccccc6)nc(-c6cccc(-c7ccccc7-c7ccccc7)c6)n5)cc4)CC4CCC3C4)cc2)cc1 ; c1ccc(B(c2ccccc2)c2ccc(C3(c4ccc(-c5nc(-c6ccccc6)nc(-c6ccc7ccccc7c6-c6ccccc6)n5)cc4)CC4CCC3C4)cc2)cc1]

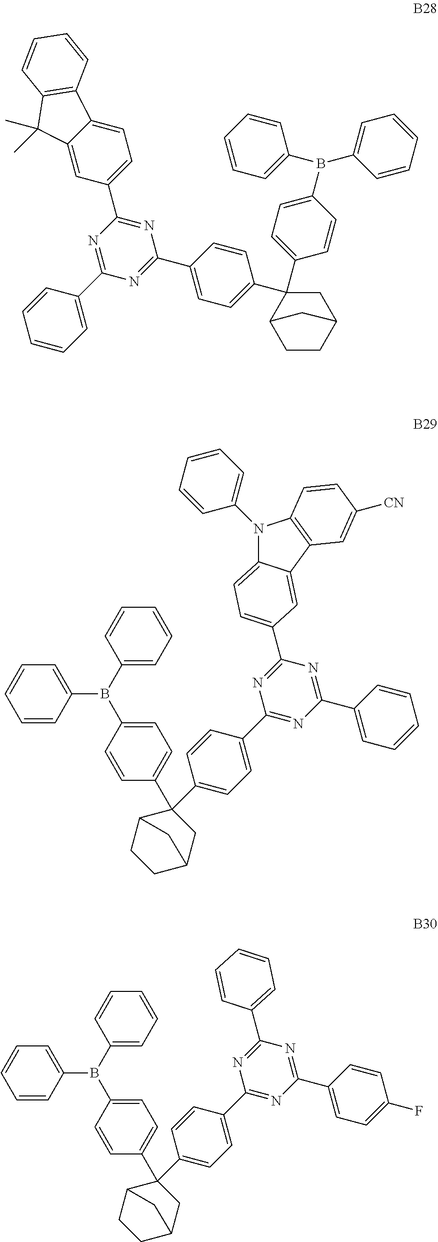 [SMILES: CC1(C)c2ccccc2-c2ccc(-c3nc(-c4ccccc4)nc(-c4ccc(C5(c6ccc(B(c7ccccc7)c7ccccc7)cc6)CC6CCC5C6)cc4)n3)cc21 ; N#Cc1ccc2c(c1)c1cc(-c3nc(-c4ccccc4)nc(-c4ccc(C5(c6ccc(B(c7ccccc7)c7ccccc7)cc6)CC6CCC5C6)cc4)n3)ccc1n2-c1ccccc1 ; Fc1ccc(-c2nc(-c3ccccc3)nc(-c3ccc(C4(c5ccc(B(c6ccccc6)c6ccccc6)cc5)CC5CCC4C5)cc3)n2)cc1]

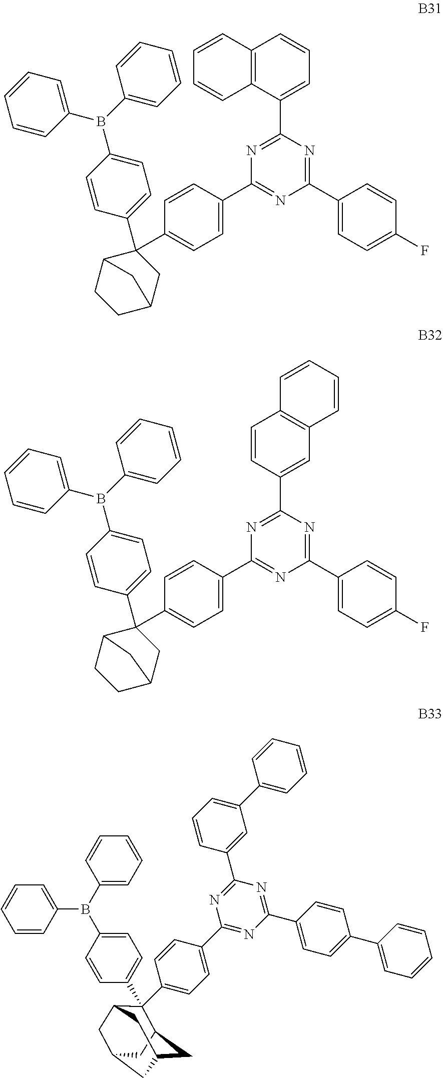

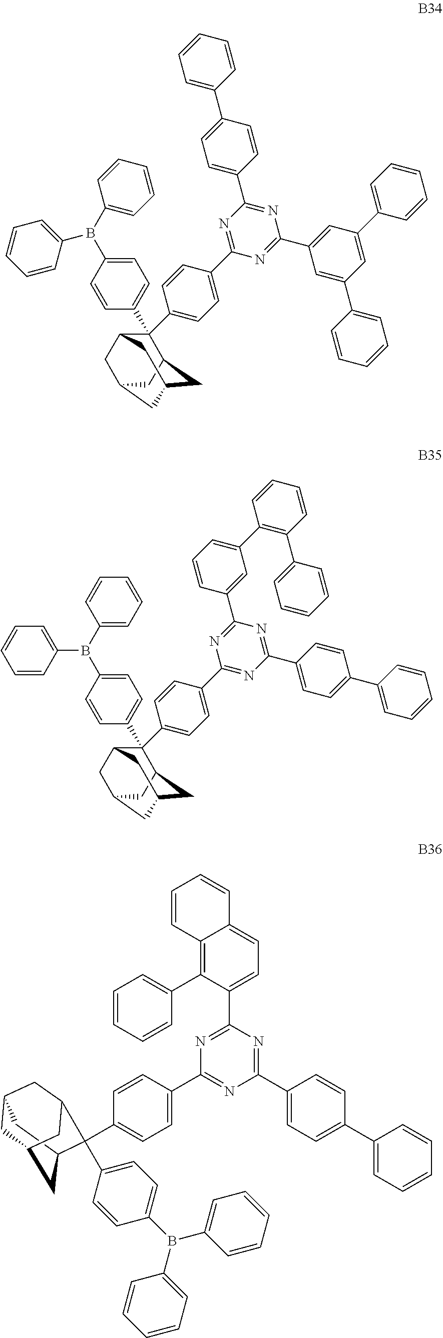

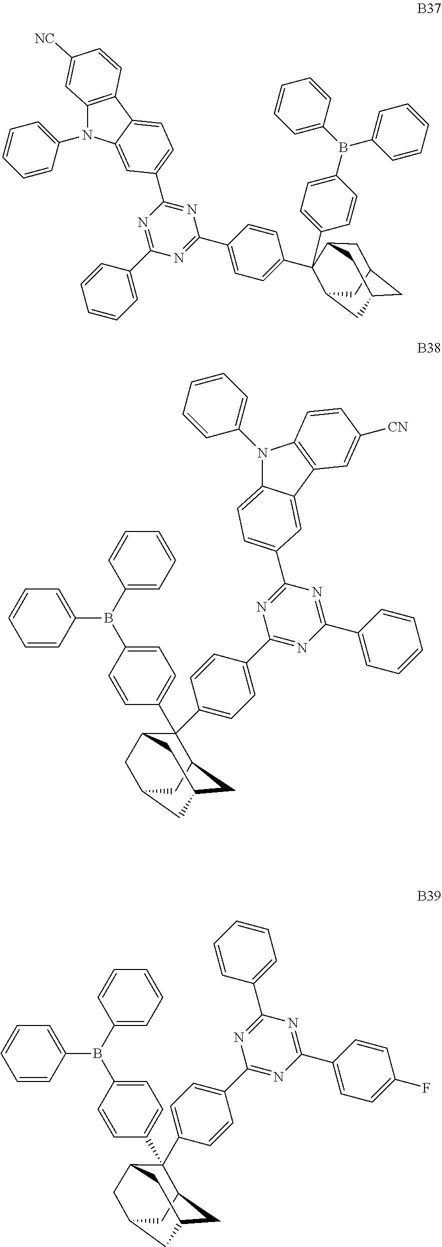

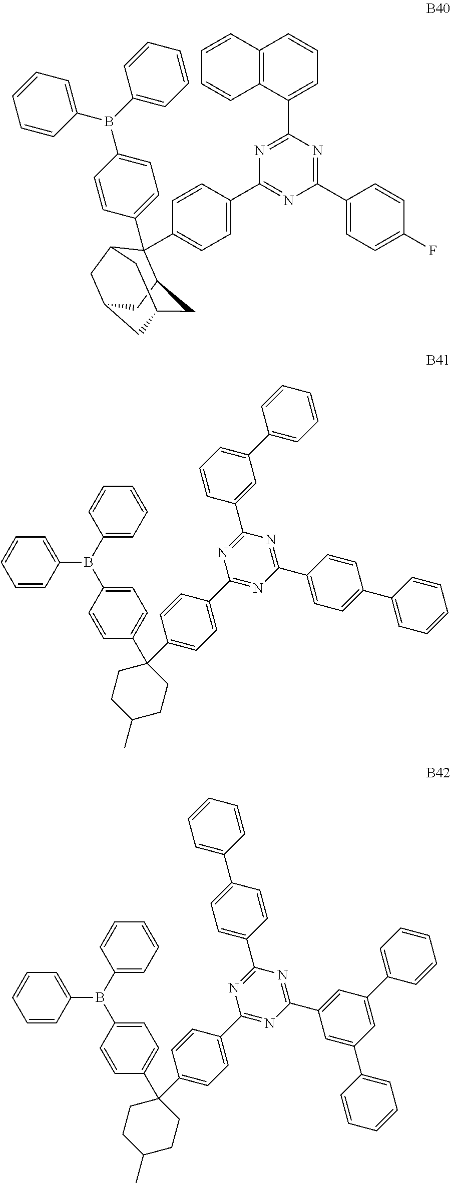 [SMILES: Fc1ccc(-c2nc(-c3ccc(C4(c5ccc(B(c6ccccc6)c6ccccc6)cc5)C5C[C@H]6C[C@@H](C5)C[C@@H]4C6)cc3)nc(-c3cccc4ccccc34)n2)cc1 ; CC1CCC(c2ccc(B(c3ccccc3)c3ccccc3)cc2)(c2ccc(-c3nc(-c4ccc(-c5ccccc5)cc4)nc(-c4cccc(-c5ccccc5)c4)n3)cc2)CC1 ; CC1CCC(c2ccc(B(c3ccccc3)c3ccccc3)cc2)(c2ccc(-c3nc(-c4ccc(-c5ccccc5)cc4)nc(-c4cc(-c5ccccc5)cc(-c5ccccc5)c4)n3)cc2)CC1]

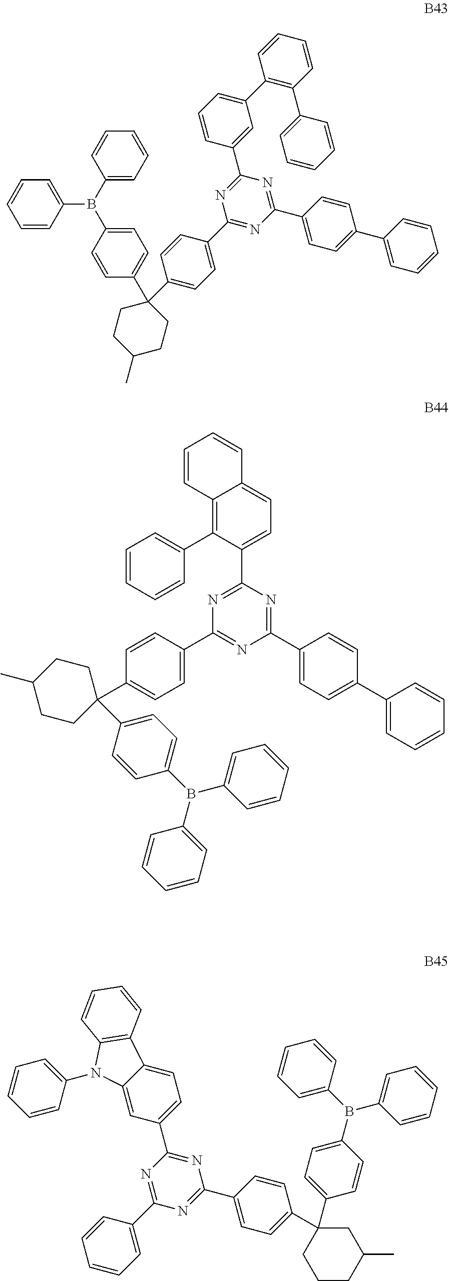 [SMILES: CC1CCC(c2ccc(B(c3ccccc3)c3ccccc3)cc2)(c2ccc(-c3nc(-c4ccc(-c5ccccc5)cc4)nc(-c4cccc(-c5ccccc5-c5ccccc5)c4)n3)cc2)CC1 ; CC1CCC(c2ccc(B(c3ccccc3)c3ccccc3)cc2)(c2ccc(-c3nc(-c4ccc(-c5ccccc5)cc4)nc(-c4ccc5ccccc5c4-c4ccccc4)n3)cc2)CC1 ; CC1CCCC(c2ccc(B(c3ccccc3)c3ccccc3)cc2)(c2ccc(-c3nc(-c4ccccc4)nc(-c4ccc5c6ccccc6n(-c6ccccc6)c5c4)n3)cc2)C1]

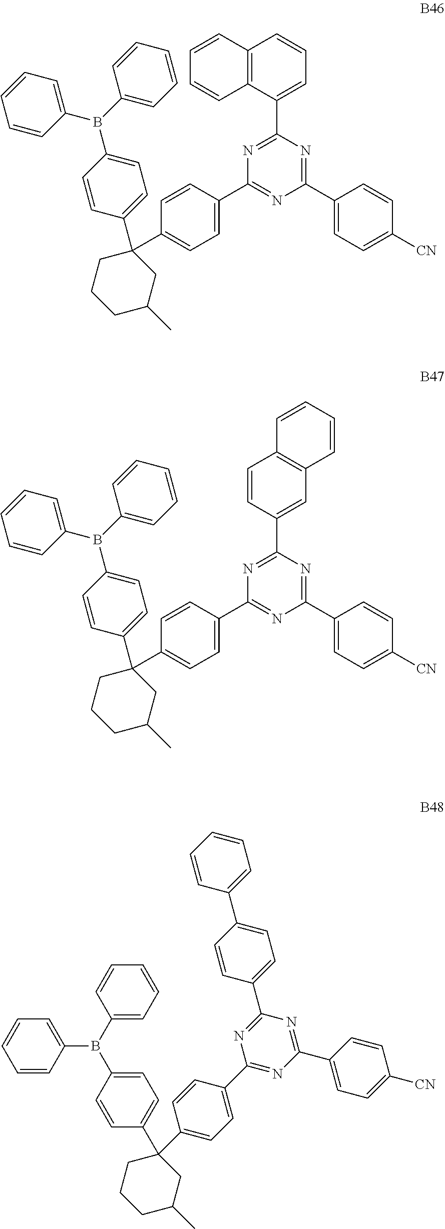 [SMILES: CC1CCCC(c2ccc(B(c3ccccc3)c3ccccc3)cc2)(c2ccc(-c3nc(-c4ccc(C#N)cc4)nc(-c4cccc5ccccc45)n3)cc2)C1 ; CC1CCCC(c2ccc(B(c3ccccc3)c3ccccc3)cc2)(c2ccc(-c3nc(-c4ccc(C#N)cc4)nc(-c4ccc5ccccc5c4)n3)cc2)C1 ; CC1CCCC(c2ccc(B(c3ccccc3)c3ccccc3)cc2)(c2ccc(-c3nc(-c4ccc(C#N)cc4)nc(-c4ccc(-c5ccccc5)cc4)n3)cc2)C1]

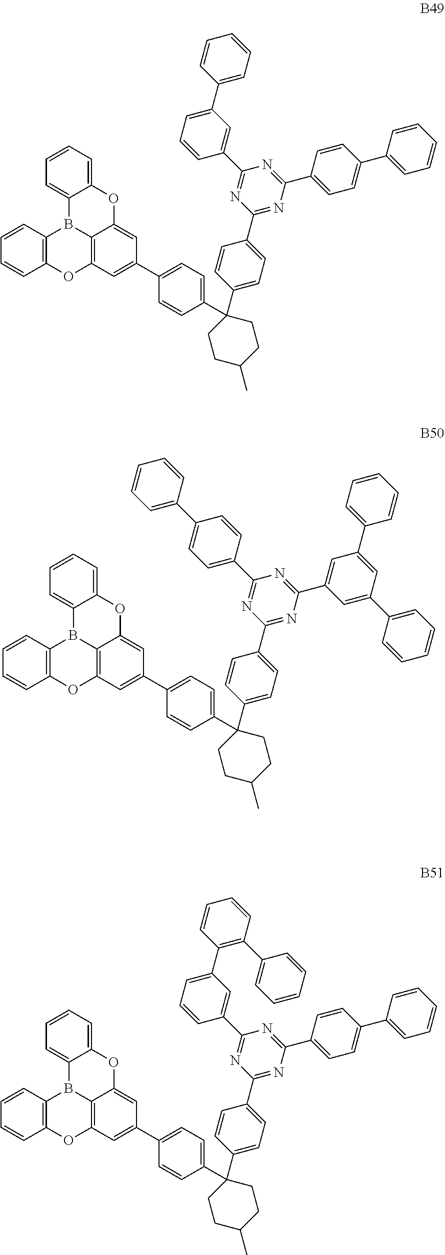 [SMILES: CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5)c4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cc(-c5ccccc5)cc(-c5ccccc5)c4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5-c5ccccc5)c4)n3)cc2)CC1]

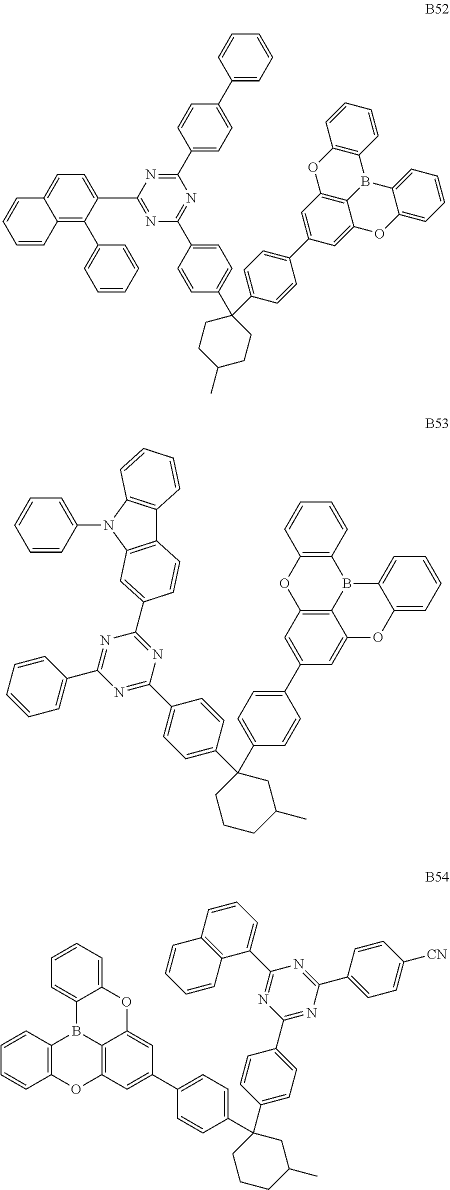 [SMILES: CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5ccccc5c4-c4ccccc4)n3)cc2)CC1 ; CC1CCCC(c2ccc(-c3cc4c5c(c3)Oc3ccccc3B5c3ccccc3O4)cc2)(c2ccc(-c3nc(-c4ccccc4)nc(-c4ccc5c6ccccc6n(-c6ccccc6)c5c4)n3)cc2)C1 ; CC1CCCC(c2ccc(-c3cc4c5c(c3)Oc3ccccc3B5c3ccccc3O4)cc2)(c2ccc(-c3nc(-c4ccc(C#N)cc4)nc(-c4cccc5ccccc45)n3)cc2)C1]

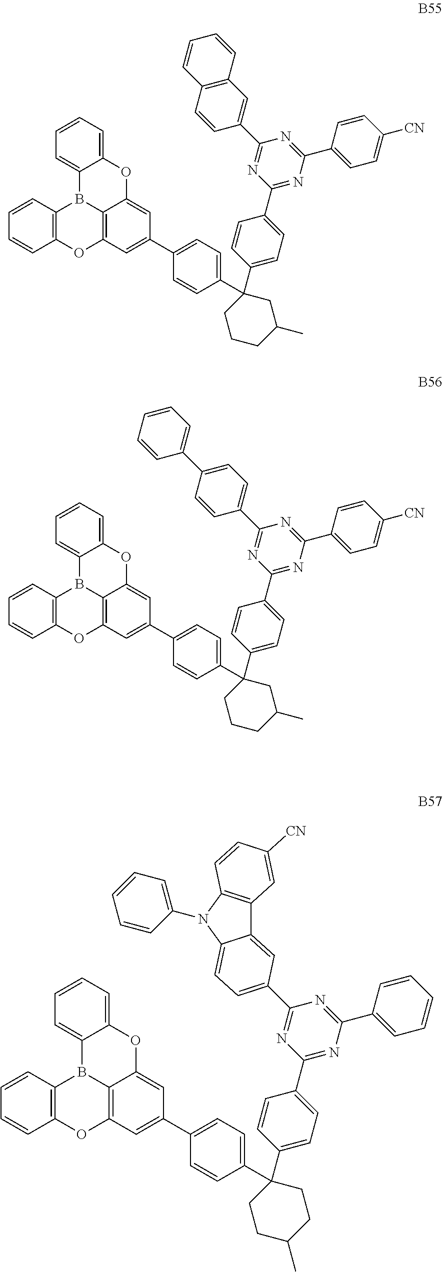 [SMILES: CC1CCCC(c2ccc(-c3cc4c5c(c3)Oc3ccccc3B5c3ccccc3O4)cc2)(c2ccc(-c3nc(-c4ccc(C#N)cc4)nc(-c4ccc5ccccc5c4)n3)cc2)C1 ; CC1CCCC(c2ccc(-c3cc4c5c(c3)Oc3ccccc3B5c3ccccc3O4)cc2)(c2ccc(-c3nc(-c4ccc(C#N)cc4)nc(-c4ccc(-c5ccccc5)cc4)n3)cc2)C1 ; CC1CCC(c2ccc(-c3cc4c5c(c3)Oc3ccccc3B5c3ccccc3O4)cc2)(c2ccc(-c3nc(-c4ccccc4)nc(-c4ccc5c(c4)c4cc(C#N)ccc4n5-c4ccccc4)n3)cc2)CC1]

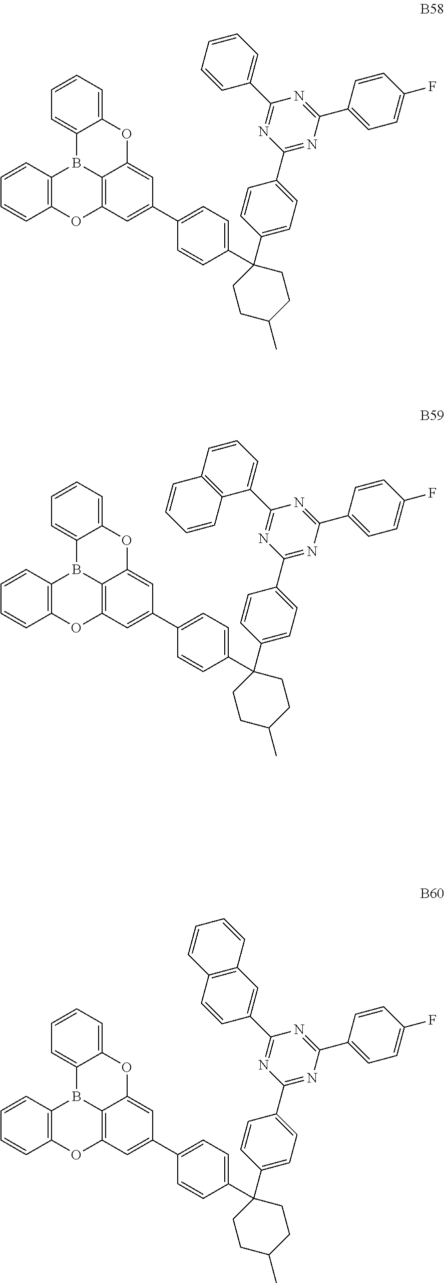 [SMILES: CC1CCC(c2ccc(-c3cc4c5c(c3)Oc3ccccc3B5c3ccccc3O4)cc2)(c2ccc(-c3nc(-c4ccccc4)nc(-c4ccc(F)cc4)n3)cc2)CC1 ; CC1CCC(c2ccc(-c3cc4c5c(c3)Oc3ccccc3B5c3ccccc3O4)cc2)(c2ccc(-c3nc(-c4ccc(F)cc4)nc(-c4cccc5ccccc45)n3)cc2)CC1 ; CC1CCC(c2ccc(-c3cc4c5c(c3)Oc3ccccc3B5c3ccccc3O4)cc2)(c2ccc(-c3nc(-c4ccc(F)cc4)nc(-c4ccc5ccccc5c4)n3)cc2)CC1]

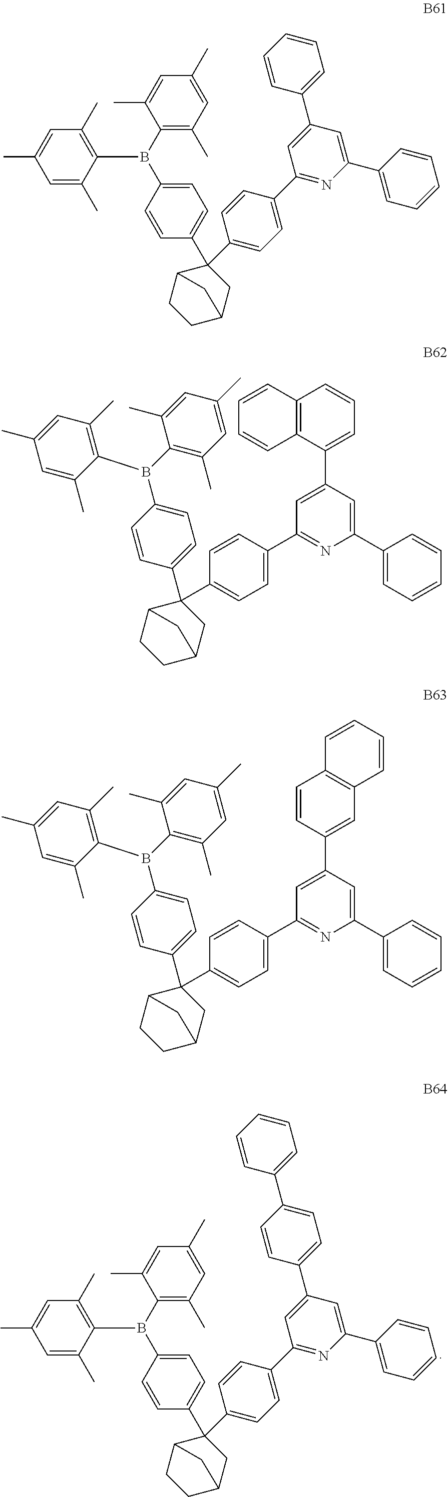 [SMILES: Cc1cc(C)c(B(c2ccc(C3(c4ccc(-c5cc(-c6ccccc6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cccc7ccccc67)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc7ccccc7c6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc(-c7ccccc7)cc6)cc(-c6ccccc6)n5)cc4)CC4CCC3C4)cc2)c2c(C)cc(C)cc2C)c(C)c1]

In one or more embodiments, in the light-emitting device, a ratio between the weight of the first compound and the weight of the second compound may be 3:7 to 7:3. The ratio between the weight of the first compound and the weight of the second compound in the electron transport layer may be 3:7 to 7:3. For example, the ratio between the weight of the first compound in the electron transport layer and the weight of the second compound in the electron transport layer may be 5:5.

According to one or more embodiments, an electronic apparatus may include: the light-emitting device; and a thin-film transistor electrically connected to the light-emitting device. For example, the thin-film transistor may include a source electrode and a drain electrode, and the first electrode of the light-emitting device may be electrically connected to the source electrode or the drain electrode. The electronic apparatus may further include a color filter, a color conversion layer, a touch screen layer, a polarizing layer, or any combination thereof. More details on the electronic apparatus may be referred to the descriptions provided herein.

According to one or more embodiments, electronic equipment may include the light-emitting device, wherein the electronic equipment may be one selected from among a flat panel display, a curved display, a computer monitor, a medical monitor, a television, a billboard, a light for indoor or outdoor lighting and/or signaling (e.g., a light for indoor or outdoor lighting (e.g., an indoor or outdoor light) or a light for indoor or outdoor signaling (e.g., an indoor or outdoor light for signal)), a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual or augmented reality display, a vehicle, a video wall including a plurality of displays tiled together, a theater or stadium screen, a phototherapy device, a signboard, and/or the like.

As such, one or more embodiments of the present disclosure may include both (e.g., simultaneously) of the first compound and the second compound. By including the first compound, the driving voltage and/or luminescence efficiency may be improved (e.g., to provide suitable driving voltage and/or luminescence efficiency), and by including the second compound, the lifespan may be enhanced (e.g., to provide the suitable lifespan). As the first compound and the second compound do not diminish each other's characteristics (e.g., each of the first compound and the second compound does not affect or influence each other), if (e.g., when) the first compound and the second compound are used as a mixture, at least one selected from among the driving voltage, luminescence efficiency, and lifespan may be improved (e.g., to provide the suitable driving voltage, luminescence efficiency, and/or lifespan), and the other characteristics may also be excellent or suitable, compared to if (e.g., when) only one selected from the first compound and the second compound is used.

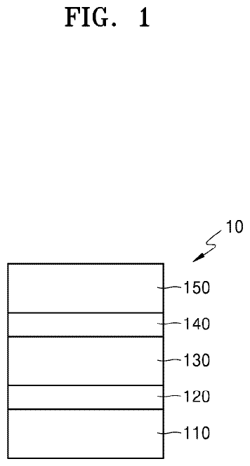

### Description of FIG. 1

FIG. 1 is a schematic cross-sectional view of a light-emitting device 10 according to one or more embodiments. The light-emitting device 10 may include a first electrode 110, an interlayer, and a second electrode 150. The interlayer may include a hole transport region 120, an emission layer 130, and an electron transport region 140.

Hereinafter, a structure of the light-emitting device 10 according to one or more embodiments and a method of manufacturing the light-emitting device 10 are described with reference to FIG. 1.

### First Electrode 110

In FIG. 1, a substrate may be further arranged under the first electrode 110 or on the second electrode 150. As the substrate, a glass substrate and/or a plastic substrate may be used. The substrate may be a flexible substrate. For example, the substrate may include plastics that have excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed or provided by depositing and/or sputtering a material that forms or provides the first electrode 110 on the substrate. If (e.g., when) the first electrode 110 is an anode, a high-work function material that facilitates injection of holes may be used acting or serving as a material that forms or provides the first electrode 110.

The first electrode 110 may be a reflective electrode, a semi-transmissive electrode, or a transmissive electrode. If (e.g., when) the first electrode 110 is a transmissive electrode, a material that forms or provides the first electrode 110 may include indium tin oxide (ITO), indium zinc oxide (IZO), tin oxide (SnO₂), zinc oxide (ZnO), or any combination thereof. If (e.g., when) the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used acting or serving as a material that forms or provides the first electrode 110.

The first electrode 110 may have a single-layered structure consisting of a single layer or a multi-layered structure including a plurality of layers. In one or more embodiments, the first electrode 110 may have a three-layer structure of ITO/Ag/ITO.

### Interlayer

The interlayer may be disposed (or provided or arranged) on a first electrode 110. The interlayer may include a hole transport region 120, an emission layer 130, and an electron transport region 140.

The interlayer may include one or more suitable organic materials, a metal-containing compound, such as an organometallic compound, an inorganic material, such as quantum dots, and/or the like.

In one or more embodiments, the interlayer may include i) at least two emitting units sequentially stacked between the first electrode 110 and the second electrode 150 and ii) a charge generation layer disposed (or provided or arranged) between the at least two emitting units. If (e.g., when) the interlayer includes the emitting units and the charge generation layer as described above, the light-emitting device 10 may be a tandem light-emitting device.

### Hole Transport Region 120

The hole transport region 120 may have i) a single-layer structure consisting of a single layer that may include a single material, ii) a single-layer structure consisting of a single layer that may include a plurality of materials that are different from each other, or iii) a multi-layer structure consisting of a plurality of layers that may include a plurality of different materials that are different from each other.

The hole transport region 120 may include a hole injection layer, a hole transport layer, an emission auxiliary layer, an electron-blocking layer, or any combination thereof.

For example, the hole transport region 120 may have a multi-layer structure that includes a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein constituent layers of each structure may be stacked sequentially from the first electrode 110.

The hole transport region may include a compound represented by Formula 201, a compound represented by Formula 202, or any combination thereof:

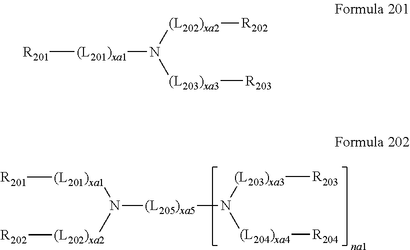

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer of 0 to 5,
xa5 may be an integer of 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (for example, a carbazole group) unsubstituted or substituted with at least one R₁₀ₐ (for example, Compound HT16),
R₂₀₃ and R₂₀₄ may optionally be linked to each other via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer of 1 to 4.

In one or more embodiments, each of Formulae 201 and 202 may include at least one selected from among the groups represented by Formulae CY₂₀₁ to CY₂₁₇:

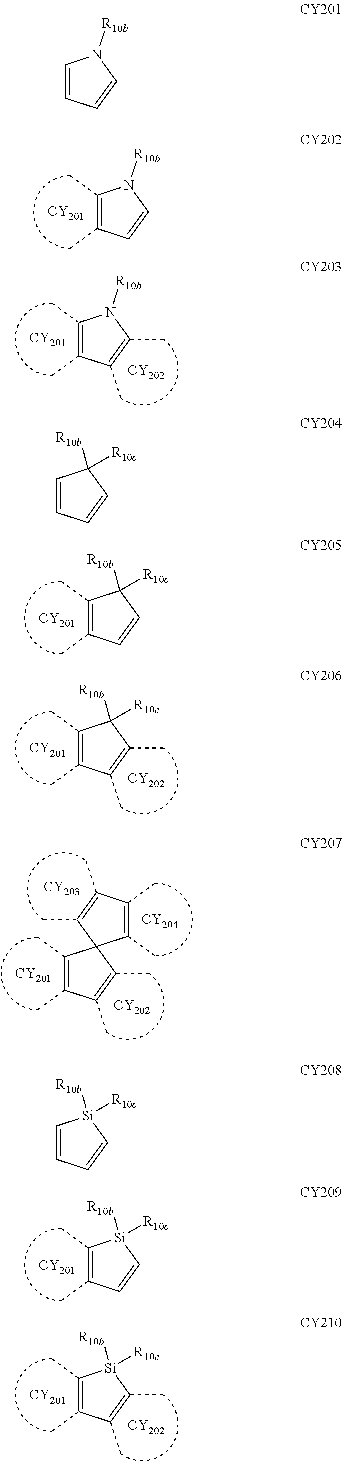

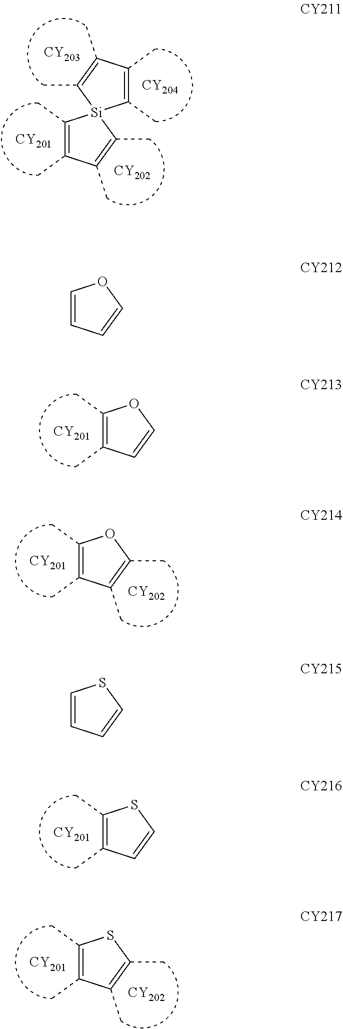

wherein, in Formulae CY₂₀₁ to CY₂₁₇, R_{10b} and R_{10c} may each independently be the same (e.g., substantially the same) as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY₂₀₁ to CY217 may be unsubstituted or substituted with R₁₀ₐ.

In one or more embodiments, in Formulae CY₂₀₁ to CY₂₁₇, ring CY₂₀₁ to ring CY₂₀₄ may each independently be a benzene group, a naphthalene group, a phenanthrene group, or an anthracene group.

In one or more embodiments, each of Formulae 201 and 202 may include at least one selected from among the groups represented by Formulae CY201 to CY203.

In another embodiment, Formula 201 may include at least one selected from among the groups represented by Formulae CY201 to CY203 and at least one selected from among the groups represented by Formulae CY204 to CY217.

In one or more embodiments, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

In one or more embodiments, each of Formulae 201 and 202 may not include groups represented by Formulae CY201 to CY203.

In one or more embodiments, Formulae 201 and 202 may each independently not include the groups represented by Formulae CY201 to CY203, and may include at least one selected from among the groups represented by Formulae CY204 to CY217.

In one or more embodiments, each of Formulae 201 and 202 may not include groups represented by Formulae CY201 to CY217.

In one or more embodiments, the hole transport region may include one selected from among Compounds HT1 to HT46, m-MTDATA, TDATA, 2-TNATA, NPB(NPD), ρ-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), or any combination thereof:

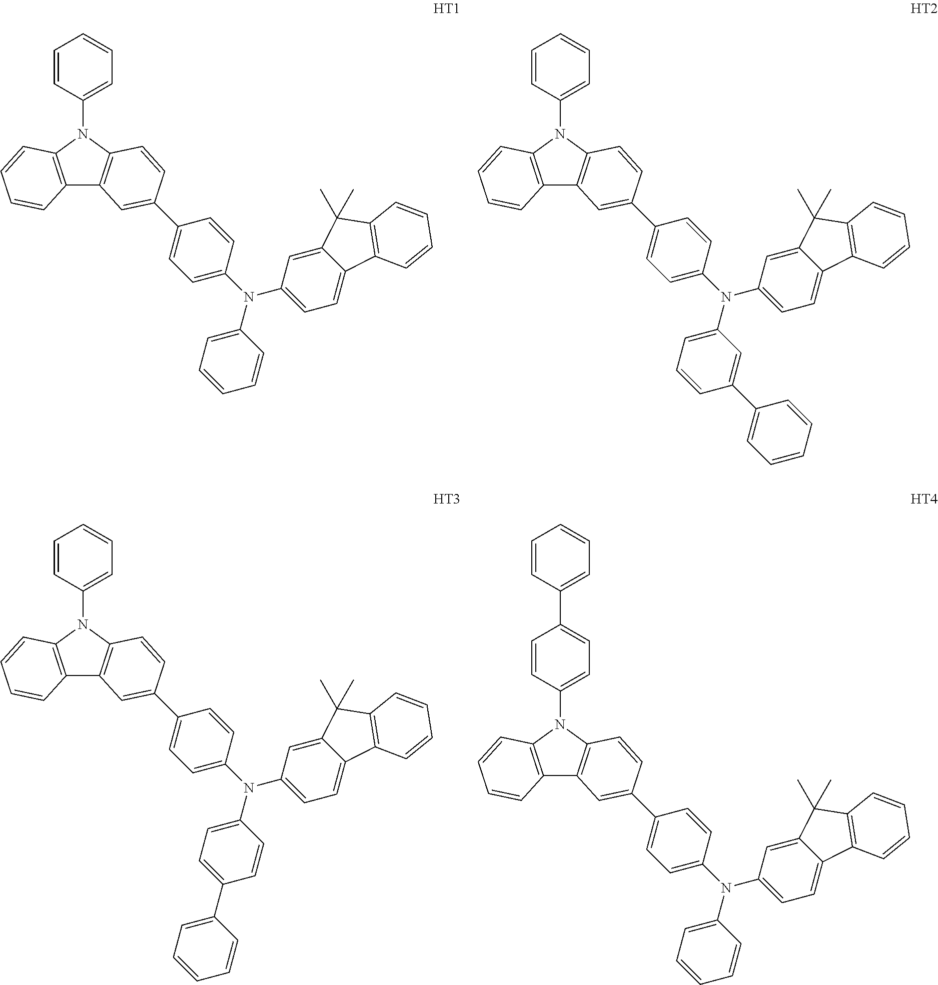 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

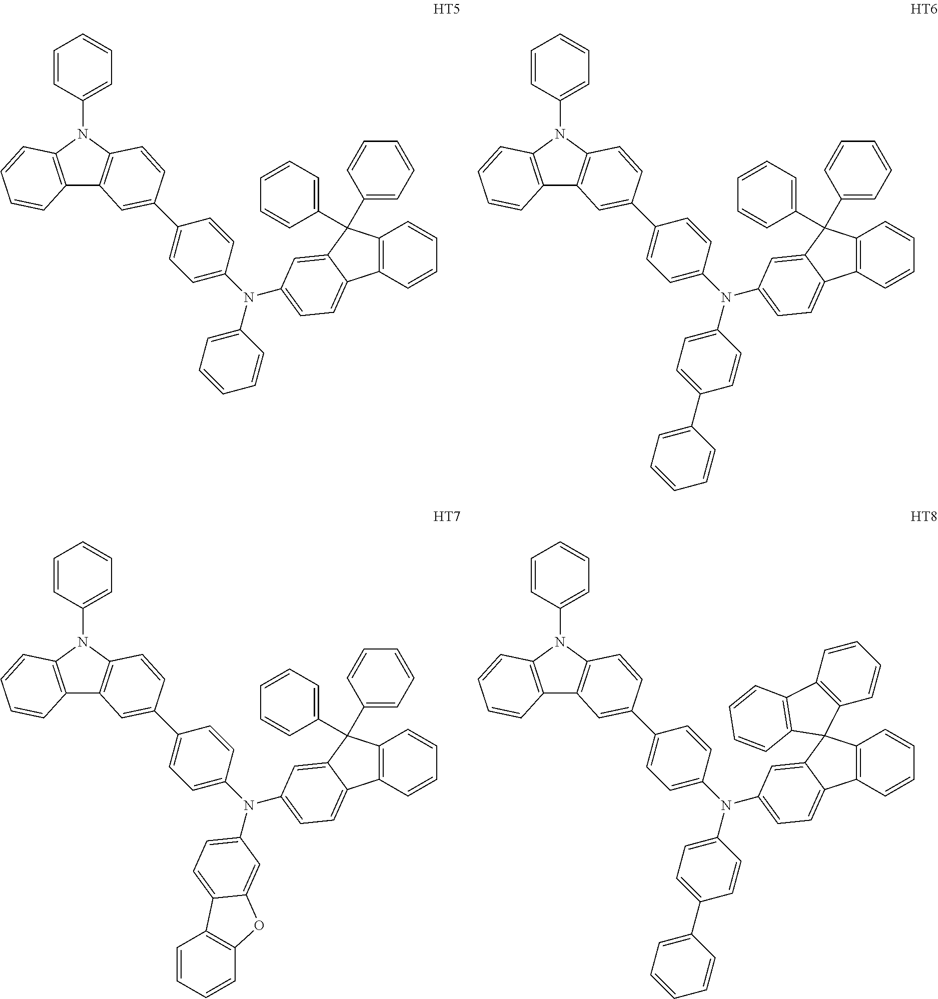 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

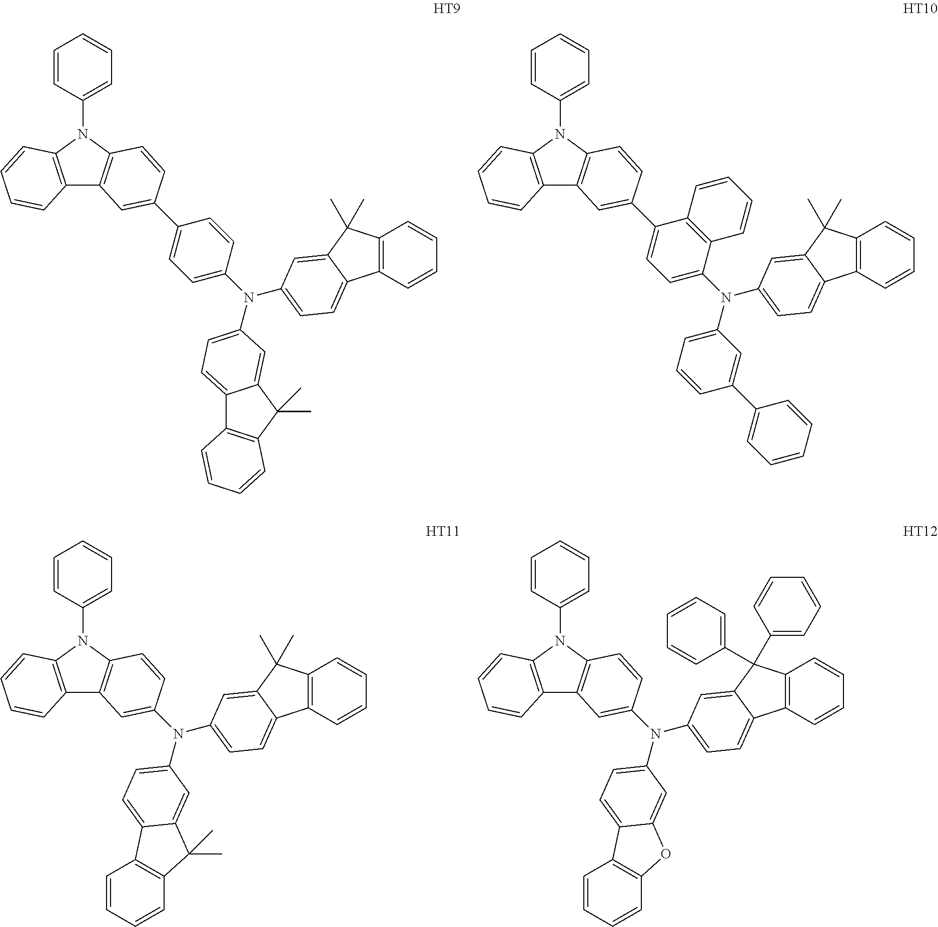 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

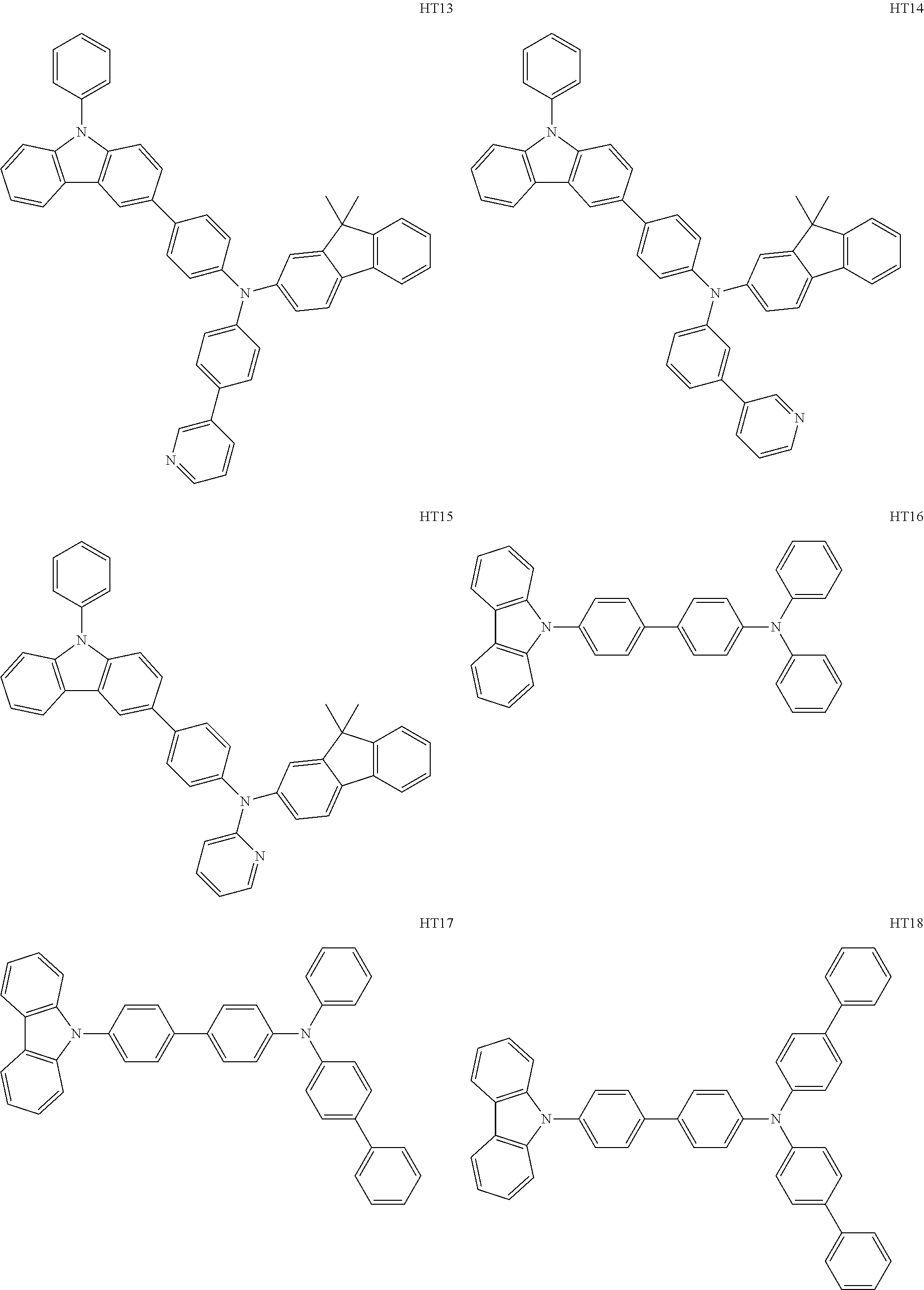 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

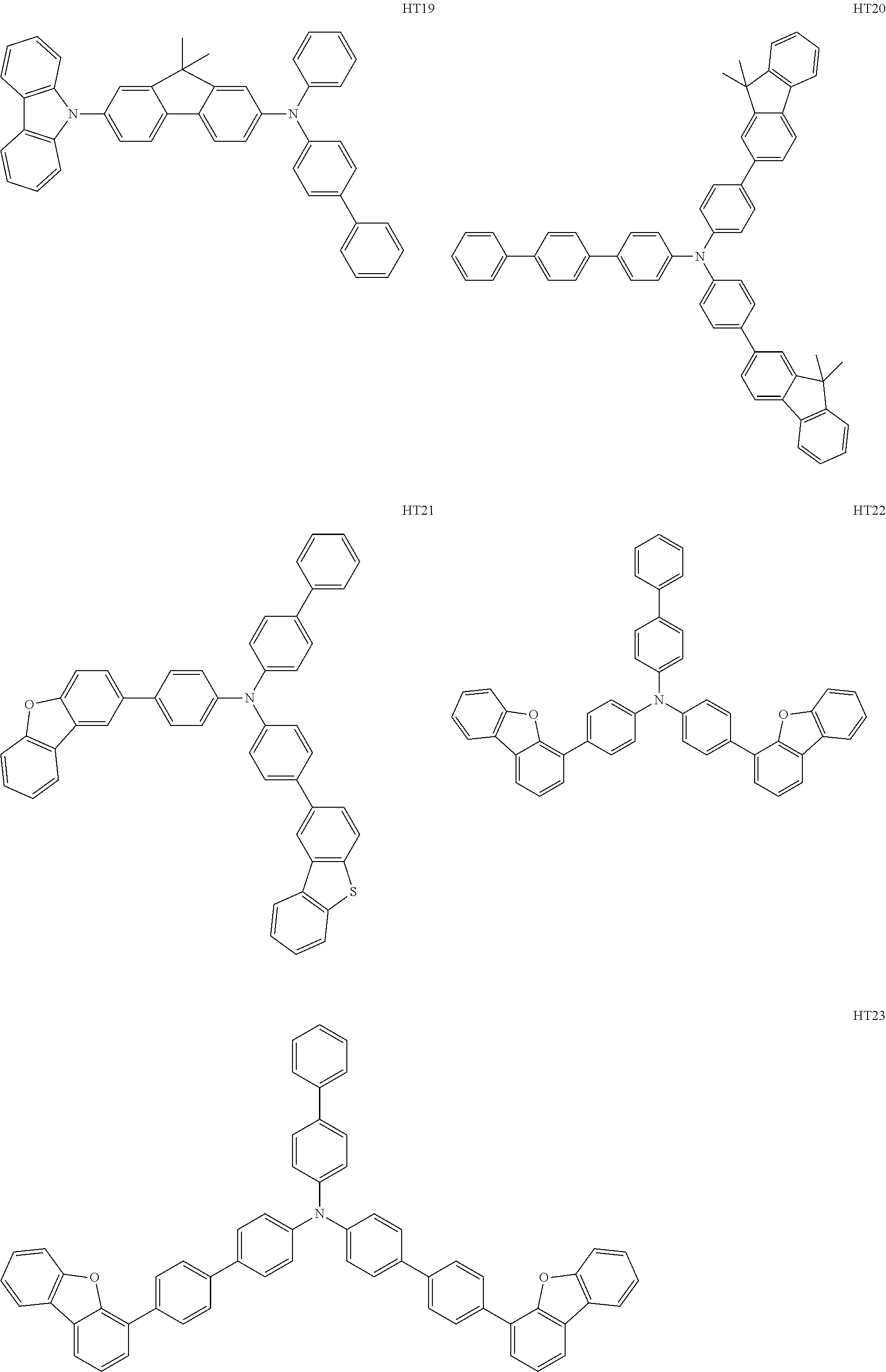 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

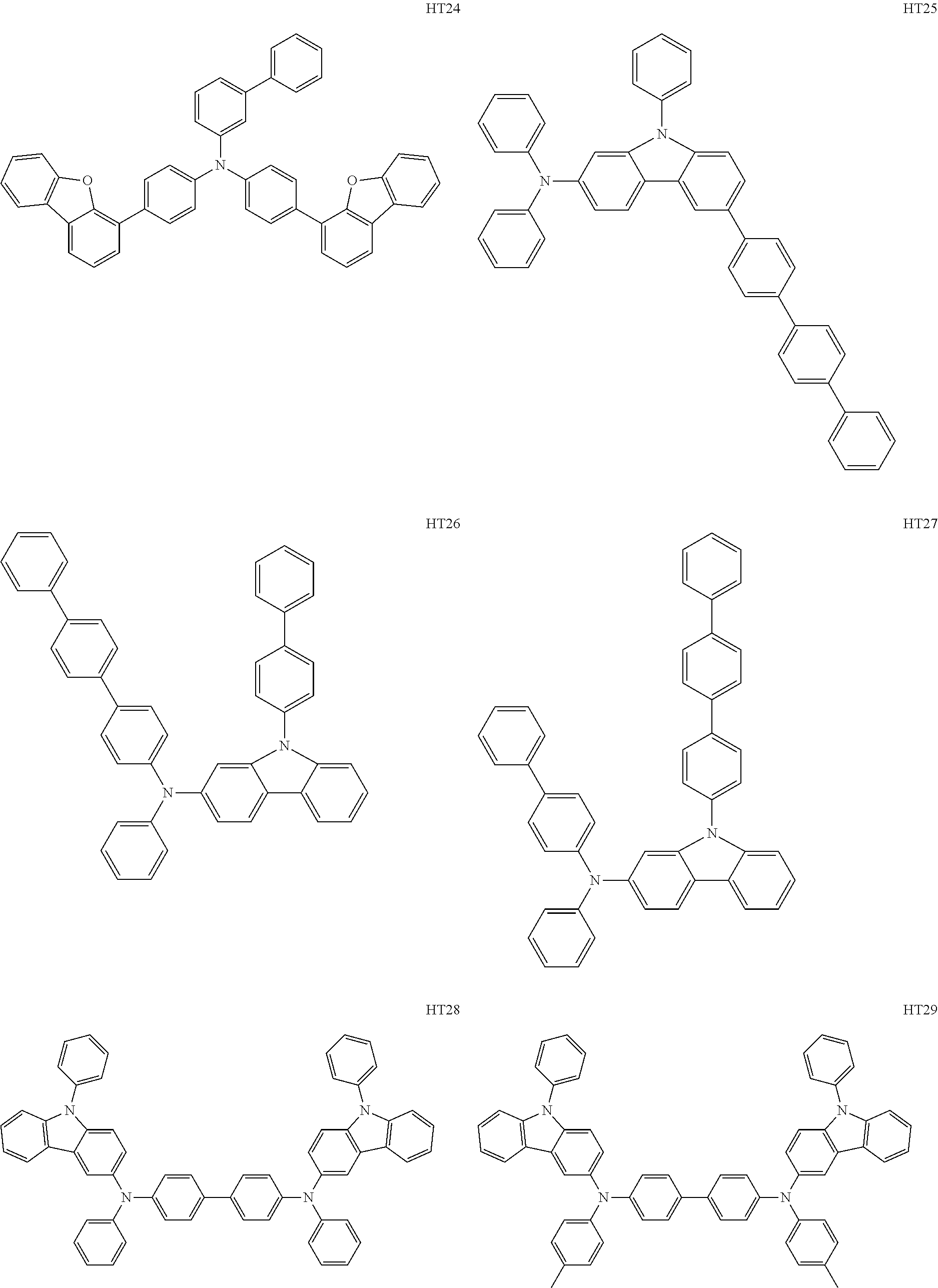

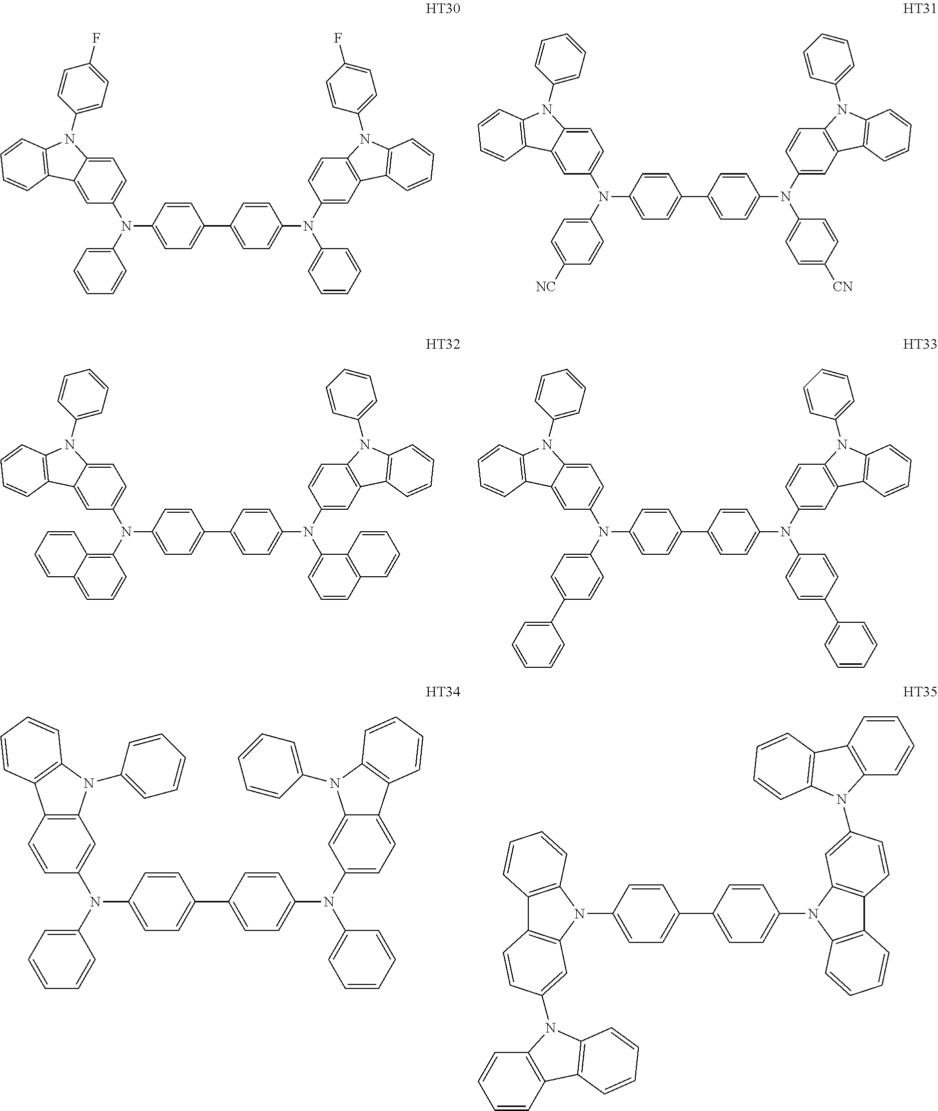

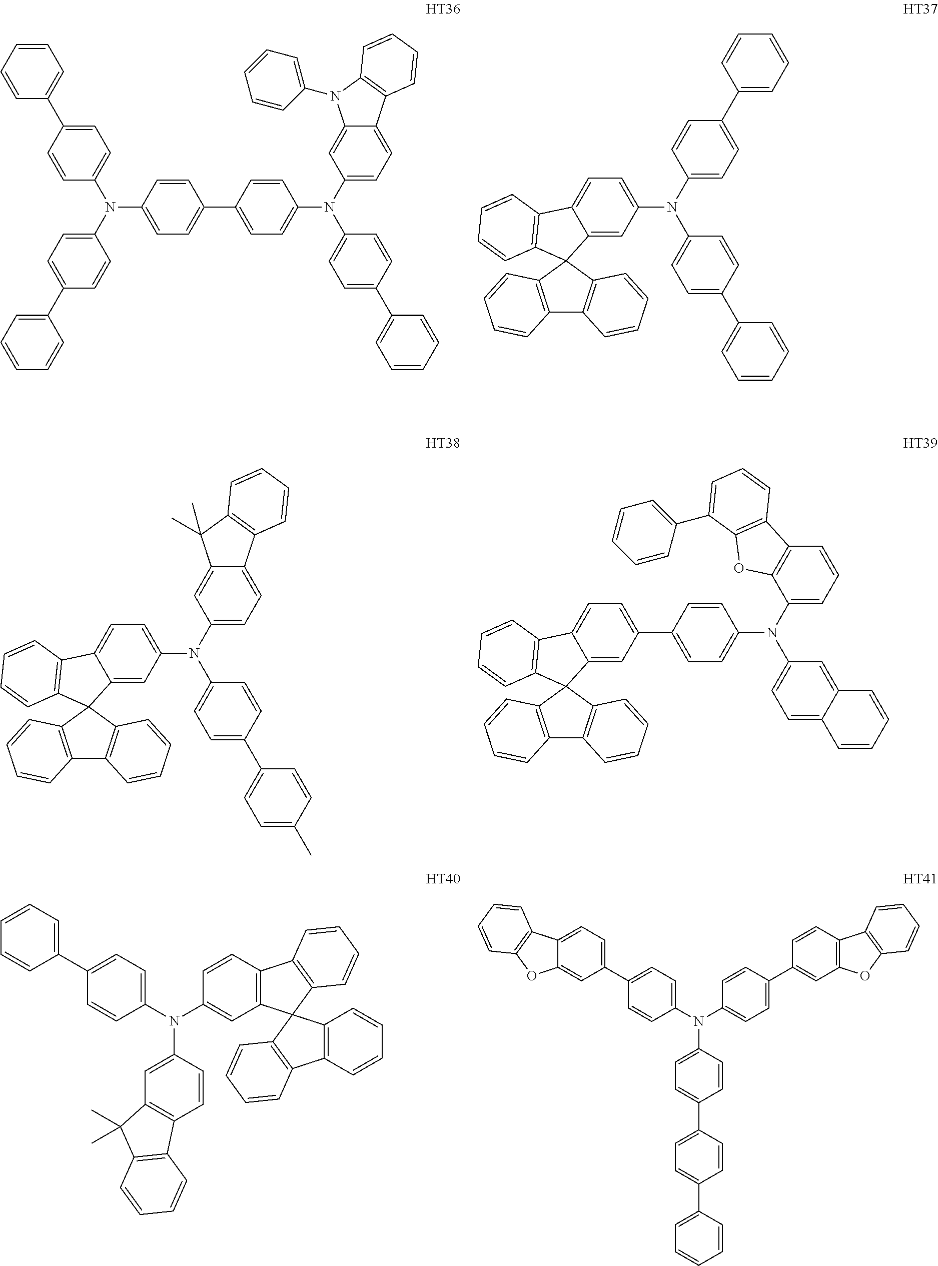

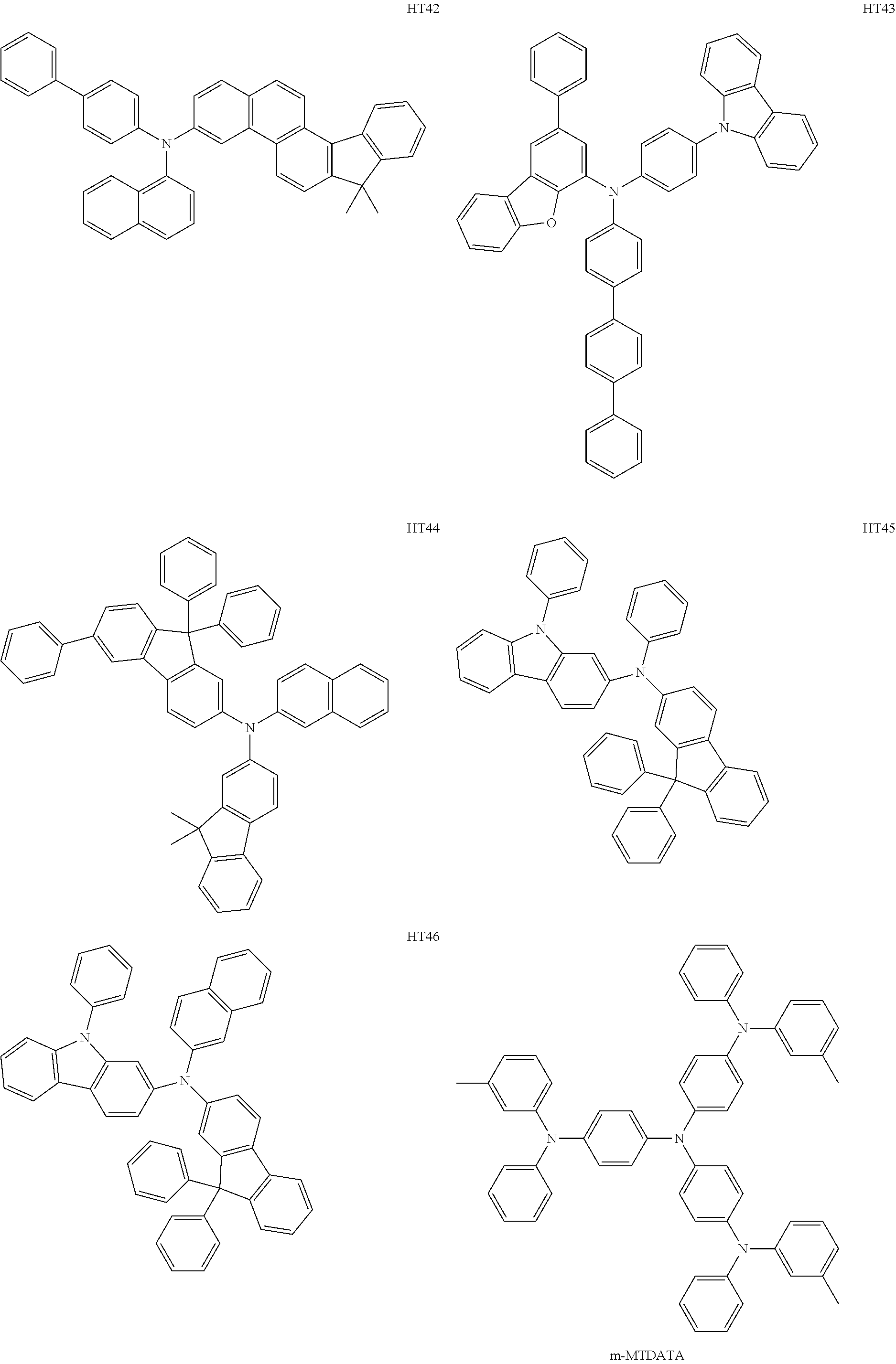

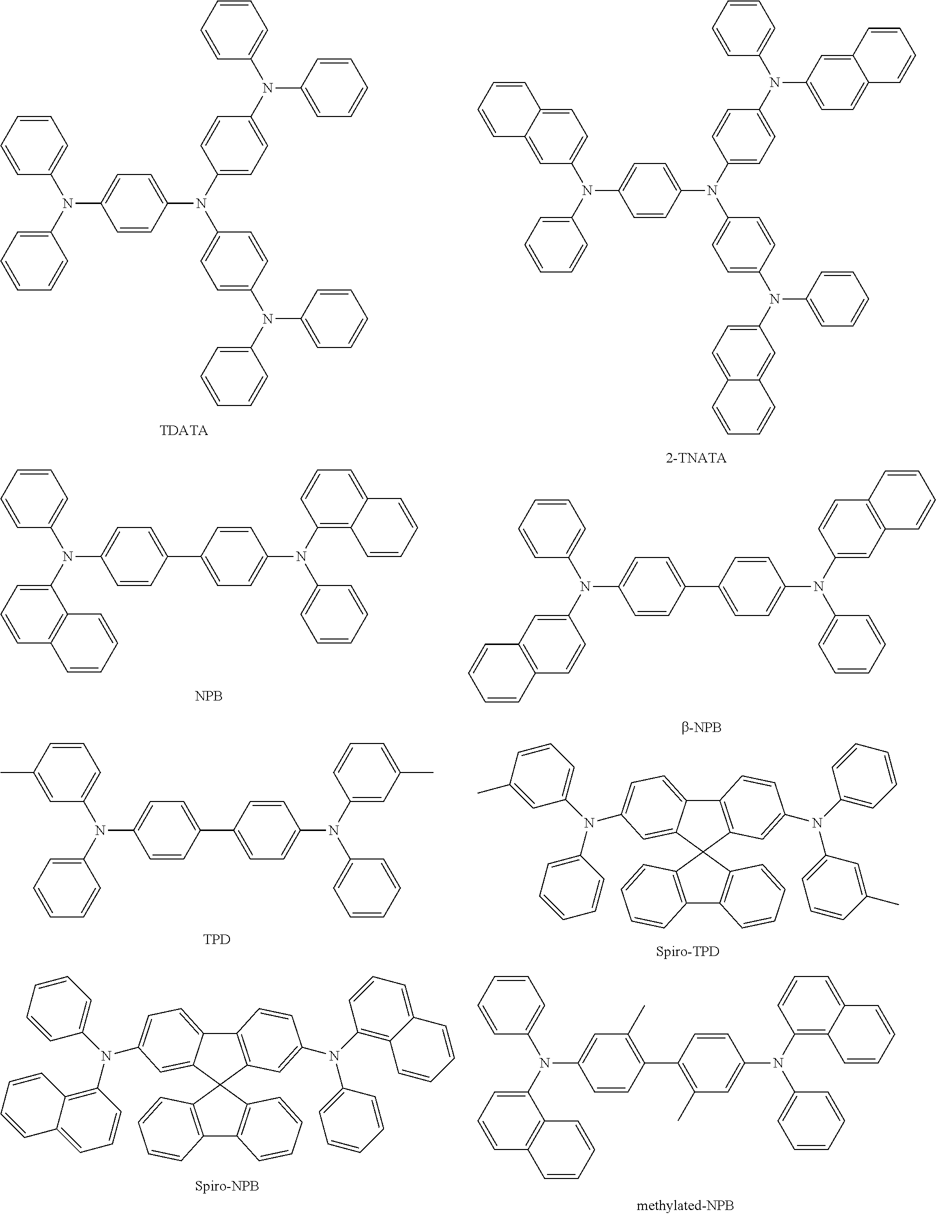

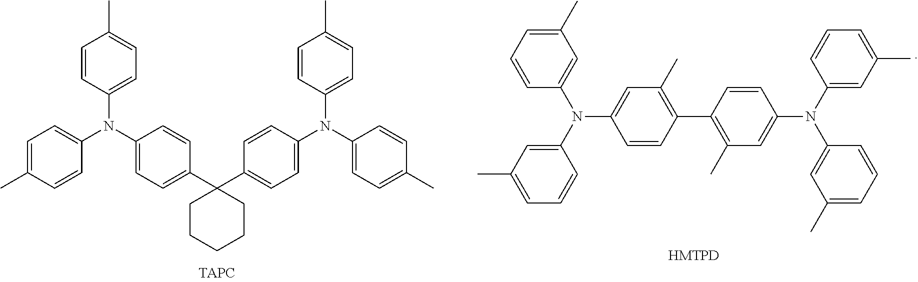

The thickness of the hole transport region may be about 50 Å to about 10,000 Å, for example, about 100 Å to about 4,000 Å. If (e.g., when) the hole transport region includes a hole injection layer, a hole transport layer, or any combination thereof, the thickness of the hole injection layer may be about 100 Å to about 9,000 Å, for example, about 100 Å to about 1,000 Å, and the thickness of the hole transport layer may be about 50 Å to about 2,000 Å, for example, about 100 Å to about 1,500 Å. If (e.g., when) the thicknesses of the hole transport region, the hole injection layer, and the hole transport layer are within the ranges described above, satisfactory or suitable hole transporting characteristics may be obtained not having a substantial increase in driving voltage (e.g., may be obtained having a suitable increase in driving voltage).

The emission auxiliary layer may act or serve to increase light-emission efficiency (e.g., suitable light-emission efficiency) by compensating for an optical resonance distance according to the wavelength of light emitted by the emission layer. The electron-blocking layer may act or serve to prevent or reduce electron leakage (or to reduce a degree or occurrence of electron leakage) from the emission layer to the hole transport region. Materials that may be in the hole transport region may be in the emission auxiliary layer and the electron-blocking layer.

p-dopant

The hole transport region 120 may further include, in addition to the materials as described in one or more embodiments of the present disclosure, a charge-generation material for the improvement of conductive properties (e.g., electrically conductive properties). The charge-generation material may be uniformly (e.g., substantially uniformly) or non-uniformly (e.g., substantially non-uniformly) dispersed or distributed in the hole transport region (for example, in the form of a single layer consisting of a charge-generation material).

The charge-generation material may be, for example, a p-dopant. For example, the p-dopant may have a lowest unoccupied molecular orbital (LUMO) energy level of about −3.5 eV or less.

In one or more embodiments, the p-dopant may include a quinone derivative, a cyano group-containing compound, a compound including an element EL1 and an element EL2, or any combination thereof.

Examples of the quinone derivative may include TCNQ and F4-TCNQ.

Examples of the cyano group-containing compound may include HAT-CN and a compound represented by Formula 221:

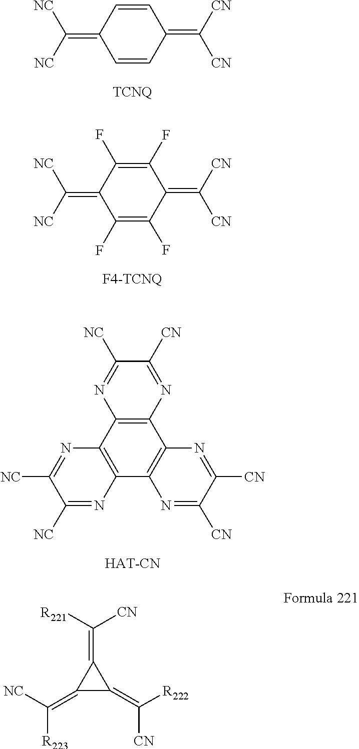

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including the element EL1 and the element EL2, the element EL1 may be a metal, a metalloid, or a combination thereof, and the element EL2 may be a non-metal, a metalloid, or a combination thereof.

Examples of the metal may include an alkali metal (for example, lithium (Li), sodium (Na), potassium (K), rubidium (Rb), cesium (Cs), and/or the like); an alkaline earth metal (for example, beryllium (Be), magnesium (Mg), calcium (Ca), strontium (Sr), barium (Ba), and/or the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (for example, zinc (Zn), indium (In), tin (Sn), and/or the like); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Examples of the metalloid may include silicon (Si), antimony (Sb), and tellurium (Te).

Examples of the non-metal may include oxygen (O) and halogen (for example, F, Cl, Br, I, and/or the like).

Examples of the compound including the element EL1 and the element EL2 may include a metal oxide, a metal halide (for example, a metal fluoride, a metal chloride, a metal bromide, a metal iodide, and/or the like), a metalloid halide (for example, a metalloid fluoride, a metalloid chloride, a metalloid bromide, a metalloid iodide, and/or the like), a metal telluride, or any combination thereof.

Examples of the metal oxide may include a tungsten oxide (for example, WO, W₂O₃, WO₂, WO₃, W₂O₅, and/or the like), a vanadium oxide (for example, VO, V₂O₃, VO₂, V₂O₅, and/or the like), a molybdenum oxide (for example, MoO, Mo₂O₃, MoO₂, MoO₃, Mo₂O₅, and/or the like), a rhenium oxide (for example, ReO₃, and/or the like), and/or the like

Examples of the metal halide may include an alkali metal halide, an alkaline earth metal halide, a transition metal halide, a post-transition metal halide, and a lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, Kl, RbI, and CsI. Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide may include a titanium halide (for example, TiF₄, TiCl₄, TiBr₄, TiI₄, and/or the like), a zirconium halide (for example, ZrF₄, ZrCl₄, ZrBr₄, ZrI₄, and/or the like), a hafnium halide (for example, HfF₄, HfCl₄, HfBr₄, HfI₄, and/or the like), a vanadium halide (for example, VF₃, VCl₃, VBr₃, VI₃, and/or the like), a niobium halide (for example, NbF₃, NbCl₃, NbBr₃, NbI₃, and/or the like), a tantalum halide (for example, TaF₃, TaCl₃, TaBr₃, TaI₃, and/or the like), a chromium halide (for example, CrF₃, CrO₃, CrBr₃, CrI₃, and/or the like), a molybdenum halide (for example, MoF₃, MoCl₃, MoBr₃, MoI₃, and/or the like), a tungsten halide (for example, WF₃, WCl₃, WBr₃, WI₃, and/or the like), a manganese halide (for example, MnF₂, MnCl₂, MnBr₂, MnI₂, and/or the like), a technetium halide (for example, TcF₂, TcCl₂, TcBr₂, TcI₂, and/or the like), a rhenium halide (for example, ReF₂, ReCl₂, ReBr₂, ReI₂, and/or the like), an iron halide (for example, FeF₂, FeCl₂, FeBr₂, FeI₂, and/or the like), a ruthenium halide (for example, RuF₂, RuCl₂, RuBr₂, RuI₂, and/or the like), an osmium halide (for example, OsF₂, OsCl₂, OsBr₂, OsI₂, and/or the like), a cobalt halide (for example, CoF₂, COCl₂, CoBr₂, CoI₂, and/or the like), a rhodium halide (for example, RhF₂, RhCl₂, RhBr₂, Rhl₂, and/or the like), an iridium halide (for example, IrF₂, IrCl₂, IrBr₂, IrI₂, and/or the like), a nickel halide (for example, NiF₂, NiCl₂, NiBr₂, NiI₂, and/or the like), a palladium halide (for example, PdF₂, PdCl₂, PdBr₂, PdI₂, and/or the like), a platinum halide (for example, PtF₂, PtCl₂, PtBr₂, PtI₂, and/or the like), a copper halide (for example, CuF, CuCl, CuBr, CuI, and/or the like), a silver halide (for example, AgF, AgCl, AgBr, AgI, and/or the like), and a gold halide (for example, AuF, AuCl, AuBr, AuI, and/or the like).

Examples of the post-transition metal halide may include a zinc halide (for example, ZnF₂, ZnCl₂, ZnBr₂, ZnI₂, and/or the like), an indium halide (for example, InI₃, and/or the like), a tin halide (for example, SnI₂ and/or the like), and/or the like.

Examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Examples of the metalloid halide may include an antimony halide (for example, SbCl₅ and/or the like).

Examples of the metal telluride may include an alkali metal telluride (for example, Li₂Te, Na₂Te, K₂Te, Rb₂Te, Cs₂Te, and/or the like), an alkaline earth metal telluride (for example, BeTe, MgTe, CaTe, SrTe, BaTe, and/or the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (for example, ZnTe, and/or the like), and a lanthanide metal telluride (for example, LaTe, CeTe, PrTe, NdTe, PmTe, EuTe, GdTe, TbTe, DyTe, HoTe, ErTe, TmTe, YbTe, LuTe, and/or the like).

### Emission Layer

If (e.g., when) the light-emitting device 10 is a full-color light-emitting device, the emission layer may be patterned into a red emission layer, a green emission layer, and/or a blue emission layer, according to a subpixel. In one or more embodiments, the emission layer 130 may have a stacked structure of two or more layers selected from among a red emission layer, a green emission layer, and a blue emission layer, in which the two or more layers may contact each other or may be separated from each other, to emit white light. In one or more embodiments, the emission layer may include two or more materials selected from among a red light-emitting material, a green light-emitting material, and a blue light-emitting material, in which the two or more materials may be mixed with each other in a single layer, to emit white light.

The emission layer 130 may include a host and a dopant. The dopant may include a phosphorescent dopant, a fluorescent dopant, or any combination thereof.

The amount of the dopant in the emission layer 130 may be from about 0.01 part by weight to about 15 parts by weight with respect to 100 parts by weight of the host.

The emission layer 130 may include a quantum dot.

The emission layer 130 may include a delayed fluorescence material. The delayed fluorescence material may act or serve as a host or a dopant in the emission layer.

The thickness of the emission layer 130 may be in a range of about 100 Å to about 1,000 Å, and in one or more embodiments, about 200 Å to about 600 Å. If (e.g., when) the thickness of the emission layer is within the range described above, excellent or suitable luminescence characteristics may be obtained not having a substantial increase in driving voltage (e.g., may be obtained having a suitable increase in driving voltage).

### Host

The host may include a compound represented by Formula 301:

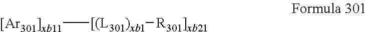

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer of 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer of 1 to 5, and
Q₃₀₁ to 0303 may each independently be the same (e.g., substantially the same) as described in connection with Q₁.

In one or more embodiments, if (e.g., when) xb11 in Formula 301 is 2 or more, two or more of Ar₃₀₁ may be linked to each other via a single bond (e.g., a single covalent bond).

In one or more embodiments, the host may include a compound represented by Formula 301-1, a compound represented by Formula 301-2, or any combination thereof:

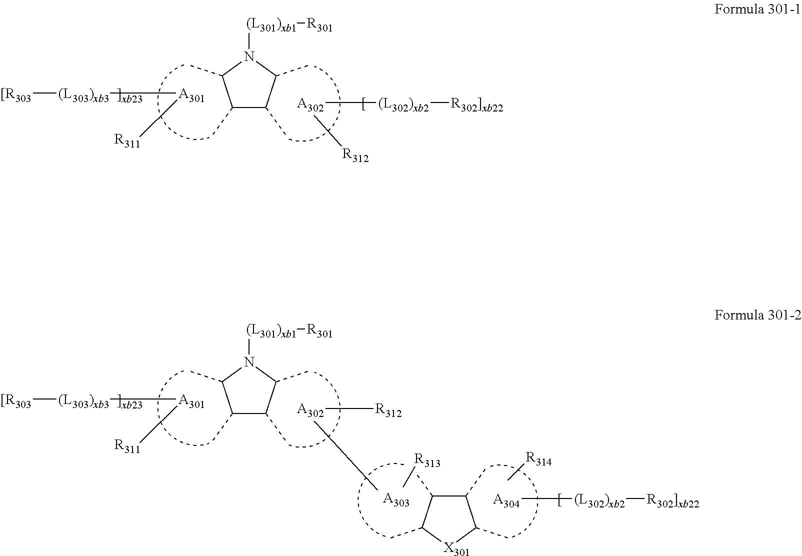

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each independently be the same (e.g., substantially the same) as described in one or more embodiments of the present disclosure,
L₃₀₂ to L₃₀₄ may each independently be the same (e.g., substantially the same) as described in connection with L₃₀₁,
xb2 to xb4 may each independently be the same (e.g., substantially the same) as described in connection with xb1, and
R₃₀₂ to R₃₀₅ and R₃₁₁ to R₃₁₄ may each independently be the same (e.g., substantially the same) as described in connection with R₃₀₁.

In one or more embodiments, the host may include an alkali earth metal complex, a post-transition metal complex, or any combination thereof. In one or more embodiments, the host may include a Be complex (for example, Compound H55), an Mg complex, a Zn complex, or any combination thereof.

In one or more embodiments, the host may include: one selected from among Compounds H1 to H128; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di(carbazol-9-yl)benzene (mCP); 1,3,5-tri(carbazol-9-yl)benzene (TCP); or any combination thereof:

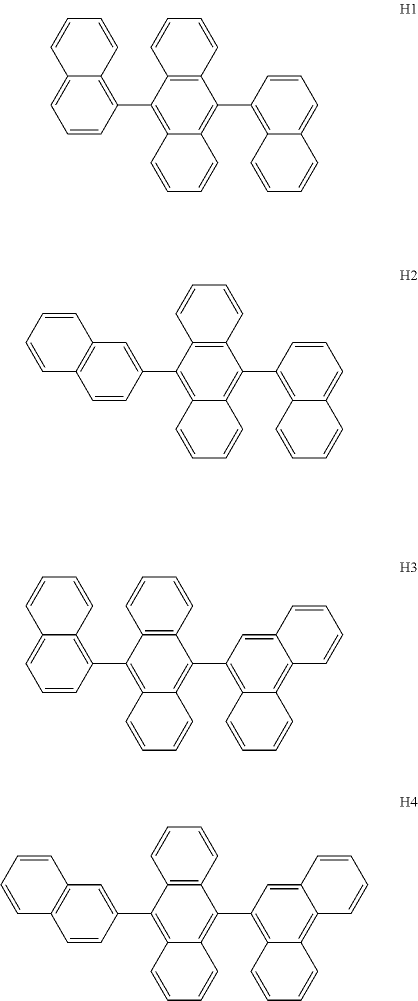

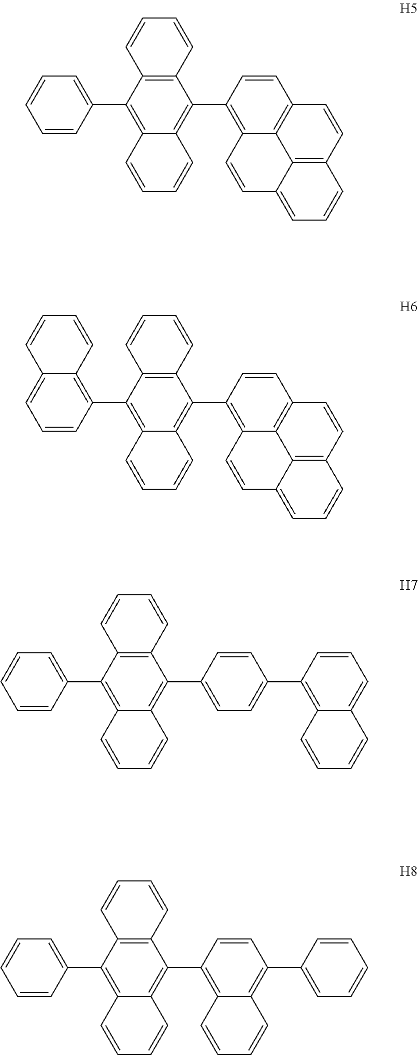

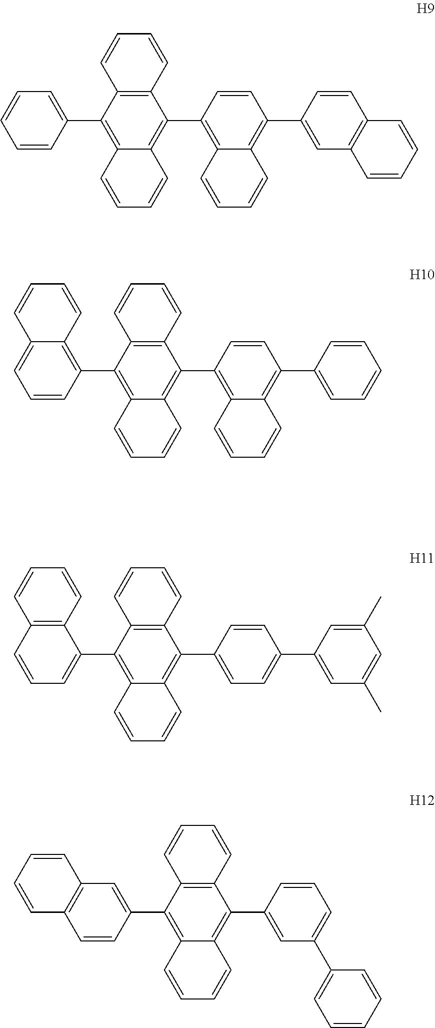

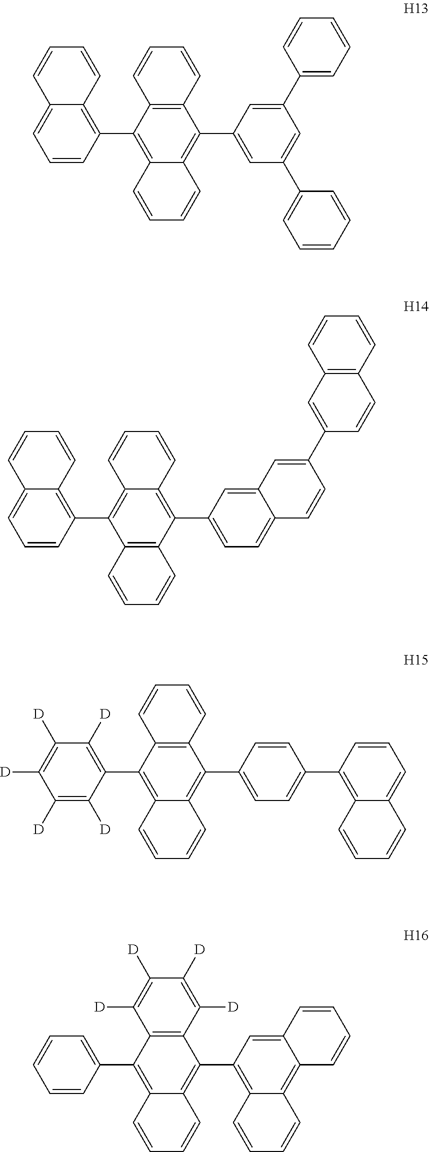

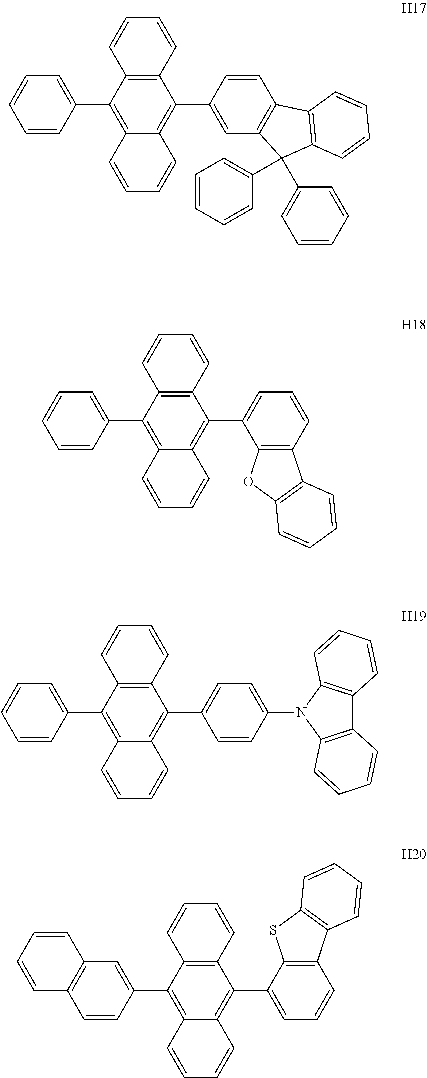

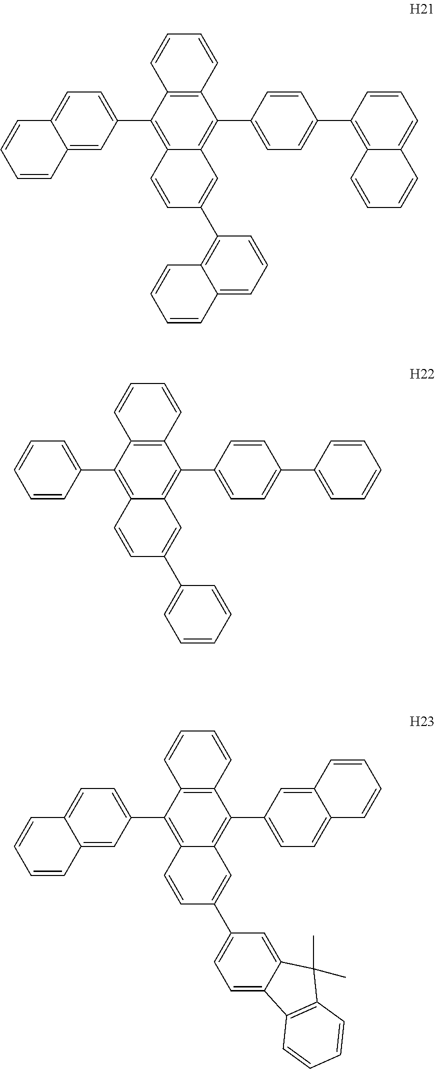

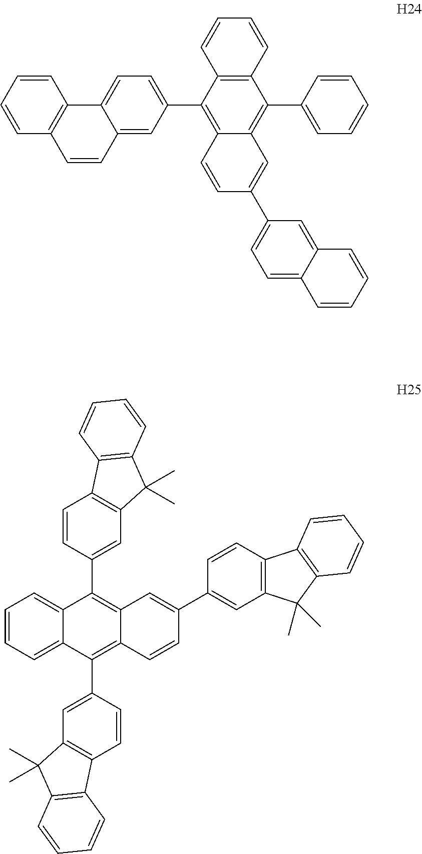

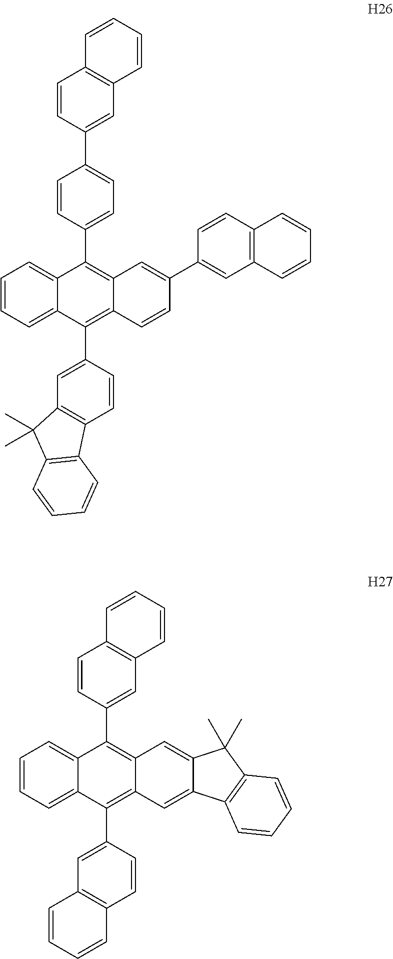

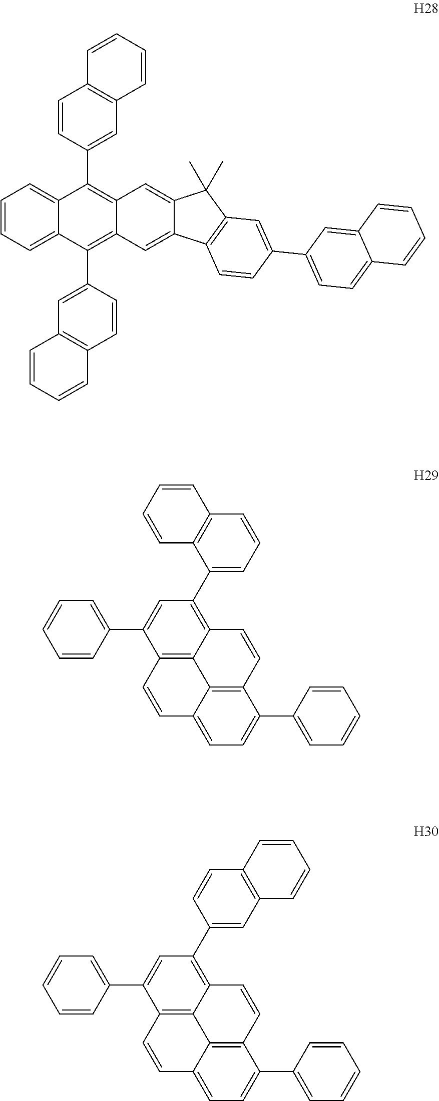

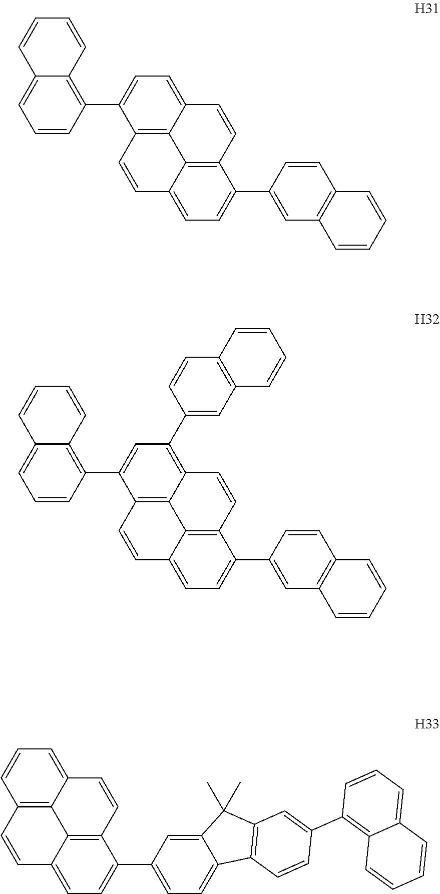

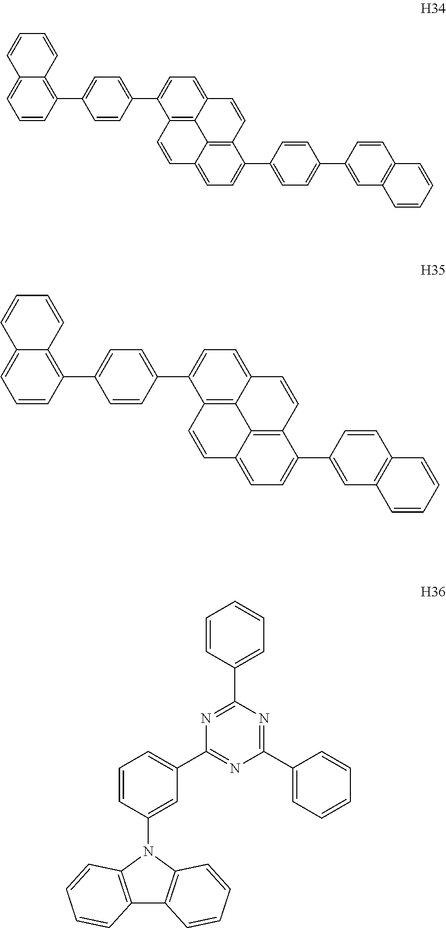

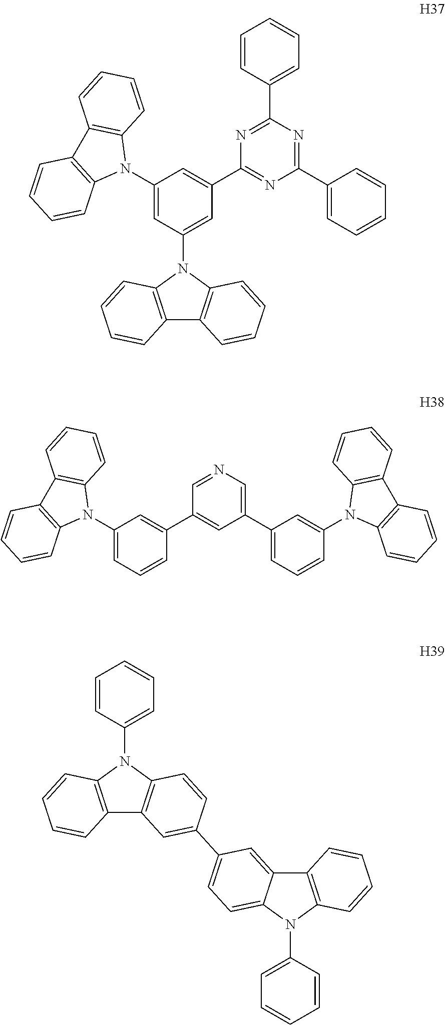 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

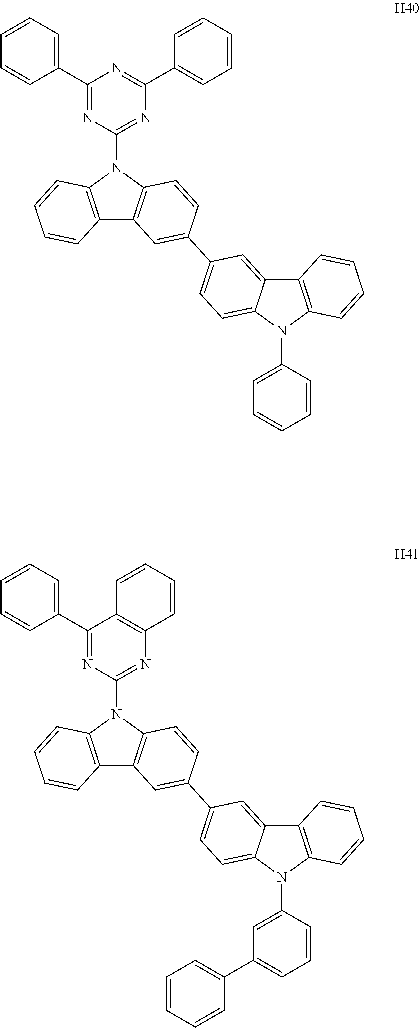 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1]

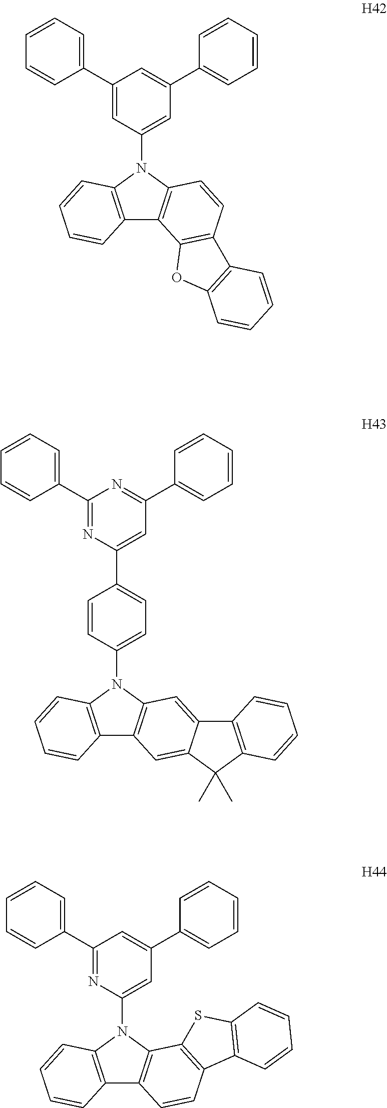 [SMILES: c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1]

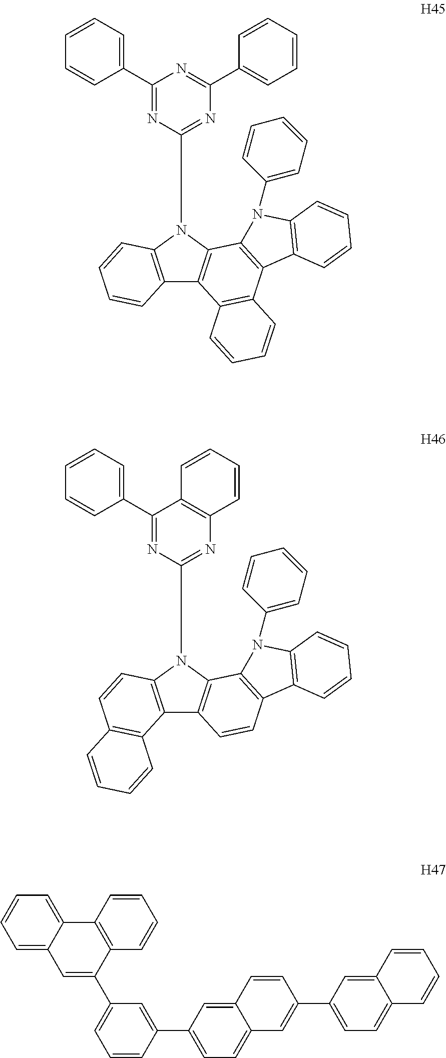

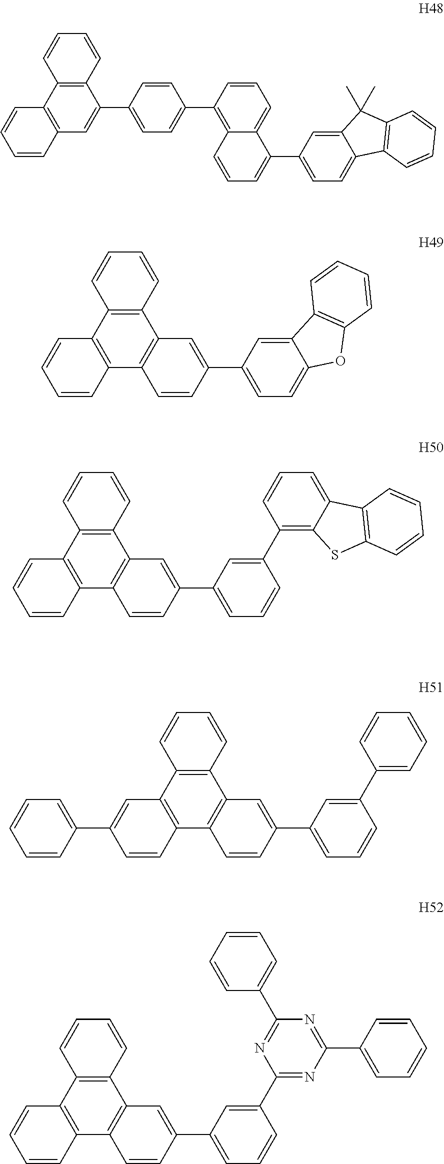

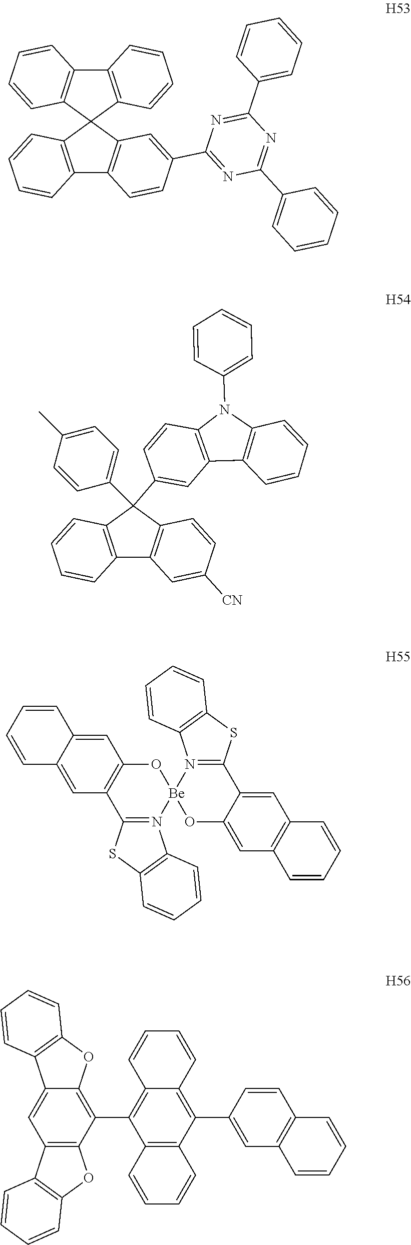

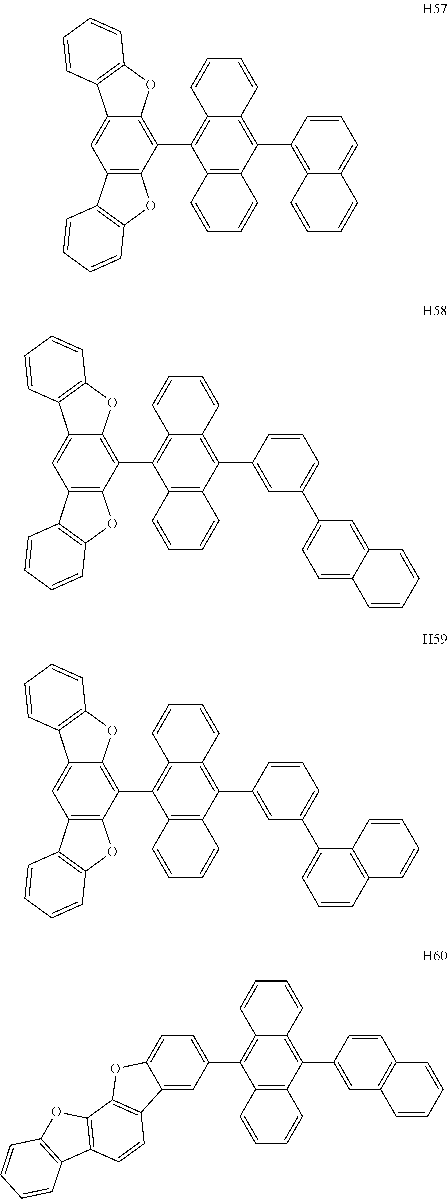 [SMILES: c1ccc2c(-c3c4ccccc4c(-c4c5oc6ccccc6c5cc5c4oc4ccccc45)c4ccccc34)cccc2c1 ; c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1]

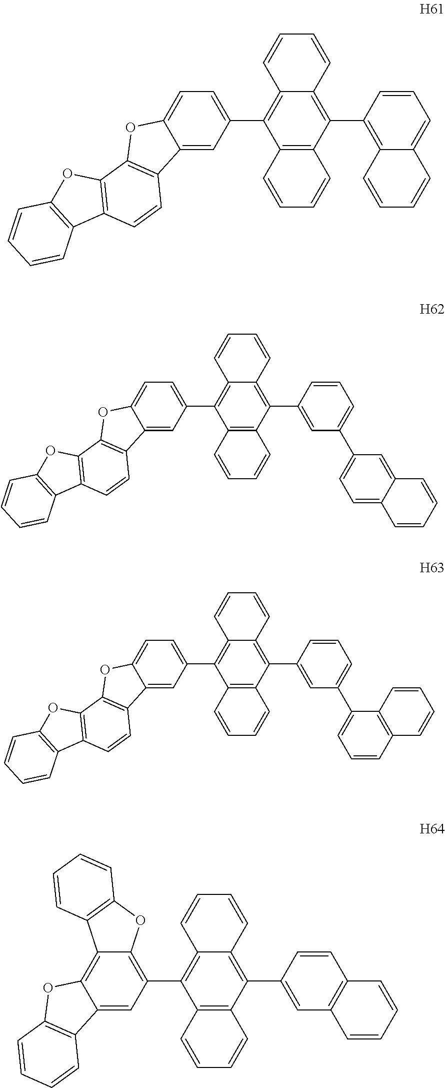 [SMILES: c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

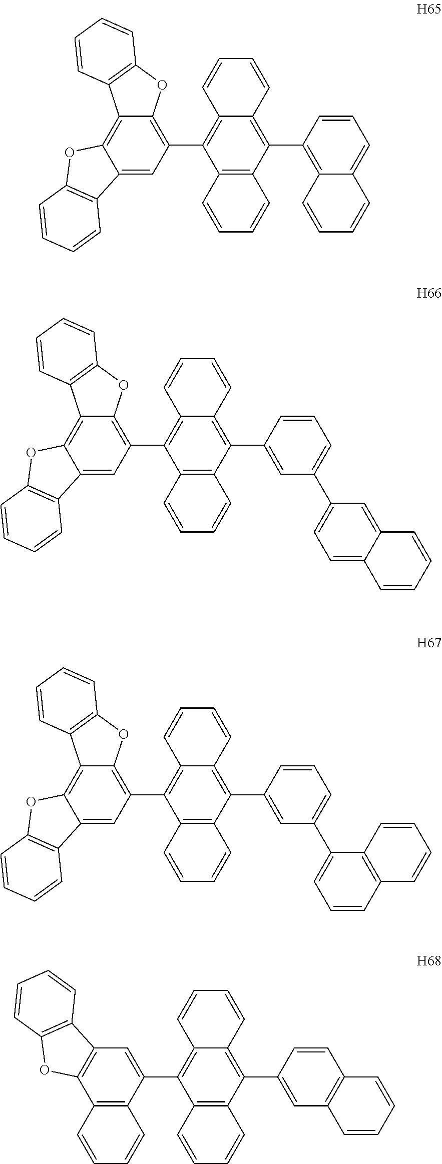 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1]

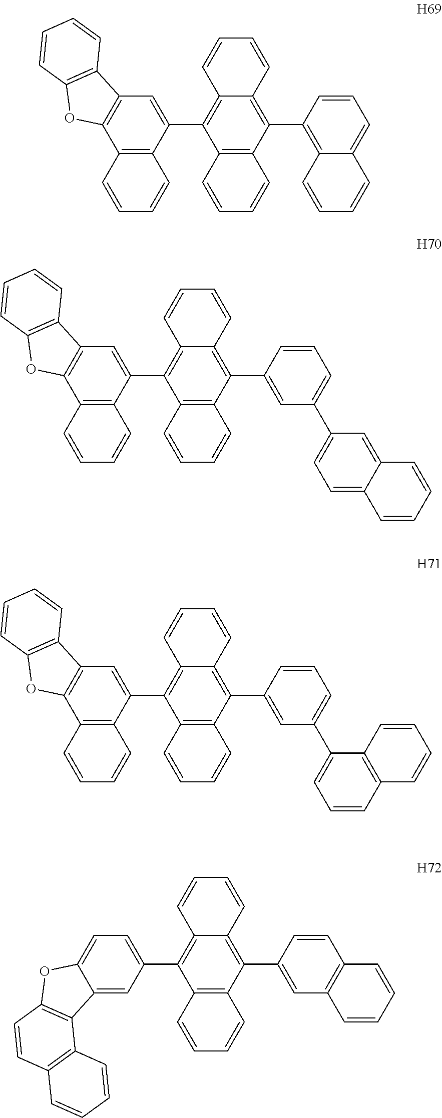 [SMILES: c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1]

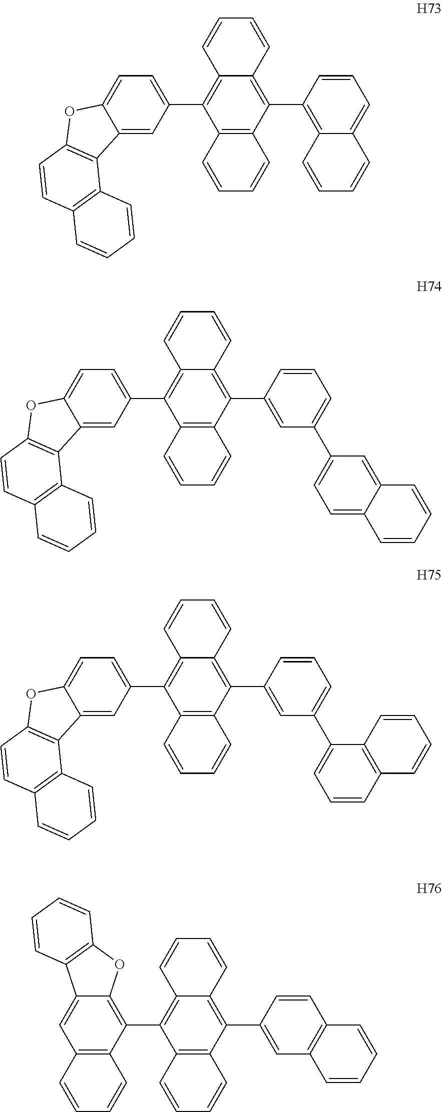 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1]

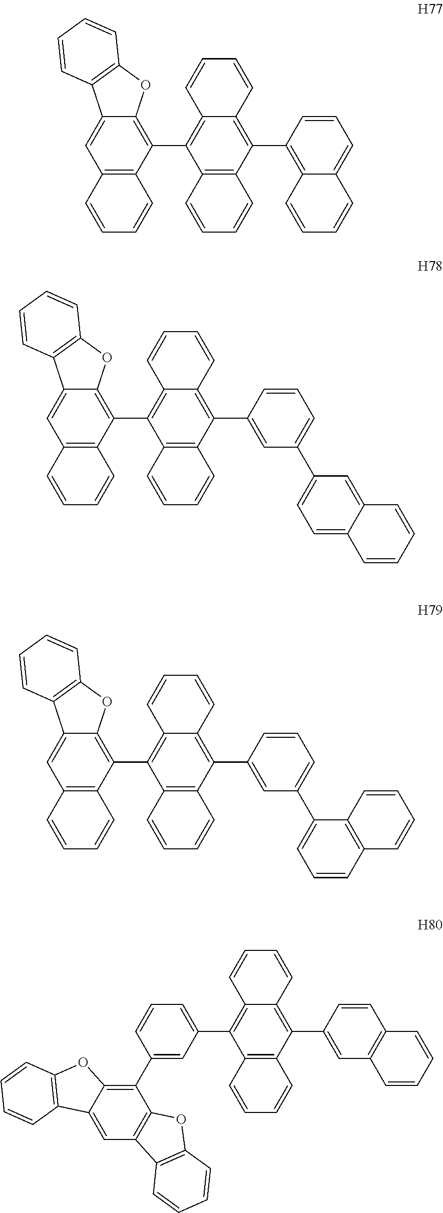 [SMILES: c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1]

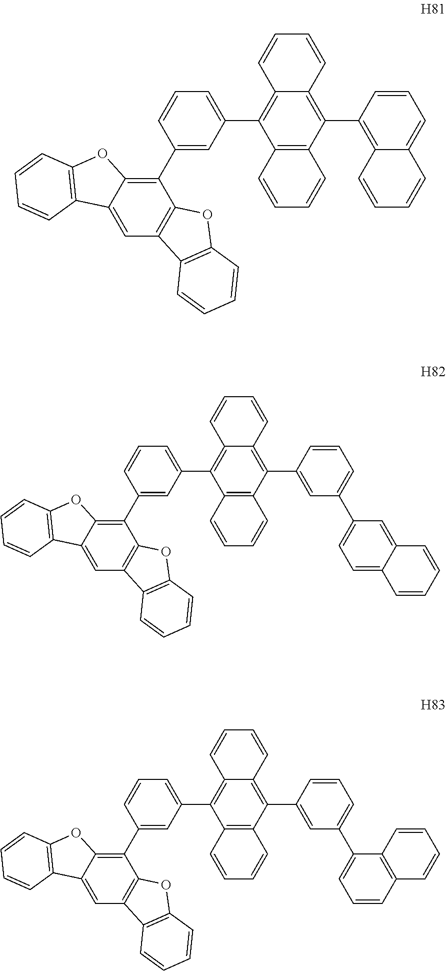 [SMILES: c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1]

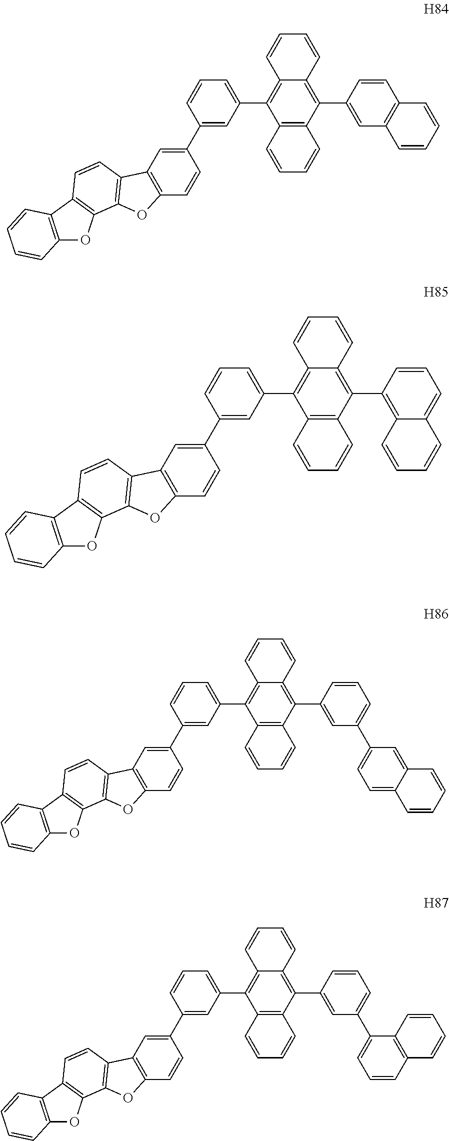 [SMILES: c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

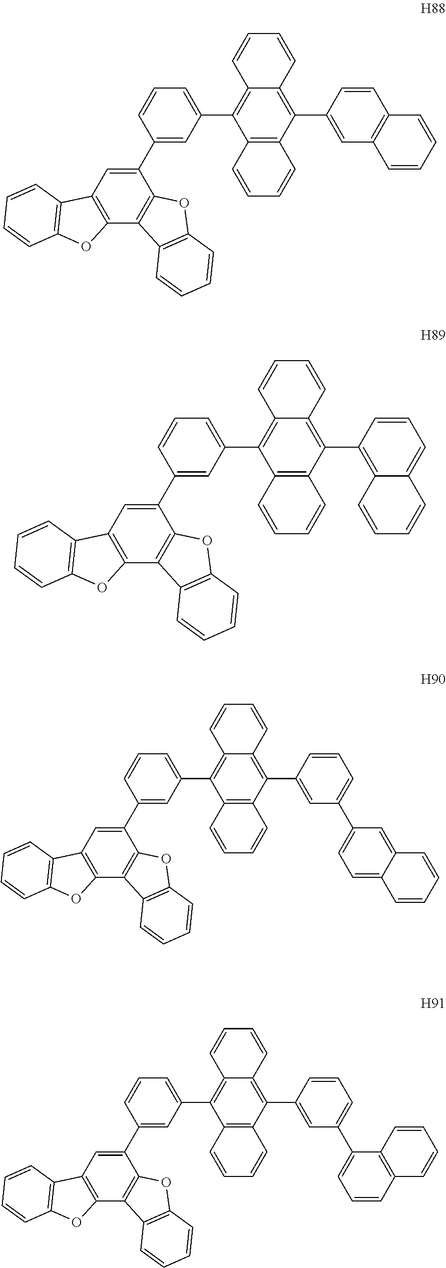 [SMILES: c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

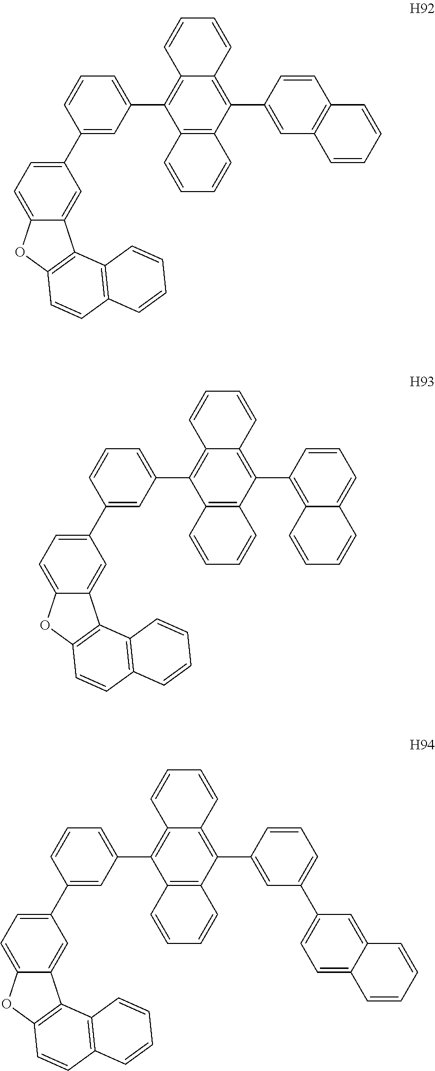 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1]

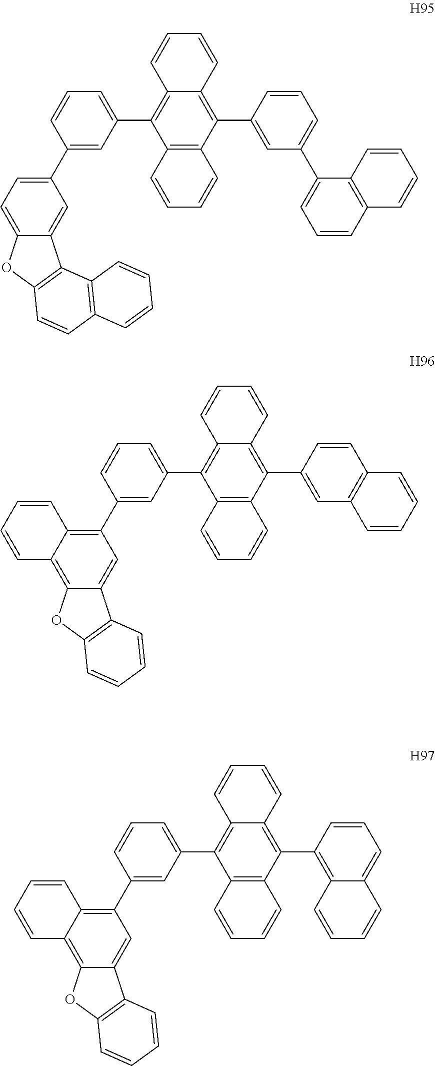 [SMILES: c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1]

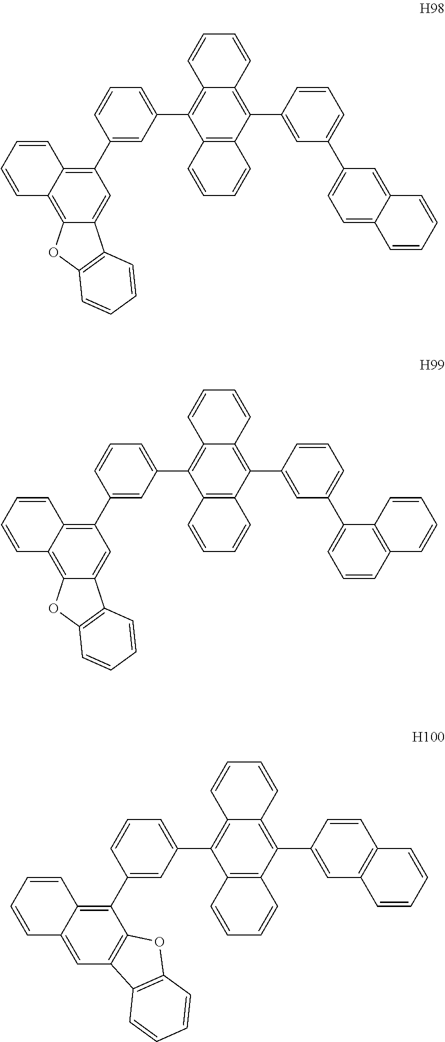 [SMILES: c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1]

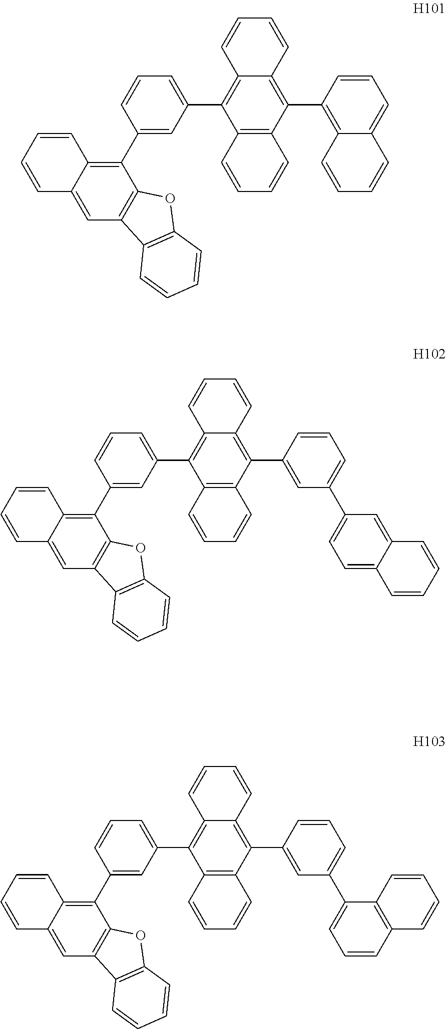 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

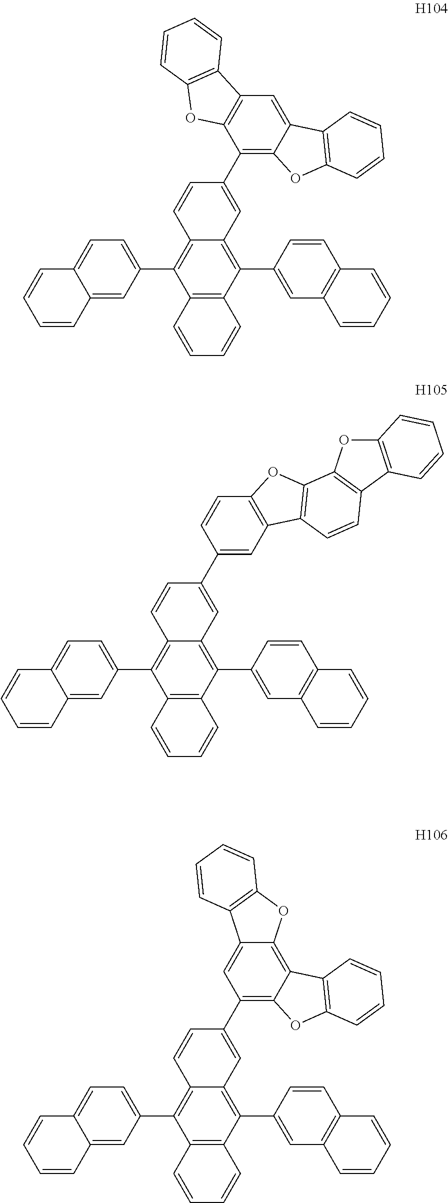 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

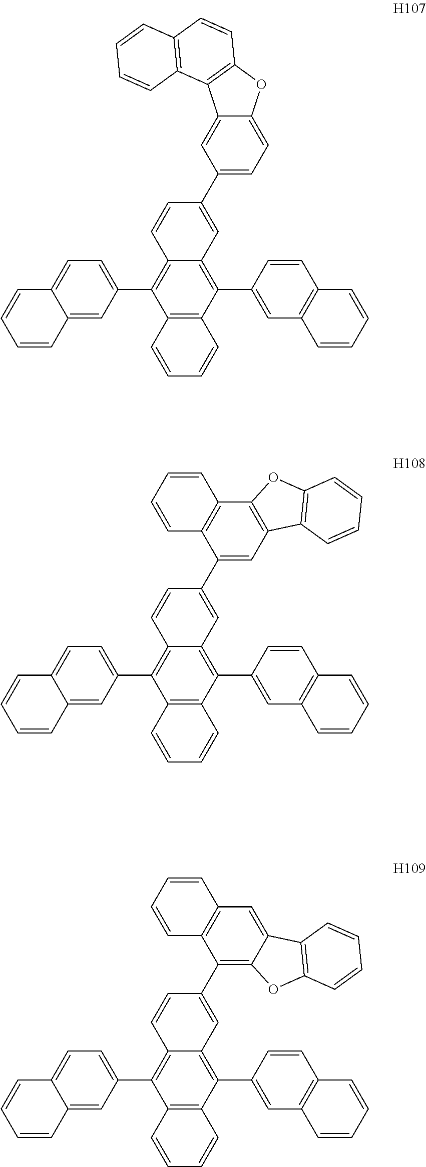 [SMILES: c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1]

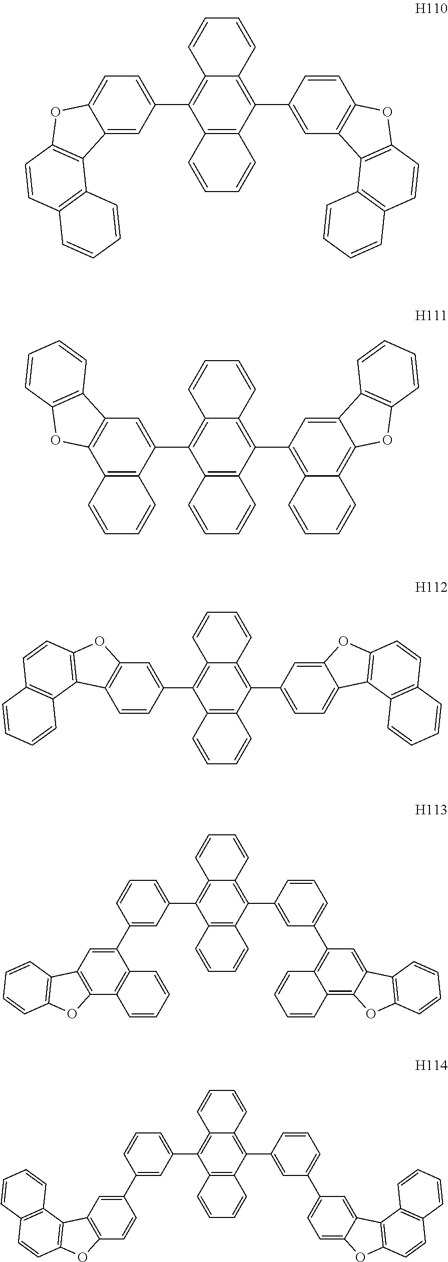 [SMILES: c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21 ; c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1]

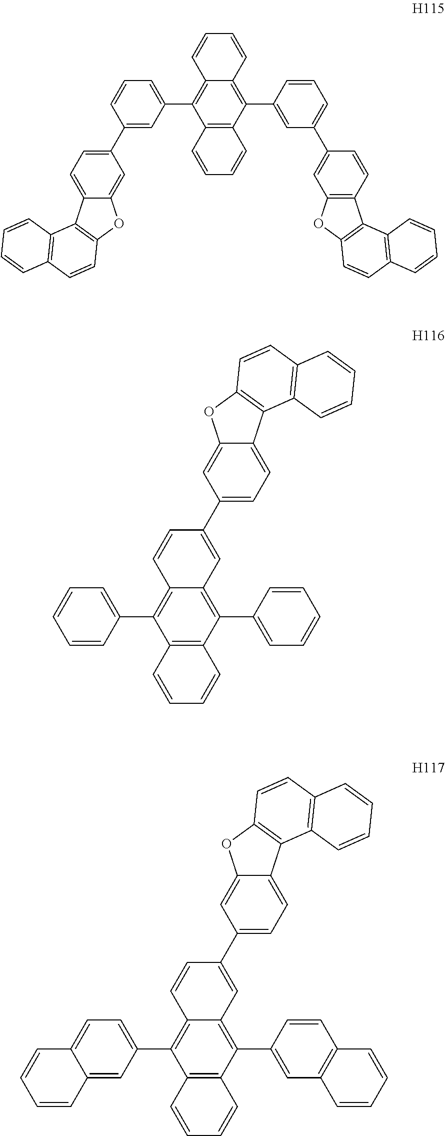 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

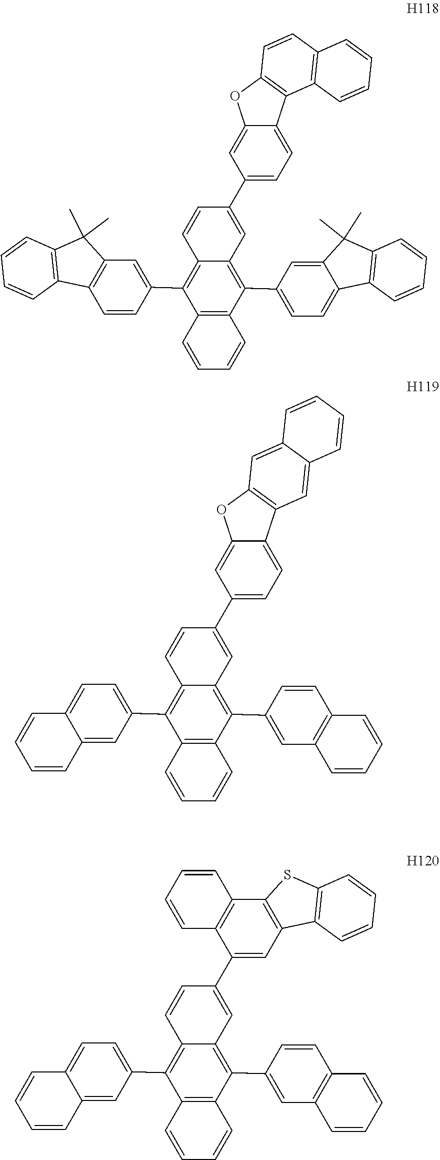 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

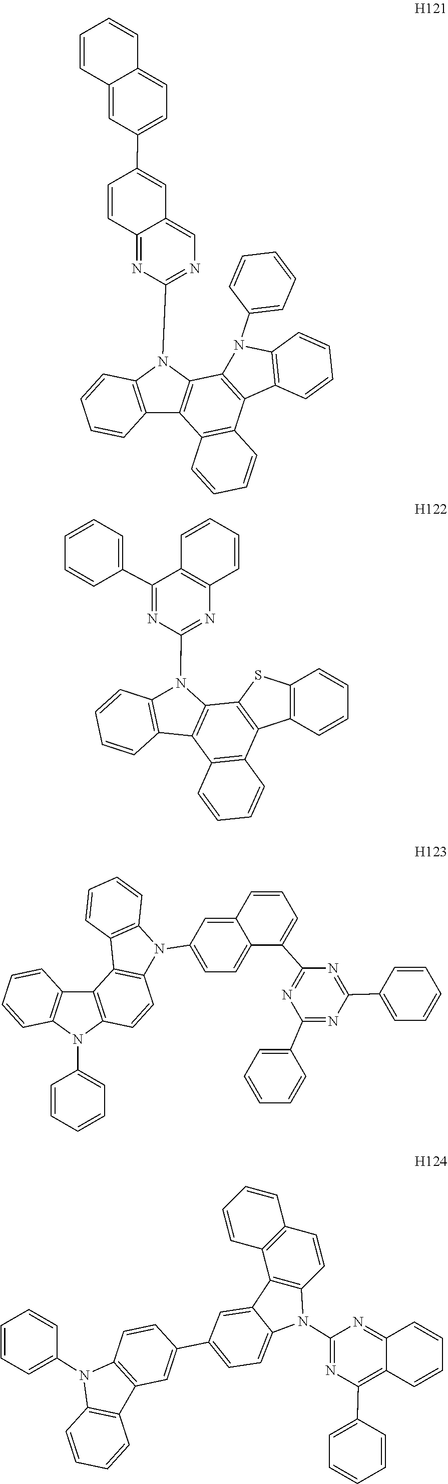

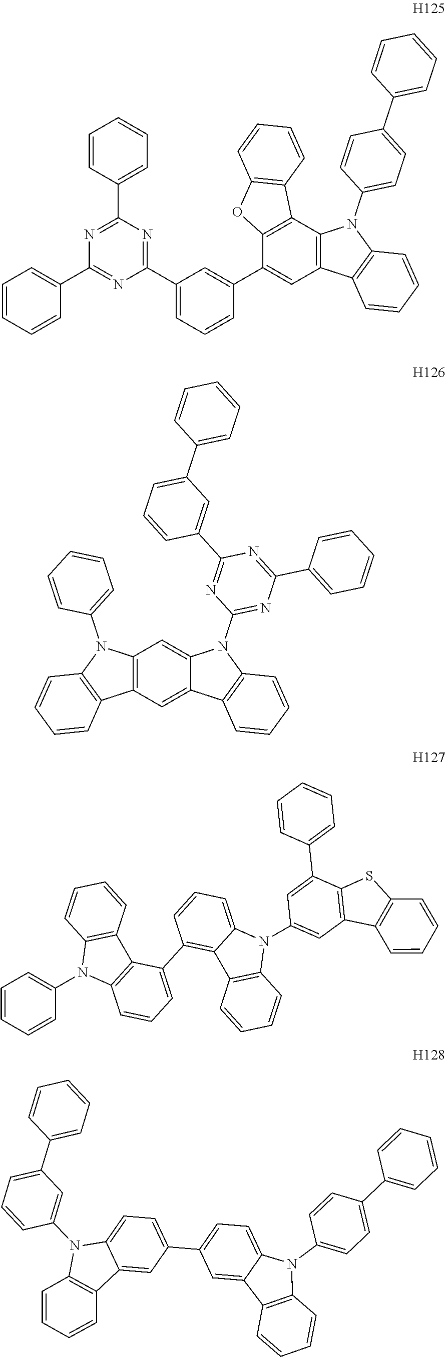 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

The phosphorescent dopant may include at least one transition metal acting or serving as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may include an organometallic compound represented by Formula 401:

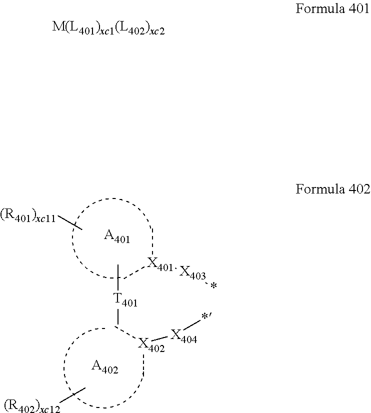

wherein, in Formulae 401 and 402,
M may be a transition metal (e.g., Ir, Pt, Pd, Os, Ti, Au, Hf, Eu, Tb, Rh, Re, or Tm),
L₄₀₁ may be a ligand represented by Formula 402, and xc1 is 1, 2, or 3, wherein, if (e.g., when) xc1 is 2 or more, two or more of L₄₀₁ may be identical to or different from each other,
L₄₀₂ may be an organic ligand, and xc2 may be 0, 1, 2, 3, or 4, wherein, if (e.g., when) xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond (e.g., a single covalent bond), *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)═*′, or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃) (Q₄₁₄),
Q₄₁₁ to Q₄₁₄ may each independently be the same (e.g., substantially the same) as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same (e.g., substantially the same) as described in connection with Q₁,
xc11 and xc12 may each independently be an integer of 0 to 10, and
* and *′ in Formula 402 may each independently be a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, if (e.g., when) xc1 in Formula 401 is 2 or more, two ring A₄₀₁ among two or more of L₄₀₁ may be optionally linked together via T₄₀₂, which is a linking group, and two ring A₄₀₂ may be optionally linked together via T₄₀₃, which is a linking group (see Compounds PD1 to PD4 and PD7). T₄₀₂ and T₄₀₃ may each independently be the same (e.g., substantially the same) as described in connection with T₄₀₁.

L₄₀₂ in Formula 401 may be an organic ligand. In one or more embodiments, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, and/or the like), or any combination thereof.

The phosphorescent dopant may include, for example, one selected from among compounds PD1 to PD39, or any combination thereof:

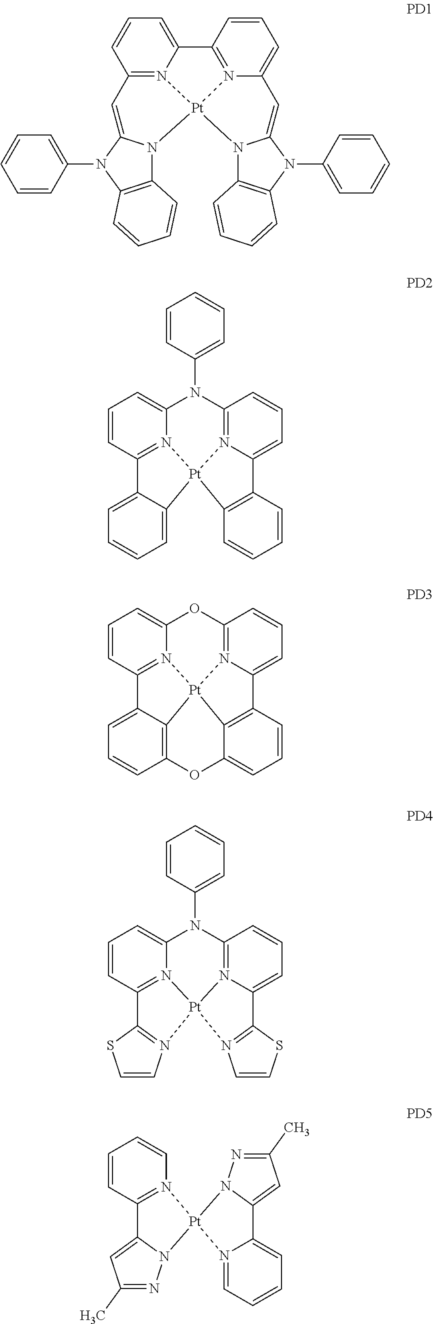

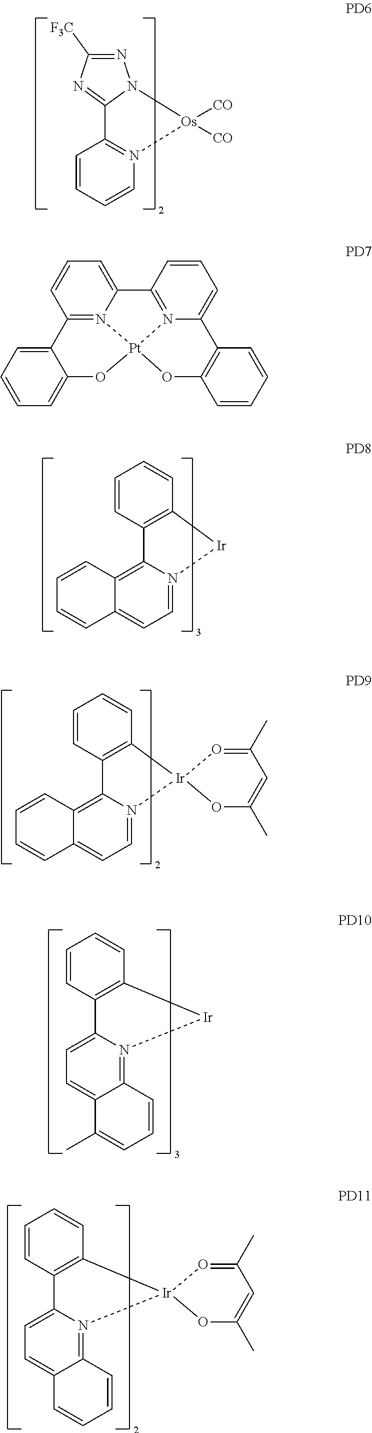

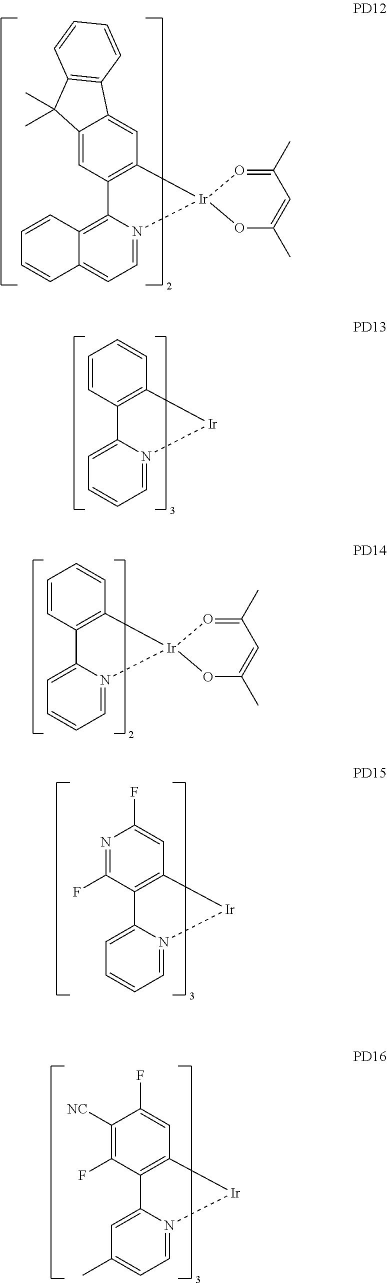

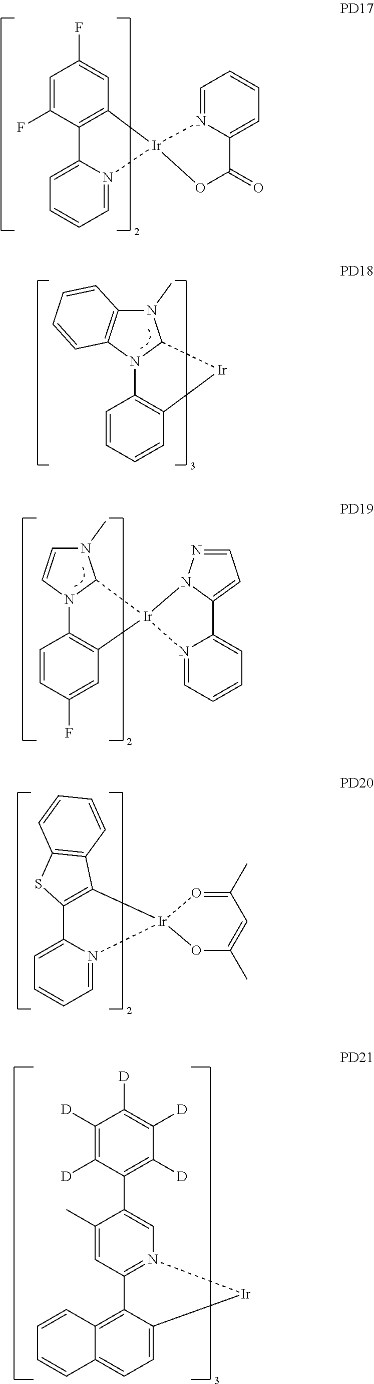

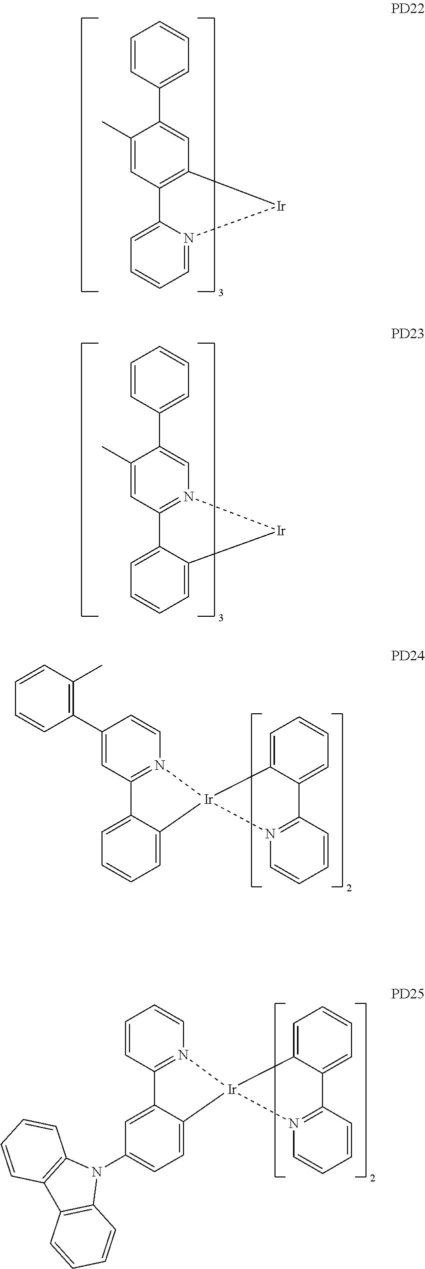

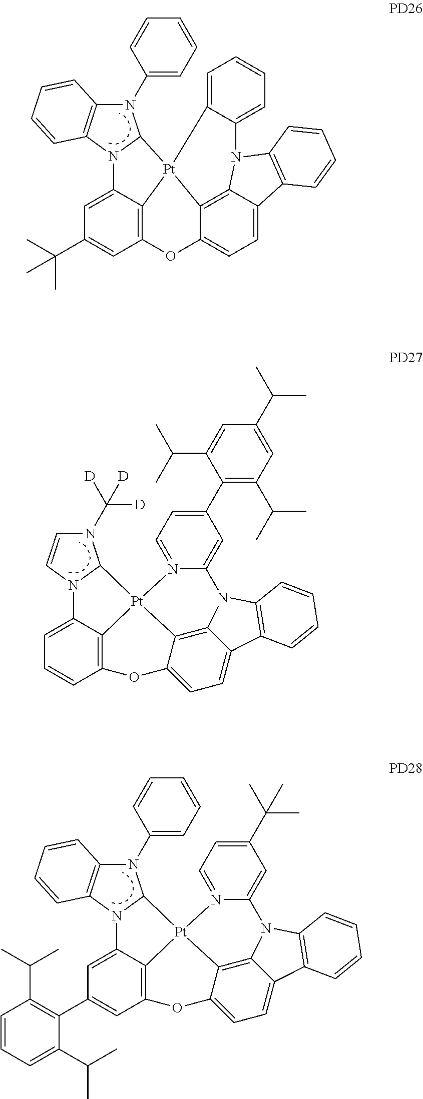

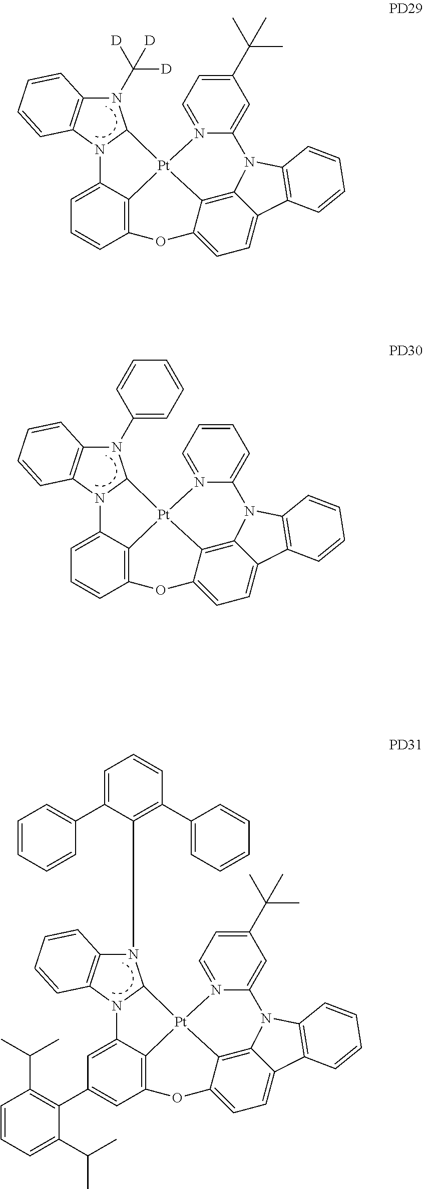

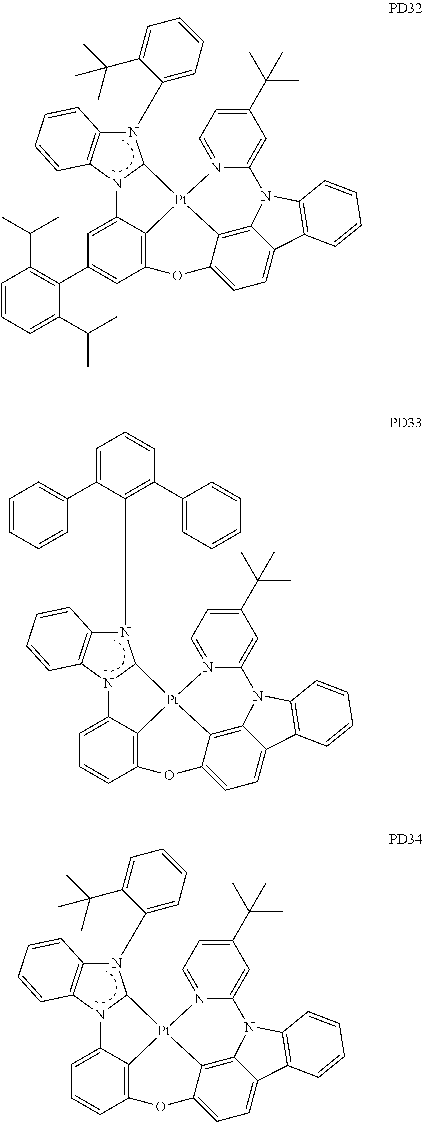

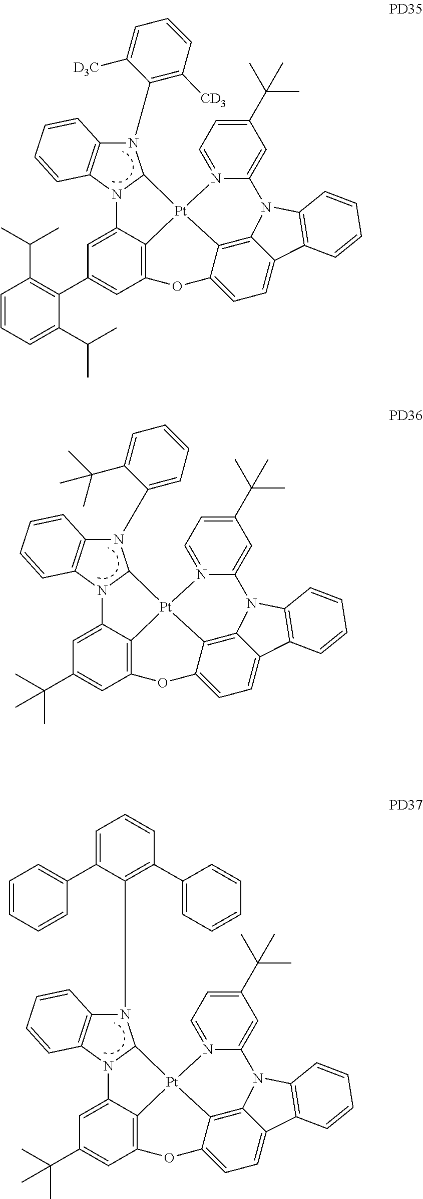

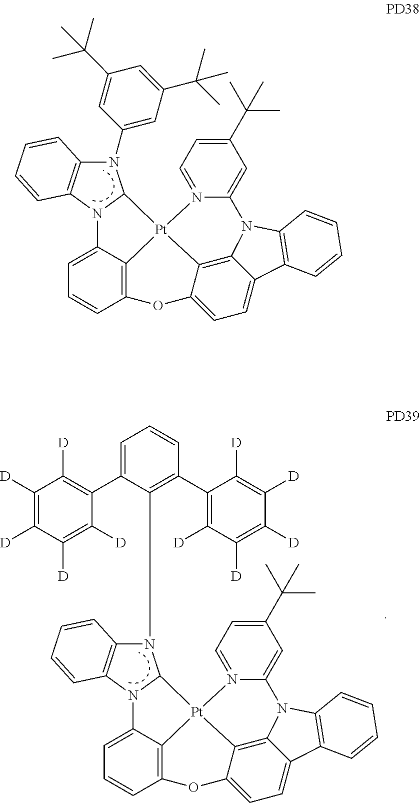

### Fluorescent Dopant

The fluorescent dopant may include an amine group-containing compound, a styryl group-containing compound, or any combination thereof.

For example, the fluorescent dopant may include a compound represented by Formula 501:

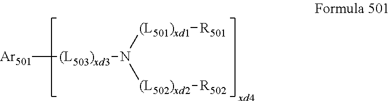

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (for example, an anthracene group, a chrysene group, a pyrene group, and/or the like) in which three or more monocyclic groups are condensed together.

In one or more embodiments, xd4 in Formula 501 may be 2.

In one or more embodiments, the fluorescent dopant may include: one selected from among Compounds FD1 to FD37; DPVBi; DPAVBi; or any combination thereof:

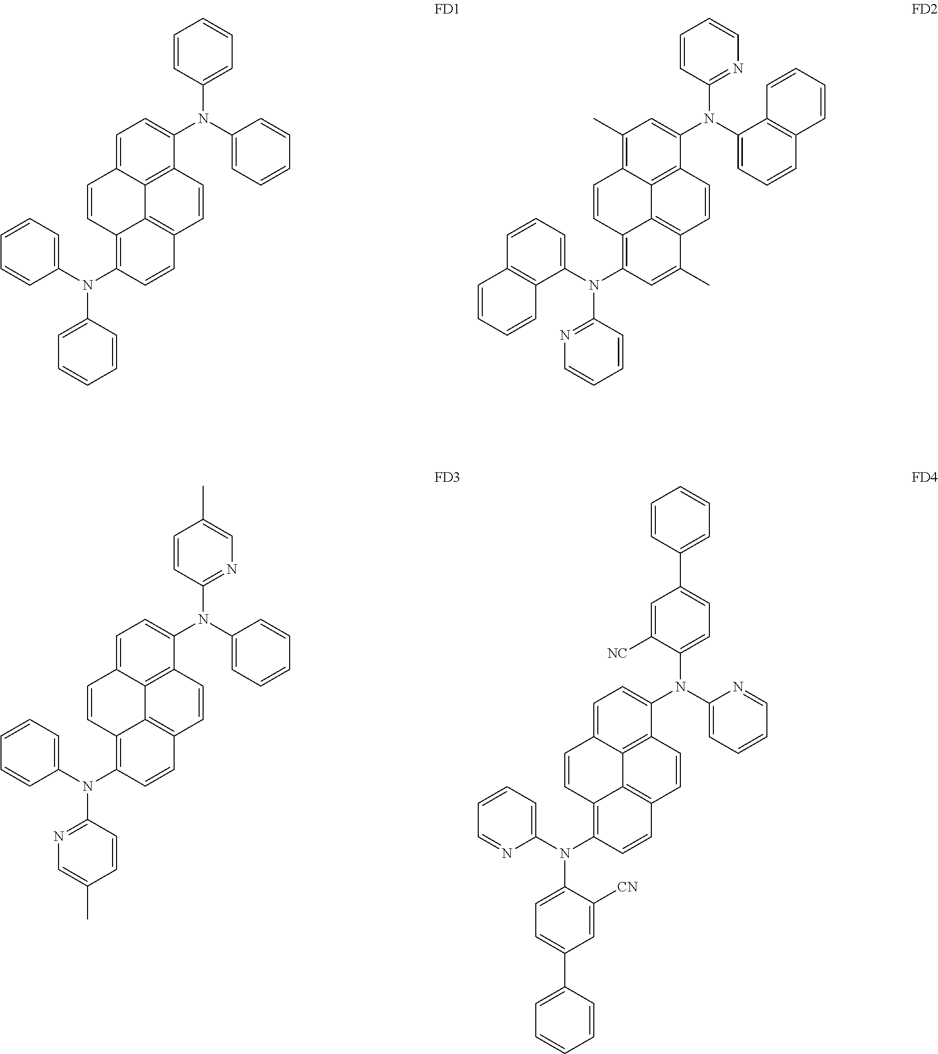 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1 ; N#Cc1cc(-c2ccccc2)ccc1N(c1ccccn1)c1ccc2ccc3c(N(c4ccccn4)c4ccc(-c5ccccc5)cc4C#N)ccc4ccc1c2c43]

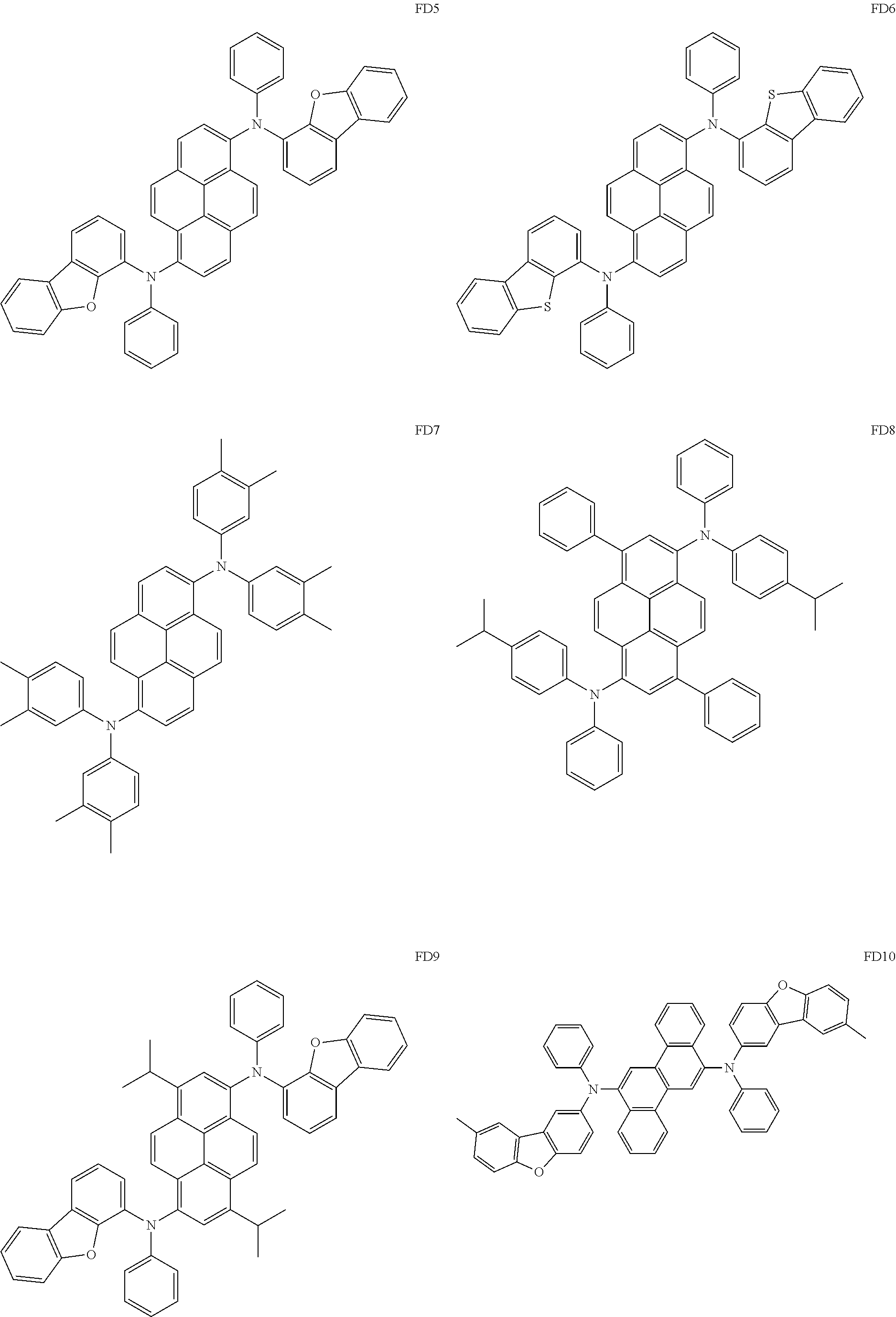

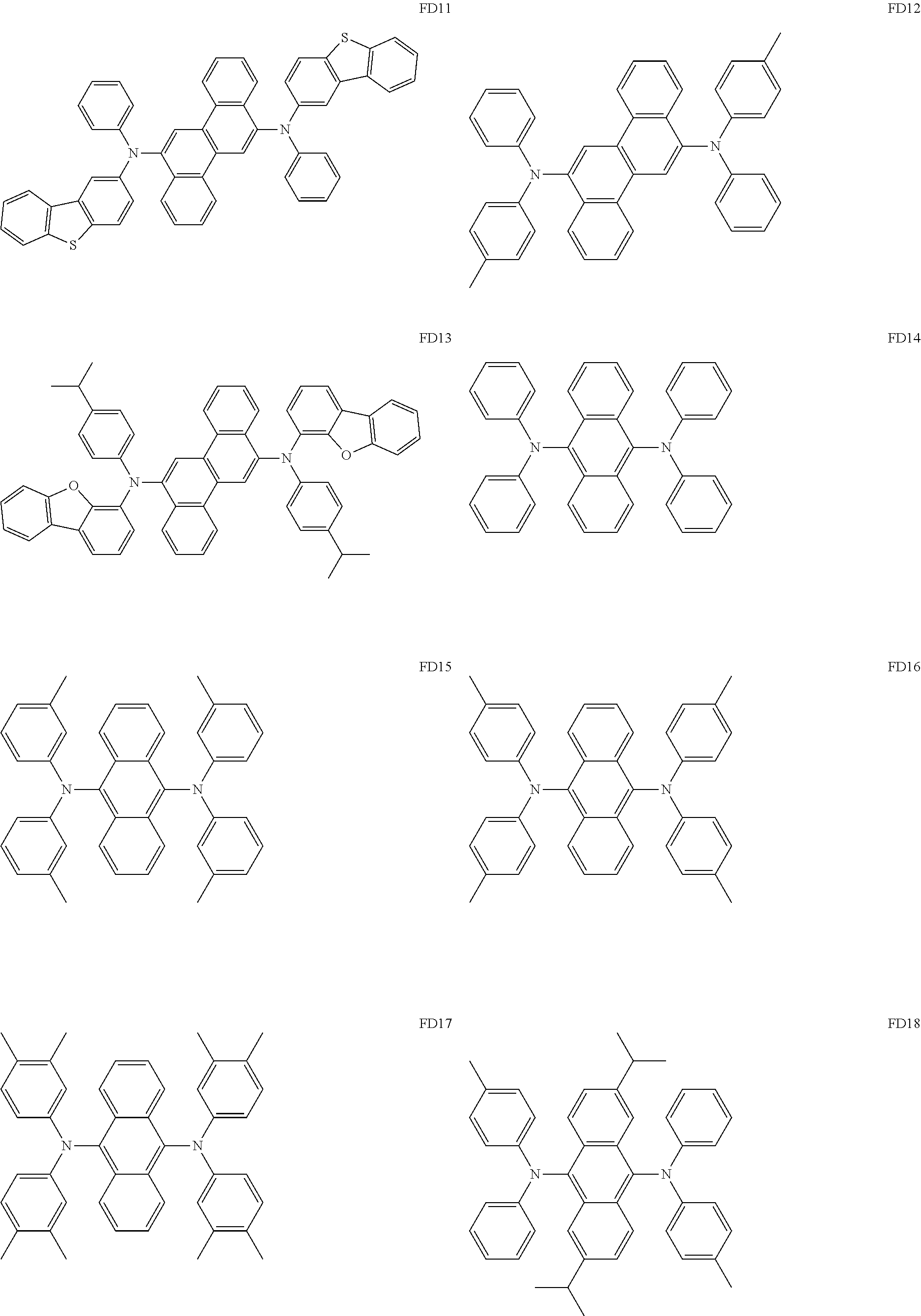

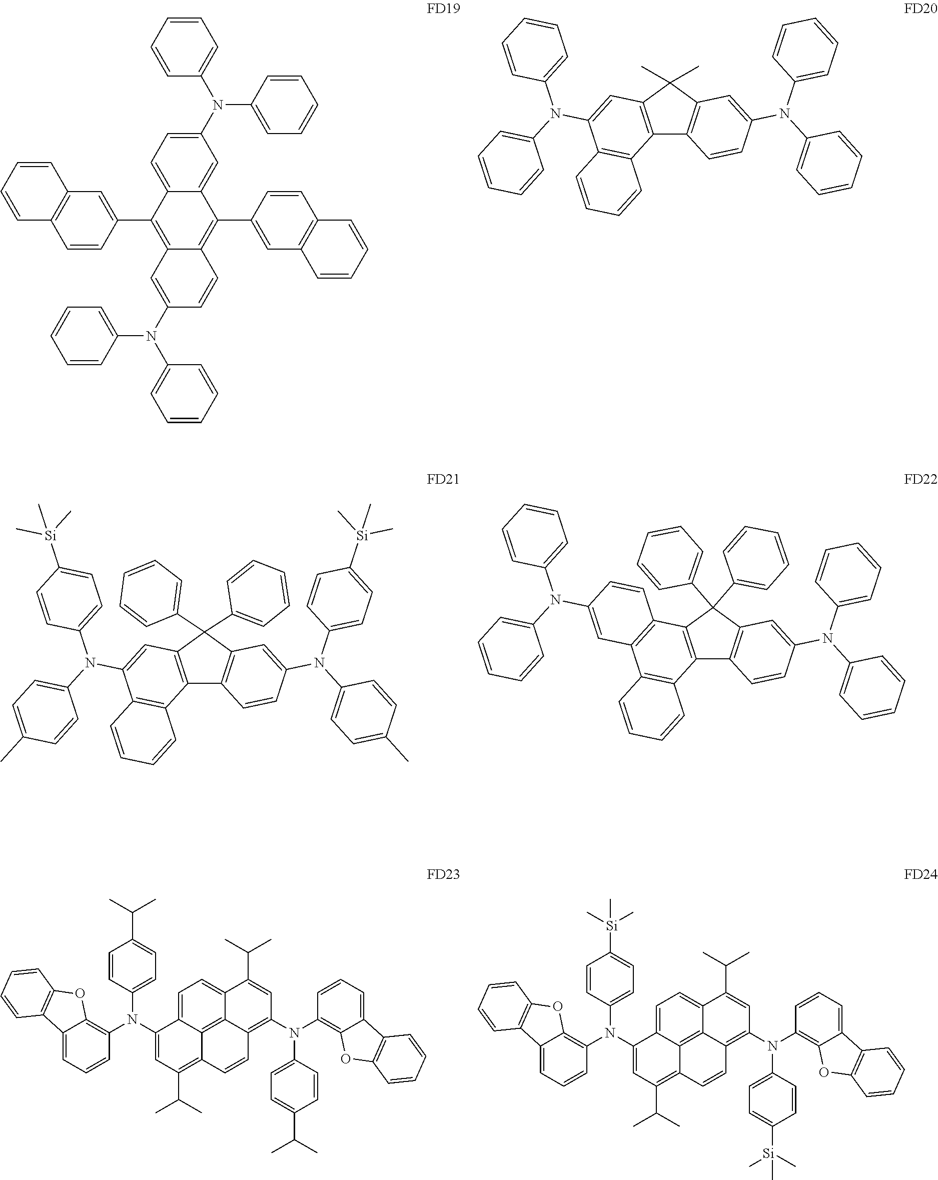

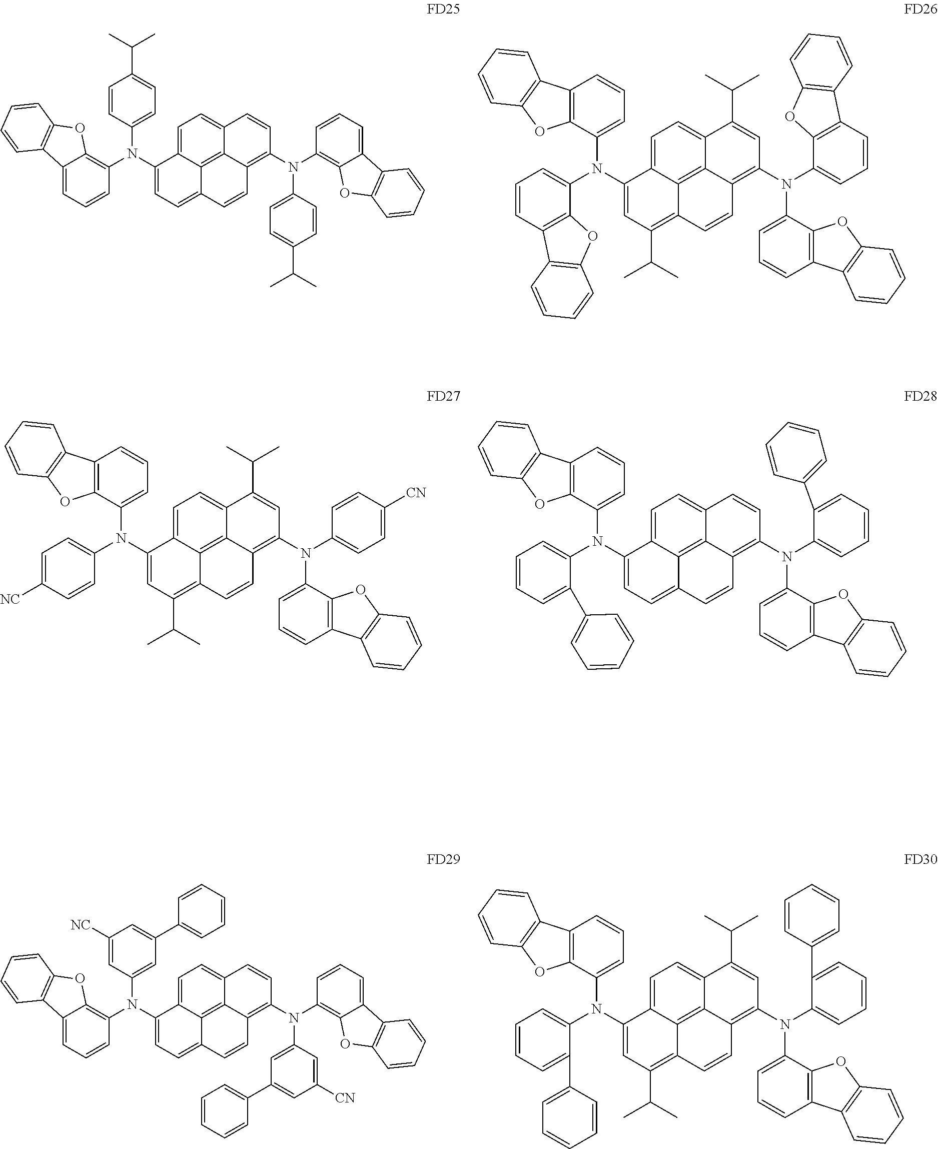

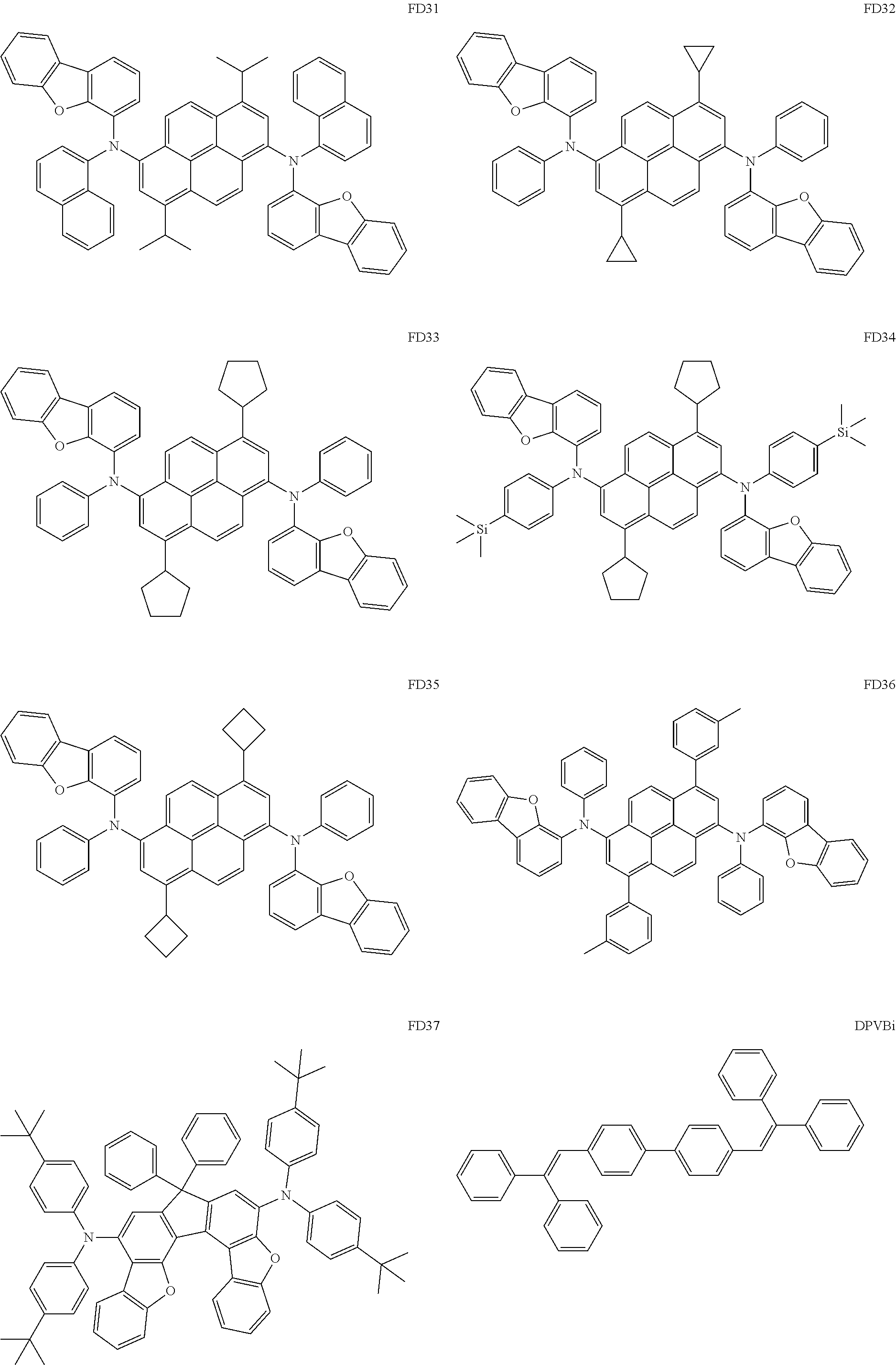

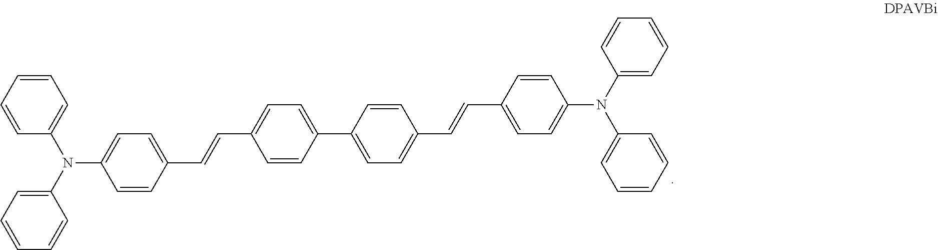 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

### Delayed Fluorescence Material

The emission layer may include a delayed fluorescence material.

Herein, the delayed fluorescence material may be selected from among compounds that are capable of emitting delayed fluorescence based on a delayed fluorescence emission mechanism.

The delayed fluorescence material in the emission layer may act or serve as a host or a dopant depending on the type or kind of other materials in the emission layer.

In one or more embodiments, a difference between a triplet energy level (eV) of the delayed fluorescence material and a singlet energy level (eV) of the delayed fluorescence material may be in a range of about 0 eV to about 0.5 eV. If (e.g., when) the difference between the triplet energy level (eV) of the delayed fluorescence material and the singlet energy level (eV) of the delayed fluorescence material is within the above range, up-conversion from the triplet state to the singlet state of the delayed fluorescence materials may effectively occur, and, for example, the light-emitting device 10 may have improved luminescence efficiency (e.g., suitable luminescence efficiency).

In one or more embodiments, the delayed fluorescence material may include: i) a material including at least one electron donor (for example, a π electron-rich C₃-C₆₀ cyclic group, such as a carbazole group) and at least one electron acceptor (for example, a sulfoxide group, a cyano group, a π electron-deficient nitrogen-containing C₁-C₆₀ cyclic group, and/or the like), ii) a material including a C₈-C₆₀ polycyclic group including at least two cyclic groups that are condensed with each other while sharing boron (B).

Examples of the delayed fluorescence material may include at least one selected from among Compounds DF1 to DF14:

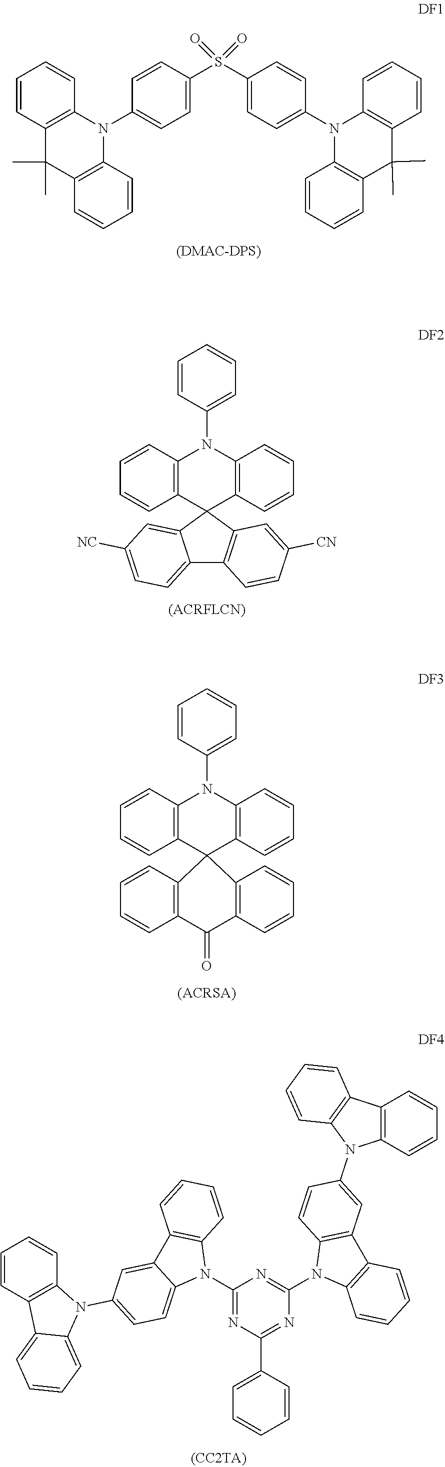

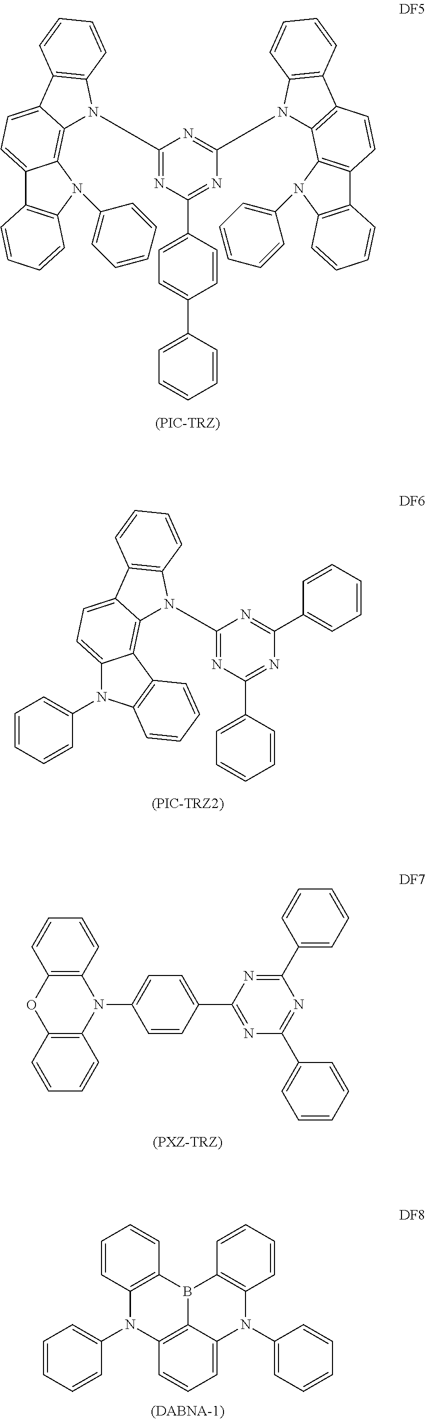

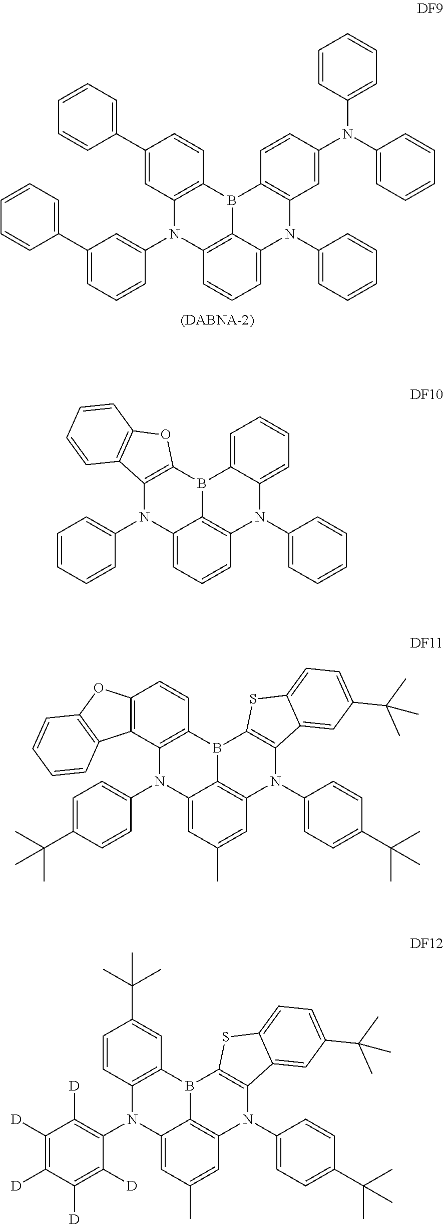

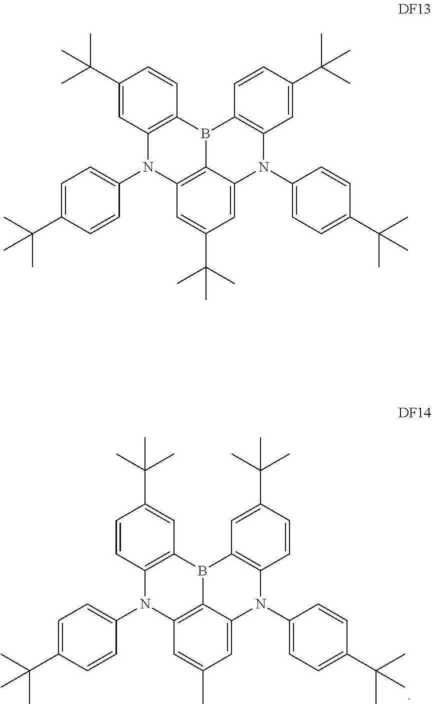

### Quantum Dot

The emission layer 130 may include a quantum dot.

The term, “quantum dot,” as used herein refers to a crystal of a semiconductor compound. Quantum dots may emit light of one or more suitable emission wavelengths according to the size of the crystal. Quantum dots may also emit light of one or more suitable emission wavelengths by adjusting the ratio of elements constituting the quantum dots.

A diameter of the quantum dots may be, for example, in a range of about 1 nm to about 10 nm.

The quantum dot may be synthesized by a wet chemical process, a metal organic chemical vapor deposition process, a molecular beam epitaxy process, and/or any suitable process similar thereto.

The wet chemical process may be a method that includes mixing a precursor material with an organic solvent and then growing a quantum dot particle crystal. If (e.g., when) the crystal grows, the organic solvent naturally may act or serve as a dispersant coordinated on the surface of the quantum dot crystal and control the growth of the crystal so that the growth of quantum dot particles may be controlled through a process which may cost lower, and may be easier than vapor deposition methods, such as metal organic chemical vapor deposition (MOCVD) or molecular beam epitaxy (MBE).

The quantum dot may include Group II-VI semiconductor compounds, Group III-V semiconductor compounds, Group III-VI semiconductor compounds, Group 1-III-VI semiconductor compounds, Group IV-VI semiconductor compounds, a Group IV element or compound, or a combination thereof.

Examples of the Group II-VI semiconductor compound may include a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or a combination thereof.

Examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; or any combination thereof. In one or more embodiments, the Group III-V semiconductor compound may further include a Group II element. Examples of the Group III-V semiconductor compound further including a Group II element may be InZnP, InGaZnP, InAlZnP, and/or the like.

Examples of the Group III-VI semiconductor compound may include: a binary compound, such as GaS, GaSe, Ga₂Se₃, GaTe, InS, InSe, In₂S₃, In₂Se₃, InTe, and/or the like; a ternary compound, such as InGaS₃, InGaSe₃, and/or the like; or any combination thereof.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, and/or the like; a ternary compound, such as AgInGaS₂, AgInGaSe₂, and/or the like; or any combination thereof.

Examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or a combination thereof.

Examples of the Group IV element or compound may include: a single element, such as Si, Ge, and/or the like; a binary compound, such as SiC, SiGe, and/or the like; or any combination thereof.

Each element in a multi-element compound, such as the binary compound, the ternary compound, and the quaternary compound may be present at a uniform (e.g., substantially uniform) concentration or non-uniform (e.g., substantially non-uniform) concentration in a particle. The above formulae may refer to the types or kinds of elements in each compound, and the element ratios in these compounds may be different from each other. For example, AgInGaS₂ may be AgInₓGa₁₋ₓS₂ (where x may be a real number satisfying 0<x<1).

In one or more embodiments, the quantum dot may have a single structure in which the concentration of each element in the quantum dot is uniform (e.g., substantially uniform), or a core-shell dual structure. For example, the material in the core and the material in the shell may be different from each other.

The shell of the quantum dot may act or serve as a protective layer that may prevent or reduce chemical degeneration of the core (or may reduce a degree or occurrence of chemical degradation of the core) to maintain semiconductor characteristics, and/or as a charging layer that may impart electrophoretic characteristics to the quantum dot. The shell may be a single layer or a multi-layer. The interface between the core and the shell may have a concentration gradient in which the concentration of an element existing in the shell decreases along a direction toward the center of the core.

Examples of the shell of the quantum dot may be an oxide of a metal, metalloid and/or non-metal, a semiconductor compound, and a combination thereof. Examples of the oxide of a metal and/or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; and any combination thereof. Examples of the semiconductor compound may include: a Group III-VI semiconductor compound; a Group II-VI semiconductor compound; a Group III-V semiconductor compound; a Group III-VI semiconductor compound; a Group I-III-VI semiconductor compound; a Group IV-VI semiconductor compound; or any combination thereof, as described in one or more embodiments. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element in a multi-element compound, such as the binary compound and the ternary compound, may be present at a uniform (e.g., substantially uniform) concentration or non-uniform (e.g., substantially non-uniform) concentration in a particle. The above formulae may refer to the types or kinds of elements in each compound, and the element ratios in these compounds may be different from each other.

A full width at half maximum (FWHM) of the emission wavelength spectrum of the quantum dot may be about 45 nm or less, for example, about 40 nm or less, for example, about 30 nm or less, and within these ranges, color purity and/or color reproducibility may be increased (e.g., suitable color purity or color reproducibility). In one or more embodiments, because the light emitted through the quantum dot is emitted in all (e.g., substantially all) directions, the wide viewing angle may be improved (e.g., the suitable viewing angle).

In one or more embodiments, the quantum dot may be in the form of a spherical particle (e.g., a generally spherical particle), a pyramidal particle (e.g., a generally pyramidal particle), a multi-arm particle (e.g., a generally multi-arm particle), a cubic nanoparticle (e.g., a generally cubic particle), a nanotube particle (e.g., a generally nanotube particle), a nanowire particle (e.g., a generally nanowire particle), a nanofiber particle (e.g., a generally nanofiber particle), or a nanoplate particle (e.g., a generally nanoplate particle).

By adjusting the size of the quantum dots, the energy band gap may be adjusted, and, for example, light of one or more suitable wavelengths may be obtained in a quantum dot emission layer. For example, by using quantum dots as described above (by using quantum dots of different sizes or by varying the ratio of elements in a quantum dot compound), a light-emitting device that emits light of one or more suitable wavelengths may be realized. In one or more embodiments, the size of the quantum dots or the ratio of elements in the quantum dot compound may be selected so that red light, green light, and/or blue light may be emitted. In one or more embodiments, the quantum dots may be provided to emit white light by combination of light of one or more suitable colors.

### Electron Transport Region 140

The electron transport region 140 may have i) a single-layer structure consisting of a single layer that may include a single material, ii) a single-layer structure consisting of a single layer that may include a plurality of materials that are different from each other, or iii) a multi-layer structure consisting of a plurality of layers that may include a plurality of different materials that are different from each other.

The electron transport region 140 may include a buffer layer, a hole-blocking layer, an electron control layer, an electron transport layer, an electron injection layer, or any combination thereof.

In one or more embodiments, the electron transport region 140 may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, wherein, for each structure, constituting layers are sequentially stacked from the emission layer 130.

In one or more embodiments, the electron transport region 140 (for example, the buffer layer, the hole-blocking layer, the electron control layer, and/or the electron transport layer in the electron transport region) may include a metal-free compound that includes at least one π electron-deficient nitrogen-containing C₁-C₆₀ cyclic group.

For example, the electron transport region 140 may include a compound represented by Formula 601:

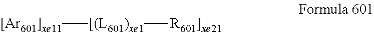

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₁)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same (e.g., substantially the same) as described in connection with Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, if (e.g., when) xe11 in Formula 601 is 2 or more, two or more of Ar₆₀₁ may be linked together via a single bond (e.g., a single covalent bond).

In one or more embodiments, Ar₆₀₁ in Formula 601 may be an anthracene group unsubstituted or substituted with at least one R₁₀ₐ.

In one or more embodiments, the electron transport region 140 may include a compound represented by Formula 601-1:

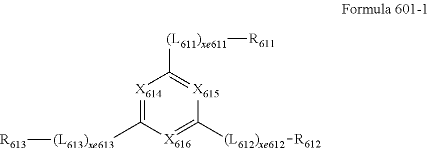

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each independently be the same (e.g., substantially the same) as described in connection with L₆₀₁,
xe611 to xe613 may each independently be the same (e.g., substantially the same) as described in connection with xe1,
R₆₁₁ to R₆₁₃ may each independently be the same (e.g., substantially the same) as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, xe1 and xe611 to xe613 in Formulae 601 and 601-1 may each independently be 0, 1, or 2.

The electron transport region 140 may include one selected from among Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

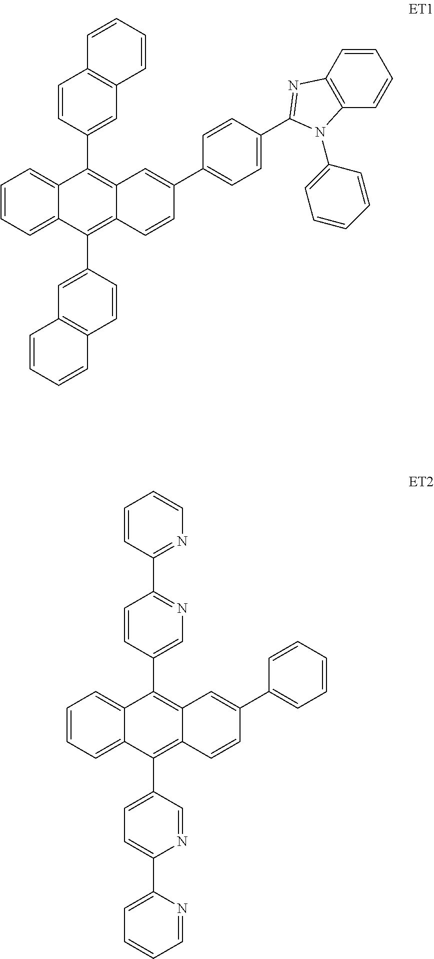 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1]

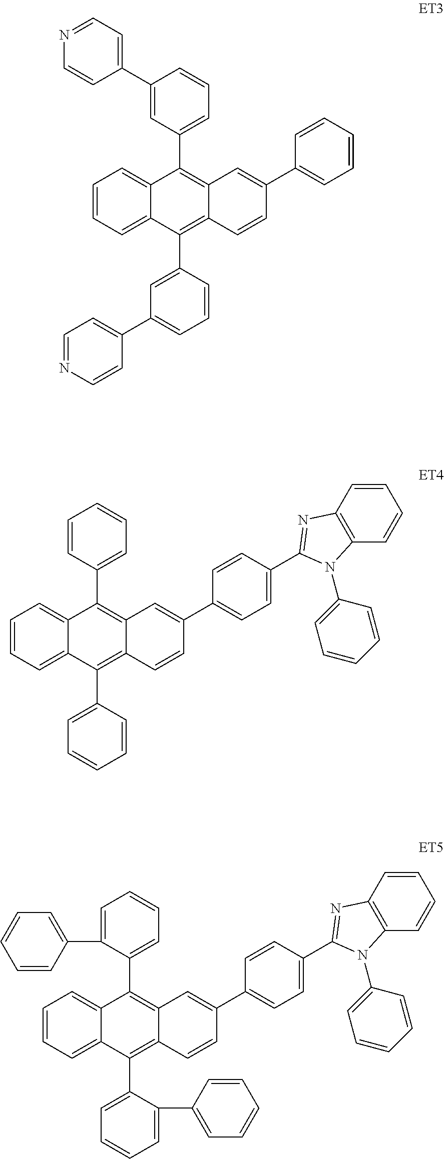 [SMILES: c1ccc(-c2ccc3c(-c4cccc(-c5ccncc5)c4)c4ccccc4c(-c4cccc(-c5ccncc5)c4)c3c2)cc1 ; c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1]

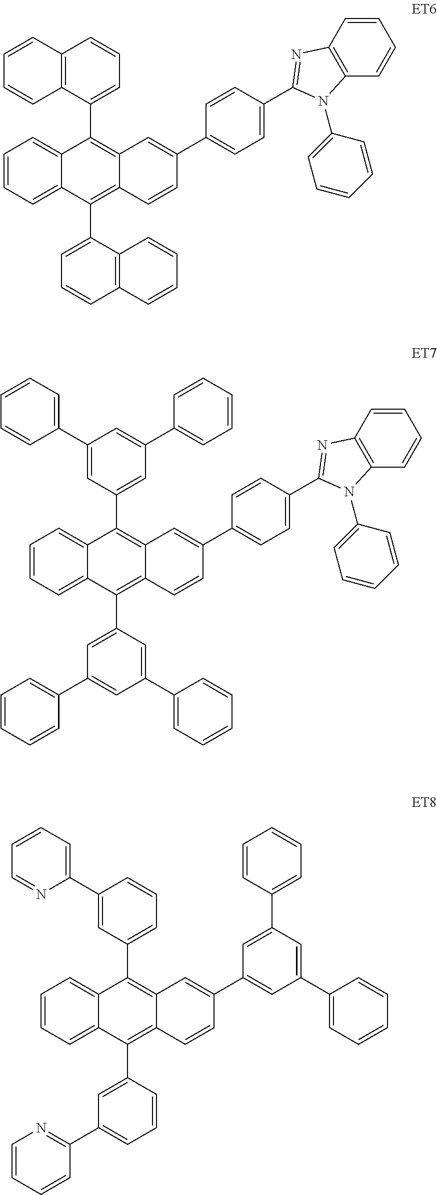 [SMILES: c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

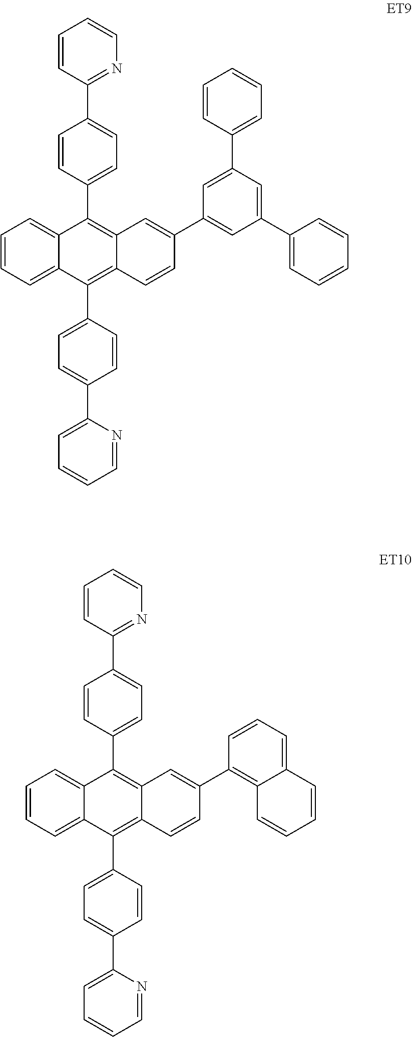 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

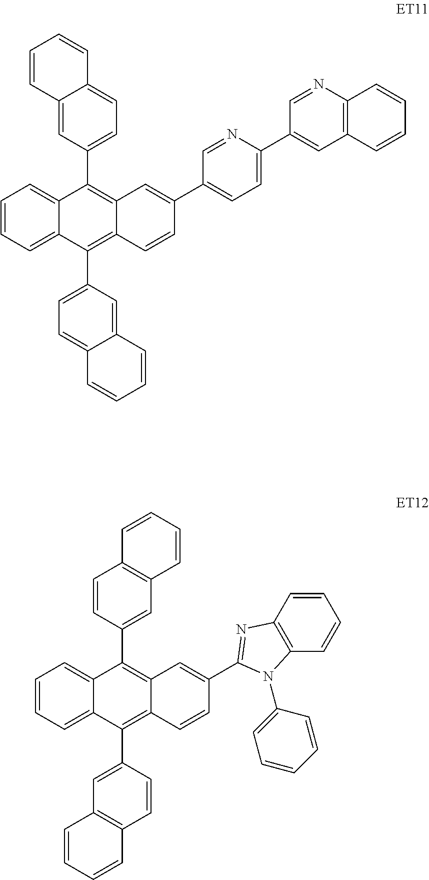 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

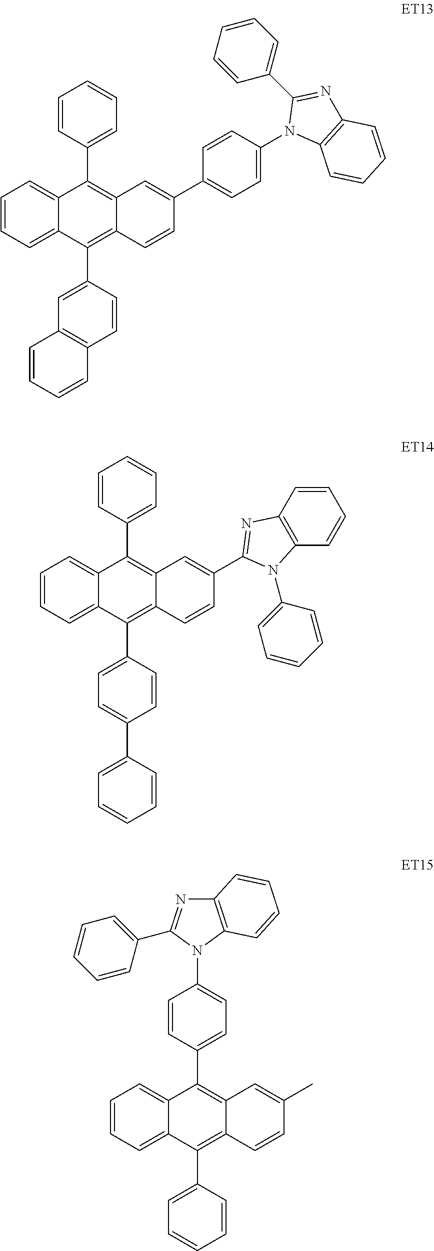 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

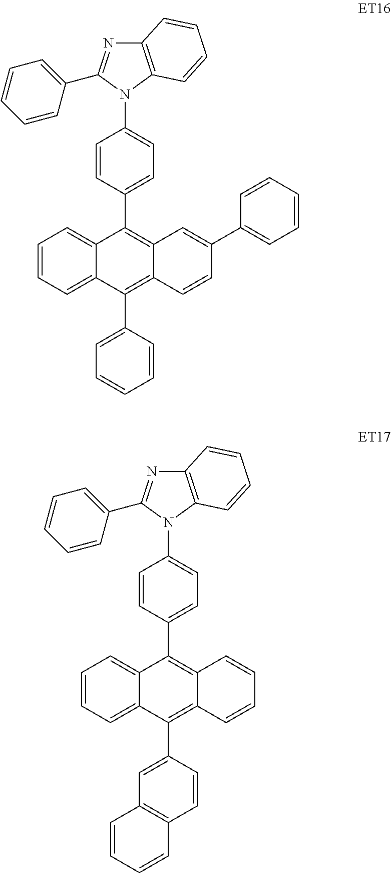 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1]

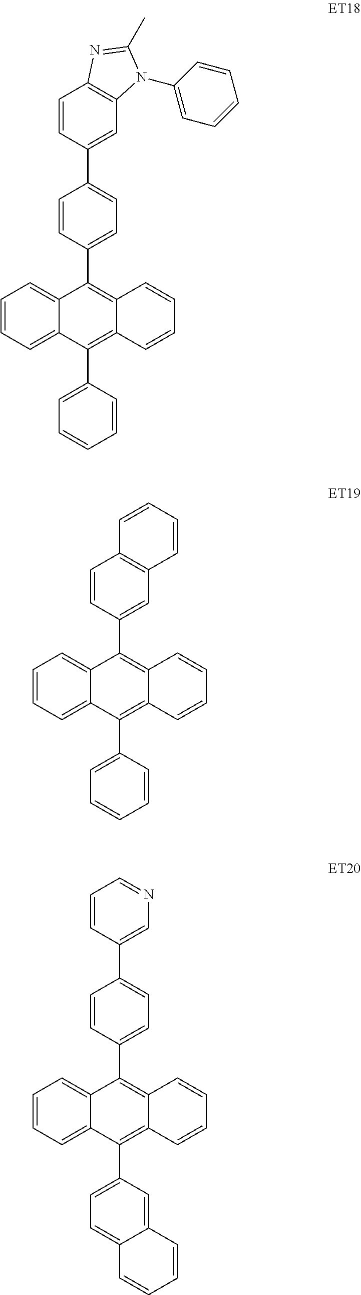

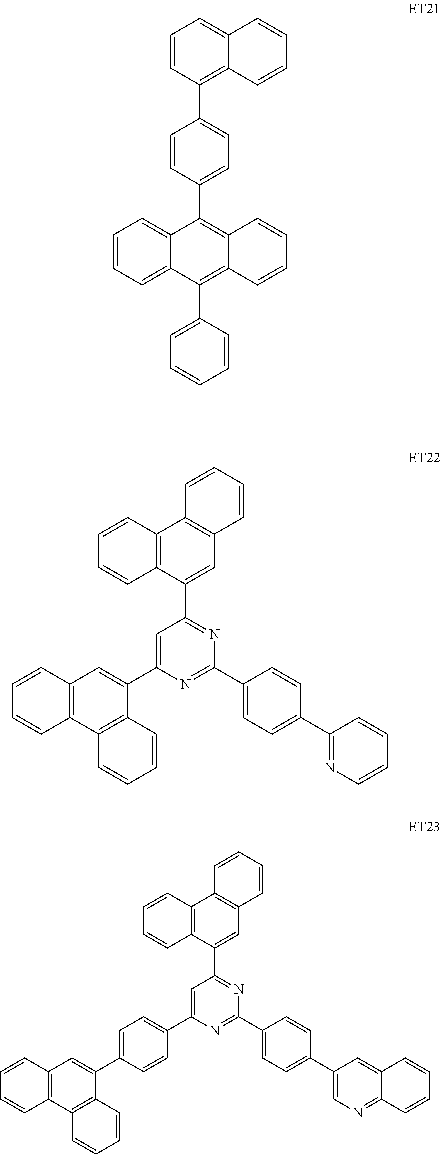

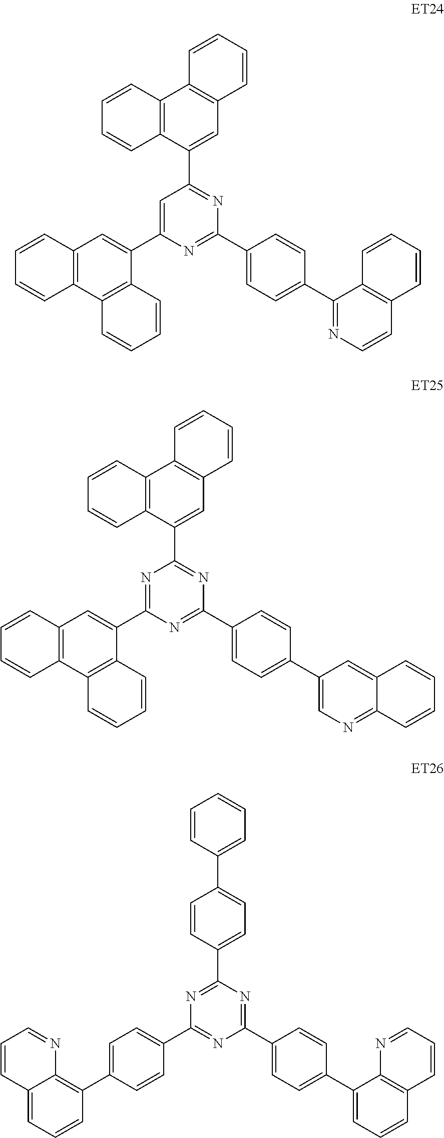 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

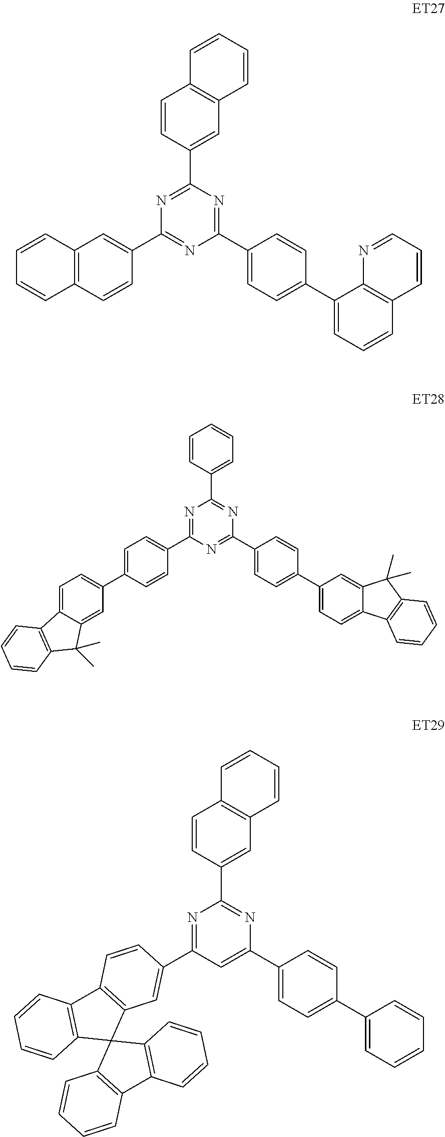 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

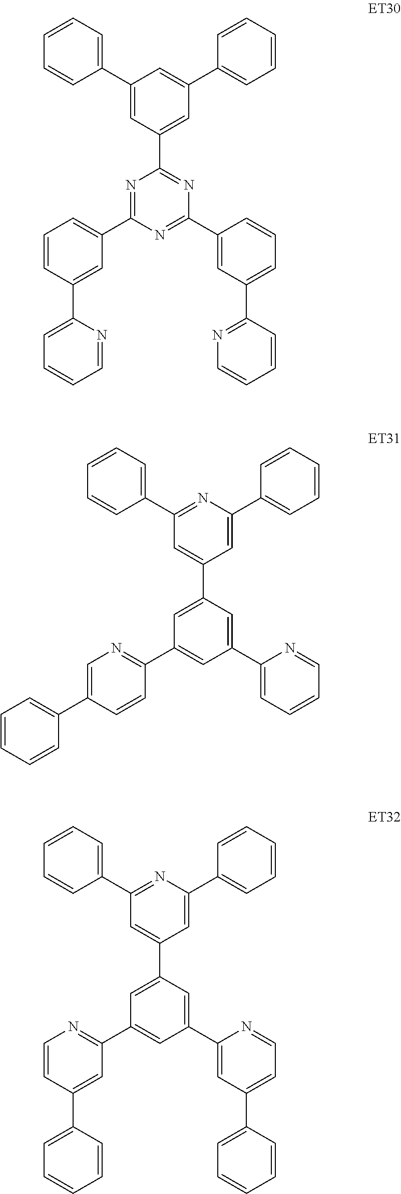 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

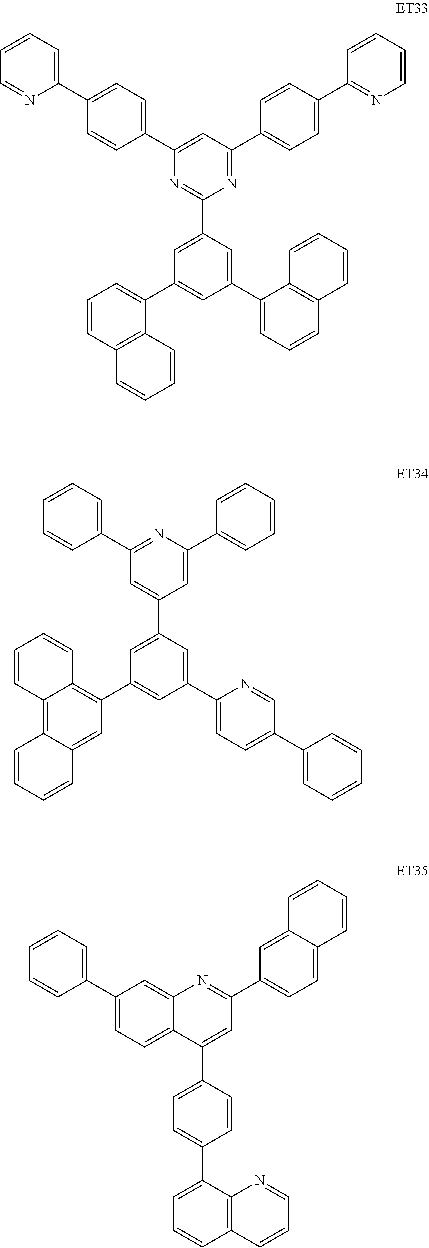 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

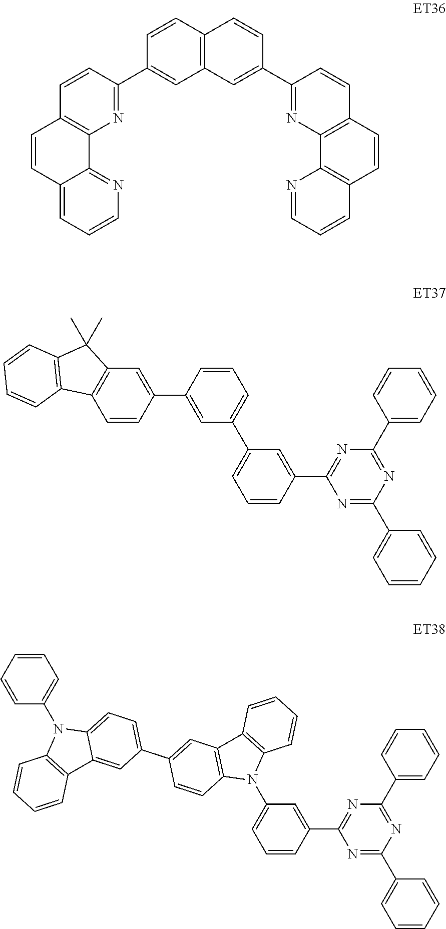 [SMILES: c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

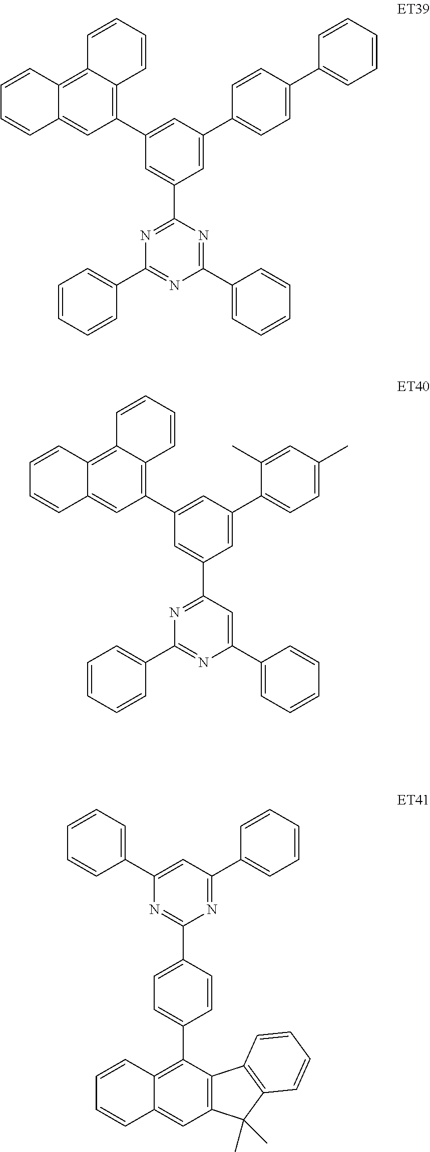 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

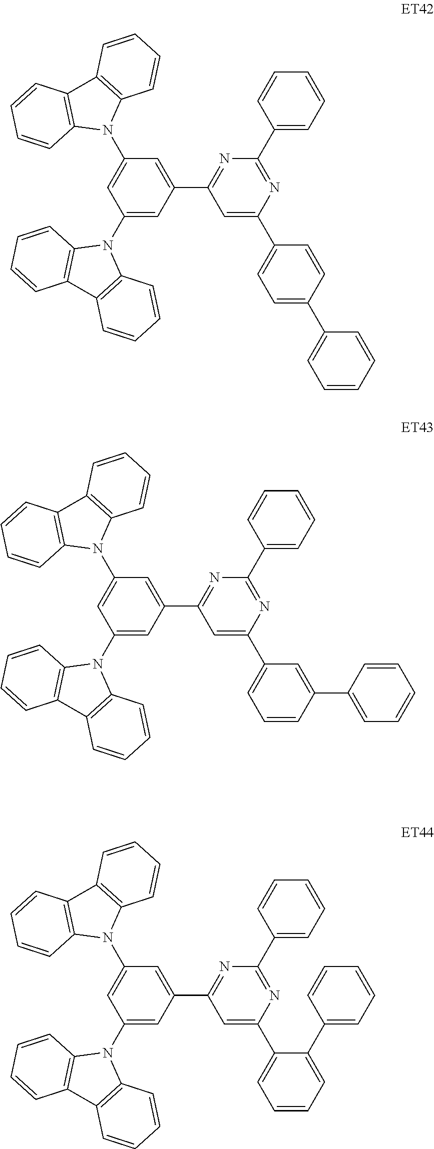 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1]

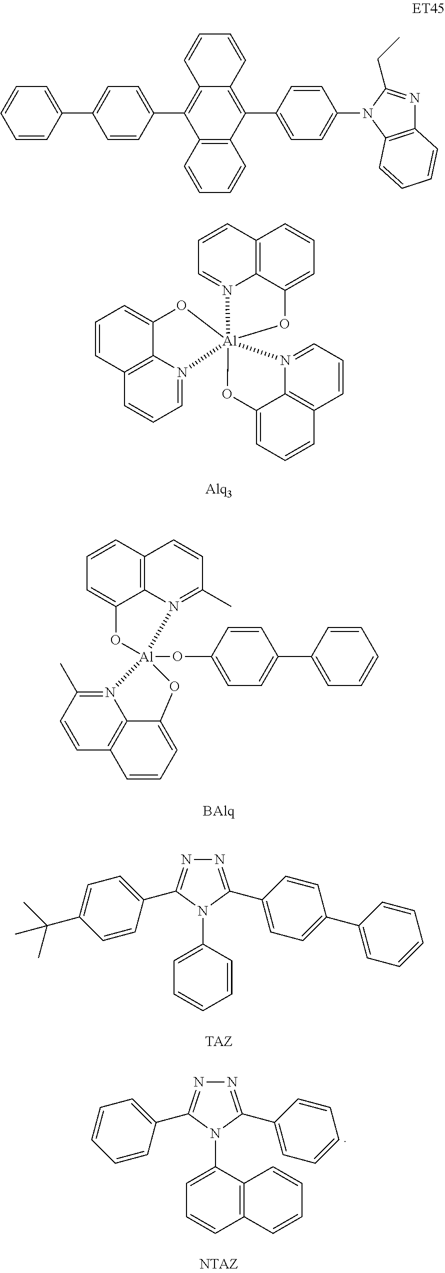

The thickness of the electron transport region 140 may be in a range of about 100 Å to about 5,000 Å, for example, about 160 Å to about 4,000 Å. If (e.g., when) the electron transport region 140 includes a buffer layer, a hole-blocking layer, an electron control layer, an electron transport layer, or any combination thereof, a thickness of the buffer layer, the hole-blocking layer, or the electron control layer may each independently be from about 20 Å to about 1,000 Å, for example, about 30 Å to about 300 Å, and a thickness of the electron transport layer may be from about 100 Å to about 1,000 Å, for example, about 150 Å to about 500 Å. If (e.g., when) the thicknesses of the buffer layer, the hole-blocking layer, the electron control layer, the electron transport layer, and/or the electron transport region are within the ranges described above, satisfactory or suitable electron transporting characteristics may be obtained not having a substantial increase in driving voltage (e.g., may be obtained having a suitable increase in driving voltage).

The electron transport region 140 (e.g., an electron transport layer in the electron transport region) may further include, in addition to the materials as described in one or more embodiments of the present disclosure, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In one or more embodiments, the metal-containing material may include a Li complex. The Li complex may include, for example, Compound ET-D1 (LiQ) and/or ET-D2:

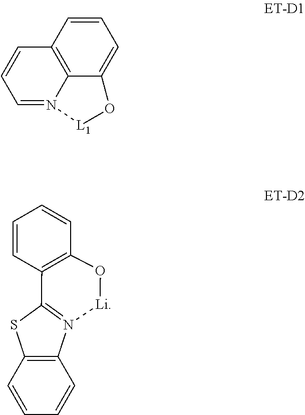

The electron transport region 140 may include an electron injection layer that facilitates the injection of electrons from the second electrode 150. The electron injection layer may directly contact the second electrode 150 (e.g., may be directly on the second electrode 150).

The electron injection layer may have: i) a single-layered structure consisting of a single layer that consists of a single material, ii) a single-layered structure consisting of a single layer that includes a plurality of different materials, or iii) a multilayer structure including a plurality of layers that includes a plurality of different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, and/or the like), and/or tellurides of the alkali metal, the alkaline earth metal, and/or the rare earth metal, or any combination thereof.

The alkali metal-containing compound may include: alkali metal oxides, such as Li₂O, Cs₂O, and/or K₂O; alkali metal halides, such as LiF, NaF, CsF, KF, LiI, NaI, CsI, and/or KI; or any combination thereof. The alkaline earth metal-containing compound may include an alkaline earth metal compound, such as BaO, SrO, CaO, BaₓSr₁₋ₓO (where x is a real number satisfying 0<x<1), and/or BaₓCa₁₋ₓO (where x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of ions selected from among the alkali metal, the alkaline earth metal, and the rare earth metal and ii) a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may consist of i) an alkali metal-containing compound (for example, alkali metal halide), ii) a) an alkali metal-containing compound (for example, alkali metal halide); and b) an alkali metal, an alkaline earth metal, a rare earth metal, or any combination thereof. In one or more embodiments, the electron injection layer may be a KI:Yb co-deposited layer, an RbI:Yb co-deposited layer, a LiF:Yb co-deposited layer, and/or the like.

If (e.g., when) the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly (e.g., substantially uniformly) or non-uniformly (e.g., substantially non-uniformly) dispersed or distributed in a matrix that includes the organic material.

The thickness of the electron injection layer may be about 1 Å to about 100 Å, and, for example, about 3 Å to about 90 Å. If (e.g., when) the thickness of the electron injection layer is within the range as described above, satisfactory or suitable electron injection characteristics may be obtained not having a substantial increase in driving voltage (e.g., may be obtained having a suitable increase in driving voltage).

### Second Electrode 150

The second electrode 150 may be arranged on the electron transport region 140. The second electrode 150 may be a cathode, which is an electron injection electrode, and may act or serve as a material that forms or provides the second electrode 150, a metal, an alloy, an electrically conductive compound, or any combination thereof, each having a low-work function, may be used.

The second electrode 150 may include Li, Ag, Mg, Al, Al—Li, Ca, Mg—In, Mg—Ag, Yb, Ag—Yb, ITO, IZO, or any combination thereof. The second electrode 150 may be a transmissive electrode, a semi-transmissive electrode, or a reflective electrode.

The second electrode 150 may have a single-layer structure or a multi-layer structure including a plurality of layers.

### Capping Layer

The light-emitting device 10 may further include a capping layer arranged outside the first electrode 110 or outside the second electrode 150. A first capping layer may be arranged outside the first electrode 110, and/or a second capping layer may be arranged outside the second electrode 150. For example, the light-emitting device 10 may have a structure in which the first capping layer, the first electrode 110, the interlayer, and the second electrode 150 are sequentially stacked in the stated order, a structure in which the first electrode 110, the interlayer, the second electrode 150, and the second capping layer are sequentially stacked in the stated order, or a structure in which the first capping layer, the first electrode 110, the interlayer, the second electrode 150, and the second capping layer are sequentially stacked in the stated order.

In one or more embodiments, the capping layer may include a first compound represented by Formula 1 and/or a second compound represented by Formula 2.

For example, the light-emitting device may further include the first capping layer arranged outside the first electrode 110. The first capping layer may include the first compound represented by Formula 1, the second compound represented by Formula 2, or a combination thereof.

In one or more embodiments, the light-emitting device may further include the second capping layer arranged outside the second electrode 150. The second capping layer may include the first compound represented by Formula 1, the second compound represented by Formula 2, or a combination thereof.

In one or more embodiments, the light-emitting device may further include the first capping layer arranged outside the first electrode 110 and the second capping layer arranged outside the second electrode 150. At least one selected from the first capping layer and the second capping layer may include the first compound represented by Formula 1, the second compound represented by Formula 2, or a combination thereof.

Light generated in the emission layer 130 of the light-emitting device 10 may pass through the first electrode 110, which may be a semi-transmissive electrode or a transmissive electrode, and through the first capping layer to the outside. Light generated in the emission layer 130 of the light-emitting device 10 may pass through the second electrode 150, which may be a semi-transmissive electrode or a transmissive electrode, and through the second capping layer to the outside.

The first capping layer and the second capping layer may increase external emission efficiency (e.g., may increase to have suitable external emission efficiency) according to the principle of constructive interference. In one or more embodiments, the light extraction efficiency of the light-emitting device 10 may be increased (e.g., suitable light extraction efficiency of the light emitting device 10), such that the luminescence efficiency of the light-emitting device 10 may be increased (e.g., suitable luminescence efficiency of the light-emitting device 10).

Each of the first capping layer and the second capping layer may include a material having a refractive index of about 1.2 or higher (at a wavelength of 460 nm).

The first capping layer and the second capping layer may each independently be an organic capping layer that may include an organic material, an inorganic capping layer that may include an inorganic material, or an organic-inorganic composite capping layer that may include an organic material and an inorganic material.

At least one selected from the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In one or more embodiments, at least one selected from the first capping layer and the second capping layer may each independently include an amine group-containing compound.

In one or more embodiments, at least one selected from the first capping layer and the second capping layer may each independently include a compound represented by Formula 201, a compound represented by Formula 202, or any combination thereof.

In one or more embodiments, at least one selected from the first capping layer and the second capping layer may each independently include one selected from among Compounds HT28 to HT33, one selected from among Compounds CP1 to CP6, β-NPB, or any combination thereof:

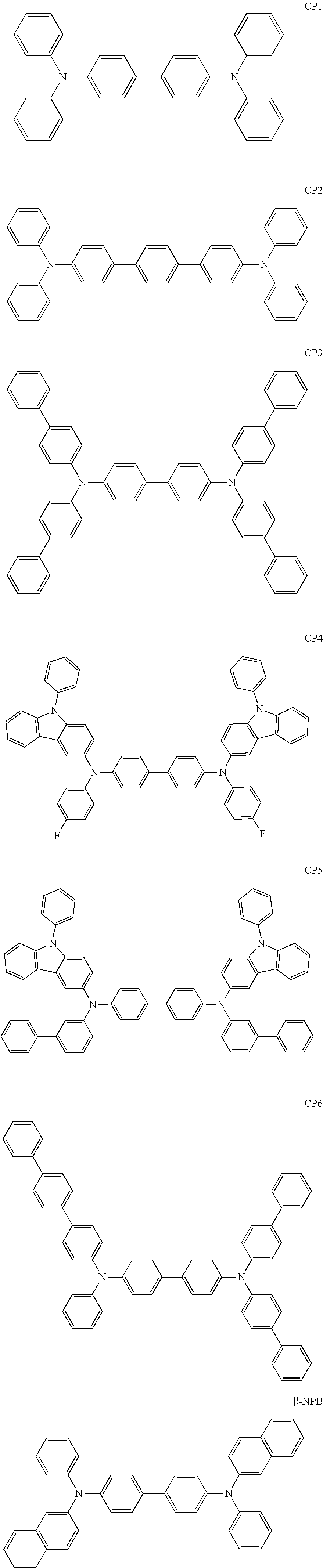

### Film

The electronic apparatus may further include a film. The film may be, for example, an optical member (or a light control means) (e.g., a color filter, a color conversion member, a capping layer, a light extraction efficiency enhancement layer, a selective light absorbing layer, a polarizing layer, a quantum dot-containing layer, and/or the like), a light-blocking member (e.g., a light reflective layer, a light absorbing layer, and/or the like), a protective member (e.g., an insulating layer, a dielectric layer, and/or the like), and/or the like.

### Electronic Apparatus

The light-emitting device 10 may be in one or more suitable electronic apparatuses. For example, an electronic apparatus including the light-emitting device 10 may be a display apparatus, an authentication apparatus, and/or the like.

The electronic apparatus (for example, a display apparatus) may further include, in addition to the light-emitting device 10, i) a color filter, ii) a color-conversion layer, or iii) a color filter and a color-conversion layer. The color filter and/or the color-conversion layer may be disposed (or provided or arranged) in at least one direction in which light emitted from the light-emitting device 10 travels. For example, light emitted from the light-emitting device 10 may be blue light or white light. The light-emitting device 10 may be the same (e.g., substantially the same) as described in one or more embodiments. In one or more embodiments, the color conversion layer may include quantum dots. The quantum dot may be, for example, a quantum dot as described in one or more embodiments.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area that emits a first color light, a second area that emits a second color light, and/or a third area that emits a third color light, wherein the first color light, the second color light, and/or the third color light may have different maximum emission wavelengths. In one or more embodiments, the first color light may be red light, the second color light may be green light, and the third color light may be blue light. In one or more embodiments, the plurality of color filter areas (or the plurality of color conversion areas) may include quantum dots. In more detail, the first area may include red quantum dots, the second area may include green quantum dots, and the third area may not include quantum dots. A more detailed description of the quantum dots is provided herein. The first area, the second area, and/or the third area may each further include a scatterer (e.g., a light scatterer).

For example, the light-emitting device 10 may emit the first light, the first area may absorb the first light to emit a 1-1 color light, the second area may absorb the first light to emit a 2-1 color light, and the third area may absorb the first light to emit a 3-1 color light. In one or more embodiments, the 1-1 color light, the 2-1 color light, and the 3-1 color light may have different maximum emission wavelengths. In more detail, the first light may be blue light, the 1-1 color light may be red light, the 2-1 color light may be green light, and the 3-1 color light may be blue light.

The electronic apparatus may further include a thin-film transistor, in addition to the light-emitting device 10. The thin-film transistor may include a source electrode, a drain electrode, and an activation layer, wherein any one selected from the source electrode and the drain electrode may be electrically connected to any one selected from the first electrode and the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion that seals the light-emitting device. The sealing portion may be arranged between the color filter and/or the color conversion layer and the light-emitting device. The sealing portion may allow light to pass to the outside from the light-emitting device and may prevent or reduces the air and moisture from permeating (or may reduce a degree of occurrence of permeation of the air and moisture) into the light-emitting device at the same time (e.g., at substantially the same time). The sealing portion may be a sealing substrate that may include a transparent glass substrate and/or a plastic substrate. The sealing portion may be a thin-film encapsulation layer that may include at least one layer of an organic layer and/or an inorganic layer. If (e.g., when) the sealing portion is a thin film encapsulation layer, the electronic apparatus may be flexible.

One or more suitable functional layers may be further arranged on the sealing portion, in addition to the color filter and/or the color conversion layer, according to the use of the electronic apparatus. Examples of the functional layers may include a touch screen layer and a polarizing layer. The touch screen layer may be a pressure-sensitive touch screen layer, a capacitive touch screen layer, and/or an infrared touch screen layer. The authentication apparatus may be, for example, a biometric authentication apparatus that authenticates an individual by using biometric information of a living body (for example, fingertips, pupils, and/or the like).

The authentication apparatus may further include, in addition to the light-emitting device as described in one or more embodiments, a biometric information collector.

The electronic apparatus may be applied to one or more suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

### Electronic Equipment

The light-emitting device 10 may be in any suitable electronic equipment.

In one or more embodiments, the electronic equipment including the light-emitting device 10 may be one selected from among a flat panel display, a curved display, a computer monitor, a medical monitor, a television, a billboard, a light for indoor or outdoor lighting and/or signaling (e.g., a light for indoor or outdoor lighting (e.g., an indoor or outdoor light) or a light for indoor or outdoor signaling (e.g., an indoor or outdoor light for signal)), a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual or augmented-reality display, a vehicle, a video wall including a plurality of displays tiled together, a theater or stadium screen, a phototherapy device, a signboard, and/or the like.

As the light-emitting device 10 has improved driving voltage, luminescence efficiency, lifespan effects (e.g., suitable driving voltage, luminescence efficiency, lifespan effects), and/or the like, the electronic equipment including the light-emitting device 10 may have characteristics, such as high luminance, high resolution, and/or low power consumption.

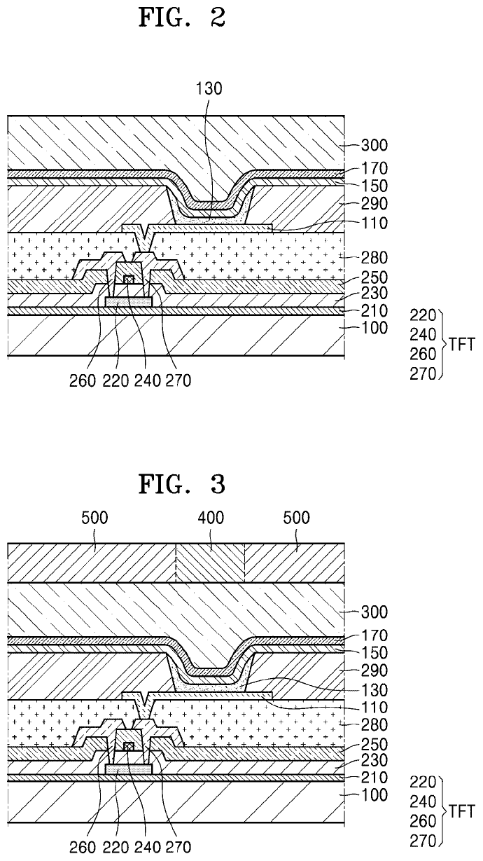

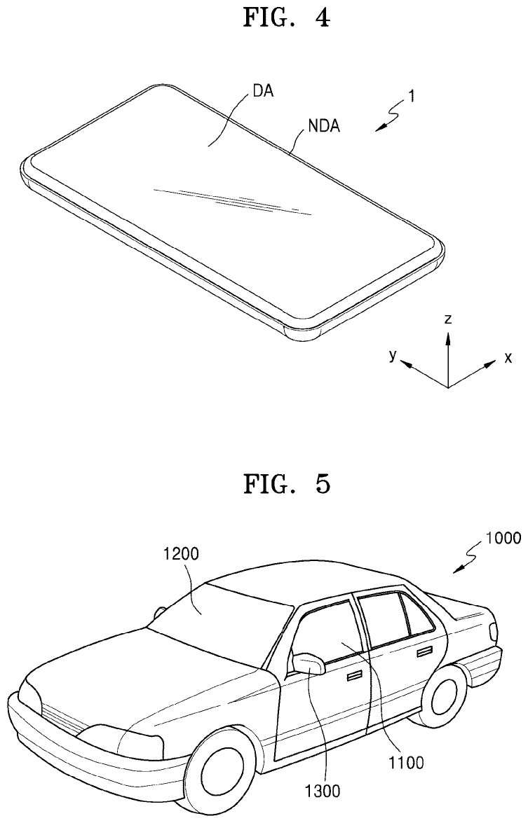

### Description of FIGS. 2-3

FIG. 2 is a cross-sectional view of an electronic apparatus according to one or more embodiments.

The electronic apparatus of FIG. 2 may include a substrate 100, a thin-film transistor (TFT), a light-emitting device, and an encapsulation portion 300.

The substrate 100 may be a flexible substrate, a glass substrate, and/or a metal substrate. A buffer layer 210 may be arranged on the substrate 100. The buffer layer 210 may prevent or reduce penetration of impurities (or may reduce a degree or occurrence of penetration of impurities) through the substrate 100 and may provide a flat surface on the substrate 100.

A TFT may be arranged on the buffer layer 210. The TFT may include an activation layer 220, a gate electrode 240, a source electrode 260, and a drain electrode 270.

The activation layer 220 may include an inorganic semiconductor, such as silicon or polysilicon, an organic semiconductor, or an oxide semiconductor, and may include a source region, a drain region, and a channel region.

A gate insulating film 230 for insulating (e.g., electrically insulating) the activation layer 220 from the gate electrode 240 may be arranged on the activation layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate (e.g., electrically insulate) from one another.

The source electrode 260 and the drain electrode 270 may be arranged on the interlayer insulating film 250. The interlayer insulating film 250 and the gate insulating film 230 may be formed or provided to expose the source region and the drain region of the activation layer 220, and the source electrode 260 and the drain electrode 270 may be arranged in contact with the exposed portions (e.g., may be arranged on the exposed portions) of the source region and the drain region of the activation layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided or arranged on the passivation layer 280. The light-emitting device may include the first electrode 110, the interlayer, and the second electrode 150.

The first electrode 110 may be arranged on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating material may be arranged on the first electrode 110. The pixel defining layer 290 may expose a certain region of the first electrode 110, and the interlayer may be formed or provided in the exposed region of the first electrode 110. The pixel-defining film 290 may be a polyimide-based organic film or a polyacrylic organic film. In one or more embodiments, at least some layers of the interlayer may extend to the upper portion of the pixel defining layer 290 and may be arranged in the form of a generally available layer.

The second electrode 150 may be arranged on the interlayer, and a capping layer 170 may be further formed (e.g., provided or arranged) on the second electrode 150. The capping layer 170 may be formed (e.g., provided or arranged) to cover the second electrode 150.

The encapsulation portion 300 may be located (or provided or arranged) on the capping layer 170. The encapsulation portion 300 may be disposed (or provided or arranged) on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and/or the like), an epoxy-based resin (for example, aliphatic glycidyl ether (AGE), and/or the like), or any combination thereof; or a combination of the inorganic film and the organic film.

FIG. 3 is a cross-sectional view of an electronic apparatus according to one or more embodiments.

The electronic apparatus of FIG. 3 may be the same (e.g., substantially the same) as the electronic apparatus of FIG. 2, except that a light-shielding pattern 500 and a functional region 400 are further arranged on the encapsulation portion 300. The functional region 400 may be i) a color filter area, ii) a color conversion area, or iii) a combination of the color filter area and the color conversion area. In one or more embodiments, the light-emitting device in the electronic apparatus of FIG. 3 may be a tandem light-emitting device.

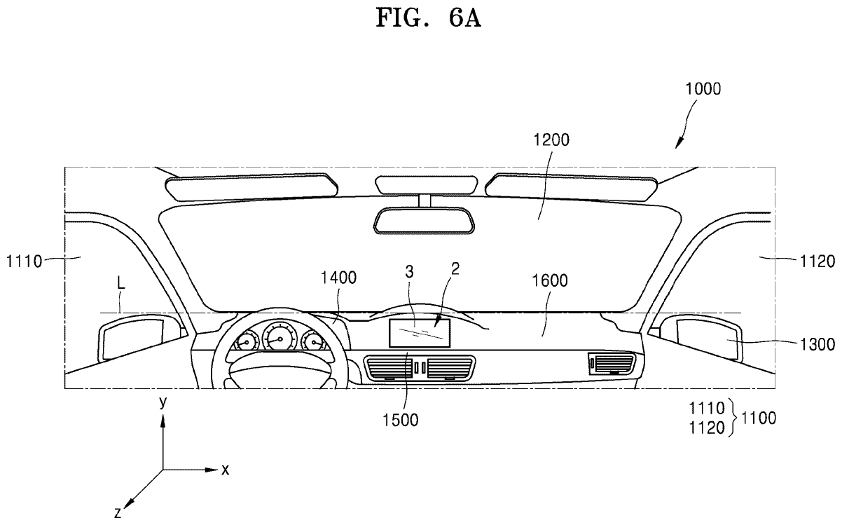

### Description of FIG. 4

FIG. 4 is a schematic perspective view of electronic equipment 1 including a light-emitting device according to one or more embodiments. The electronic equipment 1 may be an apparatus that displays a moving image or a still image, portable electronic equipment, such as a mobile phone, a smartphone, a tablet personal computer (PC), a mobile communication terminal, an electronic notebook, an electronic book, a portable multimedia player (PMP), a navigation, or an ultra-mobile PC (UMPC), as well as one or more suitable products, such as a television, a laptop, a monitor, a billboard, or an Internet of things (IoT) device. The electronic equipment 1 may be such a product above or a part thereof. In one or more embodiments, the electronic equipment 1 may be a wearable device, such as a smart watch, a watch phone, a glasses-type or -kind display, or a head mounted display (HMD), or a part of the wearable device. However, embodiments of the present disclosure are not limited thereto. In one or more embodiments, the electronic equipment 1 may be a dashboard of a vehicle, a center information display (CID) arranged on a center fascia or dashboard of a vehicle, a room mirror display instead of a side-view mirror of a vehicle, an entertainment for the back seat of a vehicle, or a display arranged on the back of the front seat of a vehicle, a head up display (HUD) that may be installed (or provided or arranged) on the front of a vehicle or projected on a front window glass, or a computer generated hologram augmented reality head up display (CGH AR HUD).

FIG. 4 illustrates one or more embodiments in which the electronic equipment 1 may be a smartphone for convenience of explanation.

The electronic equipment 1 may include a display area DA and a non-display area NDA outside the display area DA. The electronic equipment 1 may implement an image through an array of a plurality of pixels that are two-dimensionally arranged in the display area DA.

The non-display area NDA may be an area that does not display an image, and may entirely surround the display area DA. On the non-display area NDA, a driver for providing electrical signals or power to display devices arranged on the display area DA may be arranged. On the non-display area NDA, a pad, which is an area to which an electronic element or a printed circuit board, may be electrically connected may be arranged.

In the electronic equipment 1, the length in an x-axis direction and the length in a y-axis direction may be different from each other. In one or more embodiments, as shown in FIG. 4, the length in the x-axis direction may be less than the length in the y-axis direction. In one or more embodiments, the length in the x-axis direction may be the same (e.g., substantially the same) as the length in the y-axis direction. In one or more embodiments, the length in the x-axis direction may be greater than the length in the y-axis direction.

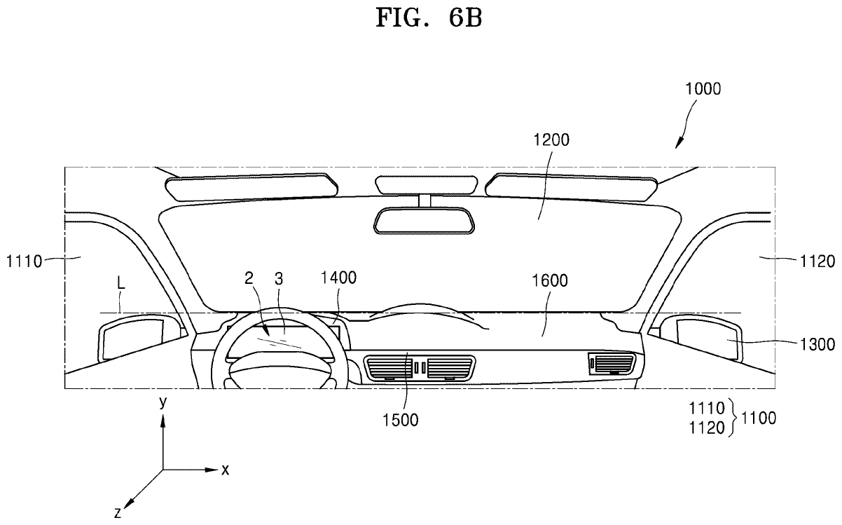

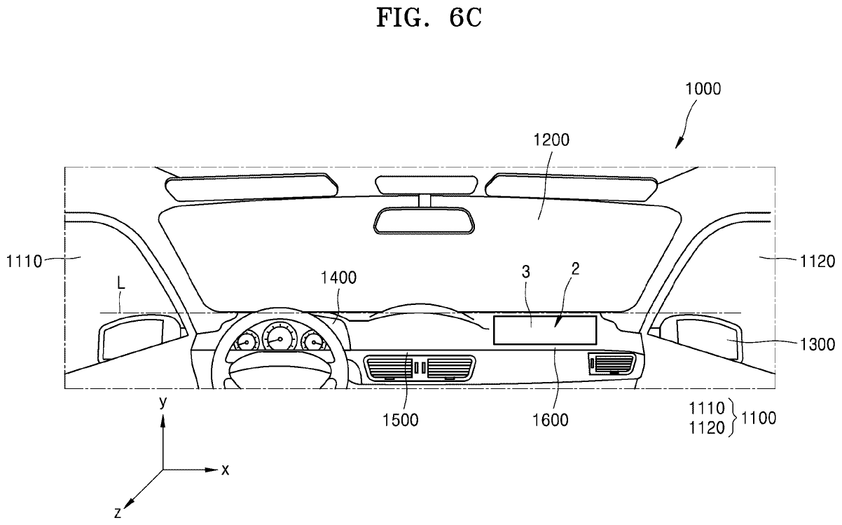

### Descriptions of FIGS. 5 and 6A-6C

FIG. 5 is a schematic view of the exterior of a vehicle 1000 as electronic equipment including a light-emitting device, according to one or more embodiments. FIGS. 6A-6C are each a schematic view of the interior of the vehicle 1000 according to one or more embodiments.

Referring to FIGS. 5 and 6A-6C, the vehicle 1000 may refer to one or more suitable apparatuses for moving a subject to be transported, such as a human, an object, and/or an animal, from a departure point to a destination point. The vehicle 1000 may include a vehicle traveling on a road or track, a vessel moving over the sea or river, an airplane flying in the sky using the action of air, and/or the like.

The vehicle 1000 may travel on a road or a track. The vehicle 1000 may move in a certain direction according to rotation of at least one wheel. In one or more embodiments, the vehicle 1000 may include a three-wheeled or four-wheeled vehicle, a construction machine, a two-wheeled vehicle, a prime mover device, a bicycle, and a train running on a track.

The vehicle 1000 may include a body of the 1000 having an interior and an exterior, and a chassis in which mechanical apparatuses necessary for driving are installed (or provided or arranged) as other parts except for the body of the vehicle 1000. The exterior of the body of the vehicle may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed (or provided or arranged) on the side of the vehicle 1000. In one or more embodiments, the side window glass 1100 may be installed (or provided or arranged) on a door of the vehicle 1000. A plurality of side window glasses 1100 may be provided or arranged and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced apart (or arranged apart) from each other in an x direction or a −x direction. In one or more embodiments, the first side window glass 1110 and the second side window glass 1120 may be spaced apart (or arranged apart) from each other in the x direction or the −x direction. In one or more embodiments, an imaginary straight line L connecting the side window glasses 1100 may extend in the x direction or the −x direction. In one or more embodiments, an imaginary straight line L connecting the first side window glass 1110 and the second side window glass 1120 to each other may extend in the x direction or the −x direction.

The front window glass 1200 may be installed (or provided or arranged) in front of the vehicle 1000. The front window glass 1200 may be arranged between the side window glasses 1100 facing each other.

The side-view mirror 1300 may provide a rear view of the vehicle 1000. The side-view mirror 1300 may be installed (or provided or arranged) on the exterior of the body of the vehicle. In one or more embodiments, a plurality of side-view mirrors 1300 may be provided or arranged. Any one selected from among the plurality of side-view mirrors 1300 may be arranged outside the first side window glass 1110. The other one selected from among the plurality of side-view mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and a seat heater are disposed (or provided or arranged). The center fascia 1500 may be arranged on one side of the cluster 1400.

The passenger seat dashboard 1600 may be spaced apart (or arranged apart) from the cluster 1400, and the center fascia 1500 may be arranged between the cluster 1400 and the passenger seat dashboard 1600. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged inside the vehicle 1000. In one or more embodiments, the display apparatus 2 may be arranged between the side window glasses 1100 facing each other. The display apparatus 2 may be arranged on at least one selected from among the cluster 1400, the center fascia 1500, and the passenger seat dashboard 1600.

The display device 2 may include an organic light-emitting display device, an inorganic electroluminescent (EL) display device, a quantum dot display device, and/or the like. Hereinafter, as the display device 2 according to one or more embodiments, an organic light-emitting display apparatus including the light-emitting device according to the disclosure will be described as an example, but one or more suitable types or kinds of display devices as described above may be used in one or more embodiments of the present disclosure.

Referring to FIG. 6A, the display apparatus 2 may be arranged on the center fascia 1500. In one or more embodiments, the display apparatus 2 may display navigation information. In one or more embodiments, the display apparatus 2 may display information regarding audio settings, video setting, or vehicle settings.

Referring to FIG. 6B, the display apparatus 2 may be arranged on the cluster 1400. In one or more embodiments, the cluster 1400 may display driving information and/or the like through the display apparatus 2. For example, the cluster 1400 may be implemented digitally. The digital cluster 1400 may display vehicle information and driving information. In one or more embodiments, a needle and a gauge of a tachometer and one or more suitable warning light icons may be displayed by a digital signal.

Referring to FIG. 6C, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may display an image related to information displayed on the cluster 1400 and/or information displayed on the center fascia 1500. In one or more embodiments, the display apparatus 2 arranged on the passenger seat dashboard 1600 may display information that is different from information displayed on the cluster 1400 and/or information displayed on the center fascia 1500.

### Manufacturing Method

Respective layers in the hole transport region 120, the emission layer 130, and respective layers in the electron transport region 140 may be formed (or provided or arranged) in a certain region by using one or more suitable methods, such as vacuum deposition, spin coating, casting, a Langmuir-Blodgett (LB) method, ink-jet printing, laser-printing, and/or laser-induced thermal imaging (LITI).

If (e.g., when) the layers constituting the hole transport region 120, the emission layer 130, and the layers constituting the electron transport region 140 are formed (or provided or arranged) by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be in a layer to be formed (or provided or arranged) and the structure of a layer to be formed (or provided or arranged).

### DEFINITION OF TERMS

The term, “C₃-C₆₀ carbocyclic group,” as used herein refers to a cyclic group consisting of carbon atoms acting or serving as the only ring-forming atoms and having 3 to 60 carbon atoms.

The term, “C₁-C₆₀ heterocyclic group,” as used herein refers to a cyclic group that has 1 to 60 carbon atoms and further has, in addition to carbon atoms, a heteroatom acting or serving as a ring-forming atom.

The C₃-C₆₀ carbocyclic group and the C₁-C₆₀ heterocyclic group may each independently be a monocyclic group consisting of one ring or a polycyclic group in which two or more rings are condensed with each other. In one or more embodiments, the number of ring-forming atoms of the C₁-C₆₀ heterocyclic group may be 3 to 61.

The term, “cyclic group,” as used herein may include both (e.g., simultaneously) the C₃-C₆₀ carbocyclic group and the C₁-C₆₀ heterocyclic group.

The term, “π electron-rich C₃-C₆₀ cyclic group,” as used herein refers to a cyclic group that has 3 to 60 carbon atoms and does not include *—N═*′ acting or serving as a ring-forming moiety.

The term, “π electron-deficient nitrogen-containing C₁-C₆₀ cyclic group,” as used herein refers to a heterocyclic group that has 1 to 60 carbon atoms and includes *—N═*′ acting or serving as a ring-forming moiety.

In one or more embodiments, the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, an indenoanthracene group, and/or the like), and
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, a xanten group, and/or the like).

The π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T₃ and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like).

The π electron-deficient nitrogen-containing C₁-C₆₀ cyclic group may be i) Group T4, ii) a condensed cyclic group in which two or more Groups T₄ are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like).

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, a benzene group, and/or the like.

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, a dihydropyridazine group, and/or the like.

Group T3 may be a furan group, a thiophene group, a 1H-pyrrole group, a silole group, a borole group, and/or the like.

Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, and/or the like.

The terms, “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group,” as used herein refer to i) a monovalent group, or ii) a polyvalent group (e.g., a divalent group, a trivalent group, a tetravalent group, and/or the like) that is condensed with any cyclic group according to the structure of a formula for which the corresponding term is used.

In one or more embodiments, the “benzene group” may be a benzo group, a phenyl group, a phenylene group, and/or the like, which may be easily understood by those of ordinary skill in the art according to the structure of a formula including the “benzene group.”

Examples of the monovalent C₃-C₆₀ carbocyclic group and monovalent C₁-C₆₀ heterocyclic group may be a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of the divalent C₃-C₆₀ carbocyclic group and the divalent C₁-C₆₀ heterocyclic group may be a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term, “C₁-C₆₀ alkyl group,” as used herein refers to a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group.

The term, “C₁-C₆₀ alkylene group,” as used herein refers to a divalent group having the same structure (e.g., substantially the same structure) as the C₁-C₆₀ alkyl group.

The term, “C₂-C₆₀ alkenyl group,” as used herein refers to a monovalent hydrocarbon group having at least one carbon-carbon double bond at a main chain (e.g., in the middle) or at a terminus of the C₂-C₆₀ alkyl group, and examples thereof may include an ethenyl group, a propenyl group, and a butenyl group.

The term, “C₂-C₆₀ alkenylene group,” as used herein refers to a divalent group having the same structure (e.g., substantially the same structure) as the C₂-C₆₀ alkenyl group.

The term, “C₂-C₆₀ alkynyl group,” as used herein refers to a monovalent hydrocarbon group having at least one carbon-carbon triple bond at a main chain (e.g., in the middle) or at a terminus of the C₂-C₆₀ alkyl group, and examples thereof may include an ethynyl group and a propynyl group.

The term, “C₂-C₆₀ alkynylene group,” as used herein refers to a divalent group having the same structure (e.g., substantially the same structure) as the C₂-C₆₀ alkynyl group.

The term, “C₁-C₆₀ alkoxy group,” as used herein refers to a monovalent group represented by −OA₁₀₁ (wherein A₁₀₁ is the C₁-C₆₀ alkyl group), and examples thereof may include a methoxy group, an ethoxy group, and an isopropyloxy group.

The term, “C₃-C₁₀ cycloalkyl group,” as used herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like.

The term, “C₃-C₁₀ cycloalkylene group,” as used herein refers to a divalent group having the same structure (e.g., substantially the same structure) as the C₃-C₁₀ cycloalkyl group.

The term, “C₁-C₁₀ heterocycloalkyl group,” as used herein refers to a monovalent cyclic group that has one to ten carbon atoms and further includes, in addition to the carbon atoms, at least one heteroatom acting or serving as a ring-forming atom, and examples thereof may include a 1,2,3,4-oxatriazolidinyl group, a tetrahydrofuranyl group, and a tetrahydrothiophenyl group.

The term, “C₁-C₁₀ heterocycloalkylene group,” as used herein refers to a divalent group having the same structure (e.g., substantially the same structure) as the C₁-C₁₀ heterocycloalkyl group.

The term, “C₃-C₁₀ cycloalkenyl group,” as used herein refers to a monovalent cyclic group that has three to ten carbon atoms and at least one carbon-carbon double bond in the ring thereof and no aromaticity, and examples thereof may include a cyclopentenyl group, a cyclohexenyl group, and a cycloheptenyl group.

The term, “C₃-C₁₀ cycloalkenylene group,” as used herein refers to a divalent group having the same structure (e.g., substantially the same structure) as the C₃-C₁₀ cycloalkenyl group.

The term, “C₁-C₁₀ heterocycloalkenyl group,” as used herein refers to a monovalent cyclic group that has one to ten carbon atoms, may further include, in addition to the carbon atoms, at least one heteroatom acting or serving as a ring-forming atom, and may have at least one double bond in the ring thereof. Examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group.

The term, “C₁-C₁₀ heterocycloalkenylene group,” as used herein refers to a divalent group having the same structure (e.g., substantially the same structure) as the C₁-C₁₀ heterocycloalkenyl group.

The term, “C₆-C₆₀ aryl group,” as used herein refers to a monovalent group having a carbocyclic aromatic system of 6 to 60 carbon atoms.

The term, “C₆-C₆₀ arylene group,” as used herein refers to a divalent group having a carbocyclic aromatic system of 6 to 60 carbon atoms.

Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group.

If (e.g., when) the C₆-C₆₀ aryl group and the C₆-C₆₀ arylene group each include two or more rings, the two or more rings may be condensed with each other.

The term, “C₁-C₆₀ heteroaryl group,” as used herein refers to a monovalent group having a heterocyclic aromatic system of 1 to 60 carbon atoms, further including, in addition to carbon atoms, at least one heteroatom, acting or serving as ring-forming atoms.

The term, “C₁-C₆₀ heteroarylene group,” as used herein refers to a divalent group having a heterocyclic aromatic system of 1 to 60 carbon atoms, further including, in addition to carbon atoms, at least one heteroatom, acting or serving as ring-forming atoms.

Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group.

If (e.g., when) the C₁-C₆₀ heteroaryl group and the C₁-C₆₀ heteroarylene group each include two or more rings, the two or more rings may be condensed with each other.

The term, “monovalent non-aromatic condensed polycyclic group,” as used herein refers to a monovalent group having two or more rings condensed with each other, only carbon atoms (for example, eight to sixty carbon atoms) acting or serving as ring-forming atoms, and no aromaticity in its molecular structure if (e.g., when) considered as a whole (e.g., is not aromatic if considered as a whole). Examples of the monovalent non-aromatic condensed polycyclic group may include an indenyl group, a fluorenyl group, a spiro-bifluorenyl group, a benzofluorenyl group, an indenophenanthrenyl group, and an indeno anthracenyl group.

The term, “divalent non-aromatic condensed polycyclic group,” as used herein refers to a divalent group having the same structure (e.g., substantially the same structure) as the monovalent non-aromatic condensed polycyclic group.

The term, “monovalent non-aromatic condensed heteropolycyclic group,” as used herein refers to a monovalent group that has two or more rings condensed with each other, and may further include, in addition to carbon atoms (for example, one to sixty carbon atoms), at least one heteroatom acting or serving as a ring-forming atom, and may have no aromaticity in its molecular structure if (e.g., when) considered as a whole (e.g., is not aromatic if considered as a whole). Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group.

The term, “divalent non-aromatic condensed heteropolycyclic group,” as used herein refers to a divalent group having the same structure (e.g., substantially the same structure) as the monovalent non-aromatic condensed heteropolycyclic group.

The term, “C6-C₆₀ aryloxy group,” as used herein may be —OA₁₀₂ (wherein A₁₀₂ may be the C₆-C₆₀ aryl group).

The term, “C6-C₆₀ arylthio group,” as used herein may be—SA₁₀₃ (wherein A₁₀₃ may be the C₆-C₆₀ aryl group).

The term, “C₇-C₆₀ arylalkyl group,” as used herein refers to -A₁₀₄A₁₀₅ (wherein A₁₀₄ may be a C₁-C₅₄ alkylene group, and A₁₀₅ may be a C₆-C₅₉ aryl group).

The term, “C₂-C₆₀ heteroarylalkyl group,” as used herein refers to -A₁₀₆A₁₀₇ (wherein A₁₀₆ may be a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃ and Q₃₁ to Q₃₃ used herein may each independently be: hydrogen; deuterium; —F; —Cl; —Br; —I; a hydroxyl group; a cyano group; a nitro group; C₁-C₆₀ alkyl group; C₂-C₆₀ alkenyl group; C₂-C₆₀ alkynyl group; C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term, “heteroatom,” as used herein refers to any atom other than a carbon atom. Examples of the heteroatom may include O, S, N, P, Si, B, Ge, Se, or any combination thereof.

The term, “third-row transition metal,” as used herein includes hafnium (Hf), tantalum (Ta), tungsten (W), rhenium (Re), osmium (Os), iridium (Ir), platinum (Pt), gold (Au), and/or the like.

The term, “D,” as used therein refers to deuterium, the term, “Ph,” refers to a phenyl group, the term, “Me,” refers to a methyl group, the term, “Et” refers to an ethyl group, the term, “tert-Bu,” “tBu,” or “But,” refers to a tert-butyl group, and the term, “Ome,” refers to a methoxy group.

The term, “biphenyl group,” as used herein refers to “a phenyl group that is substituted with a phenyl group.” In one or more embodiments, the “biphenyl group” may be a substituted phenyl group having a C₆-C₆₀ aryl group acting or serving as a substituent.

The term, “terphenyl group,” as used herein refers to “a phenyl group substituted with a biphenyl group.” The term, “terphenyl group,” as used herein may refer to i) a substituted phenyl group wherein the substituent is a C₆-C₆₀ aryl group substituted with a C₆-C₆₀ aryl group, and ii) a substituted phenyl group wherein two substituents are present, and each substituent is a C₆-C₆₀ aryl group.
* and *′ as used herein, unless defined otherwise, each refers to a binding site to a neighboring atom in a corresponding formula or moiety.

The terms, “x-axis,” “y-axis,” and “z-axis,” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, light-emitting devices according to one or more embodiments will be described in more detail with reference to the following synthesis examples and examples.

### Synthesis Example 1-1 (Synthesis of Compound A5)

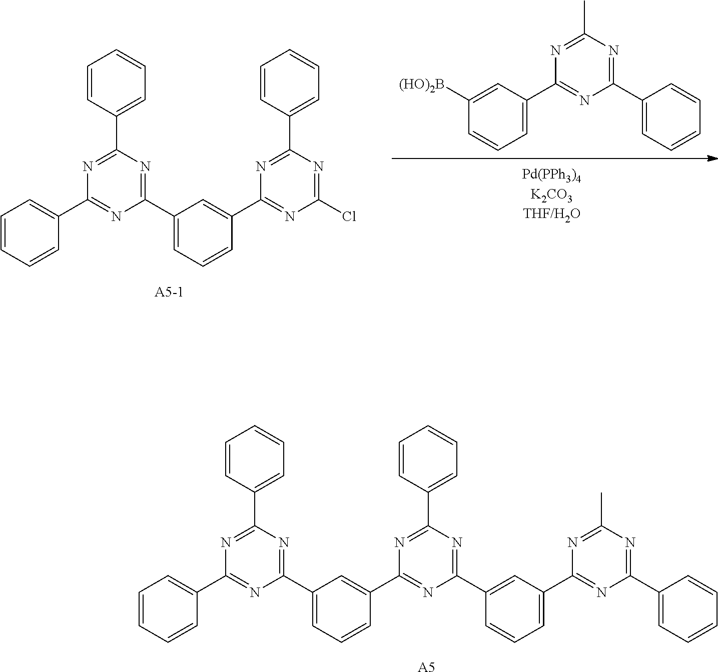 [SMILES: Clc1nc(-c2ccccc2)nc(-c2cccc(-c3nc(-c4ccccc4)nc(-c4ccccc4)n3)c2)n1 ; Cc1nc(-c2ccccc2)nc(-c2cccc(B(O)O)c2)n1 ; Cc1nc(-c2ccccc2)nc(-c2cccc(-c3nc(-c4ccccc4)nc(-c4cccc(-c5nc(-c6ccccc6)nc(-c6ccccc6)n5)c4)n3)c2)n1 ; "A5"]

### Synthesis of Compound A5

Intermediate A5-1 (4.99 g), tetrakis(triphenylphosphine)palladium(0) (Pd(PPh₃)₄) (0.56 g), potassium carbonate (K₂CO₃) (3.45 g), and (3-(4-methyl-6-phenyl-1,3,5-triazin-2-yl)phenyl)boronic acid (3.20 g) were dissolved in tetrahydrofuran/water (THF/H₂O) (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound A5 (4.97 g, yield: 70%).

### Synthesis Example 1-2 (Synthesis of Compound A34)

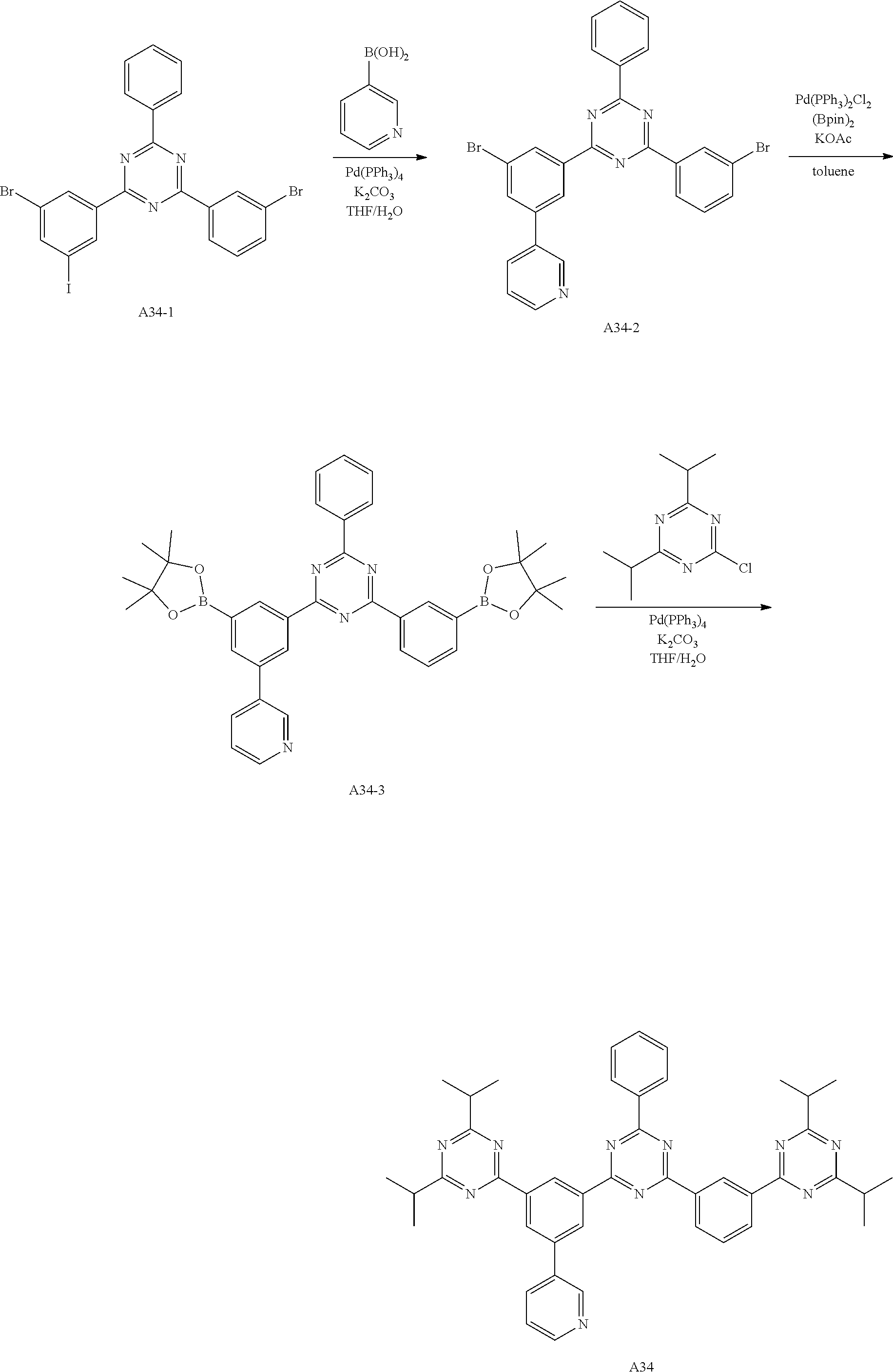

### Synthesis of Intermediate A34-2

Intermediate A34-1 (5.93 g), Pd(PPh₃)₄ (0.56 g), K₂CO₃ (3.45 g), and pyridin-3-ylboronic acid (2.67 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A34-2 (5.00 g, yield: 92%).

### Synthesis of Intermediate A34-3

Intermediate A34-2 (5.00 g), bis(triphenylphosphine)palladium(II) dichloride (Pd(PPh₃)₂Cl₂) (0.35 g), bis(pinacolato)diboron (5.06 g), and potassium acetate (KOAc) (4.9 g) were dissolved in toluene (60 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A34-3 (4.46 g, yield: 64%).

### Synthesis of Compound A34

Intermediate A34-3 (6.10 g), Pd(PPh₃)₄ (0.56 g), K₂CO₃ (3.45 g), and 2-chloro-4,6-diisopropyl-1,3,5-triazine (2.20 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound A34 (5.00 g, yield: 70%).

### Synthesis Example 1-3 (Synthesis of Compound A39)

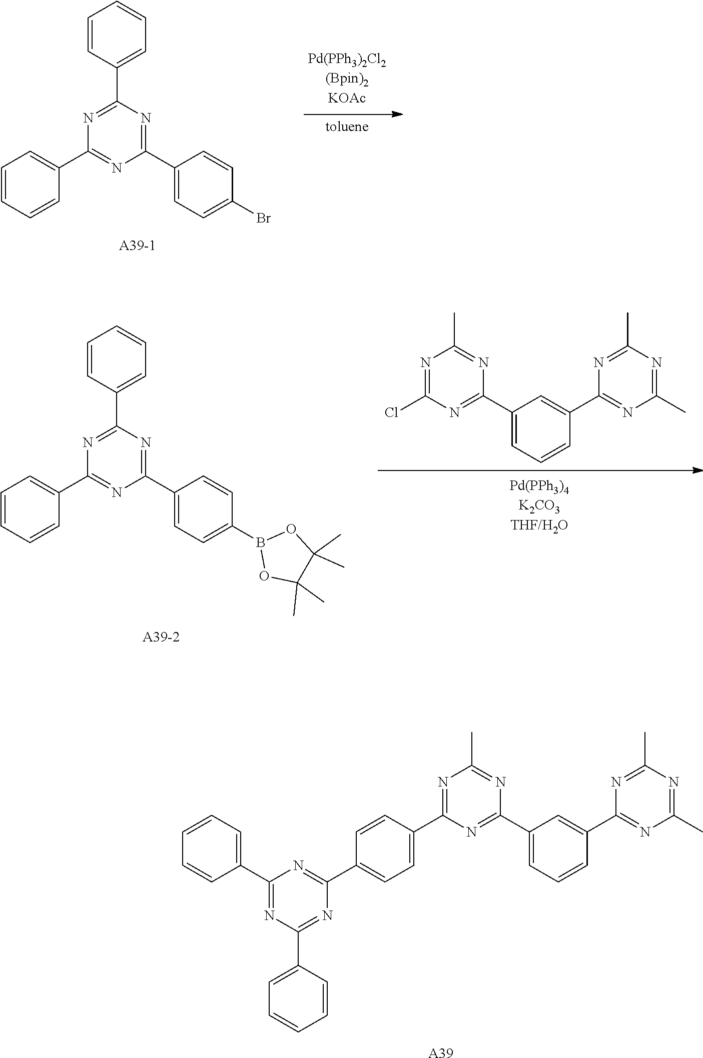

### Synthesis of Intermediate A39-2

Intermediate A39-1 (3.88 g), Pd(PPh₃)₂Cl₂ (0.35 g), bis(pinacolato)diboron (5.06 g), and KOAc (4.9 g) were dissolved in toluene (60 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A39-2 (3.48 g, yield: 80%).

### Synthesis of Compound A39

Intermediate A39-2 (4.35 g), Pd(PPh₃)₄ (0.56 g), K₂CO₃ (3.45 g), and 2-chloro-4-(3-(4,6-dimethyl-1,3,5-triazin-2-yl)phenyl)-6-methyl-1,3,5-triazine (3.440 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound A39 (5.00 g, yield: 70%).

### Synthesis Example 1-4 (Synthesis of Compound A53)

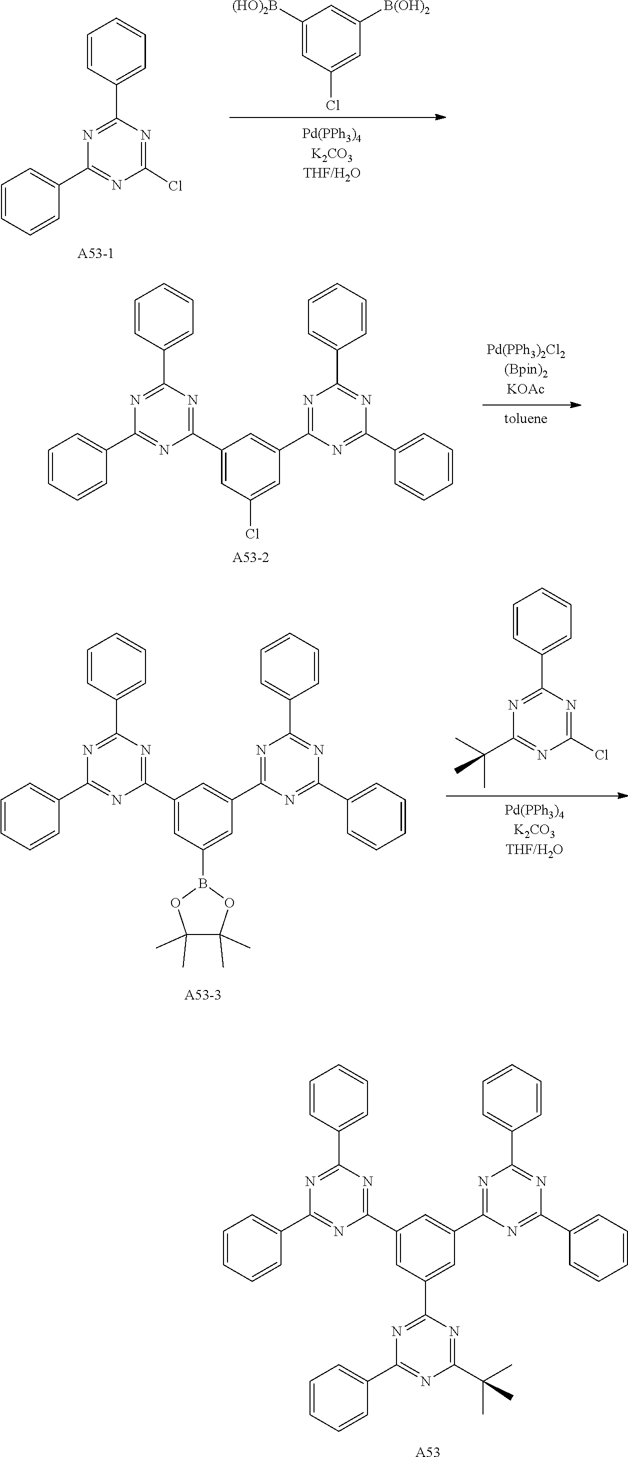

### Synthesis of Intermediate A53-2

Intermediate A53-1 (5.34 g), Pd(PPh₃)₄ (0.56 g), K₂CO₃ (3.45 g), and (5-chloro-1,3-phenylene)diboronic acid (2.00 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A53-2 (5.00 g, yield: 70%).

### Synthesis of Intermediate A53-3

Intermediate A53-2 (5.75 g), Pd(PPh₃)₂Cl₂ (0.35 g), bis(pinacolato)diboron (5.06 g), and KOAc (4.9 g) were dissolved in toluene (60 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A53-3 (4.88 g, yield: 80%).

### Synthesis of Compound A53

Intermediate A53-3 (6.66 g), Pd(PPh₃)₄ (0.56 g), K₂CO₃ (3.45 g), and 2-(tert-butyl)-4-chloro-6-phenyl-1,3,5-triazine (2.48 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound A53 (5.00 g, yield: 70%).

### Synthesis Example 1-5 (Synthesis of Compound A58)

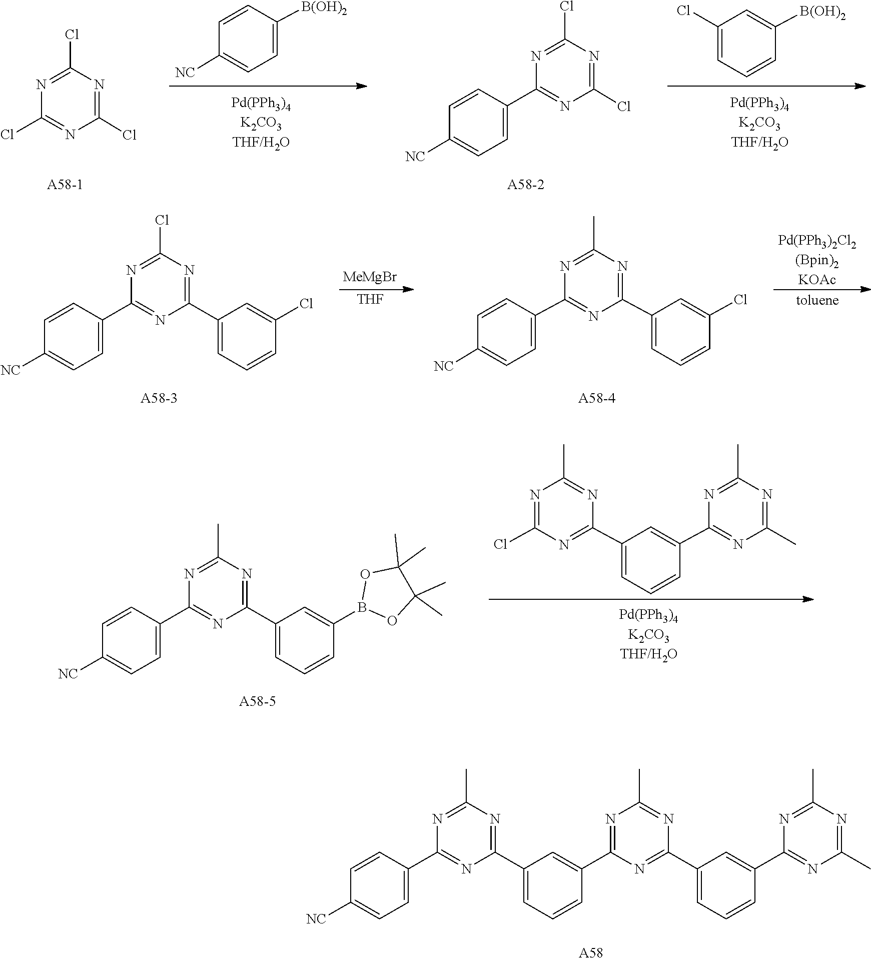

### Synthesis of Intermediate A58-2

Intermediate A58-1 (1.84 g), Pd(PPh₃)₄ (0.56 g), K₂CO₃ (3.45 g), and (4-cyanophenyl)boronic acid (1.47 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A58-2 (2.00 g, yield: 70%).

### Synthesis of Intermediate A58-3

Intermediate A58-2 (2.51 g), Pd(PPh₃)₄ (0.56 g), K₂CO₃ (3.45 g), and (3-chlorophenyl)boronic acid (1.56 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A58-3 (2.00 g, yield: 70%).

### Synthesis of Intermediate A58-4

Intermediate A58-3 (3.27 g) was dissolved in THE (100 mL) and then cooled down to 0° C. Methylmagnesiumbromide solution (2.5 M 8.0 mL) was slowly added dropwise to the reaction solution and then stirred at 0° C. for 12 hours. The reaction was terminated by using water and then an extraction process was performed thereon by using ethyl ether. An organic layer extracted therefrom was dried by using anhydrous magnesium sulfate and distilled under reduced pressure, and a residue thus obtained was separated and purified by column chromatography, thereby obtaining Intermediate A₅₈-4 (2.00 g, yield: 70%).

### Synthesis of Intermediate A58-5

Intermediate A58-4 (3.06 g), Pd(PPh₃)₂Cl₂ (0.35 g), bis(pinacolato)diboron (5.06 g), and KOAc (4.9 g) were dissolved in toluene (60 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate A58-5 (3.25 g, yield: 80%).

### Synthesis of Compound A58

Intermediate A58-5 (3.98 g), Pd(PPh₃)₄ (0.56 g), K₂CO₃ (3.45 g), and 2-chloro-4-(3-(4,6-dimethyl-1,3,5-triazin-2-yl)phenyl)-6-methyl-1,3,5-triazine (3.48 g) were dissolved in THF/H₂O (100 mL/25 mL) and then stirred at 80° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound A58 (5.00 g, yield: 70%).

### Synthesis Example 2-1 (Synthesis of Compound B1)

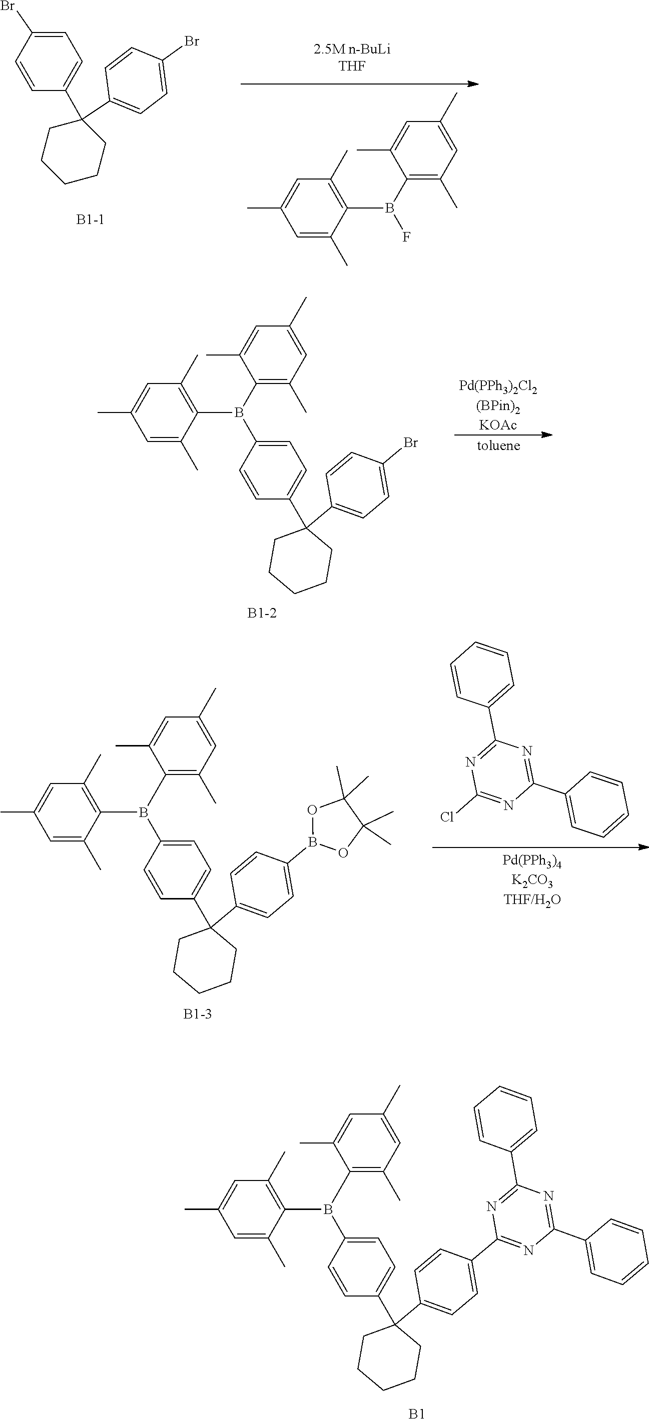

### Synthesis of Intermediate B1-2

After Intermediate B1-1 (3.94 g) was dissolved in 50 mL of tetrahydrofuran (THF) and then stirred at −78° C., 4 mL of n-butyllithium (n-BuLi) (2.5 M in hexane) was slowly added dropwise thereto. A solution obtained by dissolving fluorodimesitylborane (2.68 g) in THF (50 mL) was slowly added dropwise thereto at −78° C. The resultant solution was stirred at room temperature for 12 hours. The reaction was terminated by using water, and an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B1-2 (3.04 g, yield: 54%).

### Synthesis of Intermediate B1-3

Intermediate B1-2 (5.63 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B1-3 (3.90 g, yield: 64%).

### Synthesis of Compound B1

Intermediate B1-3 (6.10 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound B1 (5.00 g, yield: 70%).

### Synthesis Example 2-2 (Synthesis of Compound B20)

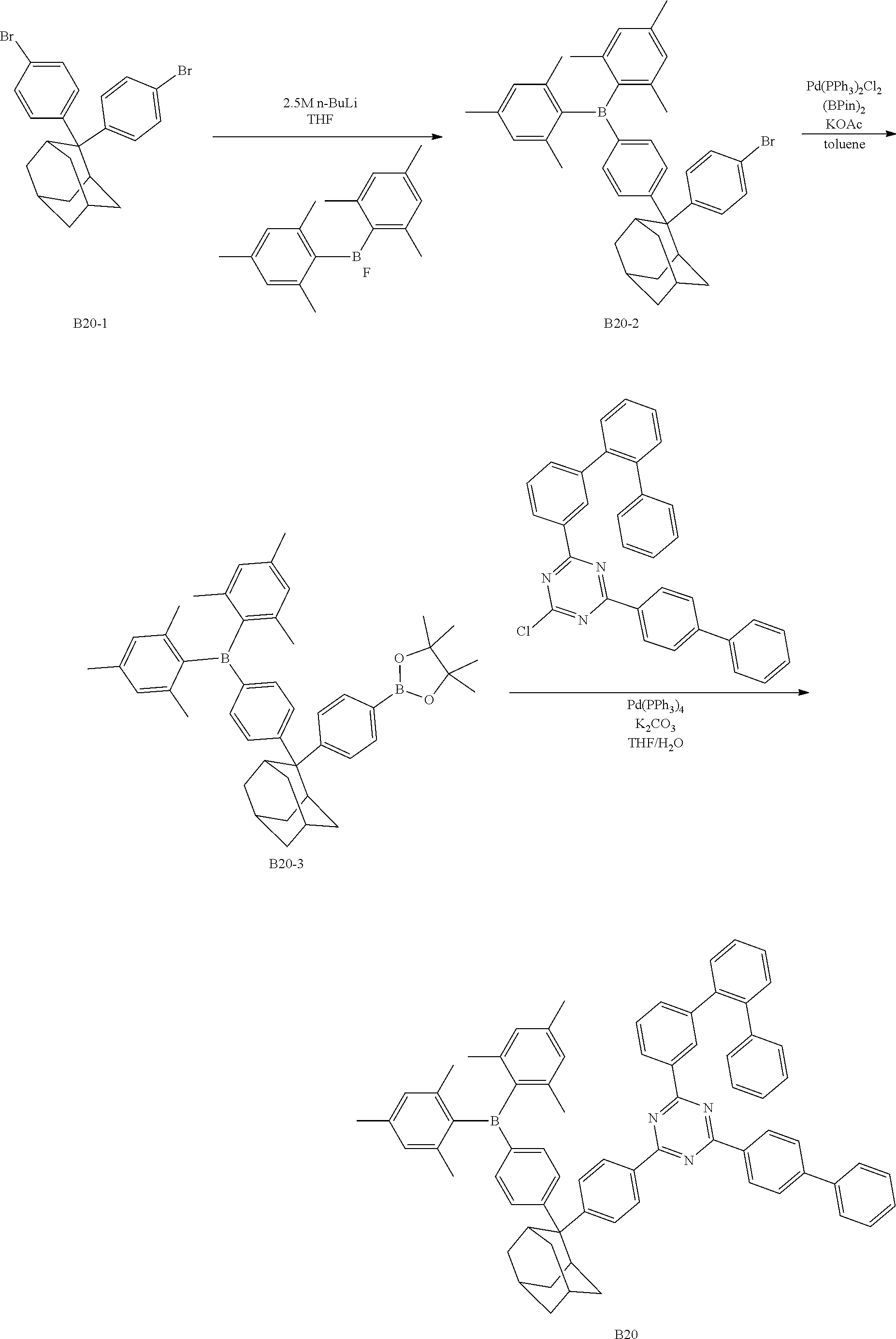

### Synthesis of Intermediate B20-2

After Intermediate B20-1 (4.46 g) was dissolved in 50 mL of tetrahydrofuran (THF) and then stirred at −78° C., 4 mL of n-BuLi (2.5 M in hexane) was slowly added dropwise thereto. A solution obtained by dissolving fluorodimesitylborane (2.68 g) in THF(50 mL) was slowly added dropwise thereto at −78° C. The resultant solution was stirred at room temperature for 12 hours. The reaction was terminated by using water, and an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B20-2 (3.44 g, yield: 56%).

### Synthesis of Intermediate B20-3

Intermediate B20-2 (6.15 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B20-3 (4.10 g, yield: 62%).

### Synthesis of Compound B20

Intermediate B20-3 (6.10 g), Pd(PPh₃)₄ (0.56 g), K₂CO₃ (3.45 g), and 2-([1,1′-biphenyl]-4-yl)-4-([1,1′:2′,1″-terphenyl]-3-yl)-6-chloro-1,3,5-triazine (4.96 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound B20 (6.57 g, yield: 66%).

### Synthesis Example 2-3 (Synthesis of Compound B32)

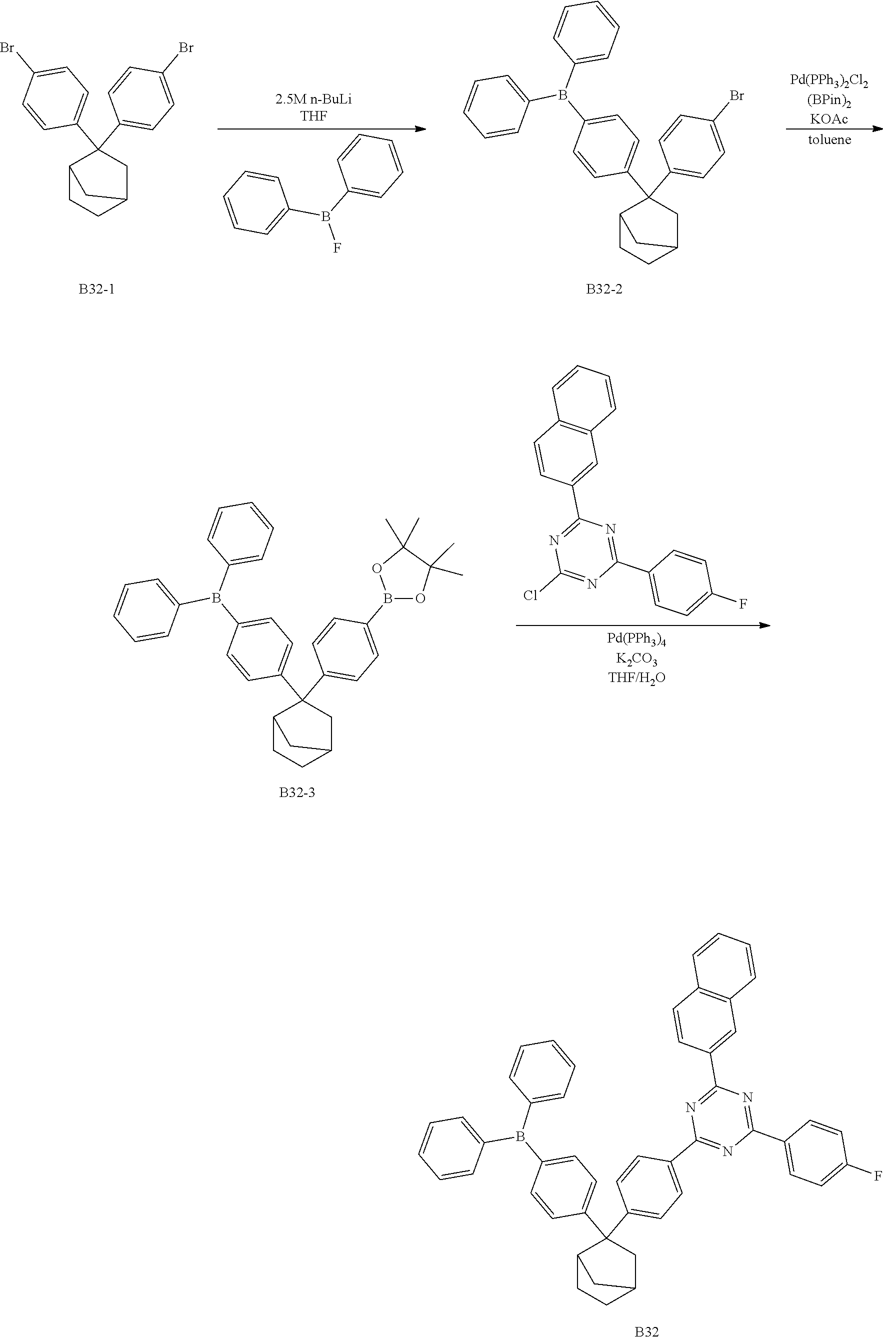

### Synthesis of Intermediate B32-2

After Intermediate B32-1 (4.01 g) was dissolved in 50 mL of THE and then stirred at −78° C., 4 mL of n-BuLi (2.5 M in hexane) was slowly added dropwise thereto. A solution obtained by dissolving fluorodiphenylborane (1.84 g) in THF(50 mL) was slowly added dropwise thereto at −78° C. The resultant solution was stirred at room temperature for 12 hours. The reaction was terminated by using water, and an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B32-2 (2.95 g, yield: 58%).

### Synthesis of Intermediate B32-3

Intermediate B32-2 (4.93 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B32-3 (3.29 g, yield: 61%).

### Synthesis of Compound B32

Intermediate B32-3 (5.40 g), Pd(PPh₃)₄ (0.56 g), K₂CO₃ (3.45 g), and 2-chloro-4-(4-fluorophenyl)-6-(naphthalen-2-yl)-1,3,5-triazine (4.00 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound B32 (5.12 g, yield: 72%).

### Synthesis Example 2-4 (Synthesis of Compound B42)

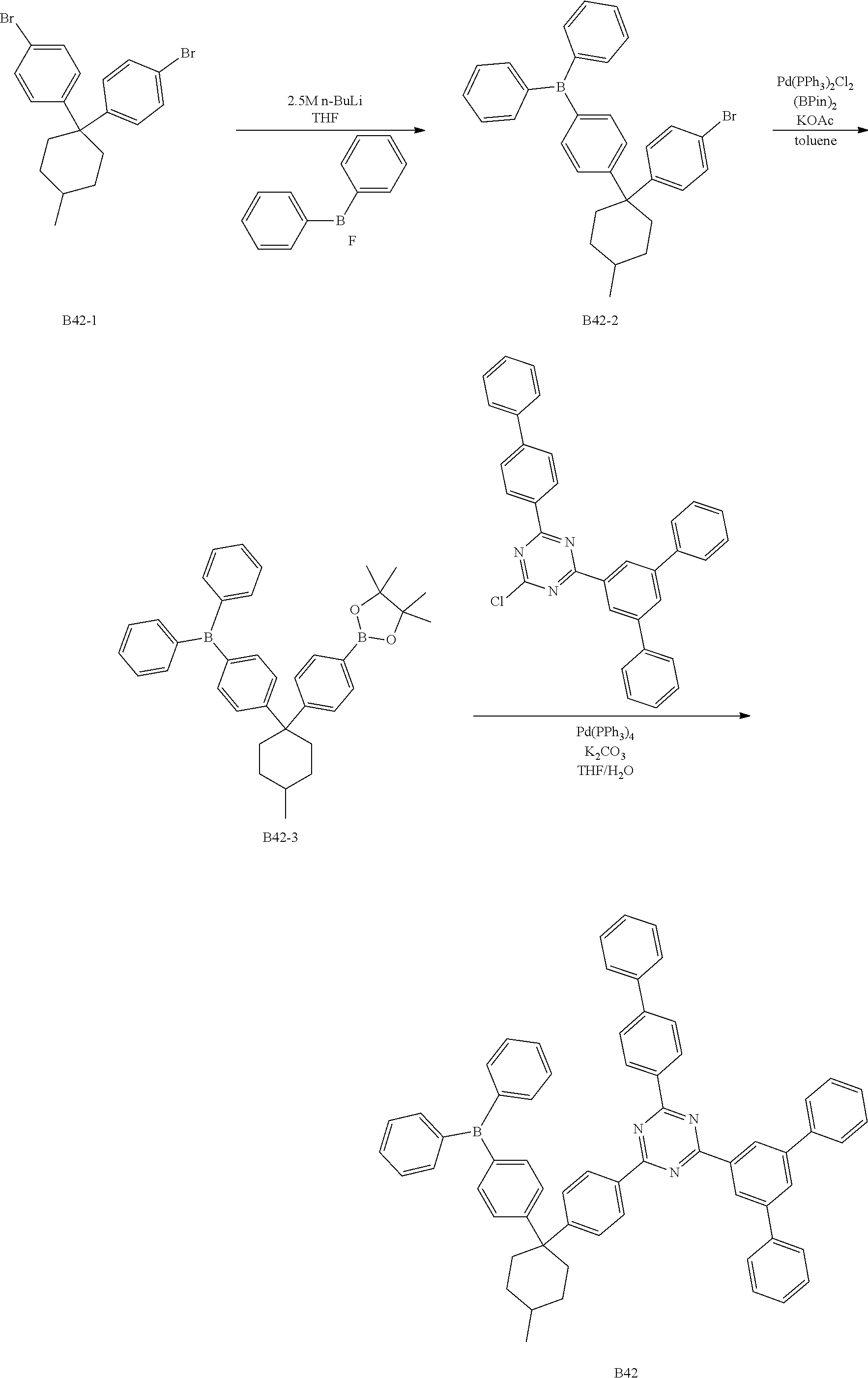

### Synthesis of Intermediate B42-2

After Intermediate B42-1 (4.08 g) was dissolved in 50 mL of THE and then stirred at −78° C., 4 mL of n-BuLi (2.5 M in hexane) was slowly added dropwise thereto. A solution obtained by dissolving fluorodiphenylborane (1.84 g) in THF(50 mL) was slowly added dropwise thereto at −78° C. The resultant solution was stirred at room temperature for 12 hours. The reaction was terminated by using water, and an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B42-2 (2.95 g, yield: 60%).

### Synthesis of Intermediate B42-3

Intermediate B42-2 (4.93 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B42-3 (3.29 g, yield: 61%).

### Synthesis of Compound B42

Intermediate B42-3 (5.40 g), Pd(PPh₃)₄ (0.56 g), K₂CO₃ (3.45 g), and 2-([1,1′-biphenyl]-4-yl)-4-([1,1′: 3′,1″-terphenyl]-5′-yl)-6-chloro-1,3,5-triazine (4.96 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound B42 (4.97 g, yield: 57%).

### Synthesis Example 2-5 (Synthesis of Compound B51)

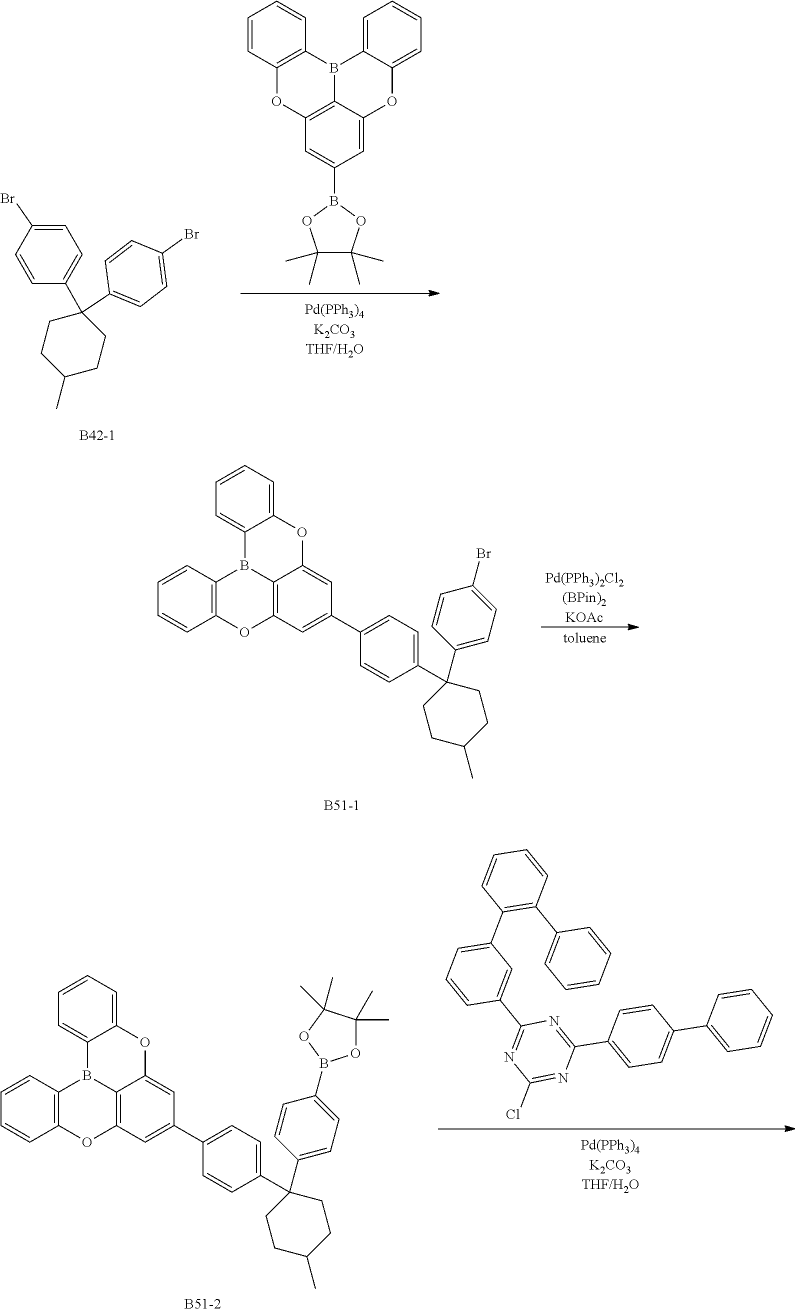

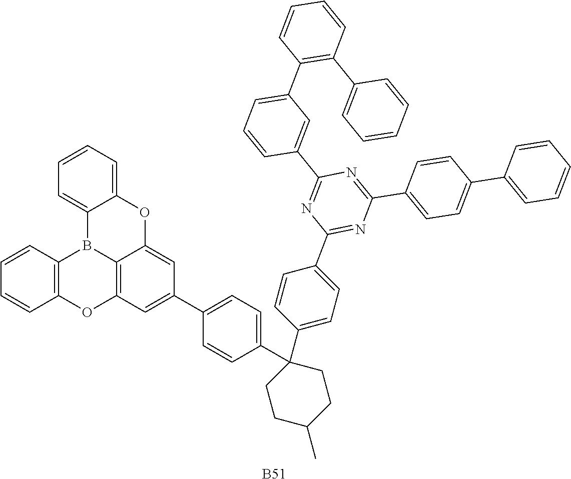

### Synthesis of Intermediate B51-1

After Intermediate B42-1 (4.08 g) was dissolved in 50 mL of THE and then stirred at −78° C., 4 mL of n-BuLi (2.5 M in hexane) was slowly added dropwise thereto. A solution obtained by dissolving 7-(4,4,5,5-tetramethyl-1,3,2-dioxaborolan-2-yl)-5,9-dioxa-13b-boranaphtho[3,2,1-de]anthracene (3.96 g) in THE (50 mL) was slowly added dropwise thereto at −78° C. The resultant solution was stirred at room temperature for 12 hours. The reaction was terminated by using water, and an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B51-1 (4.17 g, yield: 70%).

### Synthesis of Intermediate B51-2

Intermediate B51-1 (5.97 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B51-2 (4.05 g, yield: 63%).

### Synthesis of Compound B51

Intermediate B51-2 (6.44 g), Pd(PPh₃)₄ (0.56 g), K₂CO₃ (3.45 g), and 2-([1,1′-biphenyl]-4-yl)-4-([1,1′:2′,1″-terphenyl]-3-yl)-6-chloro-1,3,5-triazine (3.43 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound B51 (6.45 g, yield: 66%).

### Synthesis Example 2-6 (Synthesis of Compound B61)

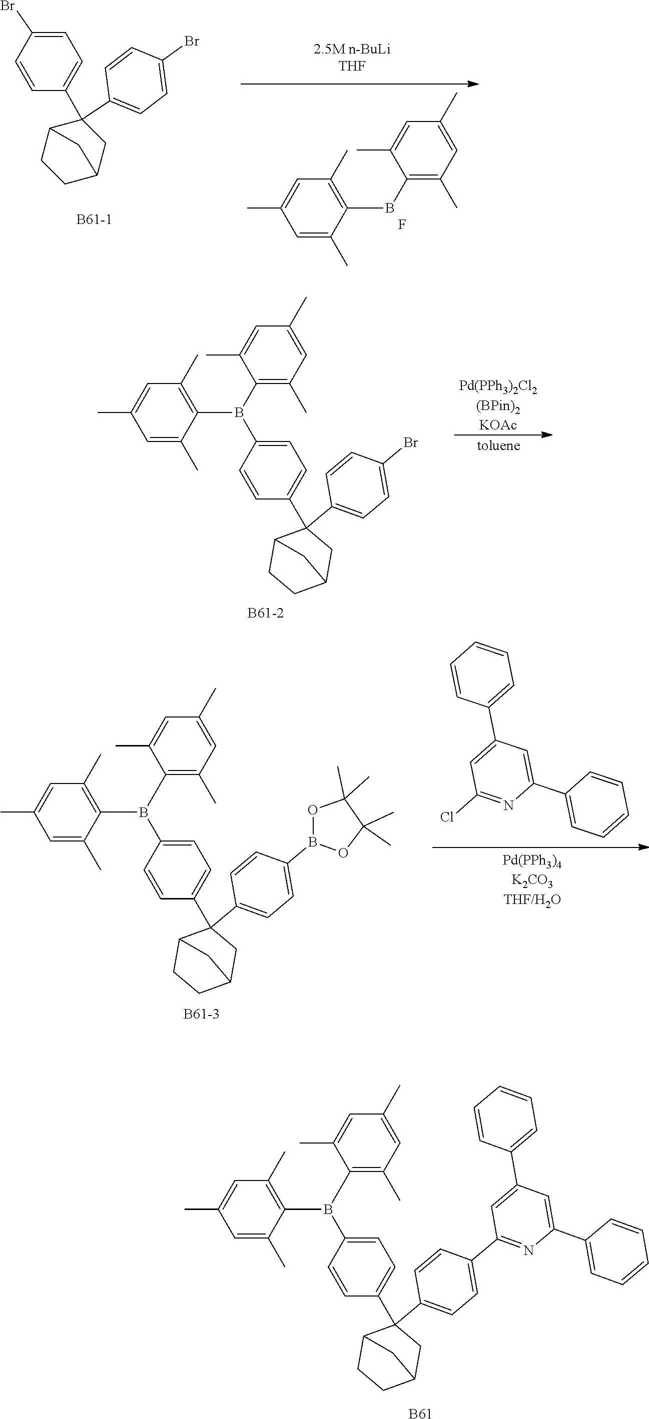

### Synthesis of Intermediate B61-2

After Intermediate B61-1 (4.06 g) was dissolved in 50 mL of THE and then stirred at −78° C., 4 mL of n-BuLi (2.5 M in hexane) was slowly added dropwise thereto. A solution obtained by dissolving fluorodimesitylborane (2.68 g) in THF(50 mL) was slowly added dropwise thereto at −78° C. The resultant solution was stirred at room temperature for 12 hours. The reaction was terminated by using water, and an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B61-2 (3.85 g, yield: 67%).

### Synthesis of Intermediate B61-3

Intermediate B61-2 (5.65 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Intermediate B61-3 (4.29 g, yield: 69%).

### Synthesis of Compound B61

Intermediate B61-3 (6.22 g), Pd(PPh₃)₄ (0.56 g), K₂CO₃ (3.45 g), and 2-chloro-4,6-diphenylpyridine (2.65 g) were dissolved in THF/H₂O (100 mL/25 mL) and then stirred at 60° C. for 12 hours. The reaction temperature was lowered to room temperature, and the reaction was terminated by using water. Then, an extraction process was performed thereon three times by using ethyl ether. An organic layer extracted therefrom was dried by using anhydrous magnesium sulfate and distilled under reduced pressure, and a residue thus obtained was separated and purified by column chromatography, thereby obtaining Compound B61 (4.35 g, yield: 60%). Synthesis methods of compounds other than the compounds synthesized in Synthesis Examples may be easily recognized by those skilled in the art by referring to the synthesis paths and source materials.

### COMPARATIVE EXAMPLE 1

As an anode, a glass substrate (product of Corning Inc.) that has a 15 Ω/cm² (1,200 Å) ITO electrode formed or provided thereon was cut to a size of 50 mm×50 mm×0.7 mm, sonicated by using isopropyl alcohol and pure water each for 5 minutes, cleaned by irradiation of ultraviolet rays and exposure of ozone thereto for 30 minutes, and then mounted on a vacuum deposition apparatus.

NPD was deposited on the anode to form or provide a hole injection layer having a thickness of 300 Å. HT3 was deposited on the hole injection layer to form or provide a hole transport layer having a thickness of a 200 Å. CzSi was deposited on the hole transport layer to form or provide an emission auxiliary layer having a thickness of 100 Å.

On the emission auxiliary layer, HTH49 acting or serving as a hole-transporting host, ETH2 as an electron-transporting host, PS-3 acting or serving as a phosphorescent sensitizer, and DFD31 acting or serving as a dopant were co-deposited at a weight ratio of 42:42:15:1 to form or provide an emission layer having a thickness of 200 Å.

TSPO1 was deposited on the emission layer to form or provide a hole-blocking layer having a thickness of 200 Å. TPBI was deposited on the hole-blocking layer to form or provide an electron transport layer having a thickness of 300 Å. LiF was deposited on the electron transport layer to form or provide an electron injection layer having a thickness of 10 Å, and Al was deposited on the electron injection layer to form or provide a cathode having a thickness of 3,000 Å, thereby manufacturing a light-emitting device.

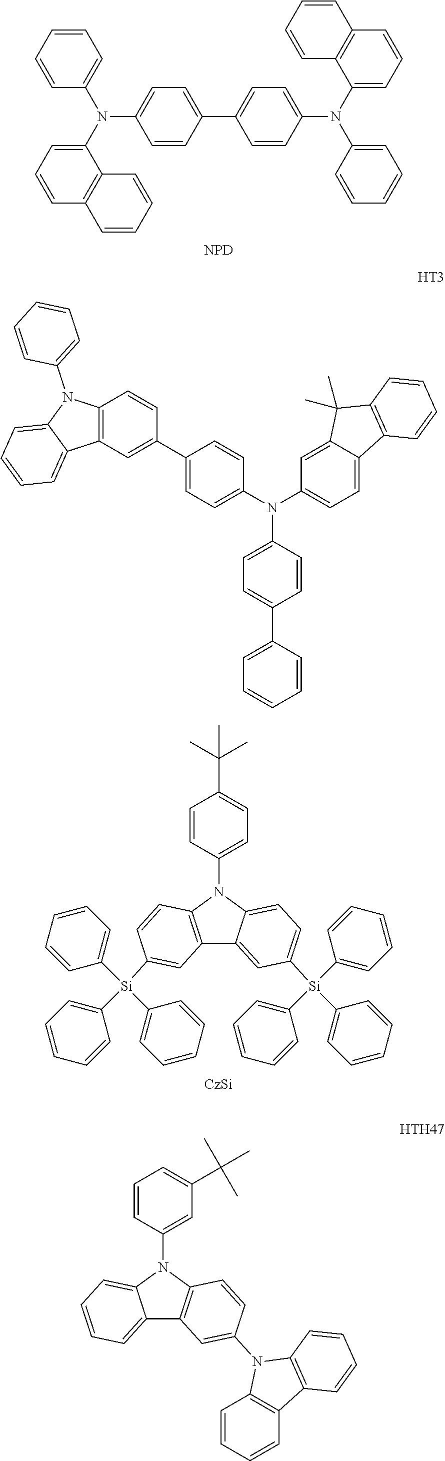

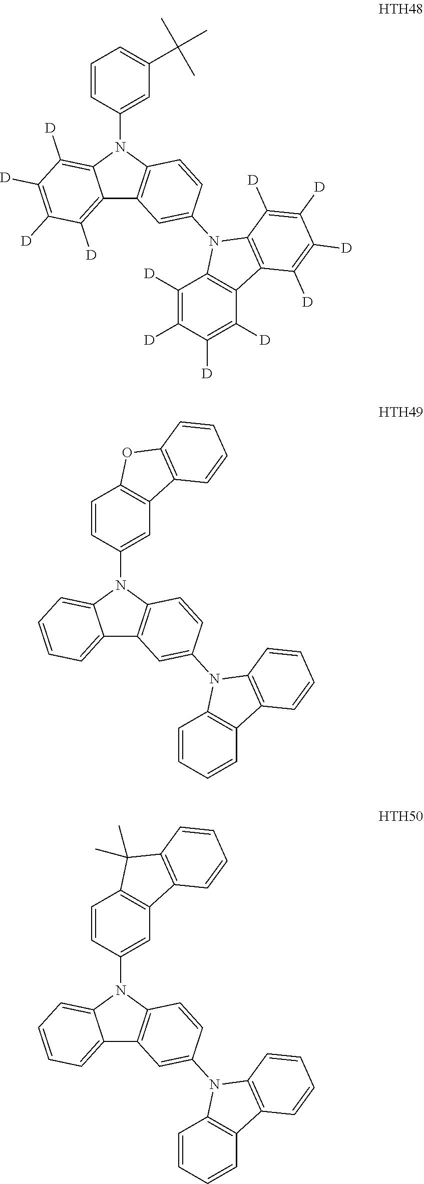 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21]

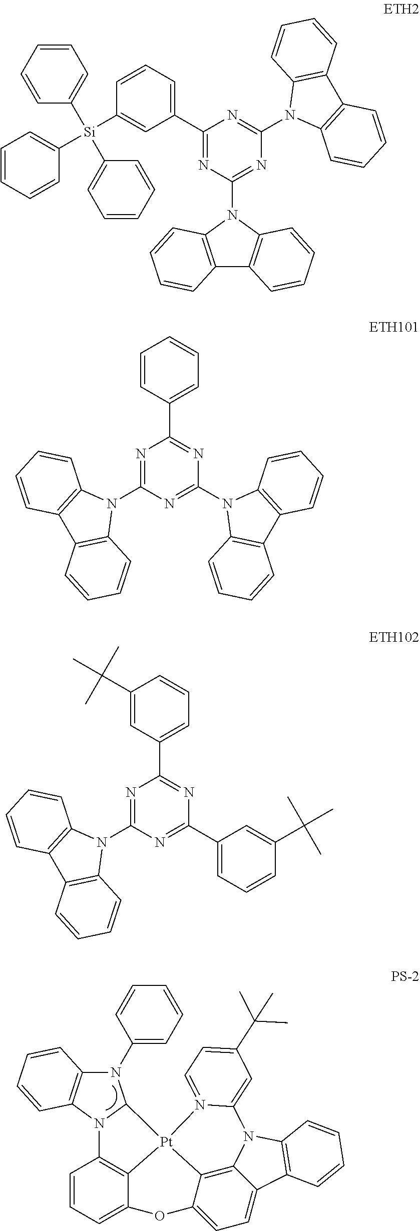

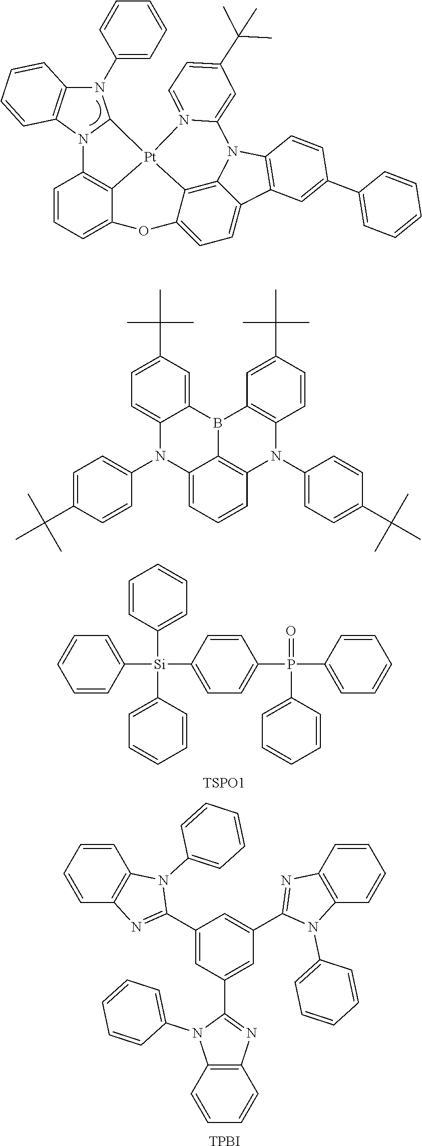

### Comparative Examples 2 to 24

Light-emitting devices were manufactured in the same manner (e.g., substantially the same manner) as in Comparative Example 1, except that compounds shown in Table 1 were each used instead of TPBI in forming or providing an electron transport layer.

### Examples 1 to 11

Light-emitting devices were manufactured in the same manner (e.g., substantially the same manner) as in Comparative Example 1, except that two compounds shown in Table 2 were used at a weight ratio of 5:5 instead of TPBI in forming or providing an electron transport layer.

### Examples 12 to 14

Light-emitting devices were manufactured in the same manner (e.g., substantially the same manner) as in Comparative Example 1, except that two compounds shown in Table 2 were used at a ratio of 5:5 instead of TPBI, and a hole-transporting host, an electron-transporting host, and a phosphorescent sensitizer shown in Table 2 were used in forming or providing an emission layer.

### Evaluation Example 1

For each of the light-emitting device of Comparative Examples 1 to 24 and Examples 1 to 14, the driving voltage (V) at 1000 cd/m², luminescence efficiency (cd/A), and lifespan (T₉₅) were measured by using Keithley MU 236 and a luminance meter PR650. The lifespan (T₉₅) may be a measure of the time (hr) taken until the luminance declines to 95% of the initial luminance. The measured lifespans were shown in Tables 1 and 2 as lifespan ratios which are relative values compared to the values of Comparative Example 1.

TABLE 1

| | | | Electron | Driving | Luminescence | Lifespan |
|---|---|---|---|---|---|---|
| | Exciplex | | transport | voltage | efficiency | ratio |
| | Host | Sensitizer | layer | (V) | (cd/A) | (T₉₅) |
| Comparative | HTH49/ | PS-3 | TPBI | 5.6 | 18.8 | 1 |
| Example 1 | ETH2 | | | | | |
| Comparative | HTH49/ | PS-3 | CA1 | 4.35 | 19.2 | 3.55 |
| Example 2 | ETH2 | | | | | |
| Comparative | HTH49/ | PS-3 | CA2 | 4.16 | 21.5 | 3.07 |
| Example 3 | ETH2 | | | | | |
| Comparative | HTH49/ | PS-3 | CA3 | 4.27 | 19.6 | 2.96 |
| Example 4 | ETH2 | | | | | |
| Comparative | HTH49/ | PS-3 | CA4 | 4.34 | 22.2 | 3.52 |
| Example 5 | ETH2 | | | | | |
| Comparative | HTH49/ | PS-3 | CB1 | 4.13 | 23.7 | 4.65 |
| Example 6 | ETH2 | | | | | |
| Comparative | HTH49/ | PS-3 | A5 | 4.05 | 23.1 | 4.55 |
| Example 7 | ETH2 | | | | | |
| Comparative | HTH49/ | PS-3 | A7 | 3.95 | 24.1 | 4.6 |
| Example 8 | ETH2 | | | | | |
| Comparative | HTH49/ | PS-3 | A11 | 4.03 | 23.3 | 4.67 |
| Example 9 | ETH2 | | | | | |
| Comparative | HTH49/ | PS-3 | A34 | 3.95 | 23 | 4.32 |
| Example 10 | ETH2 | | | | | |
| Comparative | HTH49/ | PS-3 | A37 | 4.11 | 23.2 | 4.27 |
| Example 11 | ETH2 | | | | | |
| Comparative | HTH49/ | PS-3 | A39 | 4.01 | 23.8 | 4.5 |
| Example 12 | ETH2 | | | | | |
| Comparative | HTH49/ | PS-3 | A41 | 4.25 | 20.1 | 4.07 |
| Example 13 | ETH2 | | | | | |
| Comparative | HTH49/ | PS-3 | A53 | 4.05 | 19.7 | 3.98 |
| Example 14 | ETH2 | | | | | |
| Comparative | HTH49/ | PS-3 | A58 | 3.98 | 23 | 4.33 |
| Example 15 | ETH2 | | | | | |
| Comparative | HTH49/ | PS-3 | B1 | 4.47 | 23.5 | 4.92 |
| Example 16 | ETH2 | | | | | |
| Comparative | HTH49/ | PS-3 | B4 | 4.71 | 25.2 | 5.23 |
| Example 17 | ETH2 | | | | | |
| Comparative | HTH49/ | PS-3 | B20 | 4.4 | 24.7 | 5.23 |
| Example 18 | ETH2 | | | | | |
| Comparative | HTH49/ | PS-3 | B25 | 4.62 | 26 | 5.67 |
| Example 19 | ETH2 | | | | | |
| Comparative | HTH49/ | PS-3 | B32 | 4.43 | 23.4 | 4.72 |
| Example 20 | ETH2 | | | | | |
| Comparative | HTH49/ | PS-3 | B42 | 4.34 | 25.7 | 5.7 |
| Example 21 | ETH2 | | | | | |
| Comparative | HTH49/ | PS-3 | B44 | 4.47 | 25 | 5.5 |
| Example 22 | ETH2 | | | | | |
| Comparative | HTH49/ | PS-3 | B51 | 4.86 | 22.7 | 5.48 |
| Example 23 | ETH2 | | | | | |
| Comparative | HTH49/ | PS-3 | B61 | 4.6 | 23 | 5.32 |
| Example 24 | ETH2 | | | | | |

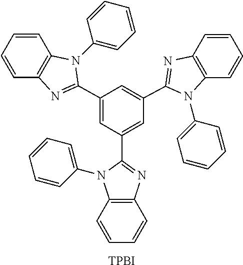

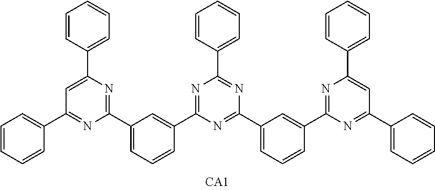 [SMILES: c1ccc(-c2cc(-c3ccccc3)nc(-c3cccc(-c4nc(-c5ccccc5)nc(-c5cccc(-c6nc(-c7ccccc7)cc(-c7ccccc7)n6)c5)n4)c3)n2)cc1]

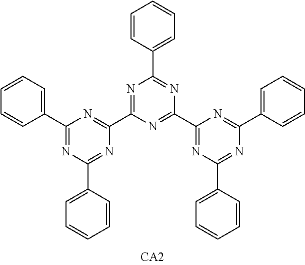 [SMILES: c1ccc(-c2nc(-c3ccccc3)nc(-c3nc(-c4ccccc4)nc(-c4nc(-c5ccccc5)nc(-c5ccccc5)n4)n3)n2)cc1]

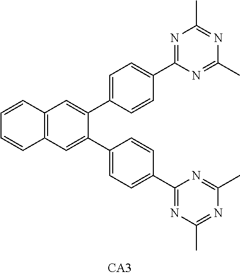 [SMILES: Cc1nc(C)nc(-c2ccc(-c3cc4ccccc4cc3-c3ccc(-c4nc(C)nc(C)n4)cc3)cc2)n1]

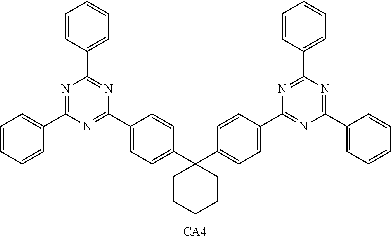 [SMILES: c1ccc(-c2nc(-c3ccccc3)nc(-c3ccc(C4(c5ccc(-c6nc(-c7ccccc7)nc(-c7ccccc7)n6)cc5)CCCCC4)cc3)n2)cc1]

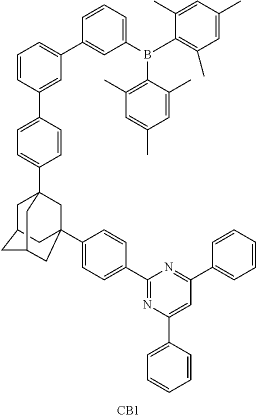 [SMILES: Cc1cc(C)c(B(c2cccc(-c3cccc(-c4ccc(C56CC7CC(C5)CC(c5ccc(-c8nc(-c9ccccc9)cc(-c9ccccc9)n8)cc5)(C7)C6)cc4)c3)c2)c2c(C)cc(C)cc2C)c(C)c1 ; "CB1"]

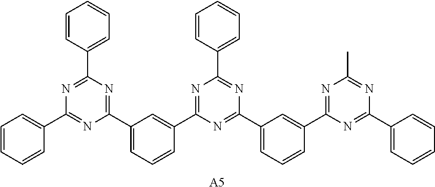 [SMILES: Cc1nc(-c2ccccc2)nc(-c2cccc(-c3nc(-c4ccccc4)nc(-c4cccc(-c5nc(-c6ccccc6)nc(-c6ccccc6)n5)c4)n3)c2)n1 ; "A5"]

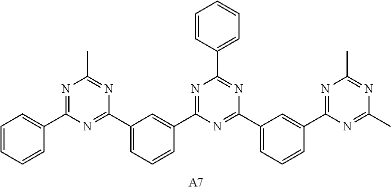 [SMILES: Cc1nc(C)nc(-c2cccc(-c3nc(-c4ccccc4)nc(-c4cccc(-c5nc(C)nc(-c6ccccc6)n5)c4)n3)c2)n1 ; "A7"]

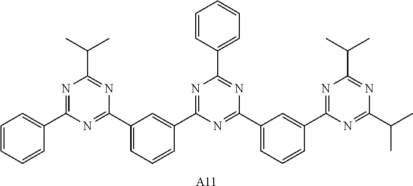 [SMILES: CC(C)c1nc(-c2ccccc2)nc(-c2cccc(-c3nc(-c4ccccc4)nc(-c4cccc(-c5nc(C(C)C)nc(C(C)C)n5)c4)n3)c2)n1 ; "A11"]

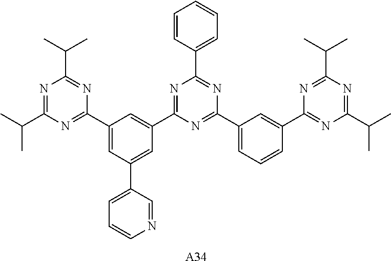 [SMILES: CC(C)c1nc(-c2cccc(-c3nc(-c4ccccc4)nc(-c4cc(-c5cccnc5)cc(-c5nc(C(C)C)nc(C(C)C)n5)c4)n3)c2)nc(C(C)C)n1 ; "A34"]

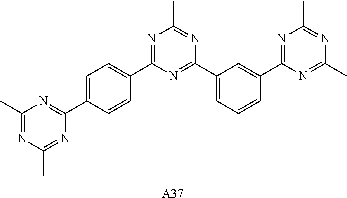

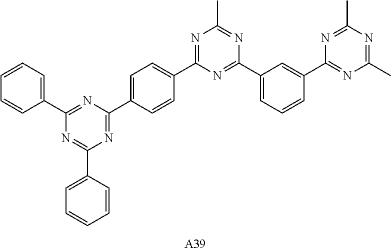 [SMILES: Cc1nc(C)nc(-c2cccc(-c3nc(C)nc(-c4ccc(-c5nc(-c6ccccc6)nc(-c6ccccc6)n5)cc4)n3)c2)n1 ; "A39"]

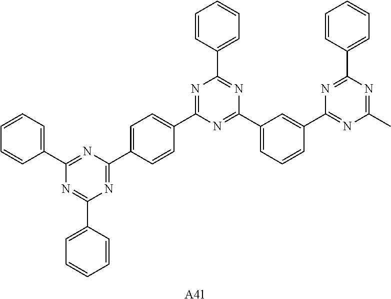 [SMILES: Cc1nc(-c2ccccc2)nc(-c2cccc(-c3nc(-c4ccccc4)nc(-c4ccc(-c5nc(-c6ccccc6)nc(-c6ccccc6)n5)cc4)n3)c2)n1 ; "A41"]

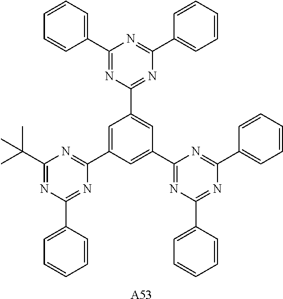 [SMILES: CC(C)(C)c1nc(-c2ccccc2)nc(-c2cc(-c3nc(-c4ccccc4)nc(-c4ccccc4)n3)cc(-c3nc(-c4ccccc4)nc(-c4ccccc4)n3)c2)n1 ; "A53"]

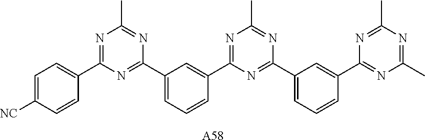

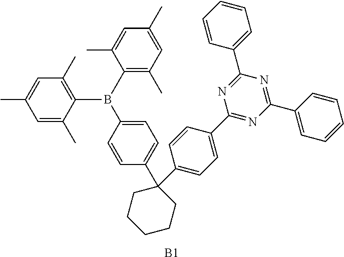

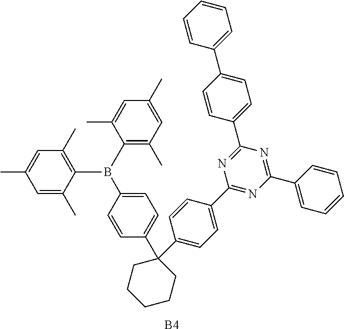

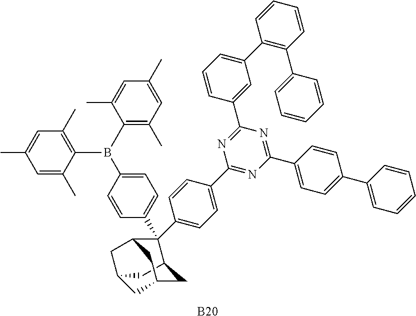

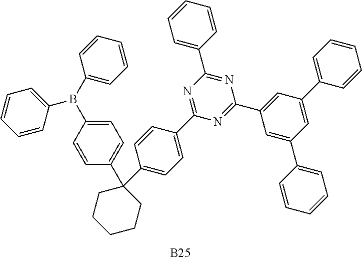

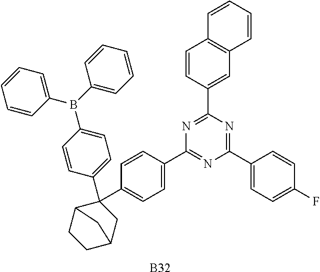 [SMILES: Fc1ccc(-c2nc(-c3ccc(C4(c5ccc(B(c6ccccc6)c6ccccc6)cc5)CC5CCC4C5)cc3)nc(-c3ccc4ccccc4c3)n2)cc1 ; "B32"]

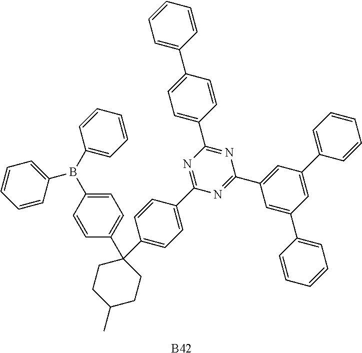

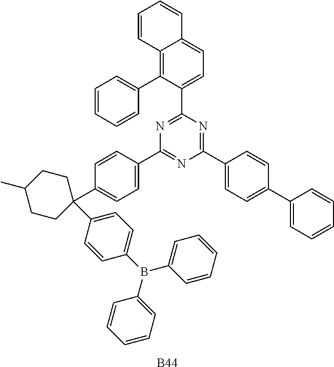

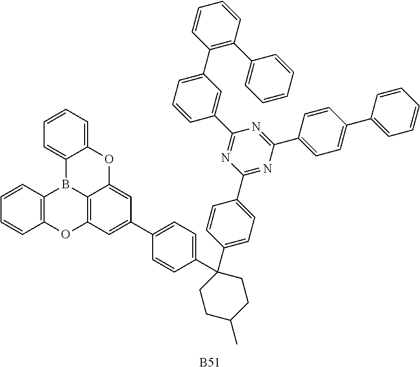

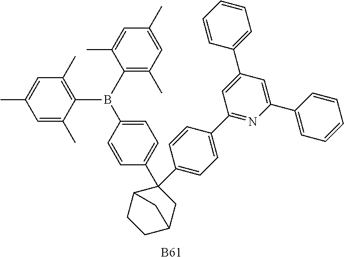

TABLE 2

| | | | | | Lumi- | Life- |
|---|---|---|---|---|---|---|
| | | | Electron | Driving | nescence | span |
| | Exciplex | Sensi- | transport | voltage | efficiency | ratio |
| | host | tizer | layer | (V) | (cd/A) | (T₉₅) |
| Example | HTH49/ | PS-3 | A5/ | 4.1 | 25.3 | 5.5 |
| 1 | ETH2 | | B42 | | | |
| Example | HTH49/ | PS-3 | A7/ | 3.99 | 24.9 | 5.2 |
| 2 | ETH2 | | B32 | | | |
| Example | HTH49/ | PS-3 | A7/ | 4.05 | 25.5 | 5.7 |
| 3 | ETH2 | | B42 | | | |
| Example | HTH49/ | PS-3 | A11/ | 4.14 | 24.2 | 4.8 |
| 4 | ETH2 | | B1 | | | |
| Example | HTH49/ | PS-3 | A34/ | 4.07 | 24.7 | 5.1 |
| 5 | ETH2 | | B4 | | | |
| Example | HTH49/ | PS-3 | A37/ | 4.21 | 25.2 | 5.4 |
| 6 | ETH2 | | B25 | | | |
| Example | HTH49/ | PS-3 | A39/ | 4.17 | 25.7 | 5.5 |
| 7 | ETH2 | | B42 | | | |
| Example | HTH49/ | PS-3 | A53/ | 4.15 | 24.8 | 5.2 |
| 8 | ETH2 | | B4 | | | |
| Example | HTH49/ | PS-3 | A34/ | 4.09 | 24.5 | 5.1 |
| 9 | ETH2 | | B20 | | | |
| Example | HTH49/ | PS-3 | A7/ | 4.22 | 24.1 | 5.4 |
| 10 | ETH2 | | B51 | | | |
| Example | HTH49/ | PS-3 | A39/ | 4 | 25.2 | 5.4 |
| 11 | ETH2 | | B61 | | | |
| Example | HTH48/ | PS-2 | A41/ | 4.11 | 24.8 | 5.2 |
| 12 | ETH102 | | B44 | | | |
| Example | HTH48/ | PS-2 | A58/ | 4.1 | 25.3 | 5.4 |
| 13 | ETH102 | | B42 | | | |
| Example | HTH48/ | PS-2 | A58/ | 4.09 | 25 | 5.3 |
| 14 | ETH102 | | B44 | | | |

From Tables 1 and 2, it is confirmed that the light-emitting devices according to Examples 1 to 14, which employed both (e.g., simultaneously) the first compound and the second compound, had better driving voltage, luminescence efficiency, and lifespan than the light-emitting devices according to Comparative Examples 1 to 6, which employed compounds that did not fall within the scopes of Formulae 1 and 2. In one or more embodiments, at least one selected from among the driving voltage, luminescence efficiency, and lifespan of the light-emitting devices according to Examples 1 to 14 was better than that of the light-emitting devices according to Comparative Examples 7 to 24, which employed one selected from the first compound and the second compound, and the other characteristics of the light-emitting devices of Examples 1 to 14 were similar to those of the light-emitting devices of Comparative Examples to 7 to 24.

As such, a light-emitting device which includes both (e.g., simultaneously) of the first compound and the second compound may have improved driving voltage and/or luminescence efficiency (e.g., suitable driving voltage and/or luminescence efficiency) by including the first compound, and may have a longer lifespan by including the second compound. As the first compound and the second compound do not diminish each other's characteristics, if (e.g., when) the first compound and the second compound are used as a mixture, at least one selected from among the driving voltage, luminescence efficiency, and lifespan may be improved (e.g., to provide the suitable driving voltage, luminescence efficiency, and lifespan), and the other characteristics may also be excellent or suitable, compared to if (e.g., when) only one selected from the first compound and the second compound is used.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims, and equivalents thereof.

What is claimed is:

1. A light-emitting device comprising:
a first electrode;
a second electrode facing the first electrode; and
an interlayer arranged between the first electrode and the second electrode and comprising an emission layer,
wherein the interlayer comprises: a first compound represented by Formula 1; and a second compound represented by Formula 2: 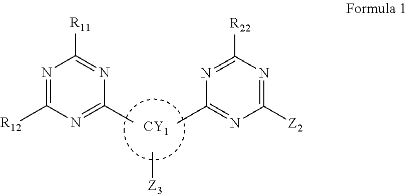
wherein, in Formula 1,
at least one selected from among Z₁ to Z₃ is a group represented by Formula TZ: 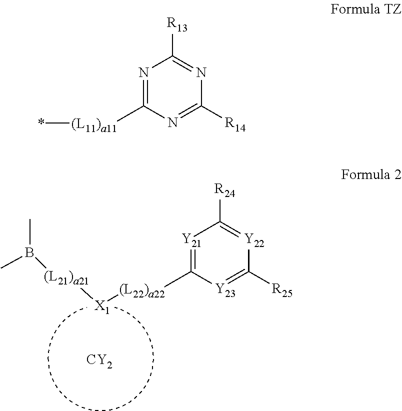
wherein, in Formula 1, Formula TZ, and Formula 2,
ring CY₁ is a C₃-C₃₀ carbocyclic group unsubstituted or substituted with at least one R₁₀ₐ or a C₁-C₃₀ heterocyclic group unsubstituted or substituted with at least one R₁₀ₐ,
ring CY₂ is a C₃-C₂₀ cycloalkyl group unsubstituted or substituted with at least one R₁₀ₐ,
X₁ is a carbon atom (C) that forms a ring of CY₂, and X₁ is bonded to four different atoms,
L₁₁, L₂₁, and L₂₂ are each independently a single bond, a C₃-C₃₀ carbocyclic group unsubstituted or substituted with at least one R₁₀ₐ, or a C₁-C₃₀ heterocyclic group unsubstituted or substituted with at least one R₁₀ₐ,
a11, a21, and a22 are each independently an integer of 1 to 5,
Y₂₁ is N or C(R₂₁), Y₂₂ is N or C(R₂₂), Y₂₃ is N or C(R₂₃), and at least one selected from among Y₂₁ to Y₂₃ is N,
Z₁ to Z₃, R₁₁ to R₁₄, and R₂₁ to R₂₇ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₂₆ and L₂₁ are optionally bonded to each other via a direct bond or *—O—*′ to form a C₁-C₃₀ heterocyclic group unsubstituted or substituted with at least one R₁₀ₐ,
R₂₇ and L₂₁ are optionally bonded to each other via a direct bond or *—O—*′ to form a C₁-C₃₀ heterocyclic group unsubstituted or substituted with at least one R₁₀ₐ,
R₂₆ and R₂₇ are optionally bonded to each other via a direct bond or *—O—*′ to form a C₁-C₃₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(032), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ each are a binding site to a neighboring atom.

2. The light-emitting device as claimed in claim 1, wherein the first compound and the second compound are mixed with each other.

3. The light-emitting device as claimed in claim 1, wherein the interlayer further comprises an electron transport region arranged between the emission layer and the second electrode, and
the electron transport region comprises the first compound and the second compound.

4. The light-emitting device as claimed in claim 1, wherein the interlayer comprises: a hole-transporting host comprising a group represented by Formula 3; an electron-transporting host comprising at least one π electron-deficient nitrogen-containing C₁-C₆₀ heterocyclic group; a sensitizer comprising a transition metal; a dopant comprising at least one cyclic group comprising boron and nitrogen each as a ring-forming atom; or any combination thereof, and
the first compound, the second compound, the hole-transporting host, the electron-transporting host, the sensitizer, and the dopant are different from each other: 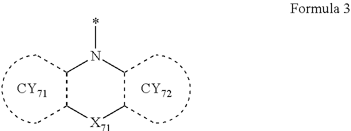
wherein, in Formula 3,
ring CY₇₁ and ring CY₇₂ are each independently a π electron-rich C₃-C₆₀ cyclic group or a pyridine group,
X₇₁ is a single bond or a linking group comprising O, S, N, B, C, Si, or any combination thereof, and
* is a binding site to any atom in the remaining part other than Formula 3 in the hole-transporting host.

5. The light-emitting device as claimed in claim 1, wherein one selected from among Z₁ to Z₃ is a group represented by Formula TZ.

6. The light-emitting device as claimed in claim 1, wherein the first compound comprises three triazine groups.

7. The light-emitting device as claimed in claim 1, wherein ring CY₁ is a C₆-C₆₀ aryl group unsubstituted or substituted with at least one R₁₀ₐ, a C₁-C₆₀ heteroaryl group unsubstituted or substituted with at least one R₁₀ₐ, a non-aromatic condensed polycyclic group unsubstituted or substituted with at least one R₁₀ₐ, or a non-aromatic condensed heteropolycyclic group unsubstituted or substituted with at least one R₁₀ₐ.

8. The light-emitting device as claimed in claim 1, wherein, in Formula 1, a group represented by 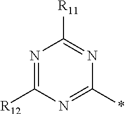
and a group represented by 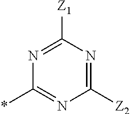
are in a meta relationship with respect to ring CY₁.

9. The light-emitting device as claimed in claim 1, wherein the first compound is represented by Formula 1-1: 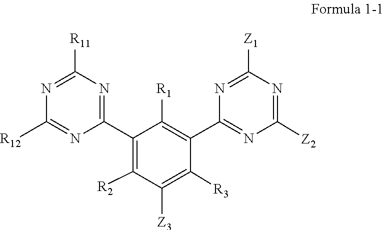
wherein, in Formula 1-1,
Z₁ to Z₃, R₁₁, and R₁₂ are each as claimed in connection with Formula 1, and
R₁ to R₃ are each as claimed in connection with R₁₀ₐ.

10. The light-emitting device as claimed in claim 1, wherein i) when Z₁ or Z₂ in Formula 1 is a group represented by Formula TZ, L₁₁ is a C₃-C₃₀ carbocyclic group unsubstituted or substituted with at least one R₁₀ₐ or a C₁-C₃₀ heterocyclic group unsubstituted or substituted with at least one R₁₀ₐ, and
ii) when Z₃ in Formula 1 is a group represented by Formula TZ, L₁₁ is a single bond.

11. The light-emitting device as claimed in claim 1, wherein L₁₁, L₂₁, and L₂₂ are each independently a single bond, a C₆-C₆₀ aryl group unsubstituted or substituted with at least one R₁₀ₐ, a C₁-C₆₀ heteroaryl group unsubstituted or substituted with at least one R₁₀ₐ, a non-aromatic condensed polycyclic group unsubstituted or substituted with at least one R₁₀ₐ, or a non-aromatic condensed heteropolycyclic group unsubstituted or substituted with at least one R₁₀ₐ.

12. The light-emitting device as claimed in claim 1, wherein L₁₁, L₂₁, and L₂₂ are each independently a single bond or a group represented by any one selected from among Formulae BZ1 to BZ3: 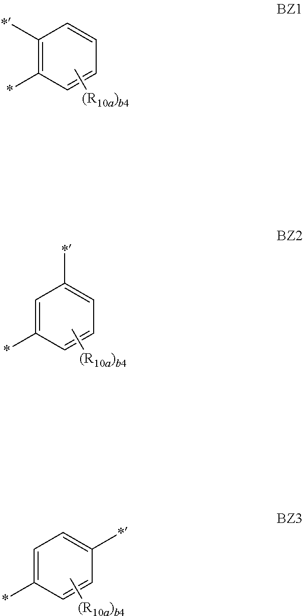
wherein, in Formulae BZ1 to BZ3,
R₁₀ₐ, *, and *′ are each as claimed in claim 1, and
b4 is an integer of 0 to 4.

13. The light-emitting device as claimed in claim 1, wherein, in Formula 1, R₁ to R₁₄ and Z₁ to Z₃ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a phenyl group unsubstituted or substituted with at least one R₁₀ₐ, a pyridinyl group unsubstituted or substituted with at least one R₁₀ₐ, or a pyrimidinyl group unsubstituted or substituted with at least one R₁₀ₐ.

14. The light-emitting device as claimed in claim 1, wherein ring CY₂ is a cyclopentyl group unsubstituted or substituted with at least one R₁₀ₐ, a cyclohexyl group unsubstituted or substituted with at least one R₁₀ₐ, a cycloheptyl group unsubstituted or substituted with at least one R₁₀ₐ, a cyclooctyl group unsubstituted or substituted with at least one R₁₀ₐ, a norbornanyl group unsubstituted or substituted with at least one R₁₀ₐ, or an adamantanyl group unsubstituted or substituted with at least one R₁₀ₐ.

15. The light-emitting device as claimed in claim 1, wherein the second compound is represented by Formula 2-1: 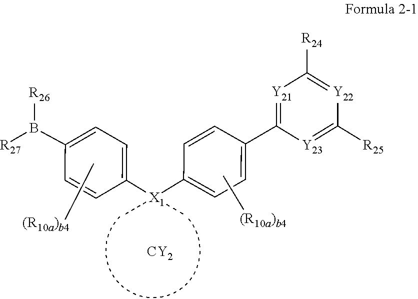
wherein, in Formula 2-1, ring CY₂, X₁, L₂₁, L₂ a21, a22, Y₂₁ to Y₂₃, R₂₄ to R₂₇, and R₁₀ₐ are each as claimed in claim 1, and
b4 is an integer of 0 to 4.

16. The light-emitting device as claimed in claim 1, wherein, in Formula 2, R₂₁ to R₂₇ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a phenyl group unsubstituted or substituted with at least one R₁₀ₐ, a naphthyl group unsubstituted or substituted with at least one R₁₀ₐ, a fluorenyl group unsubstituted or substituted with at least one R₁₀ₐ, a carbazolyl group unsubstituted or substituted with at least one R₁₀ₐ, a dibenzofuranyl group unsubstituted or substituted with at least one Rio, or a dibenzothiophenyl group unsubstituted or substituted with at least one R₁₀ₐ.

17. The light-emitting device as claimed in claim 1, wherein a ratio between a weight of the first compound and a weight of the second compound is 3:7 to 7:3.

18. The light-emitting device as claimed in claim 1, wherein the first compound is any one selected from among Compounds A₁ to A₆₀, and the second compound is any one selected from among Compounds B1 to B64:

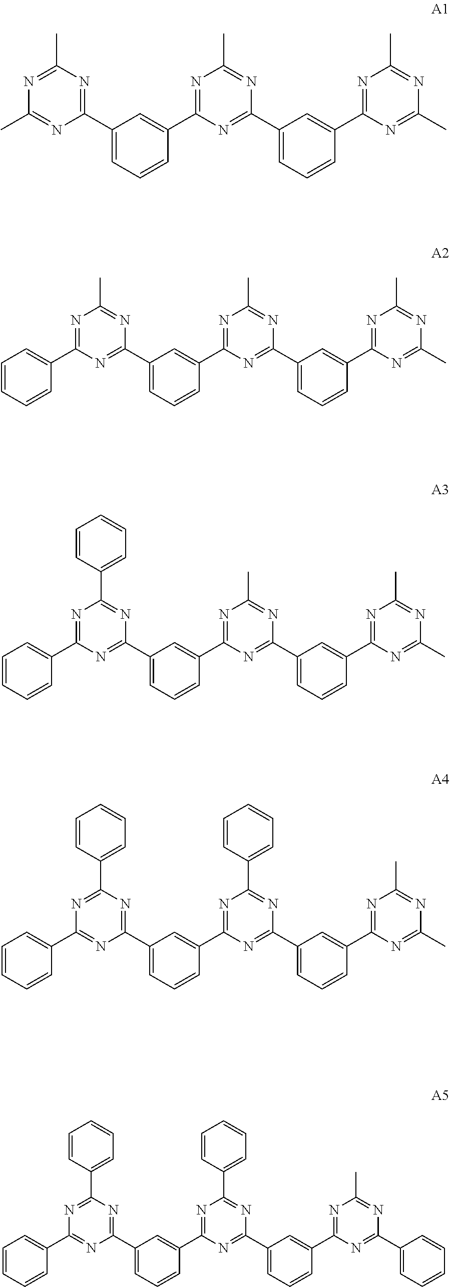

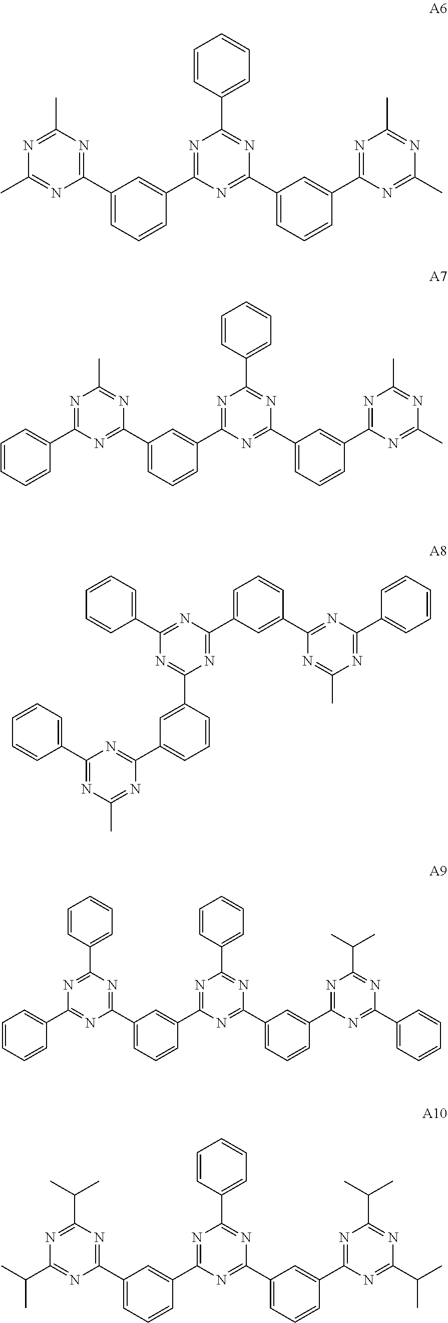

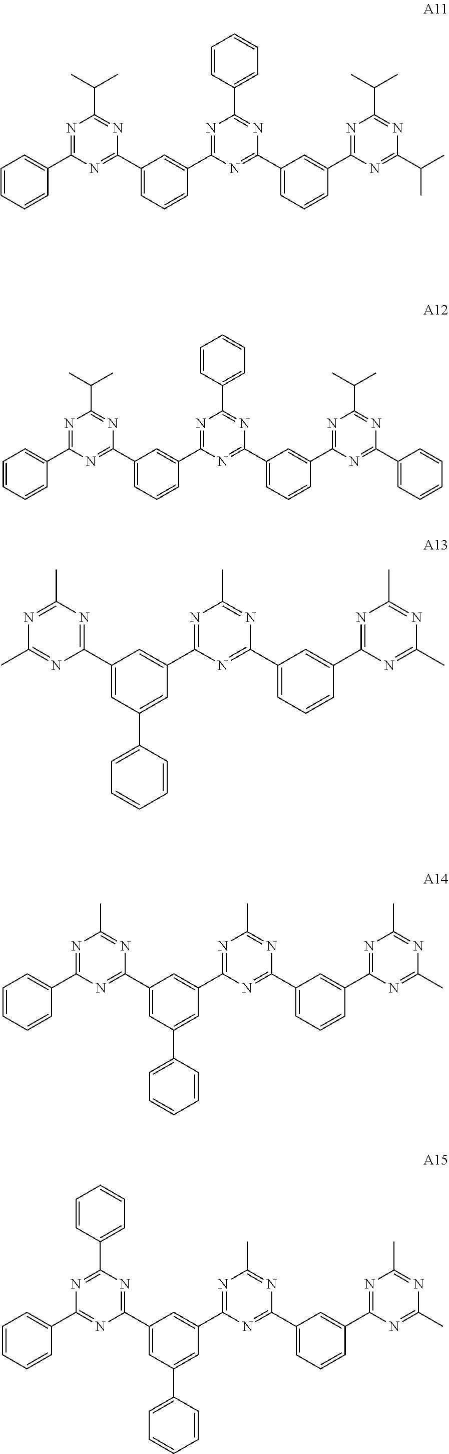

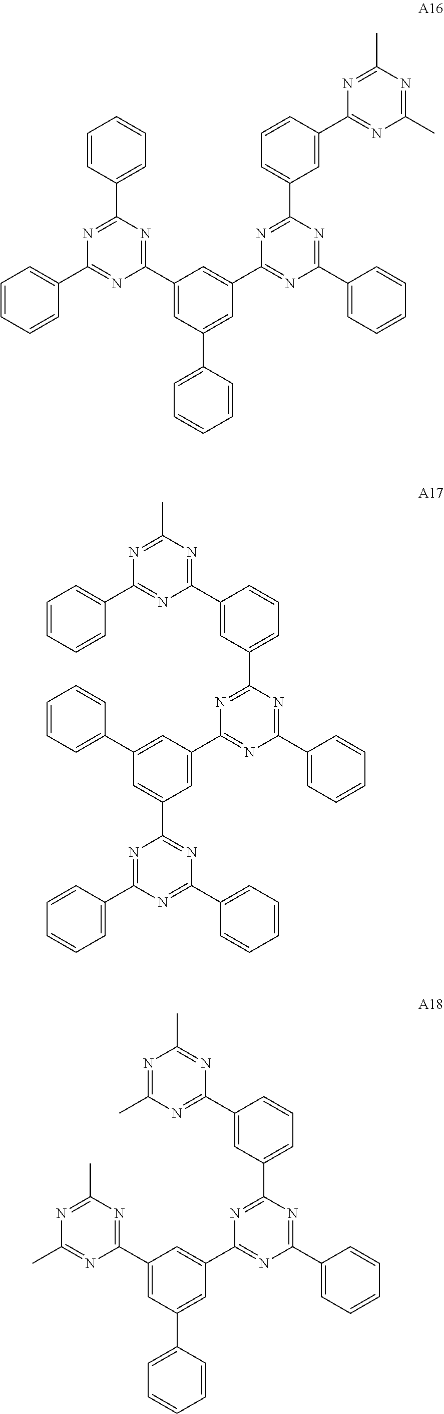

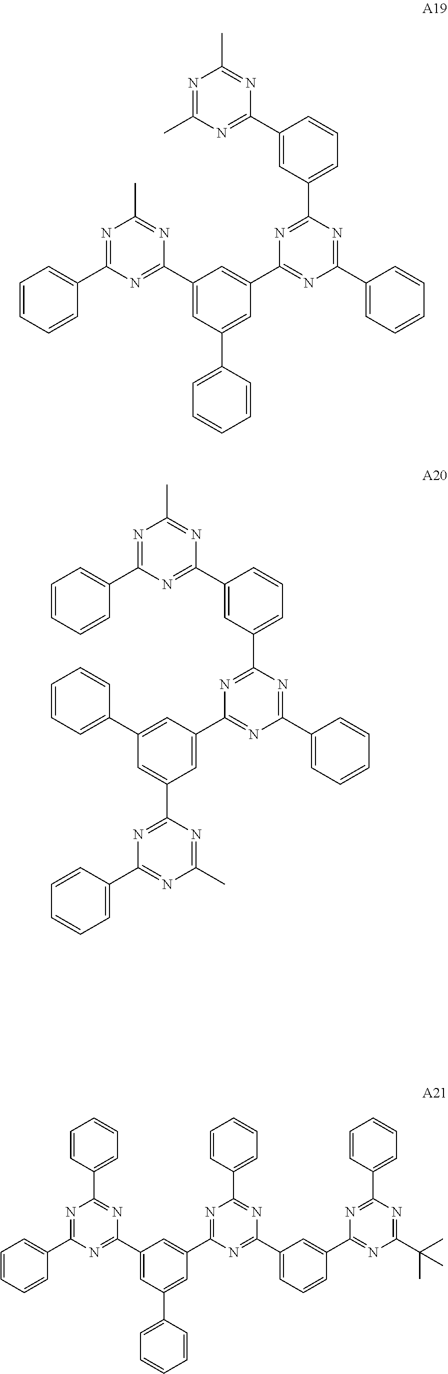 [SMILES: Cc1nc(C)nc(-c2cccc(-c3nc(-c4ccccc4)nc(-c4cc(-c5ccccc5)cc(-c5nc(C)nc(-c6ccccc6)n5)c4)n3)c2)n1 ; Cc1nc(-c2ccccc2)nc(-c2cccc(-c3nc(-c4ccccc4)nc(-c4cc(-c5ccccc5)cc(-c5nc(C)nc(-c6ccccc6)n5)c4)n3)c2)n1 ; CC(C)(C)c1nc(-c2ccccc2)nc(-c2cccc(-c3nc(-c4ccccc4)nc(-c4cc(-c5ccccc5)cc(-c5nc(-c6ccccc6)nc(-c6ccccc6)n5)c4)n3)c2)n1]

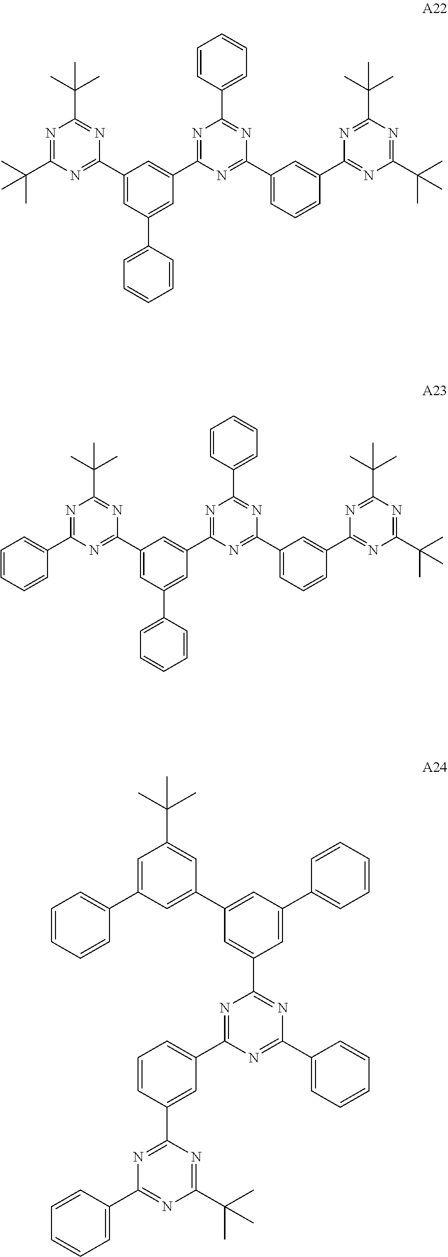 [SMILES: CC(C)(C)c1nc(-c2cccc(-c3nc(-c4ccccc4)nc(-c4cc(-c5ccccc5)cc(-c5nc(C(C)(C)C)nc(C(C)(C)C)n5)c4)n3)c2)nc(C(C)(C)C)n1 ; CC(C)(C)c1nc(-c2ccccc2)nc(-c2cc(-c3ccccc3)cc(-c3nc(-c4ccccc4)nc(-c4cccc(-c5nc(C(C)(C)C)nc(C(C)(C)C)n5)c4)n3)c2)n1 ; CC(C)(C)c1cc(-c2ccccc2)cc(-c2cc(-c3ccccc3)cc(-c3nc(-c4ccccc4)nc(-c4cccc(-c5nc(-c6ccccc6)nc(C(C)(C)C)n5)c4)n3)c2)c1]

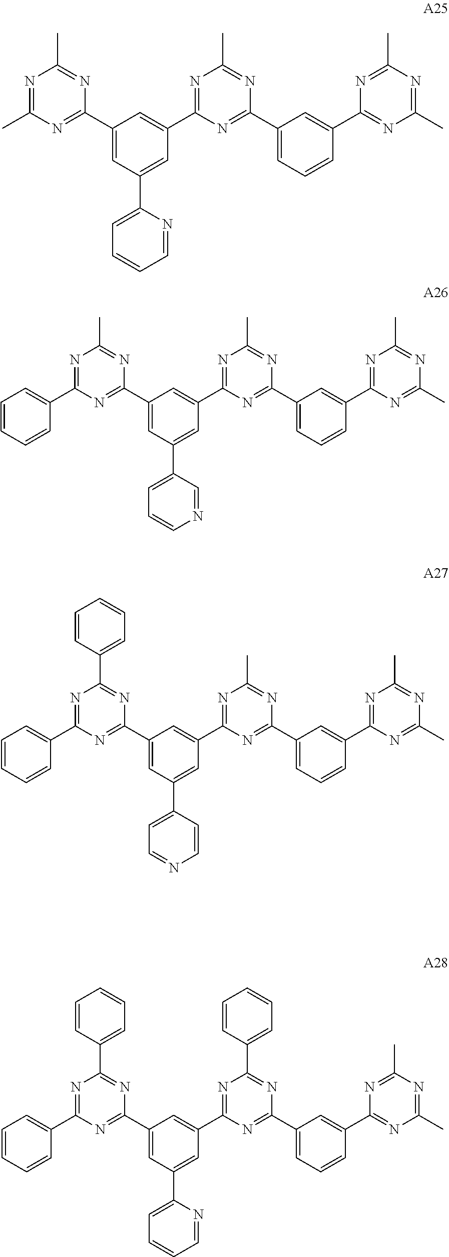

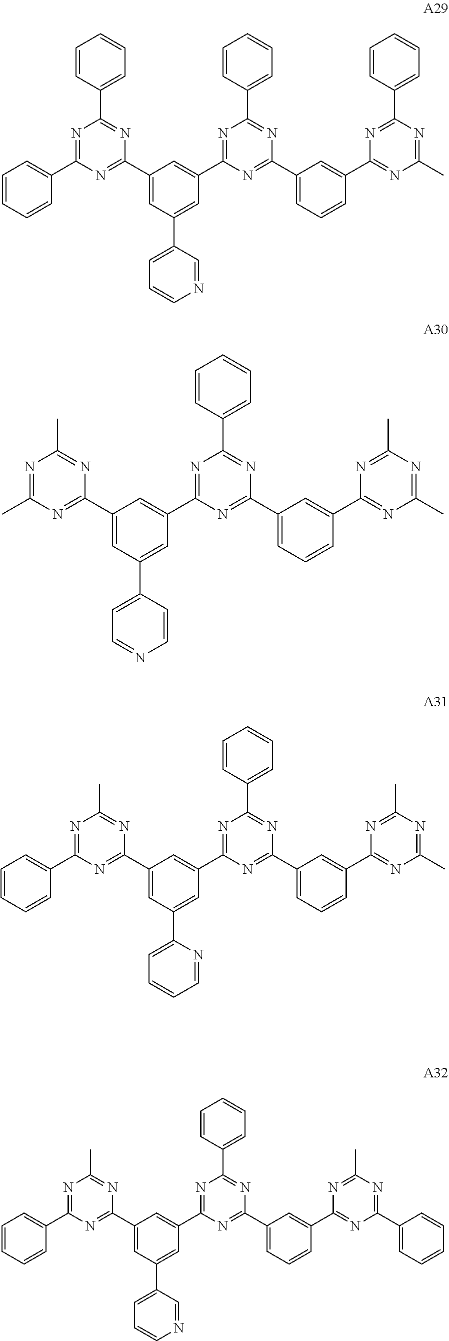

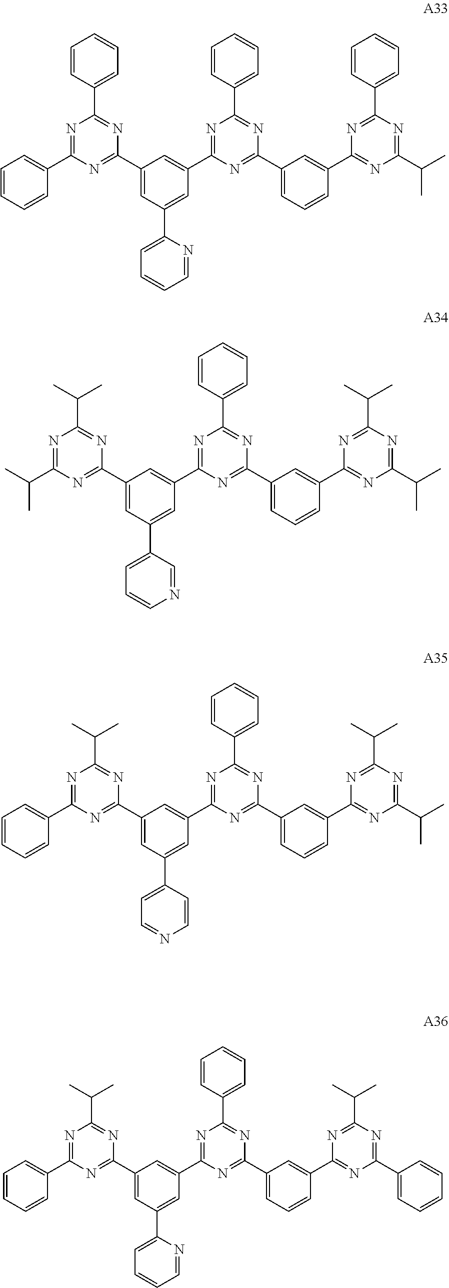

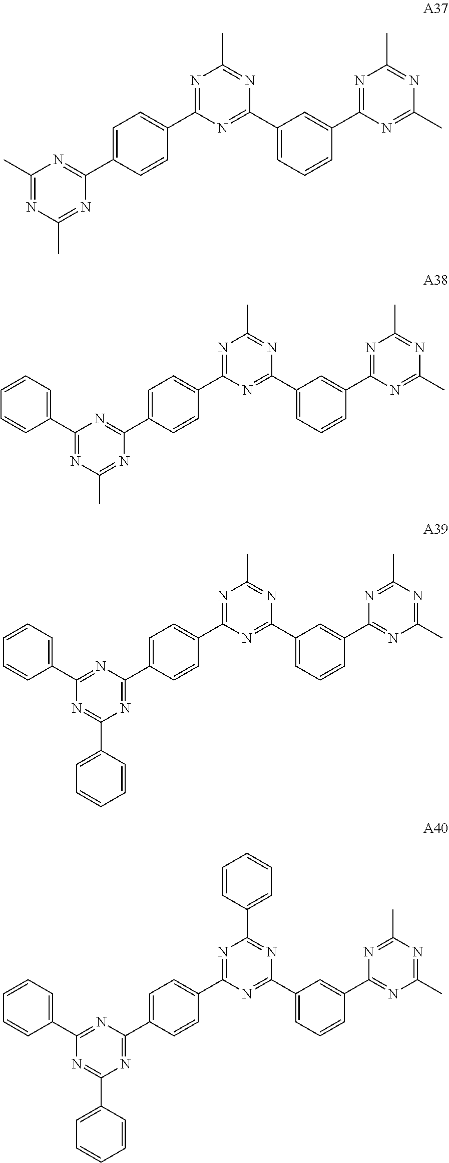

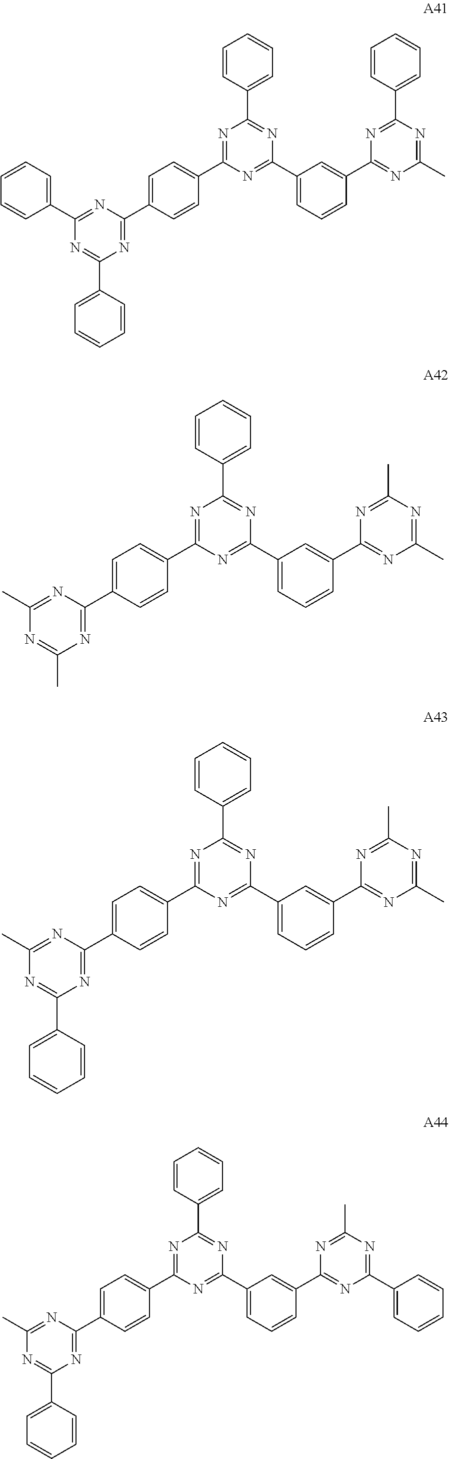

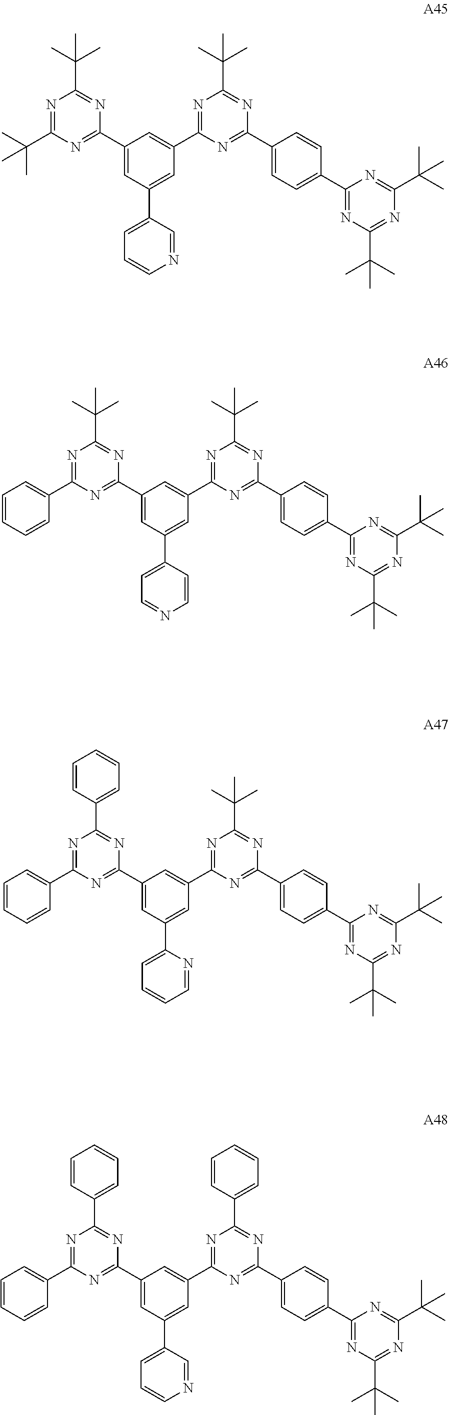 [SMILES: CC(C)(C)c1nc(-c2ccc(-c3nc(C(C)(C)C)nc(C(C)(C)C)n3)cc2)nc(-c2cc(-c3cccnc3)cc(-c3nc(C(C)(C)C)nc(C(C)(C)C)n3)c2)n1 ; CC(C)(C)c1nc(-c2ccccc2)nc(-c2cc(-c3ccncc3)cc(-c3nc(-c4ccc(-c5nc(C(C)(C)C)nc(C(C)(C)C)n5)cc4)nc(C(C)(C)C)n3)c2)n1 ; CC(C)(C)c1nc(-c2ccc(-c3nc(C(C)(C)C)nc(C(C)(C)C)n3)cc2)nc(-c2cc(-c3ccccn3)cc(-c3nc(-c4ccccc4)nc(-c4ccccc4)n3)c2)n1 ; CC(C)(C)c1nc(-c2ccc(-c3nc(-c4ccccc4)nc(-c4cc(-c5cccnc5)cc(-c5nc(-c6ccccc6)nc(-c6ccccc6)n5)c4)n3)cc2)nc(C(C)(C)C)n1]

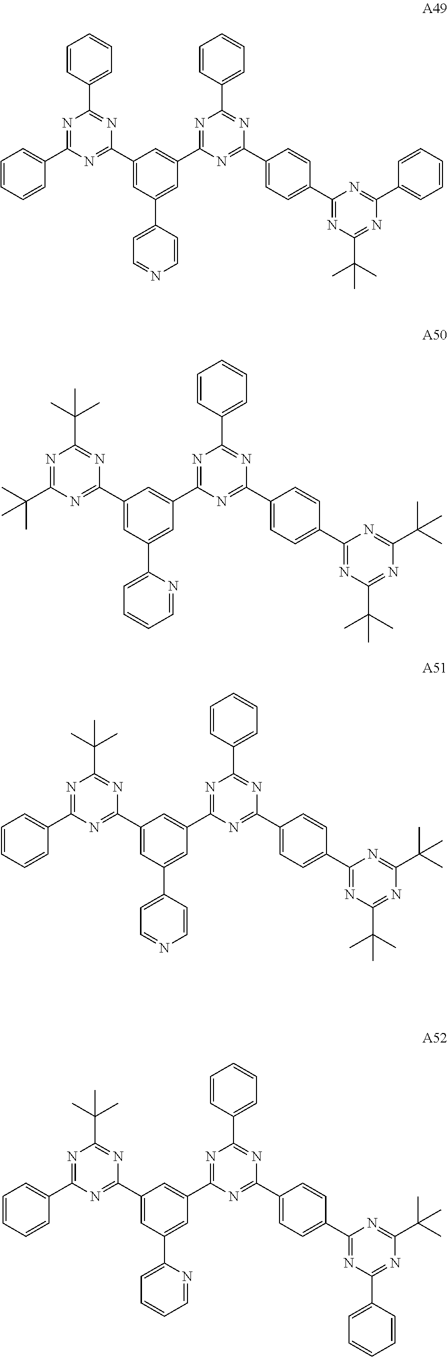 [SMILES: CC(C)(C)c1nc(-c2ccccc2)nc(-c2ccc(-c3nc(-c4ccccc4)nc(-c4cc(-c5ccncc5)cc(-c5nc(-c6ccccc6)nc(-c6ccccc6)n5)c4)n3)cc2)n1 ; CC(C)(C)c1nc(-c2ccc(-c3nc(-c4ccccc4)nc(-c4cc(-c5ccccn5)cc(-c5nc(C(C)(C)C)nc(C(C)(C)C)n5)c4)n3)cc2)nc(C(C)(C)C)n1 ; CC(C)(C)c1nc(-c2ccccc2)nc(-c2cc(-c3ccncc3)cc(-c3nc(-c4ccccc4)nc(-c4ccc(-c5nc(C(C)(C)C)nc(C(C)(C)C)n5)cc4)n3)c2)n1 ; CC(C)(C)c1nc(-c2ccccc2)nc(-c2ccc(-c3nc(-c4ccccc4)nc(-c4cc(-c5ccccn5)cc(-c5nc(-c6ccccc6)nc(C(C)(C)C)n5)c4)n3)cc2)n1]

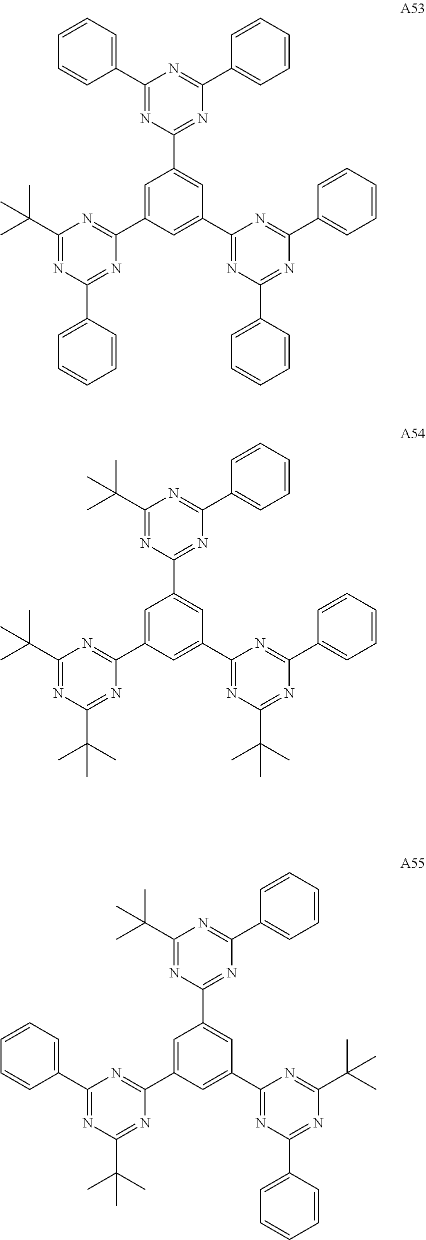 [SMILES: CC(C)(C)c1nc(-c2ccccc2)nc(-c2cc(-c3nc(-c4ccccc4)nc(-c4ccccc4)n3)cc(-c3nc(-c4ccccc4)nc(-c4ccccc4)n3)c2)n1 ; CC(C)(C)c1nc(-c2ccccc2)nc(-c2cc(-c3nc(-c4ccccc4)nc(C(C)(C)C)n3)cc(-c3nc(C(C)(C)C)nc(C(C)(C)C)n3)c2)n1 ; CC(C)(C)c1nc(-c2ccccc2)nc(-c2cc(-c3nc(-c4ccccc4)nc(C(C)(C)C)n3)cc(-c3nc(-c4ccccc4)nc(C(C)(C)C)n3)c2)n1]

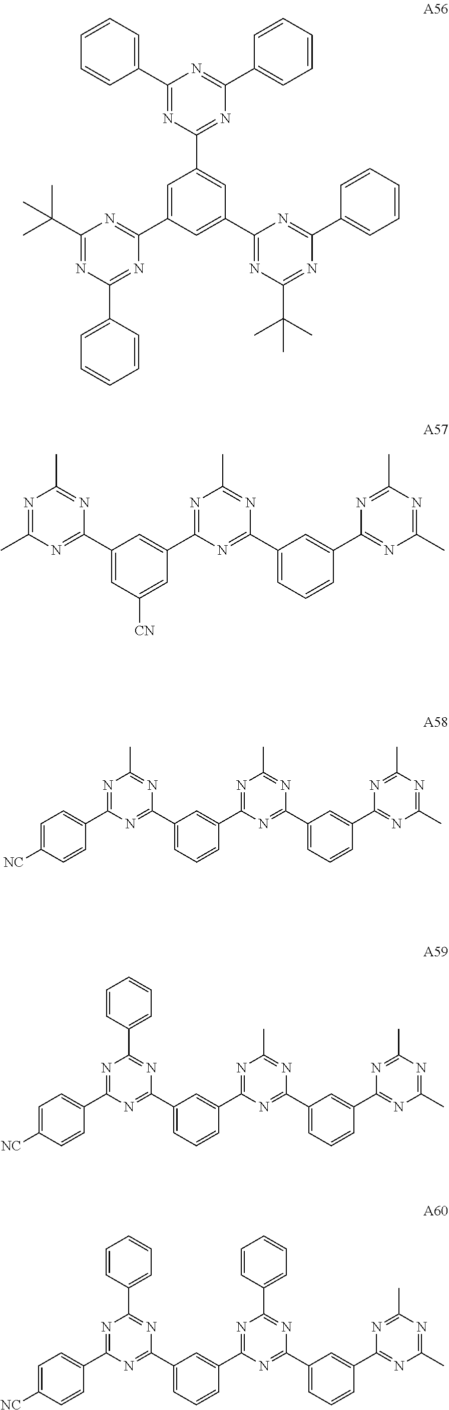

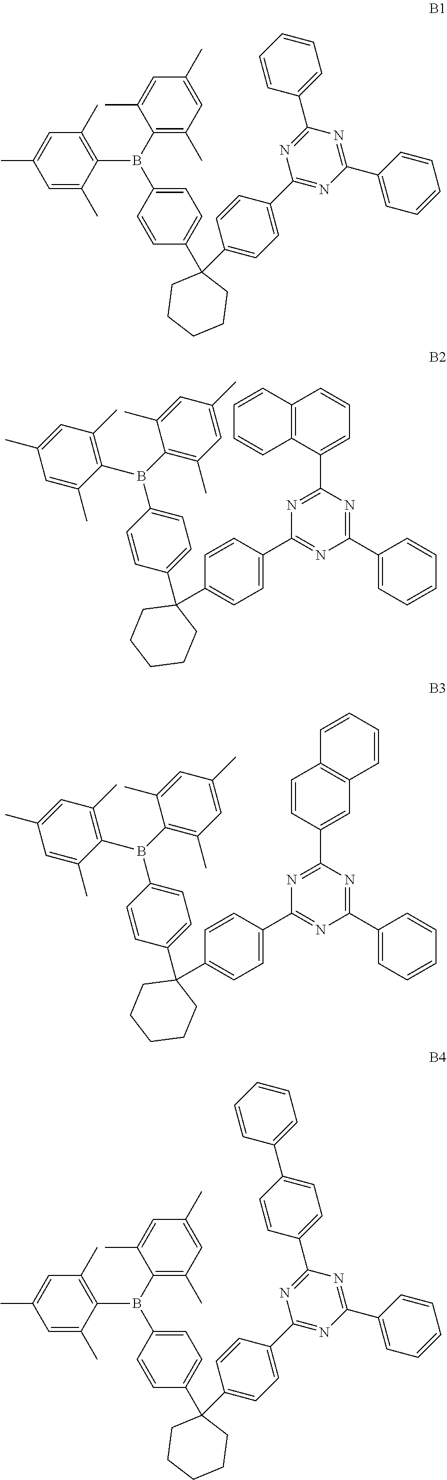 [SMILES: Cc1cc(C)c(B(c2ccc(C3(c4ccc(-c5nc(-c6ccccc6)nc(-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cccc7ccccc67)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc(-c7ccccc7)cc6)n5)cc4)CCCCC3)cc2)c2c(C)cc(C)cc2C)c(C)c1]

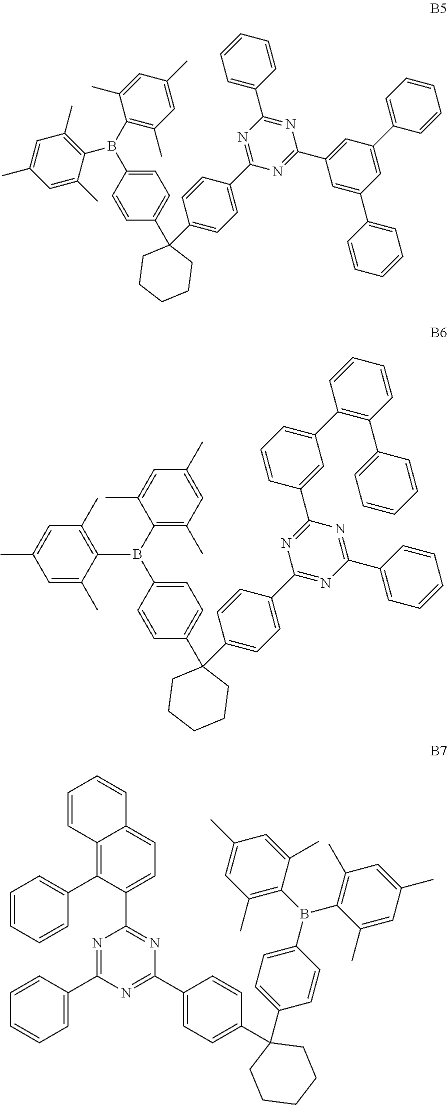 [SMILES: Cc1cc(C)c(B(c2ccc(C3(c4ccc(-c5nc(-c6ccccc6)nc(-c6cc(-c7ccccc7)cc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6-c6ccccc6)n5)cc4)CCCCC3)cc2)c2c(C)cc(C)cc2C)c(C)c1]

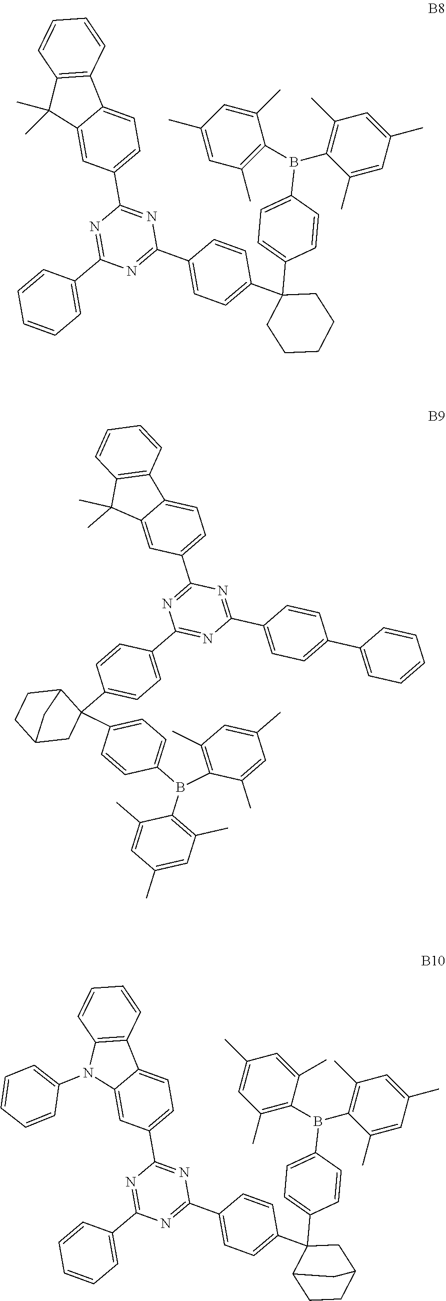

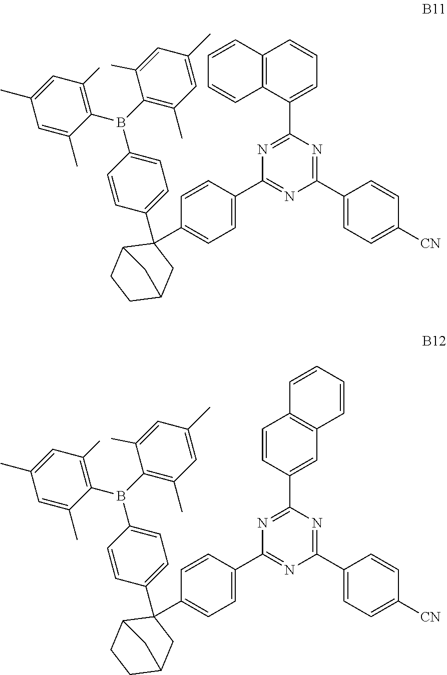 [SMILES: Cc1cc(C)c(B(c2ccc(C3(c4ccc(-c5nc(-c6ccc(C#N)cc6)nc(-c6cccc7ccccc67)n5)cc4)CC4CCC3C4)cc2)c2c(C)cc(C)cc2C)c(C)c1 ; Cc1cc(C)c(B(c2ccc(C3(c4ccc(-c5nc(-c6ccc(C#N)cc6)nc(-c6ccc7ccccc7c6)n5)cc4)CC4CCC3C4)cc2)c2c(C)cc(C)cc2C)c(C)c1]

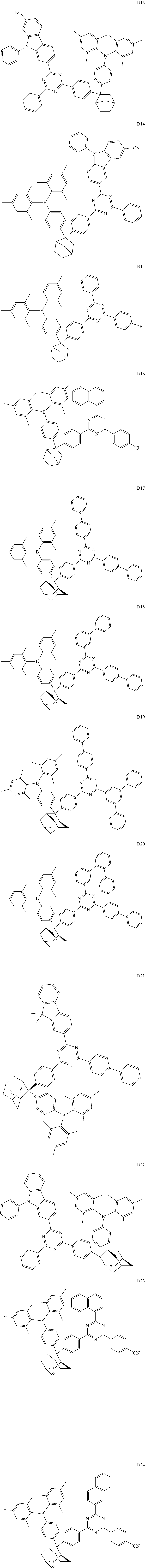

[chemical structure]

[chemical structure]

[chemical structure]

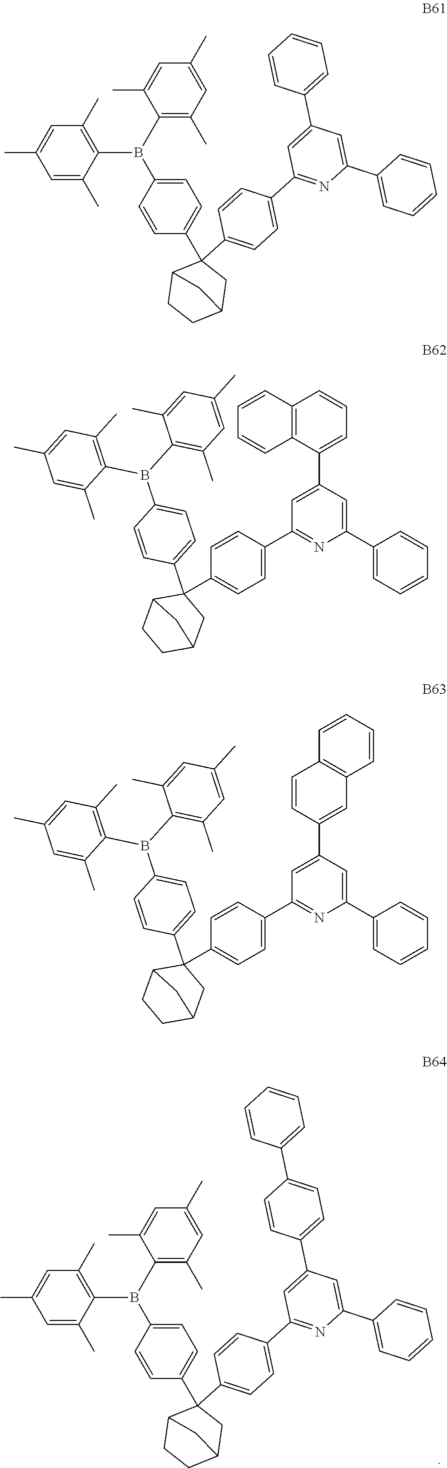 [SMILES: Cc1cc(C)c(B(c2ccc(C3(c4ccc(-c5cc(-c6ccccc6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cccc7ccccc67)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc7ccccc7c6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc(-c7ccccc7)cc6)cc(-c6ccccc6)n5)cc4)CC4CCC3C4)cc2)c2c(C)cc(C)cc2C)c(C)c1]

19. An electronic apparatus comprising:
the light-emitting device as claimed in claim 1; and
a thin-film transistor electrically connected to the light-emitting device.

20. Electronic equipment comprising the light-emitting device as claimed in claim 1, wherein the electronic equipment is one selected from among a flat panel display, a curved display, a computer monitor, a medical monitor, a television, a billboard, an indoor or outdoor light, an indoor or outdoor light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with a plurality of displays tiled together, a theater or stadium screen, a phototherapy device, and a signboard.
